(19) United States
(12) Patent Application Publication
(10) Pub. No.: US 2025/0093316 A1
(43) Pub. Date: Mar. 20, 2025

(54) SENSORS AND SENSING METHODS

(71) Applicant: James J. Myrick, Saint Augustine, FL (US)

(72) Inventor: James J. Myrick, Saint Augustine, FL (US)

(21) Appl. No.: 18/958,951

(22) Filed: Nov. 25, 2024

Related U.S. Application Data
(63) Continuation of application No. 18/306,176, filed on Apr. 24, 2023, now abandoned.
Application No. 18/306,176 is a continuation of application No. 16/877,399, filed on May 18, 2020, now abandoned.
Application No. 16/877,399 is a continuation-in-part of application No. 16/014,875, filed on Jun. 21, 2018, now abandoned.
Application No. 16/014,875 is a continuation-in-part of application No. 15/714,078, filed on Sep. 25, 2017, now abandoned.
Application No. 16/014,875 is a continuation-in-part of application No. 15/091,344, filed on Apr. 5, 2016, now abandoned.
Application No. 15/714,078 is a continuation-in-part of application No. 14/261,416, filed on Apr. 24, 2014, now abandoned.
Application No. 14/261,416 is a continuation-in-part of application No. 13/525,351, filed on Jun. 17, 2012, now abandoned.
(60) Provisional application No. 62/439,432, filed on Dec. 27, 2016.
(60) Provisional application No. 62/276,751, filed on Jan. 8, 2016.
(60) Provisional application No. 62/143,124, filed on Apr. 5, 2015.
(60) Provisional application No. 61/815,706, filed on Apr. 24, 2013.
(60) Provisional application No. 61/498,513, filed on Jun. 17, 2011.

(51) Int. Cl. G01N 31/22; G01N 27/12; H01L 31/107

(52) U.S. Cl. CPC G01N 31/223; G01N 27/129; H10F 30/225

(57) ABSTRACT

Sensors and sensing methods are provided which can be highly sensitive but relatively inexpensive and small, which are suitable for uses such UAVs, distributed field monitors, medical diagnosis, and environmental monitoring. Various of these sensors can be characterized by one or more features which produce extreme insect antenna sensitivity and identification capability for chemical analytes.

### CROSS REFERENCE TO RELATED APPLICATIONS

This application is a continuation of U.S. patent application Ser. No. 18/306,176, filed Apr. 24, 2023, which was a continuation of U.S. patent application Ser. No. 16/877,399, filed May 18, 2020, which was a continuation-in-part of U.S. patent application Ser. No. 15/714,078 filed Sep. 25, 2017, which claimed the benefit of priority from U.S. Provisional Application No. 62/439,432 filed on Dec. 27, 2016 and was a continuation-in-part of U.S. patent application Ser. No. 14/261,416 filed on Apr. 24, 2014, which claimed the benefit of priority from U.S. Provisional Application No. 61/815,706 filed on Apr. 24, 2013 and was also a continuation-in-part of U.S. patent application Ser. No. 13/525,351 filed on Jun. 17, 2012, now abandoned, which claimed the benefit of priority from U.S. Provisional Application No. 61/498,513 filed on Jun. 17, 2011; U.S. patent application Ser. No. 16/877,399 is also a continuation-in-part of U.S. application Ser. No. 16/014,875 filed Jun. 21, 2018, which is a continuation-in-part of U.S. patent application Ser. No. 15/091,344 filed Apr. 5, 2016, which claimed the benefit of U.S. Provisional Application Nos. 62/276,751 and 62/143,124 filed Jan. 8, 2016 and Apr. 5, 2015 respectively and is a continuation-in-part U.S. patent application Ser. No. 14/261,416, mentioned above. The disclosures of each of these related applications described above are incorporated herein by reference.

### FIELD OF THE INVENTION

The present invention is directed to sensors, and more particularly to sensors and sensing methods for detecting analytes in gases and liquids. The sensors can have biomimetic characteristics together with multiple functions, such as imaging, analyte detection and analyte differentiation.

### BACKGROUND OF THE INVENTION

Biological “sense of smell” insect and mammalian olfactory systems produce exquisite sensitivity despite being based on thousands or millions of “noisy”, energetically metastable or unstable (“hair trigger”) neural sensors. For example, energetically-charged sensilla along insect antennae are triggered like mousetraps by the presence of odorant molecules at selective neuron ion channels. Statistical processing by the tiny insect “brain” of many signal pulses from tens of thousands of “noisy” olfactory sensilla removes their “noise”, distinguishes different odors, and generates overall extreme sensitivity.

Insect sensilla have selective odorant-binding proteins which capture specific types of odorant molecules and transport them to selective olfactory neuron ion channels. Upon binding to a neuron ion channel, the odorant activates an electrochemical cascade which causes the neuron to “fire” an action potential to the insect brain, to signal the detection of that individual odorant molecule¹. To permit fast sensilla recovery for continuous sensing, odorant molecules are removed by enzymes, with an odorant molecule half-life probably in the millisecond range² and the olfactory neurons are electrochemically recharged by biological processes.

Insect sensilla have a variety of differently sensitive olfactory receptors. These different receptors produce different responses to different odorants, in olfactory neurons connecting to specific parts of the insect “brain” where specific odors are identified³. Insects also “pulse” and sensilla gas analyte concentration over their sensilla at rest and in flight, by wing-flapping (the analog of “sniffing”)⁴. This may function to temporarily concentrate, or “pulse” odorant on the receptors. Perhaps with signals from antennal mechanicoreceptors sensing wing flap air, insect brain “attention” is heightened at times when odorant concentration should be highest, in a manner similar to the signal selection of a lock-in amplifier.

After “firing” an action potential, insect olfactory neurons quickly recharge to their energetically unstable “hair trigger” state after a short quiescent period. Such olfactory neurons may typically fire and then recharge to an energetically unstable “hair trigger” state, for example at a rate in the range of about 5-50 action potentials per second, the rate increasing with odorant concentration. The olfactory neurons are so “hair-triggered” that they can still “fire” at low rates even in the absence of any odorant, producing random “dark current” events. But despite such random “dark current” firings, the simple insect brain can statistically process the combined input of tens of thousands of olfactory neurons having a variety of odorant sensitivities, to achieve remarkably sensitive detection and identification. Overall sensitivity can be so high that only a few pheromone molecules can guide insect flight direction and other behavior.

Mammalian olfaction is similarly remarkable. The human olfactory epithelium contains about 10 million olfactory neurons over an approximately 4 cm² area. The 2004 Nobel Prize winners Linda Buck and Richard Axel identified ˜1000 mammalian genes which encode about 1000 different olfactory receptors (some not used) that can each be expressed individually in one of these millions of olfactory receptor neurons. The “hair triggered” outputs of many neurons with each type of olfactory receptors are summed and subsequently processed with other differently-sensitive neuron composites, for odorant recognition.

Semiconductor Metal Oxide (MOX) Sensors of high-bandgap semiconductors such as Sn, Ti, In, Zn, Hf, W and similar oxides are conventionally used for gas detection. Heated semiconductor metal oxide sensors (“MOX”) are conventionally used for detection and identification of a wide variety of analytes, including hydrocarbons, explosives and chemical warfare agents⁵. Sensors of different compositions (based on ZnO, SnO2, TiO2, MoO3, WO3, etc) and doping have enhanced sensitivities to different organic molecule analytes. N-type and P-type sensors also have different sensitivities to oxidizing and reducing gases⁶.

MOX analyte detection is typically conductimetric, but optical⁷, FET⁸ and capacitive sensing are also used conventionally. Electrical conductivity of metal oxide gas sensors varies with the concentration of an analyte to which they are sensitive as a result of modulation by analyte gas of the surface and intergrain potential barrier. The conductivity is believed to be affected by surface and grain boundary depletion regions, caused by negative oxygen-induced charge which is reduced by adsorption and combustion of the analyte gas. Because the detector response is dominated by grain boundaries, sensitivity in conventional designs can be increased by designing sensors with large surface area to volume ratios, small nanoscale crystal sizes and 1- or 2-dimensional structures (nanotubes, nanorods and nanothin films) so that the variable depletion regions dominate sensor behavior⁹.

Displacement and removal of oxygen and electrons by gas adsorption and combustion reduces the negative charge responsible for the depletion region, and thereby increases conductivity. Similarly, conductivity can be reduced by gas analyte reactions (see Endnotes/cited references).

Catalytic sensors typically have optimum reaction temperatures for specific gases, and most are typically heated in order to combust the gas analytes. Analytes generally adsorb more strongly at lower temperature, so optimum response occurs at a balance between minimizing the oxidation combustion temperature without causing excessive analyte desorption. For thicker gas detectors, diffusion increases the response times to minutes. But thinner nanoscale detectors still have relatively long response times to equilibrate. The adsorption, desorption and surface oxidation reaction rates have been estimated for simple reactant gases H₂ and CO on typical SnO₂ surfaces at a conventional elevated sensor temperature¹⁰.

In typical n-type heated gas sensors, organoanalyte combustion reduces the external negative surface charge, thereby reducing the semiconductor grain boundary depletion region, and increasing the conductivity. Unfortunately the response time of catalytic oxide sensors is notoriously slow. The sensitivity of MOX sensors also needs to be improved for many industrial, public safety and defense applications such as explosive and chemical agent detection. As noted, the present disclosure provides a variety of ways to decrease the MOX sensor response time, and decrease (or reduce the effects of) the MOX sensor recovery time. Illustrated embodiments of the present disclosure use electron transport directly through nanothin sheets, rather than along multigrain resistive paths. Buried grain boundaries are minimized to minimize extended oxygen diffusion times. The effects of long-lived surface hole traps are “designed around” or utilized for signal amplification. Short IR pulses at the hole trap energy can be used with an electric field to speed equilibrium recovery, if appropriate.

In order to reduce the operating temperature required for combustion sensitivity, recent gas sensor work has applied a continuous ultraviolet light to generate holes and electrons at reduced temperatures¹¹. It is noted that wide bandgap semiconductor oxides such as TiO₂ (˜3.2 eV/380 nm for anatase and ˜3.0 eV/410 nm for rutile) can utilize ultraviolet radiation to completely mineralize organic materials at ambient temperatures¹².

Resistively heated temperature modulation of fine-grained MOX sensors has also been used to decrease power requirements and improve sensor response¹³, but the heating cycle times are relatively long compared to individual gas molecule reaction times.

Another conventional approach to increasing the sensitivity of catalytic oxide gas detectors is to characterize the “noise” of the detector response¹⁴. This “noise” may be the result of fluctuations in conductivity resulting from adsorption, desorption and combustion of individual analyte molecules. “Bispectral noise” is typically in the 10 Hz-to-2 KHz frequency range, which is consistent with redox reaction timescales in the millisecond+ range.

The characteristics of MOX materials, including their grain-boundary depletion region structure, also enables use of metal oxides as varistors for surge protection of electronics¹⁵. The grain boundaries form back-to-back diode pairs having high electrical resistance at low voltage¹⁶. However, when a high voltage is applied, the diode junction breaks down at a characteristic breakdown field. Breakdown voltage thresholds can range from about 30V/cm to about 20,000V/cm¹⁷. The current conducted by a metal oxide varistor is very highly nonlinear, with a very high resistance at low voltages and a very low resistance at high voltages, eg, I∝V^{α} where the current I is proportional to the applied voltage V, to a power factor α. The power factor α can range from about 5 up to 50 or more. When subjected to a very fast, <1 ns rise-time voltage transient greater than the breakdown voltage, the breakdown response time for a MOV can be in the 40-60 ns range. Varistor behavior and compositions can provide useful information for nanothin MOX layer design.

Such MOX gas sensors such as sensor 100 illustrated in FIG. 1 are relatively crude and insensitive, compared to insect sensilla and antennal responses. Such MOX sensors typically comprise a crystallized layer 102 of metal oxide grains 104 between electrodes 110, 112 on a heated substrate 108 for operation under steady-state conditions at elevated temperatures. Surface oxygen creates a negative surface charge on n-type MOX sensors, which produces thin (˜several debye-length) depletion layers 106 with reduced electrical conductivity at surfaces and intergrain boundaries¹⁸. Reaction (chemisorption and combustion) of an analyte gas removes negative surface oxygen species and injects electrons into the surface zones, increasing gross averaged conductivity measured through many MOX grain boundaries, as schematically illustrated in FIG. 1. Both reaching conductivity equilibrium with analyte gas concentration, and recovery processes are slow in conventional MOX sensors.

Moreover, measured gross conductivity change across extended boundaries with long reaction time constants merely “averages” and effectively dilutes individual molecular reaction events over time and distance. Sharp reaction peaks of localized gas molecule surface reaction are lost. Typically, MOX sensors are also compromised in detection and recovery times under such steady state measurement conditions, because of cross-interference of different timescales for electronic and chemical activation, adsorption, diffusion, reaction and detrapping times. The timescales of the various physical and chemical processes affecting conventional MOX sensor behavior can vary from nanoseconds to minutes. Some aspects of the illustrated embodiments herein focus on isolating the timescale-range gas analyte reactions, and shortening or avoiding the effects of long second-to-minutes MOX recovery times, to maximize sensor response.

Detecting liquid¹⁹ and gas phase²⁰ analytes as described herein is important for security, biomarker detection, environmental monitoring, food palatability and safety, industrial process control, and other analytical applications. Compact, high-performance “sense of smell” sensors described herein open up medical²¹, environmental²², hazardous manufacturing, plant badge/safety-security-identification²³, new smartphone²⁴ personal health and environmental monitoring applications. Optical sensors can provide a high degree of accuracy and specificity²⁵, and near-field resonant devices such as plasmonic optical biosensors²⁶ can be used to strengthen optical interaction with the sample. Surface plasmons can propagate on the surface of a smooth metal film and are often used for biosensing, while metallic nanostructures offer subwavelength control of optical fields²⁷. Plasmons are extremely sensitive to surface changes and show significant potential for on-chip integration, low cost processing, and massive sensor parallelization. Plasmons can provide surface enhanced effects for Raman spectroscopy (SERS) and phase-sensitive interferometric techniques²⁸. In biosensing, plasmon-enhanced optical transmission through an array of nano-structured holes can facilitate label-free optical biosensing²⁹ in multichannel assays, sub-micron resolution imaging, and on-chip integration with microfluidics and flow-through geometries³⁰ in a liquid and vapor environments³¹. Self-assembled monolayers³², electrochemical functionalization, and analyte-sensitive substrates such as described herein may be used to enhance the specificity of these sensors to various liquid and gas phase analytes. Multiple, differently-enhancing sensing sites are critically important for distinguishing unknown analytes and mixtures of analytes (known and unknown), but add size, cost and complexity in a variety of conventional sensing systems. For miniaturization or even lab-on-a-chip integration, bulky optical setups need to be eliminated. As described herein and subsequently, plasmonic arrays can be functionally compactly assembled onto a CMOS, CCD or other integrated many-pixel imager, but some lens-free computational techniques³³ can lose important spectral information. Also, while surface plasmon imaging is an important technique for multiplex sensing (e.g., integration with microfluidics, with flat films or with nanohole arrays³⁴), it is often accomplished with monochromatic light, which can lose potentially available chromatic information. Plasmonic nanostructures as described herein and subsequently may be used as color filters integrated with CMOS imagers or for multi-spectral imaging³⁵. Compact systems are needed with low cost, high performance, and relatively simple manufacture of (up to) hundreds-to-thousands of different, fast, stable detectors onto millions imager pixel sites, for bloodhound-quality sensing and recognition capability. Compact digital output “sense of smell” chips as described herein can be very small (<0.1 to 1 cc), long-lived, and directly pluggable into current cellphones or computer data analysis systems.

In security applications, vapor sensing of dangerous and/or rapidly fatal or disabling vapors such as nerve agents and other toxic or hazardous compounds such as insecticides and the like may be conventionally carried out by disrupting phase-rotating anisotropic birefringent liquid crystals aligned or “directed” at metal perchlorate surfaces³⁶ in crossed-polarizer optic cells. Such cells can be relatively large, and use thick anisotropic liquid crystal layers (eg, ˜3 to 20+ microns thick) which rotate light polarization through the thickness for crossed polarization response. Polarized light rotation is blocked by the gross disruption of liquid crystal rotatory alignment caused by adsorption of phosphonates at the liquid crystal anchoring sites. Such crossed-polarizer cells may tend to be relatively slow (˜15 to 2,900 seconds³⁷) for sensing nerve agents and other volatile organophosphorous compounds. For a sensor in the field, speed is critical, because nerve agents can stun/kill in seconds.

New approaches, sensing methods and devices are needed to overcome these limitations, and to provide new capabilities and affordable sensing equipment and methods for environmental, medical, security, defense and other liquid and vapor-sensing applications.

### SUMMARY

In accordance with the present disclosure, sensors and sensing methods are provided which can be highly sensitive but relatively inexpensive and small, which are suitable for uses such UAVs, distributed field monitors, medical diagnosis, and environmental monitoring. Various of these sensors can be characterized by one or more features which produce extreme insect antenna sensitivity and identification capability for chemical analytes:
Very small, low-energy systems, with single-to-few molecule response
Localized sensitivity to individual analyte reaction events
High field gradient for high signal amplification/detection
Statistical or stochastic processing of many “noisy” detections, rather than one precise measurement
Rapid analyte removal and detector reset for fast, sensitive operation.
Concentration of analyte sensing to amplify system signal-to-noise response
Enhanced, selective analyte capture.
Differently sensitive detection responses to different chemical molecules

In various embodiments, the present disclosure is directed to “organodiode” detectors which permit direct, immediate, real-time “hair trigger” detection of individual localized gas reaction events, in a manner similar to biological olfactory neurons.

In other embodiments, the present disclosure is also directed to multisample (eg, megasample) sensors built on digital imager foundations, which can carry out static localized sensing and dynamic sensing, rather than the gross conductive equilibrium sensing of conventional long-equilibration-time MOX sensors. Such dynamic sensing methods can concentrate and maximize detection of activation/reaction events at their respective timescales. This approach can also facilitate differential sensing of molecular characteristics from functional gradients, as well as individual sensor reactivity. Such dynamic sensing methods and sensors can also provide VIS and near IR imaging capability. Dual-function imaging and fluid analyte sensing capability provides high performance-to-weight ratios which are very important for applications such as UAVs and portable or distributed instrumentation. Various sensor embodiments can also function as MWIR imagers and fluid and (e.g. seawater) sensor systems.

Various detection methods in accordance with the present disclosure involve direct sensing of MOX charge carriers released by interaction of analyte vapor(s) at a nanoscale metal oxide surface, as to time and location of the carrier release, rather than gross conductivity measurement. Individual MOX detection zones may desirably be less than 100 nm thick, and more preferably less than 10 nm thick, immediately adjacent and in electrically conductive communication with charge carrier sensing and measuring zones such as imager pixels, used to directly detect and measure charge carriers (eg, electrons or holes) produced by analyte interacting with the MOX sensing zone. By utilizing differently sensitive MOX sensing zones (eg, different MOX materials, molecularly-imprinted MOX materials, etc.) of predetermined location, and correlating their responses, analytes can be readily detected and at least partially distinguished or identified with high sensitivity. Embodiments of such methods for detecting and distinguishing analytes may comprise the steps of applying a fluid (directly or indirectly) to be analyzed for analytes to an array of a differently-sensitive MOX detection zones which are differently responsive in charge carrier generation to different analytes, transporting charge carriers produced at such respective MOX detection zones to immediately respectively adjacent charge carrier detection or collection zones, or pixels, and measuring the amount of charge carriers transported to or collected at each to each pixel to determine the presence or absence of analyte at each detector zone. The measured charge carriers at each charge carrier collection or measurement zone (the responses of multiple detector sites) can be correlated to at least partially distinguish, resolve or identify an analyte or analytes so detected.

The present disclosure is also directed to other embodiments which involve direct immediately adjacent coupling of differently-selective sensing zones to respective charge carrier measurement pixels. Methods for detecting and distinguishing analytes comprise the steps of applying a fluid (directly or indirectly) to be analyzed for analytes to an array of a plurality of substantially independent plasmonic detection zones which are differently responsive in permittivity or refractive index change to different analytes, and applying an interrogation light to the array of detection zones to transmit light through the detection zones as a function of permittivity or refractive index at the near surfaces of the detection zones. Such methods may further include directly applying the interrogation light transmitted through each plasmonic detection zone at a respectively adjacent light sensing zone, or pixel, measuring the amount of light applied to each pixel to determine the presence or absence of analyte at each detector zone, and correlating the responses of multiple detector sites to at least partially distinguish, resolve or identify an analyte or analytes so detected.

### DESCRIPTION OF THE DRAWINGS

FIG. 1 is a partially transparent, schematic cross-sectional view of a conventional MOX gas sensor on a heated dielectric substrate as previously described, illustrating metal oxide semiconductor (MOX) grains with negative oxygen-moiety-terminated surface zones depleted of majority carriers.

FIG. 2 is a cross-sectional side view of an avalanche organodiode embodiment 200 in accordance with the present disclosure, also illustrating an enlarged view of its nanoscale MOS surface gas analyte reaction zone 202. The illustrated avalanche organic diode (AOD) 200 comprises a nanothin MOX reaction surface 202, a p+ type anode 204, a p− type avalanche region 206 (an optional p type region 208) and an n-type cathode 210.

FIGS. 3A, 3B, and 3C are schematic representations of the output spikes or “firings” of the avalanche organodiode 200 of FIG. 2 in Geiger mode. FIG. 3A illustrates the low-level random dark current firing “noise” in the absence of any gas analyte, FIG. 3B schematically illustrates the output in the presence of very low levels of analyte, and FIG. 3C illustrates the output avalanche “firings” in the presence of larger amounts of gas analyte.

FIG. 4 is a cross sectional partial schematic side view of an embodiment 400 of a dual function VIS imager and gas sensor on-a-chip.

FIG. 5 illustrates various patterns such as Bayer 502, RGBW 504 and CYGM 506 for differently sensitive analyte reaction zones and color filters which are useful for dual function imaging and gas sensing applications.

FIGS. 6A and 6B are schematic top views of a dual function sensor like that of FIG. 4 in which a voltage gradient is applied between electrodes 606, 608 across the imager pixel sensor MOX surface 602. The reaction of one redox potential sensitive gas analyte is shown in FIG. 6A, and the different reaction pattern of a different gas analyte at the same dual-function sensor is shown in FIG. 6B.

FIG. 7A Is a schematic cross-sectional view of an n-type nanothin MOX sensor surface 702 with a negative oxygen surface species 704 with specific molecular imprint zones 706.

FIG. 7B is a schematic cross-sectional view of an n- or p-type nanothin MOX sensor surface 702 with redox-stable organic moieties 708 at the surface to limit analyte desorption.

FIG. 8 is a schematic illustration of the broad timescale of various types of MOX sensor reactions and recovery mechanisms which can affect gross conductivity.

FIG. 9 is a schematic diagram of an analytical instrument 900 comprising an avalanche organodiode like that of embodiment 200 of FIG. 2 or embodiment 400 of FIG. 4, which is useful for calibrating gas sensor performance and behavior.

FIGS. 10A and 10B are cross-sectional side views of nanopillar arrays 1000 and 1010 which are useful at the imaging and gas-detection surfaces of detectors such as those illustrated in FIGS. 2 and 4.

FIG. 11 is a schematic cross-sectional side view of a dual-function frontside CMOS gas- and image-sensor 1102 having a nanopillar array 1104 at the sensing surface 1106.

FIG. 12 is a schematic cross-sectional side view of a dispersive prism lenslet 1202 for separating the color components (wavelengths) 1204 of image pixels incident on an imager surface

FIG. 13 is a schematic partially perspective cross-sectional side view of a color-separating prism array which separates the color components of incident image pixels into three (red, green, blue) pixel components aligned with specific underlying imaging pixels of an imager such as that of FIG. 4 or FIG. 11.

FIG. 14A and FIG. 14B are schematic views of a readout system having separate RGB readouts for an imager array utilizing a color-separating lenslet prism array like that of FIG. 13, which also may include an avalanche multiplying LLLCCD region.

FIG. 15 is a perspective and schematic view of an embodiment of a vapor detector “sense of smell” module which utilizes a plasmonic detection of refractive index changes at thousands-to-millions of detector sensel sites, comprising hundreds-to-thousands of differently-sensitive detector types, and which may also sense infrared spectroscopic characteristics of adsorbed gases.

FIG. 16 is a side view of a VIS NIR light source and a tuned sub wavelength nanohole pattern nominally resonant with the light source to funnel light through the sub wavelength holes.

FIG. 17A is a schematic top view of a square array of holes through a conductive metal film with a pattern repeat spacing, or periodicity, of αₒ, which has a plasmonic resonant light transmission maximum wavelength of λₘₐₓ.

FIG. 17 B is a schematic top view of a hexagonal array of holes through a conductive metal film with a pattern repeat spacing of αₒ, which has a plasmonic resonant light transmission maximum wavelength of λₘₐₓ.

FIG. 18 is a cross-sectional side view of an individual, plasmonically isolated sensor suitable for use in the device of FIG. 15.

FIG. 19 is a top view of a plurality of plasmonically isolated sensing elements 1902 responsive to a range of VIS wavelengths.

FIG. 20 is a top view of a partially chirped plasmonic component 2002 like those of 1902,

FIG. 21 is a cross-sectional side view of a plasmonic sensor (“sensel”) for enhancing the infrared absorption of analytes present in the sensel to transform infrared absorption into dielectric change for VIS-NIR interrogation light transmission detection.

FIG. 22 is schematic cross-sectional side view of a compact, non-cryogenic MWIR camera utilizing VIS plasmonic transmission response to thermal refractive index change.

FIG. 23 is a schematic top view of an isolated “chirped” plasmonic element 2302 for an IR “multicolor” camera embodiment, in which a multipixel chirped metal film plasmon nontransmissive “rainbow” grating 2304 receives wideband infrared radiation and separates it into waveband zones where that waveband is most resonant, and permits VIS interrogation of the thermal response of the separated IR waveband zones at respective individual imager pixels adjacent the respective waveband zones.

FIG. 24 is a schematic top view of isolated plasmonic elements 2402 having a regular hexagonal array of nanoholes 2406, which form portion of a plasmonic transmission array 2404 of individual nominally VIS-NIR resonant hexagonal arrays fabricated atop the frontside pixels of a frontside CCD or frontside CMOS silicon imager.

FIGS. 25A, B, and C are schematic cross-sectional side views, with reference to FIGS. 7 A and 7 B, of detector surfaces (A) having negative surface ions which deplete carriers, B upon adsorption of an analyte (such as by a molecularly imprinted MOX selective for specific analytes changing dielectric constant, C upon application of a UV light pulse in a programmed and appropriately timed manner to generate electrons/holes so the analyte can be oxidized (reduced) introducing charge carriers in the MOX,

FIG. 26 is a schematic cross-sectional view of a compact plasmonic digital camera SERS Raman system for detecting Raman spectra of adsorbed analytes.

FIG. 27 is a schematic cross-sectional side view of a plasmonic digital camera SERS RAMAN sensor 2702 similar to that of FIG. 26, comprising a plasmonic topside “rainbow” graded plasmon layer 2704 with high-field RAMAN layer 2706 compactly and functionally adjacent bottomside camera imager pixels 2708 to collect red-shifted Stokes light emitted along the “rainbow” plasmon topside layer.

FIG. 28 is a schematic cross-sectional view of a plasmonic digital camera RAMAN sensor similar to those of FIGS. 26 and 27 illustrating efficient compact structures designed to direct only the Stokes emission to imager pixels adjacent the “rainbow” emitting backside of the plasmon layer.

FIG. 29 is a schematic illustration of a compact plasmonic sensor system for use in either a liquid and vapor sensing environment, comprising a light source, analyte introduction means, multiple differently-selective plasmon sensor zones (eg, 10-1000 differently selective zones) for transmissive interrogation by the light source, an integrated circuit imager to receive transmitted interrogation light from the selective plasmon zones, and a control and analysis computer system.

FIG. 30, subfigures a, b, c, and d sequentially illustrate a fabrication scheme for nanohole arrays used in a compact plasmonic spectrographic analyte sensor.

FIG. 31, subfigures a and b illustrate two nanohole spectroscopy analyte sensing apparatus testing setups: (a) “Setup 1” and (b) “Setup 2”.

FIG. 32 subfigures a, b, c, d, e and f illustrate nanohole arrays coated with a solvatodielectric and solvatochromic plasmonic sensing enhancer (Reichardt's dye) for vapor sensing. (a) Photograph of an uncoated nanohole array chip immediately after template stripping. The uniform nanohole array covers an area approximately the size of a CMOS imager to which the array is to be applied in the apparatus of FIG. 31 (b) Photograph of the same chip after coating with Reichardt's dye. A thin layer on and around the nanohole array is seen. (c) Zero-order transmission spectrum through the nanoholes of the nanohole array before and after coating with dye. (d) SEM image of a nanohole array chip before coating. (c) SEM image of the same chip after coating with the Reichardt's dye, noting the dye tended to form plugs inside the nanoholes. (f) Backscatter SEM image of the same area showing good elemental contrast, indicating that the nanoholes are indeed plugged with dye and not just covered with silver from the template stripping procedure.

FIG. 33 subfigures a and b graphically illustrate real-time vapor sensing with an external fiber optic spectrometer (“Setup 1”) of FIG. 31: (a) Spectrum of the nanohole transmission from the fiber optic spectrometer. These sensing results are used as a basis to validate results obtained with “Setup 2.” (b) Tracking the silver-air peak around 650 nm shows a large shift upon exposure to 100 ppm ethanol vapor in nitrogen. The peak position returns back to the baseline upon washing the surface with pure nitrogen. Without the solvatodielectric dye coating, a negligible shift was observed. Tracking other peaks also showed substantially no shift.

FIG. 34 subfigures a, b, c and d graphically illustrate real-time vapor sensing with a CMOS imager camera as an integrated spectrometer (“Setup 2”). (a) Photograph of CMOS imager camera and electronics module. The nanoholes (appearing purple from this angle and after coating with dye) were mounted to the CMOS imager camera surface using an index matching oil layer. The nanohole array is large enough to completely cover the active area of the imager. The entire sensing device is about 1-inch by 1-inch square. (b) Image obtained from a color CMOS imager with nanoholes. The bright spot in the middle is the undiffracted zero-order light. Six first-order bands are visible (due to the hexagonal arrangement of the nanoholes). Extracting a line from one of the camera-sensed bands reveals (c) a complete transmission spectrum of the nanoholes showing three peaks, as with Setup 1. By tracking the red-most peak (d) real-time vapor sensing is achieved as with Setup 1. The nanohole plasmon chip with solvatodielectric dye was exposed to 100 ppm ethanol vapor in nitrogen, returning to the baseline after washing with pure nitrogen. Tracking the other peaks showed negligible shift, as with Setup 1, indicating that the diffracted light bands are indeed due to the transmission spectrum of the nanohole arrays and are showing plasmonic sensing behavior.

FIG. 35 subfigures a and b graphically illustrate multiplex, real-time vapor sensing with the CMOS imager camera having diffractive plasmonic nanohole array functionally applied as a compactly integrated spectrometer (“Setup 2”). (a) An image of two sensing regions on the CMOS imager. The illumination aperture from the LED has been modified to include two openings instead of one. One region (on the left) has been sealed with transparent tape while another region (on the right) has been left open. Two spectra can be extracted from these two illuminated spots. (b) Tracking the peaks from the extracted spectra. The sealed region shows no spectral shift whereas the unsealed region responds to the ethanol vapor. These results show test results for multiplexing capability of the compact sensor.

FIG. 36 graphically illustrates real-time liquid index sensing with a CMOS camera and plasmonic nanohole diffractive array functionally integrated as a spectrometer (“Setup 2”).

FIG. 37 is a schematic illustration of a gas chromatography system which uses selective electromagnetic (eg, MWIR) radiation to selectively heat analytes undergoing chromatographic separation, and which may optionally be utilized with sensor devices of the present disclosure to enhance detection and discrimination of analytes.

FIG. 38 is a schematic illustration of an EC-QCL MWIR source with a lightpipe GC analyte irradiation zone.

FIG. 39 is an illustration of the operation of an integrated, addressable multi-LED or laser interrogation light source array in alignment with differently sensitive sensing cells each diffracting onto an integrated megapixel camera chip, in a compact sensor system.

FIG. 40 is a schematic cross sectional side view of a selective injection analyte pre-concentrator which is useful for applications including miniaturized vapor detection systems, and

FIG. 41 is a schematic of a gas chromatic system.

FIGS. 42A, 42B, and 42C are elution profiles.

FIG. 43A is a schematic functional top and cross sectional side views of a shape memory alloy vacuum pump for miniaturized mass spectrographic analytical systems.

FIG. 43B is a cross-sectional view of lightpipe construction of the lightpipe of FIG. 38,

FIG. 43C is a system for dielectric heating applied to a pre-concentrator and/or GC column to selectively energize polar compounds of GC samples being analyzed. Comprising a microwave AC driver 4302 may be coupled to a low tan δ dielectric sample collector 4304.

FIG. 44 illustrates column and/or pre-concentrator fabrication from etched substrate halves.

FIG. 45 illustrates an analytical system comprising a tunable MWIR laser, analyte pre-concentrator, FTIR spectroscope, gas chromatographic column, and detector, useful for describing various peocess embodiments of the present disclosure,

FIG. 46 is a schematic illustration of another embodiment of a gas chromatic analytical system in accordance with the present disclosure, useful for practicing the present processes,

FIGS. 47A and 47B illustrate a SMA metal or piezoelectric bellows structure hermetically sealed and mounted on a MEMS chip with other GC-MS structures with little or no internal volume in its “collapsed” condition (47A) compared to its expanded condition (47B),

FIG. 48 is a schematic illustration of a pumping system comprising parallel and series connected bellows like those of FIG. 47,

FIGS. 49 and 50 are a schematic illustration of a cylindrical piezoelectric travelling wave pumping system.

FIG. 51 is a cross sectional view through the cylindrical axix of a piezoelectric pump.

FIG. 52 is a schematic illustration of a gaschromatic analysis system utilizing a pulsed MWIR laser and a plurality of digital microphones with analyte sorbent coatings as a detector system

FIG. 53 is a schematic side view of a 4-phase planar piezoelectric pumping system,

FIG. 54 is a top view and an aligned cross sectional side view of a discoid piezoelectric multistage fluid pump.

FIGS. 55A and 55B are a schematic cross sectional side view of an MWIR camera.

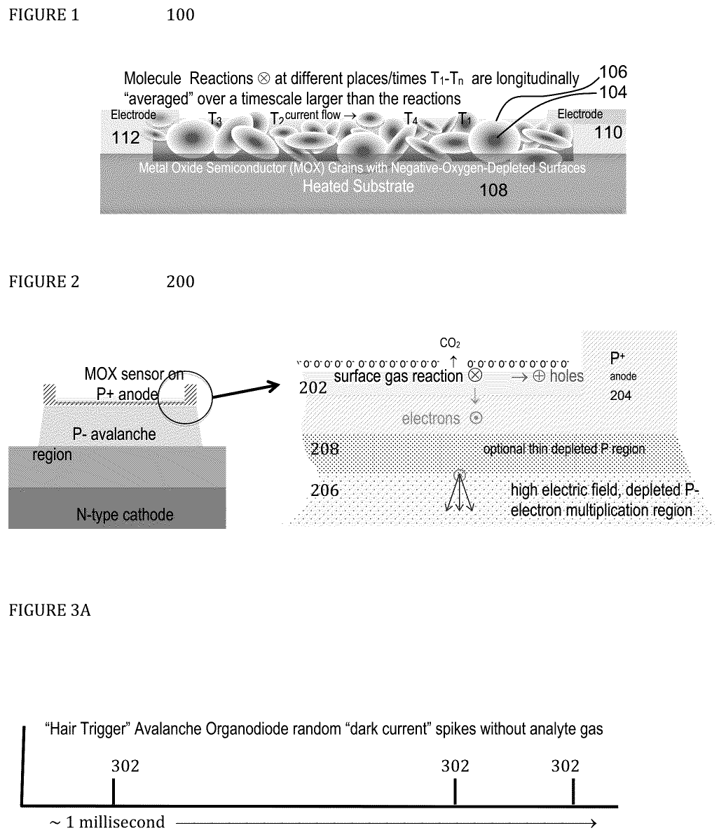

### DETAILED DESCRIPTION

A number of high-bandwidth gas analyte MOX nanosensors (built on inexpensive existing technology platforms), with extreme sensitivity like that of insect sensilla, are provided in accordance with the present disclosure.
MHz-bandwidth Avalanche Organodiodes which “fire” individual spikes like insect olfactory neurons, when triggered by gas analyte molecules (“hair-trigger” sensitivity)
Dual-Function MegaPixel VIS Camera and MegaSensor Gas Detector-on-a-Chip (millions of high-sensitivity image pixels and gas sensors for different gases)
Tiny uncooled Midwave IR (MWIR) camera-on-a-chip with MegaSensor gas detection
Sea- and freshwater solute sensors for tracking mines, ships, etc.
Statistical processing methods for high sensitivity and analyte differentiation

The present sensors, methods and systems also permit differentiated sensing of gas molecule characteristics such as shape/size, molecular weight, organic functional groups (eg, nitro, aliphatic, arene, azido, thio, carbonyl, etc.) and redox potential, to facilitate compound identification. Like insect olfactory systems, various embodiments of sensors in accordance with the present disclosure can produce very large amounts of sensed data for precision correlation and/or statistical analysis to both detect and distinguish different chemical molecules.

Like insect sensilla, various of the embodiments of the present disclosure utilize “hair trigger” high electric field-gradients for detecting individual gas molecules. Illustrated in FIG. 2 is a cross-sectional side view of an avalanche organodiode embodiment 200 in accordance with the present disclosure. FIG. 2 includes an enlarged view of the nanoscale MOS surface gas analyte reaction zone 202 of the AOD 200. The illustrated avalanche organic diode (AOD) 200 comprises a nanothin MOX reaction surface 202, a p+ type anode 204, a p− type avalanche region 206 (an optional p type region 208) and an n-type cathode 210. In accordance with such embodiments, Avalanche Organodiodes” and “organomultipliers” (AODs) are provided which, like insect sensilla, can “fire” with very high signal multiplication upon detection of individual gas molecules, rather than photons. Such AODs use a nanothin semiconductor metal oxide (MOX) surface to generate carriers for subsequent avalanche multiplication. Individual analyte gas molecules react with the nanothin semiconductor MOX surface to remove surface oxygen species and inject electrons at the molecular reaction site, directly into the underlying diode structure³⁸. The sensitivity of such embodiments is not limited by “averaging” or longitudinal transit through multiple grains along the length of sensor film and equilibrium stabilization, as in typical conventional MOX sensors. The molecular-reaction electrons are introduced directly into the underlying reverse-biased, fully-depleted, high-field diode structure to create a high-gain burst of electrons detected at the device cathode³⁹. An avalanche can be immediately reset by passive or active resistance. AODs in accordance with the present disclosure can, for example, operate at KHz to GHz cycle rates/bandwidth, which is orders of magnitude faster than the typical ˜60 Hz rate of insect sensilla. Such AODs can be designed in accordance with the present disclosure to detect individual gas molecule reactions at the sensor surface in real time.

Semiconductor Avalanche Photodiodes (APDs) and photomultipliers are conventionally used to detect very low numbers of photons. Individual supra-bandgap photons create electrons and holes within the diode structure which are separated in a depleted, reverse-biased absorption zone of the APD. The carriers avalanche in a high electric field zone within the detector to produce enormous gain below photon-counting fields, and avalanche spikes for each carrier introduced into the avalanche zone at high “Geiger mode” potentials. Silicon photomultipliers⁴⁰ SPADS and APDs⁴¹ can have signal gains of 1×10⁷. SiC photodiodes can produce up to 10,000 electrons per captured photon. Coincidentally, this is approximately the charge multiplication produced by the attachment of an odorant molecule to an insect olfactory neuron gate to “fire” the neuron. APDs can count single photons in “Geiger” modes, at high counting rates from KHz to GHz⁴². Silicon can operate at elevated temperatures of up to 100-200° C., at least intermittently, at an exposed surface. For higher temperatures, GaN-based APDs can have high gain and SiC-based APDs have been demonstrated with low dark current, gains of 5000-10,000, automatic passive avalanche reset, and very low noise equivalent power.

Because of their high bandgap, and adequate crystal growth and epitaxy, silicon carbide avalanche photodiodes have been developed for high-temperature (eg well-bore) and UV-detection (eg, solar blind detectors) uses. Conventional SiC avalanche designs for both electron and hole avalanche are conventional, and may be used for avalanche organodiode detection systems in accordance with the present disclosure⁴³. The SiC APDs can operate in both high amplification, and in “Geiger” mode cycles of sharp avalanche “firing” followed by immediate reset, at high frequency.

An excellent way to calibrate Si and SiC Avalanche Organodiodes is to divide the hot gas output from a Gas Chromatography column, so that one half goes to the conventional FID Detector, and the other goes to the AOD with its front surface within the GC oven. In this regard, illustrated in FIG. 9 is a schematic diagram of an analytical instrument 900 comprising an avalanche organodiode (AOD) 910 like that of embodiment 200 of FIG. 2 or embodiment 400 of FIG. 4, which is useful for calibrating sensor performance and behavior. The analytical instrument 900 comprises a gas chromatograph 902, including a conventional programmable oven 904 enclosing the separation column, and a flame ionization detector (FID) 906. The gas chromatographic output of separated gas analytes in an inert gas stream is split, so that it is simultaneously applied with oxygen from source 902 to the FID 906 and the AOD 908, as appropriate. By introducing known molecular analytes into the GC, the response of the FID and the AOD can be compared and characterized with respect to specific chemical analytes and the timing of their application to the FID and AOD sensor surface. Oxygen used in the FID for flame ionization is also introduced to ˜20% sample volume in the GC sample effluent for the AOD with optional ambient humidity, and the heated effluent GC sample gas with O₂ is directed at the reactive AOD surface at an elevated operating temperature for the MOX active surface, say 150-300° C., which can conveniently be the temperature within the GC oven.

The Avalanche Organodiode back surface can be cooled to reduce bulk dark current if desired, while the nanothin MOX front surface of the AOD is heated (eg, at the oven interior, or exterior wall) by the heated GC sample gas+O₂ to maintain the MOX surface activity.

The quality of the MOX sensor layer and its interface with the avalanche diode can be important to control dark current. The MOX nanothin layers should minimize defects and in many embodiments should best be outside the highest field anode-cathode depletion region. There are a variety of ways to apply high-quality MOX layers on semiconductor surfaces⁴⁴. Atomic Layer Deposition, pulsed laser deposition and/or MBE may be utilized to apply high-quality layers.

FIG. 2 is a cross-sectional schematic illustration of a reverse-biased Avalanche Organodiode, also illustrating its MOX sensor layer portion in more detail in an enlarged zone. The illustrated P+ anode may be very thin, eg 25-50 nm. The MOX sensor layer is very thin, for example 5-50 nanometers. The MOX layer may be a high quality ALD deposited, doped SnO2, ITO, HfO2 or TiO2 layer⁴⁵. It may also be operated with pulsed surface heating in order to reduce dark current, as discussed below in connection with another specific embodiment. The high-temperature SiC diode may be operated at 100-300° C. like a conventional MOX gas sensor. When a reactive gas molecule is adsorbed on the sensor surface, it oxidizes to consume negative oxygen surface species, injecting One or more electrons ⊙ at the surface gas chemisorption/reaction site ⊗ on the reverse-biased surface of the sensor exposed to the atmosphere. These electrons drift under the surface depletion field, directly to the underlying depleted P+ anode under the site of the reaction. From there, the electrons drift to the high-field P− avalanche region, where they are accelerated by the high electrical field within the zone to trigger an electron avalanche which is easily detected by the diode output circuit. Passive (on chip) or active resistance stops the avalanche, and resets the diode for detection of the next gas molecule reaction.

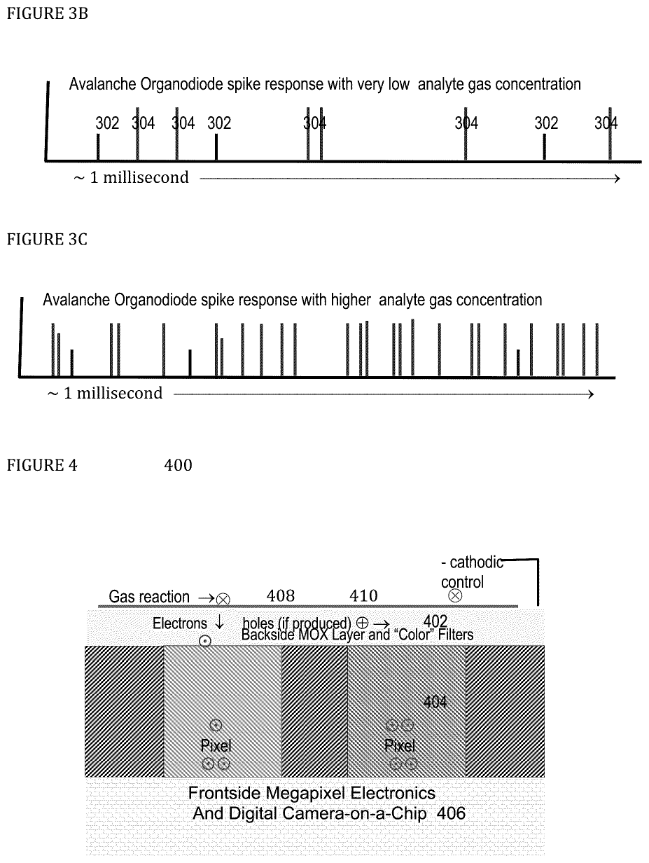

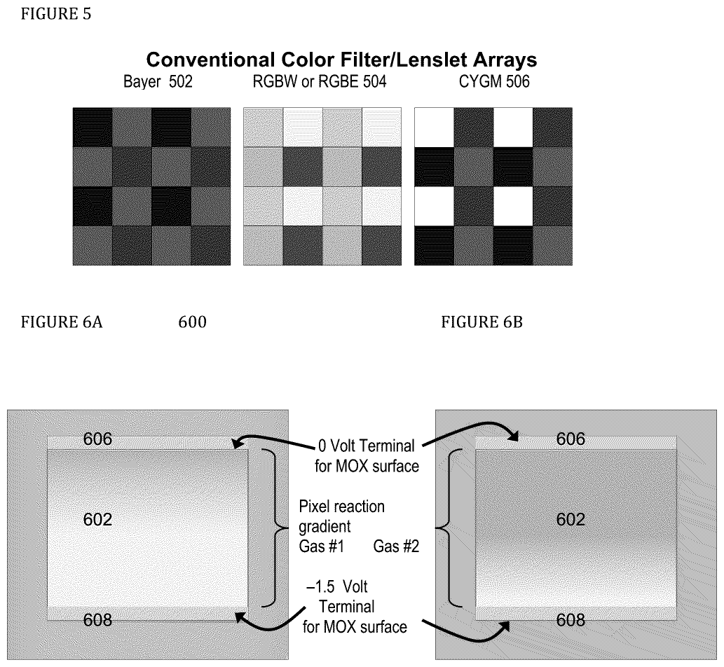

In a manner somewhat analogous to biological processing: many olfactory neuron firing, statistical processing of many stochastical “noisy” firings can be applied to the output of the AOD embodiment 200 to achieve high sensitivity and differentiation. Response of one AOD is similar to (but with a much broader range than) an insect olfactory neuron. With no gas analyte present, the small dark current of the fully-depleted “hair trigger” diode in Geiger mode may produce a low level of spike “firings” 302 (blue lines) as shown in FIG. 3A. These random “dark-current firings are a stochastic process, so are not deterministically predictable. At very low gas analyte levels at which each pixel has few, if any electrons produced by gas reaction within the frame integration (sampling) timespan, the “firings” of the AOD are also a stochastic process producing “firings” in addition to the dark current firings. Dark current noise can be effectively removed at the cost of counting multiple electrons simultaneously entering the avalanche zone of the AOD as a single electron. For example, by subtracting the dark current firing count of a control AOD which does not detect gas analyte from the firing count of a substantially similar AOD which is sensitive to gas analyte, the resulting count represents the detected gas molecule count.

Very low gas analyte concentration sensed by the AOD detector 200 produces a statistically significant response 304 in addition to the background dark current noise spike 302 level (blue lines), as shown in FIG. 3B. Because the gas-reaction spikes 304 (red lines) may be initiated by multiple electrons, the spikes may be slightly stronger in Geiger mode than the dark current spikes, as shown in FIG. 3B.

Because the high bandwidth of an avalanche diode structure (eg, MHz) can greatly exceed the bandwidth of an insect olfactory neuron (<100 Hz), a single avalanche diode structure can process a much larger concentration range than an insect neuron. FIG. 3C schematically illustrates the “Geiger mode” output of the AOD embodiment 200 at relatively higher gas analyte concentration.

In AOD design of the embodiment 200 of FIG. 2, individual gas molecules are reacted, detected and destroyed in real time, much like the sensing and removal of an odorant in an insect olfactory neuron. The electrons generated at the MOX surface diffuse through the extremely thin nanoscale layer at the site of the reaction, rather than having to equilibrate, with other gas molecules, the average longitudinal conductivity of an MOX bulk layer. The gas molecules are “cleaned” from the sensor by the reaction, and the avalanche spikes are reset by passive or active resistance in the AOD, or off-chip. Equilibration of surface oxide species can take longer, without preventing detection.

Use of multiple Avalanche Organodiodes with MOX surfaces selective for (e.g., having a different reactivity for) different gases permits distinguishing different gases⁴⁶. Insect antennae may have, for example ˜100,000 neurons of less than 100 types of different sensitivity to different odorants. At a maximum “firing” rate of about 60 Hz, an insect has roughly a maximum statistical bandwidth very much less than 6,000,000 “firings”/second, including much redundant information. Two 8×8 arrays of simple SiC Avalanche Organodiodes (eg, one n-type, one p-type), each with a different MOX surface having different sensitivity to a wide variety of gases, operating at 10 MHz will provide a bandwidth orders of magnitude larger than an insect olfactory system [see APPENDIX C].

Silicon carbide (SIC) AODs can operate at the higher temperatures of some conventional catalytic MOX sensor materials. Silicon-based avalanche diodes can operate, at least intermittently, at temperatures up to 100° C. or more, which is adequate for a number of lower-temperature MOX sensor compositions⁴⁷. Large arrays of silicon avalanche diodes or SPADS, each with a differently-sensitive MOX surface sensor, together with CMOS-compatible read out circuitry can provide high sensitivity and differentiation of gases detected using precision statistical methods. Principal component analysis and support vector regression (SVR) can be applied for differentiation of different analyte gases from the different responses of sensed data from multiple sensor elements and sensing conditions⁴⁸.

Avalanche gas sensors operated in geiger mode can produce extremely high gain applied to individual molecule reactions, in a very high speed detector design such as embodiment 200 of FIG. 2. Another approach to increased sensitivity is to collect the gas analyte(s) on the sensor surface(s) over a period of time, as described in respect to the embodiment 400 of FIG. 4 having charge collection wells with high (eg 5-25 electron minimum) sensitivity. The collected charge carriers over the frame timespan at each gas-reaction site effectively multiply the respective detector sensitivity.

The present disclosure is also directed to dual-functionality megapixel camera and megasensor gas detector-on-a-chip devices and systems. Such embodiments are particularly useful for lightweight UAVs, as well as distributed and portable sensor systems. In accordance with the present disclosure, dual function, inexpensive CMOS cameras-and-gas-sensors-on-a-chip are provided for use both as a VIS imager, and as an ultra-sensitive megasensor gas detector. As a functional “add-on” to an existing imaging system, this provides an effectively “weightless and energy-free” addition of functionality for UAV, stationary surveillance sensors, cell phones, etc. which already require a VIS imaging functionality.

Backside-thinned multi-megapixel VIS cameras-on-a-chip are well developed for high-performance space, military and science applications⁴⁹, as well as consumer cameras. Sony, Samsung, and Omnivision mass-market technically sophisticated, inexpensive, high-performance backside-thinned silicon CMOS megapixel consumer cameras-on-a-chip. A Sony IMX050 2nd Generation Backside Sensor with CXD4122GG camera chip generates 10 Megapixel digital images at 50 frames per second, and high-speed video up to 1,000 fps or more⁵⁰. OmniVision, a consumer CMOS image sensor manufacturer, also has a range of backside commercial consumer camera systems. Micron spin-off Aptina is a US domestic commercial source of CMOS cameras-on-a-chip⁵¹. Very high performance, low-noise, backside CCD and frontside camera systems with high sensitivity are commercially available.

Such digital imaging systems and cameras are very inexpensive, yet very powerful, fully-integrated electron sensing, digitization and spatial data processing systems. Low-cost CCD and CMOS cameras on a chip (or 2 chips for CCD cameras) for cell phones and consumer cameras can have 5 to 15 or more megapixels, each with a remarkable sensitivity threshold of only ˜5-10 electrons or less. High-performance CCD and LLLCCD systems can have even lower sensitivity thresholds. This is in the range of the number of electrons injected into a MOX sensor by oxidation of one or two organic molecules (eg DNT, TATB, Sarin). The electron well capacity of each pixel in a conventional CMOS camera-on-a-chip can be 100,000 electrons or more. In accordance with the embodiment 400 of FIG. 4, each pixel of a digital camera-on-a-chip is converted into a MOX gas analyte sensor. So the detection capacity range of each pixel is enormous, ranging from several molecules, to tens of thousands of sensed gas molecules. In addition, the integration time (whether under reactive or non-reactive conditions) for adsorption of gas analyte(s) before a sensing cycle can be varied over a large range, adding system flexibility under program control. The range of differently-sensitive MOX materials for individual pixel gas sensing (sensel) surfaces is also very large (see Endnotes). And the number of pixels in a single inexpensive “camera-on-a-chip” can be enormously larger than the number of insect or mammalian olfactory neurons. A typical inexpensive consumer CCD or CMOS imager has 5-25 megapixels, each of which outputs a digitized value of electrons collected from gas analyte molecule reactions at that pixel, geometrically indexed to the specific pixel from which it came, with each image cycle. The MOX sensor surface and reaction conditions can be controlled for each pixel. Just as some imager pixels are covered under a light shield in a conventional CMOS or CCD imager to provide dark current information for image processing, “control” pixel sensors which are not sensitive to gas analytes can be fabricated in the pixel array for dark and/or spurious current information for processing the sensed gas analyte data. Coordination and indexing of the specific pixel reaction sensitivity, reaction conditions (eg, temperature/UV/IR/Efield, etc.) and sensed data, together with dark and spurious current information provides a powerful statistical database for determining gas concentration and identity.

In “backside” CCD and CMOS imagers, image light image enters from the “backside” of the chip. The image photons generate electrons in the silicon substrate near respective image pixel circuits on the “frontside” of the imager. These image pixel electrons are captured, digitized and transmitted off-chip by circuitry on the “front side” of the imager.

A backside CCD or CMOS imager design can use a transparent metal oxide surface layer to reduce semiconductor interface “dark current”, which would otherwise add spurious electrons to the image and adversely affect image sensitivity. A recent Sony patent application⁵² describes nanothin, 1-50 nm backside layers of Indium Tin Oxide (ITO), Zirconium, Zinc, Titanium, Tantalum, Yttrium, Lanthanide and/or Hafnium oxides for this purpose. An externally applied negative potential for the nanothin metal oxide surface layer, or an inherently negatively charged depletion zone at its surface, prevents “backside” leakage dark current from entering the “frontside” CMOS image pixels of the Sony VIS backside CMOS camera-on-a-chip.

The illustrated embodiment 400 of FIG. 4 uses the extremely electron-sensitive overall structure and digital-data generating capability of such highly-developed CCD and CMOS backside imagers, with structural modification and nanothin MOX sensing surface addition such that gas adsorption and/or other reaction on the MOX surface introduces carriers (electrons in the illustrated embodiment 400) into the underlying imager pixels. Except as modified as described herein, the embodiment 400, partially illustrated in FIG. 4, is a complete “camera-on-a-chip” structurally and operationally as described in Sony Patent Application Publication 20110058062, “Solid-State Imaging Device, Method For Producing Same, And Camera”, published Mar. 10, 2011, assigned to Sony Corporation, incorporated in its entirety herein. When an organic analyte is chemisorbed and/or oxidized at the MOX surface, negative oxygen species are removed and electrons are injected into the nanothin MOX layer for collection by the underlying CMOS pixel electron-collection zone.

Just one molecule of a multi-carbon organic analyte reacting on the MOX surface above a pixel removes negative oxygen species, and can inject a number of electrons approximating the 5-10 electron sensitivity threshold for that pixel. Scientific imagers can be operated with lower sensitivity/noise thresholds. Multiple gas reactions can create a statistical “image” of gas analytes at differently-reactive nanothin MOX sensor surfaces on the “backside” of the imager 402.

The backside sensor system 400 can be used in a steady-state collection mode in a manner similar to light imaging—the electrons from gas-reaction are collected in their underlying pixels for a time period, then the gas-reaction data of each pixel in the frame is read out from the sensor. Sensor sensitivities of, for example, 5-10 electrons per pixel, with statistical processing to denoise the data, can produce high gas-sensing sensitivity. A number of MOX sensor materials can function at relatively low temperatures⁵³. And silicon devices can operate from ambient temperatures up to about 100-200° C., at least intermittently, at a cost of higher dark current. Backside heating of the MOX surface (such as by pulsed IR light) with frontside cooling can minimize dark current from the underlying silicon bulk, while optimizing gas sensor response of the nanothin MOX sensor surface.

But dynamic (non-steady-state) pulsed-sensing modes offer the capability of controlled “sniffing” and modulation of gas concentration on the sensor surface. Sensitivity can be multiplied by “collecting” gases by adsorption on relatively cool, inactive MOX pixel surfaces, followed by rapid activation to suddenly react the adsorbed gas(es). This dynamic reaction mode can increase sensitivity and discrimination of the adsorbed gases⁵⁴. When the MOX sensor surface is at ambient temperature, it does not function like a typical, heated gas sensor in which the sensed gas is combusted continuously as it contacts the sensor. During the ambient temperature collection period, the concentration of analyte increases because it is thermodynamically adsorbed to the MOX surface. This collection capability can be enhanced by nanopillar structures as described hereinbelow.

Differently sensitive nanoscale catalytic sensors can also be “pulsed” with IR-VIS-UV light of energy greater than the bandgap to generate electrons and holes. Bright UV LEDs are small, efficient, and readily available⁵⁵. The pulse can be very short, eg 1 microsecond or less. In the absence of analyte, initial recombination will consume many of the generated energetic charge carriers, and subsequent mechanisms (detrapping, restoration of surface oxygen equilibrium, etc.) will produce a rapidly decaying conductivity curve.

In the presence of adsorbed analyte, energetic carriers are consumed “combusting” the analyte over a sub- to multi-millisecond range time span characteristic of the analyte. There may also be a change in the net electrical charge balance and surface trap states, which can be used to increase “dark current”. Because all of the analyte molecules are subjected to “combustion” effects starting at the same time, sensor sensitivity can be significantly increased over the steady state case of the conventional catalytic sensor. Persistent “dark current” from long-lived hole traps can be used as a signal amplifier, as described above. To operate the MOX-CMOS imager as a gas sensor in a pulsed-sensing mode, the image light can be shuttered off, as with other gas sensing methods described herein. The atmosphere to be tested is passed over the imager backside surface for a selected period of time such as 0.1 to 30 seconds, at ambient temperature to “collect” a sample by adsorption (which is thermodynamically favored) on the respective imager MOX pixel surface. A longer collection time can be used for lower concentrations of analyte gases.

To initiate a dynamic pulsed detection cycle, very short (eg <1 microsecond) UV, VIS and/or IR pulsed energy faster than the thermal transfer timescale (eg <1 millisecond) can be applied to the nanothin MOX surface to heat it and activate the chemisorbed organic molecules present on the surface. The imager circuitry can be in non-collecting reset mode to minimize “swamping” of the pixels by VIS or UV photons in the first image cycle. Alternatively, a pulsed resistive heating of an electrically conductive MOX surface or electrically isolated resistive nanogrid can be carried out (eg, together with a UV pulse to induce conductivity if appropriate).

A UV pulse above bandgap generates free carriers at the MOX surface which can oxidize or reduce an adsorbed organic compound (analogous to thermal carrier generation at higher temperatures) and can photodesorb surface oxygen species, particularly those near adsorbed gas analyte molecules. An infrared pulse below bandgap can also be directed at the MOX sensor surface to heat organic molecules and/or nanoparticle catalyst particles on the MOX surface. Different IR wavelengths can be applied in an IR spectrographic way to selectively activate different analytes having different IR absorption spectra. Stable surface room temperature ionic liquid (RTIL) components and metal catalytic nanoparticles can also assist in heat deposition to the nanothin MOX sensor surface [see below]. A very short UV pulse can also be used to activate oxygen radicals with precise timing to assist reaction. UV can “substitute” for high-temperature in MOX surface reactions with gas analytes⁵⁶. A conductive MOX surface can be positively biased to remove electrons for eg, the first 100 ns after the UV (VIS and/or IR) pulse. Then the MOX oxide surface can be biased negative and the imager pixels armed to collect electrons in the millisecond reaction time range of the analyte materials present.

Conventional consumer CMOS and CCD imagers have reasonably fast readout times, from typically 30 to 1000 or more frames per second. Such frame-to-frame gas pixel sensor data can provide information about the time course of gas analyte reaction, which correlates with different gas molecule characteristics such as molecular size, energy and reactivity⁵⁷. Available high speed backside CCDs can operate at image frame rates well over a million frames per second⁵⁸, while retaining a per-pixel sensitivity of less than 5 electrons. Even faster backside CCD imagers are under development⁵⁹.

With high speed imagers, the time-course of a pulsed reaction of collected gas analytes can be precisely followed. Different gas analytes are reacted in a series of steps through intermediates, over a period of time. Each different gas analyte of different molecular weight, composition, redox potential, functional groups, etc. produces its own time-course reaction “signature” in the frame-to-frame sequence. Larger organic molecules react at MOX surfaces in a series of intermediate steps and intermediate reaction products, which can be characteristic for molecular identification.

A series of “gas-detection-images” can also show hole traps produced by pulsed UV analyte reaction in the specific pixel locations where they were produced. Under appropriate detector conditions, such hole-trap-induced “dark leakage” can be used to multiply the effect of gas-reaction on the MOX surface over time until it decays. MOX materials such as ZnO have relatively fast hole-detrapping recovery time⁶⁰, but TiO2 has a long UV hole-detrapping time which can greatly amplify “dark current” to the respective underlying individual pixels⁶¹. This effect can be used to amplify “dark current” at the respective pixels where the traps are located. If desired, trap recovery can be accelerated by applied negative potential and infrared pulse at the trap depth energy level, which is primarily in the IR range below the silicon bandgap.

By doping the backside surface of the imager with different catalyst metal ions in different zones (or with a gradient), different responses to different analytes can be produced in the different zones (including zone gradients as described in respect to FIG. 6A). This permits differentiation and identification of different gas molecules. Although not shown in FIG. 4, the MOX pixel surface of the sensor-on-a-chip 400 includes “control” pixels which are not accessible to or reactive with gas analytes in the atmosphere. The pixel zone also includes pixels shielded from the light⁶². The output from the control pixels provides data for compensating for dark and spurious current or other non-analyte background.

The “gas-reaction image data” (from adsorption and/or combustion) output from the MOX-modified CCD or CMOS imager presents megasample, digitized gas detection information ready for statistical “number crunching” such as Hidden Markov model processing for analyte detection and recognition.

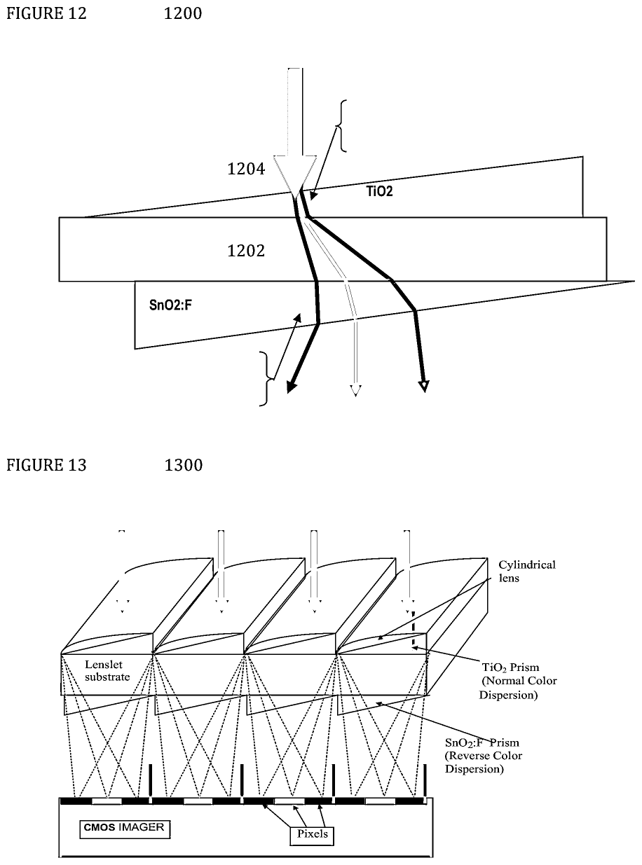

Conventional CCD and CMOS imagers use relatively thick planarization layers, plastic lenslets and color filters to generate color images instead of grayscale images. However, such thick conventional lenslets/filters prevent the external atmosphere from direct access to a nanothin MOX sensing layer atop the semiconductor substrate. As shown in FIG. 4, the gas-sensor pixels of the imaging and gas-sensing device 400 are not completely covered by planarization and color filter layers. To preserve the color imaging capability of a dual function imager/gas sensor, nanoscale sensor surfaces can be fabricated which transmit limited spectrum colors, but which retain their electron-generating capability upon chemisorption/reaction of gases with the surface. Approaches to accomplish this include:
Inorganic catalytic dopants for the MOX surface can have VIS absorbance bands, as well as IR and UV bands. Many dyes which have been developed for solar energy systems are relatively stable on TiO2 and other MOX surfaces with UV
Layer thickness and refractive index of multiple layers of controlled MOX thicknesses can vary color transmission⁶³ [also see Sony patent application No. 20110058062 cited above]
Metal and semiconductor nanoparticles and quantum dots can be designed in size, shape and concentration to control spectrum absorption and transmission⁶⁴. Metal nanoparticles of specific size, composition and pattern⁶⁵ can be applied from RTIL solution.
Nanoparticle arrays, distance from the reflective silicon surface, and plasmon structures are also color-transmission design options.
Pillar and diffractive arrays, such as nanopillar arrays described hereinbelow, can be designed for selective waveband transmission.
Refractive lenslet arrays such as described with respect to FIGS. 12, 13 and 14 can be used to utilize more of the available light by indexing pixels to specific refractive color zones.

Importantly, different bulk MOX dopants produce different gas chemisorption/reaction sensitivities at the MOX surface. Similarly, metal nanoparticles such as Pt, Pd, Au, Ag are conventionally used to produce different sensitivities on the surface of MOX gas sensors. Gas sensors with different sensitivities are also necessary to distinguish gas analytes. Accordingly, a color filter pattern for color imaging can be combined with a differential gas sensing pattern in the multifunctional sensors of the present disclosure. Gas sensor “filters” can also serve as image color filters. Such filters can be combined with selective IR spectroscopic activation, electric field gradients across the imager backside surface, and/or “molecular imprinting” as described below, to create a very wide range of gas reactivity differentiation for gas identification.

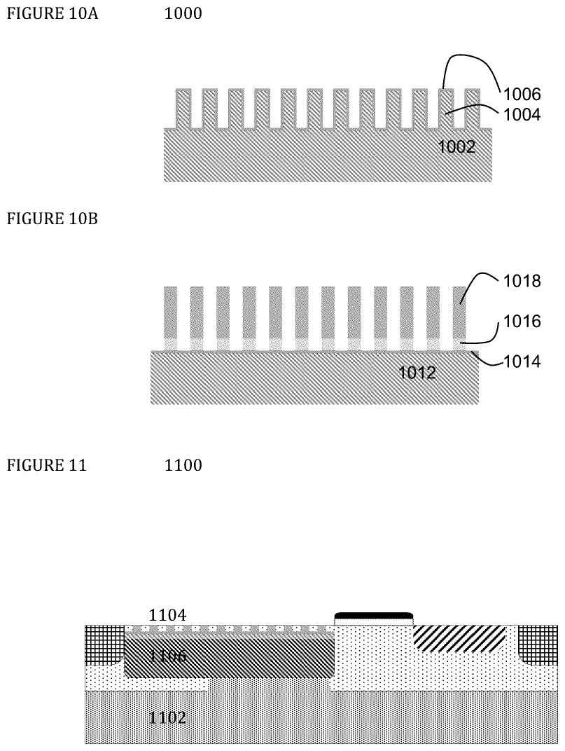

As indicated, nanopillar arrays are useful at the gas-sensor surfaces of devices in accordance with the present disclosure. FIGS. 10A and 10B are cross-sectional schematic side views of embodiments of nanopillar arrays which can be formed or applied to the sensor surfaces of detectors such as those illustrated in FIGS. 2 and 4. Illustrated in FIG. 10A is a nanopillar array 1000 comprising the semiconductor pixel substrate 1002 with a plurality of nanopillars 1004 projecting therefrom. The nanopillars 1004 are desirably less than 2 microns (eg 0.1-1.5 microns) high, and less than 0.5 microns (eg 1-200 nm) wide. The semiconductor substrate 1002 and the nanopillars 1004 are monocrystalline. The nanopillar array and internal surface zones of the semiconductor substrate 1002 are coated with a nanothin MOX layer 1006, as illustrated in FIG. 10A. Atomic layer deposition and similar vapor treatment (eg, with TiCl₄ and other volatile MOX precursors) are particularly useful methods for depositing a uniform nanothin MOX layer 1006 on the nanopillar array. Like insect sensilla, a nanopillar array more effectively captures gas analytes than a flat planar surface. In addition, a nanopillar array surface is more readily heated by a subbandgap infrared pulse. Because the nanopillars of the device 1000 are part of the monocrystalline semiconductor pixel, the readily conduct the carriers produced by gas reaction at the MOX surfaces to the detection circuitry. To enhance gas-detection sensitivity, nanopillar arrays can also be optimized for analyte collection over extended periods of time (under program control). In this regard, a variety of high-temperature-stable polymer materials such as poly(dimethylsiloxane) in fiber form are conventionally used to absorb odorants and other volatile organic molecules. The SPME fiber materials with absorbed gas analyte(s) are conventionally inserted into the heated injection port of a gas chromatograph to release the absorbed materials for separation in the chromatographic column. Different solid phase microextraction materials (SPME) can have selective absorption characteristics, depending for example, on the polarity of the target analyte(s)⁶⁶.

Illustrated in FIG. 10B is a nanopillar array 1010 which utilizes an organopolymeric material for capture and storage of gas analytes. As illustrated in FIG. 10B, the image pixel nanopillar array 1010 comprises a semiconductor pixel substrate 1012 with a nanothin MOX gas-detection layer 1014 like that of the embodiment 200 of FIG. 2 or the embodiment 400 of FIG. 4, and organopolymeric nanopillars 1018 which are suitable for collecting and entrapping gas analytes. In this regard, polymers such as polysiloxanes and acrylic polymers are conventionally used to collect samples of (typically unknown) gas analytes from the atmosphere, for subsequent analysis by gas chromatograpy, HPLC, mass spectroscopy or other analytic instrument. If the nanopillar polymer material is reactive with the MOX nanothin sensor layer at temperatures of sensor operation, an intermediate layer 1016 of nonreactive material (for example silicon dioxide) may be provided between the MOX sensing layer 1014 and the polymer nanopillars 1018. A wide variety of fabrication processes for nanopillar formation and/or application, including etching, self-assembly and nanoimprinting have been developed⁶⁷. The organopolymeric nanopillars 1018 collect and store gas analytes at lower (eg, ambient) temperatures, and release them at elevated temperatures. Accordingly, the nanopillar surface can collect analytes for a period of time under program control, for example while the device is operating in imaging mode with the imager nanopillar surface exposed to the atmosphere. Upon initiation of a gas-sensing cycle, the imaging light is first shuttered, and the nanopillars are pulse-heated to release their stored gas analyte(s) to the MOX sensing surface 1014. Pulse heating is readily accomplished by IR pulse on the IR-absorbing organopolymer nanopillars. It is noted that a variety of different polymer materials or different absorption selectivity may be used to form nanopillars in different zones of the image sensor, to provide sensor selectivity and analyte-differentiation data. The nanopillar materials can also be molecularly imprinted to increase selectivity to specific molecules of particular interest as analytes for detection. Illustrated in FIG. 11 is a schematic cross-sectional side view of a portion of dual-function frontside CMOS gas- and image-sensor 1100 having a nanopillar array at the sensing surface 1102 like that of either FIG. 10A or 10B. The imager 1100 is, except for the nanopillar MOX sensor surface, a frontside CMOS image sensor for a CMOS camera-on-a-chip, like that described in U.S. Pat. No. 7,741,664 to Choi et al, issued Jun. 22, 2010, which is hereby incorporated by reference herein in its entirety.

Thin and/or nanoporous titania dielectric (doped and undoped semiconductor, including molecularly-imprinted TiO₂) has surface depletion zones which reduce its electronic carrier density. Accordingly, reduction of the “native” negative surface charge of oxygen-surface-charged TiO₂ caused by adsorption and/or reaction of analyte, can significantly change the titania dielectric constant at VIS/IR plasmon frequencies. Also, pulsing UV at a TiO₂ plasmonic sensor zone with analyte adsorbed can remove surface Oxygen and negative charge, increasing the semiconductive character, which is sensed by plasmon effects. Similar effects can be utilized with other semiconductor layers. Accordingly, thin and/or porous metal oxide layers can change dielectric constant with adsorbed material, and upon “combustion” of adsorbed material via temperature or UV pulse. Oxidation of different analytes can vary in kinetics with UV pulse-induced oxidation. The electrons/holes induced in the thin oxide layer, and accordingly the dielectric constant of the material, vary over different timeframes upon and after a UV pulse, depending on the presence of adsorbed analyte. When the dielectric material of a plasmonic detector site has known selective analyte absorbing

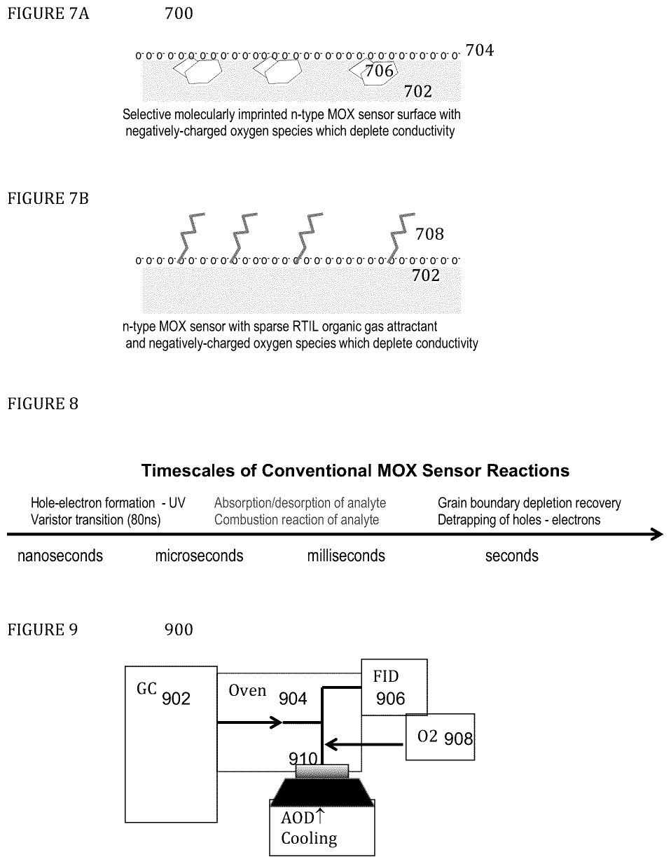

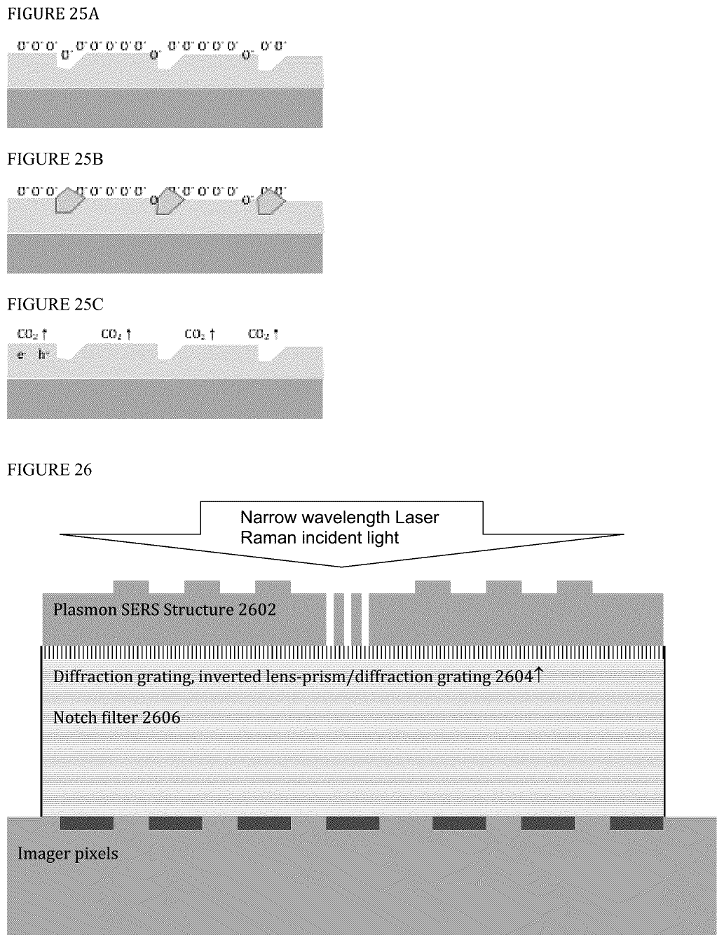

In this regard, as illustrated in FIG. 25A with reference to FIGS. 7A and 7 B), MOX surfaces 2502 can be designed to have negative surface ions which deplete carriers. As shown in FIG. 25 B, upon adsorption of an analyte (such as by a molecularly imprinted MOX selective for specific analyte(s), the dielectric constant can change by charge change and analyte addition to the near-metal plasmon zone (especially for a porous molecularly-imprinted material) As illustrated in FIG. 25 C, upon application of a UV light pulse in a programmed and appropriately timed manner, electrons/holes are generated, the analyte can be oxidized (reduced), depleting the surface oxygen ions and introducing charge carriers in the MOX. Bigger molecules are combusted by a series of sequential oxidation reactions, so produce a different response time than smaller analytes. CMOS and CCD imagers can sample this rate of change at rates corresponding to their frame rates, which can range from say, about 4, to over a million frames per second (for short bursts). This response rate information is useful for distinguishing analytes.

IR spectroscopy is widely used for analytical identification and characterization of organic molecules. Specific organic groups (eg, energetic nitrates⁶⁸, aliphatics, aromatics, azides, arenes, amines) have specific IR absorption band signatures. Organic molecules can also have broad, less specific UV and VIS signatures. For example, by applying a short (eg 1-100 microsecond) intense IR pulse to the MOX surface, of a wavelength(s) intensely absorbed by gas molecule #1, but not by gas molecule #2, the sensing of gas molecule #1 will be enhanced. (The MOX surface layer may be designed to absorb a broad IR spectral pulse range to “instantaneously” heat it to a desired operating temperature if appropriate). A UV pulse may also be used for surface heating and reaction activation, with concurrent or different IR pulse timing to control the reaction mechanism timing and sensing. Quantum Cascade MWIR lasers are available in small size, high power, and wide tunable wavelength range (3-160μ). A very broad range of conditions can be generated at or applied to the MOX imager sensing surface in different zones for differential gas-sensing data. The IR/UV pulse-heated MOX nanothin surface can cool for the next gas-sensing cycle, or reversion to photographic imaging use. By simultaneously applying a pulsed IR spectrum across the imager surface (eg, by refractive or diffractive separation of a broad IR LED pulse), reaction of different gases will be optimally favored at different locations on the MOX surface, much like an FTIR spectral analysis (eg, a broad IR spectrum may be pulsed perpendicular to the electric field gradient of the illustration of FIG. 6A, for a 2-D reactivity gradient, 1D for variation of IR spectral activation, and an orthogonal 1D for redox potential variation as described below).

As indicated, CCD and CMOS image sensors and cameras-on-a-chip can use a transparent, electrically-conductive MOX surface to control dark current. The Sony “backside” CMOS imagers of Patent Application Publication 20110058062 can apply a uniform external field of about −1 volt to one embodiment having a conductive ITO layer, to control hole-generated dark current. Like the IR absorption spectrum, the redox potential of different gas analytes is one of their distinguishing characteristics. Different gas compounds have different oxidation-reduction potentials. These differences may be exploited by biasing the MOX sensor surface of the gas sensor embodiments of the present disclosure during the sensing cycle. Different bias levels may be used sequentially with the same sensor, or simultaneously with otherwise identical sensors to obtain a redox profile of the analyte gas(es) to facilitate characterization.

FIGS. 6A and 6B are schematic top views of a dual function sensor “camera-on-a-chip” 600 like that of FIG. 4, in which a voltage gradient is applied between electrodes 606, 608 across the imager pixel sensor MOX surface 602. The reaction of one redox potential sensitive gas analyte is schematically shown in FIG. 6A, and the different reaction pattern of a different gas analyte at the same dual-function sensor is schematically shown in FIG. 6B. By applying an electric field gradient across the MOX surface 602 of the gas-detecting imager surface 602, a redox reaction gradient can be provided across the MOX surface, to produce a gas detection response somewhat analogous to cyclic voltammetry in analytical electrochemical analysis.

To enhance “capture” of particular organic gas molecules, MOX sensor surfaces can by “molecularly imprinted” to enhance adsorption of specific gas molecules to mimic the highly selective recognition of biological receptors. Semiconductor metal oxide layers can be “molecularly imprinted” for increased thermodynamic bonding for adsorption of specific analytes⁶⁹.

Relatively redox-stable organic molecules can be sparsely attached to the MOX sensor surface to retain organic gas molecules from desorbing from the MOX sensor surface. Some organics such as certain Room Temperature Ionic Liquids (RTILs) can have broad (eg, 5-6 volt) redox windows and negligible vaporization. They can be sufficiently stable not to be oxidized by OH radicals formed on semiconductor oxides (eg TiO₂) by UV⁷⁰.

Both approaches may be used to enhance collection of (by increasing thermodynamic attraction to reduce desorption), and distinguish specific analytes in these sensor systems.

While the embodiment 400 has been described with respect to VIS imaging, dual function Ambient SWIR and MWIR Camera and Gas Sensors can also be designed. Midwave (3-7μ) IR cameras of decent performance typically require cryogenic cooling of exotic focal-plane materials such as HgCdTe or III-V quantum well devices which are bump-bonded to read-out chips. They are expensive, power-hungry weight-hogs. MWIR camera designs with dual function gas-detection capability which can be directly applied to the backside of inexpensive, lightweight silicon “cameras-on-a-chip” for use without cryogenic cooling, together with gas-sensing MOX capability of the type discussed above can transform inexpensive (eg, less than $50 silicon “Cameras-on-chips”) into high-performance, uncooled MWIR camera systems and gas sensor systems which are very lightweight, very inexpensive, and extremely small, at cell phone camera cost. Such systems are particularly useful for small UAVs and portable equipment where cost, sensor weight and energy consumption must be minimized.

The sensors described need not necessarily be dual-purpose gas sensors and imagers. There are many applications for high sensitivity, inexpensive, high bandwidth analyte sensors, particularly including medical diagnosis and environmental monitoring⁷¹. The present sensor designs can also be utilized for detection of analytes present in liquids such as seawater and other solvents. Such avalanche organodiodes and CCD/CMOS analyte-imaging designs can be used, for example, to detect pollution in rivers and streams, and to detect and trace back to the origin location of mine plumes in seawater. Molecularly imprinted MOX films⁷² are readily applied to avalanche organodiode or CMOS/CCD imager pixel input surfaces as previously described. A thin electroconductive diamond (BDD) or diamondlike carbon coating is desirable intermediate the pixel semiconductor substrate and the MOX or other electrocatalytic surface. Conductive boron-doped diamond electrosensor surfaces have a wide electrochemical potential window in aqueous and non-aqueous media, very low capacitance and extreme electrochemical stability. Diamond electrodes have high overpotentials for inner-sphere electrochemical interaction (eg, hydrogen and oxygen evolution) which facilitates electroanalysis of a wide variety of chemical species. The relatively inert diamond sensor surface can be modified by catalysts for specific analytes. It is noted that the area of the electroactive sensor surface in contact with the seawater or other liquid can be reduced significantly in the avalanche organodiode and CMOS/CCD designs to adjust the total current flow to be within the total maximum current-removal capacity of the respective sensels (analyte sensor pixels). By employing a variety if differently-selective electrode surfaces on the analyte pixel surfaces, different analytes are caused to produce different sensed responses at the different pixels of the sensor. The potential of the sensor surface may be varied, while the camera-on-a-chip or avalanche diode is operating, to produce an electropotential redox data for each pixel and its associated sensor surface. This provides additional analyte-distinguishing information in addition to the surface selectivity information which may be based on molecular shape and/or site-complexing affinity, such as for differently molecularly-imprinted sensor detector element surfaces.

A lenslet prism dispersion array can be used for efficient image light utilization in the VIS and IR, and to facilitate color imaging in dual function gas-sensing imagers in accordance with the present disclosure. As illustrated in the embodiment 1200 of FIG. 12, the imaged light energy from an imaging lens applied to a high dispersion (eg, low Abbe number) lenslet prism can be separated into RGB color components, rather than being “wasted” by being absorbed in a filter. Upon passing through refractive prisms, the different wavelengths of the image are refracted at different angles depending on the refractive index of the lenslet prism at that wavelength.

By using refractive microlens optics, incoming image light can be separated along one image axis with minimal loss into separate RGB components directed to multiple adjacent pixels on the same imager. The adjacent pixels can be designed to be rectangular rather than square (with the narrow width along the color-refraction-dispersion direction).

For a triangular prism, the angular dispersion δE, the angle by which the emergence wave front is rotated when the wavelength changes from λ to λ+δλ, is given approximately by

δE=b/l dn/dλδλ.

where b is the base thickness, l is the width, and dn the dispersion. By adjusting the distance of a prism lenslet array, and by using lenslet prism materials with high dispersion, such as TiO₂ and SrTiO₃ as well as high dispersion plastics such as polystyrene and polycarbonate, relatively large color separation on a scale corresponding to imager pixel dimensions can be provided. In addition, by using a second layer of microprisms of a different material which has an additive dispersion, or even an anomalous “reverse dispersion” curve such as SnO₂:F⁷³, the color separation can be further enhanced, while correcting for the “off-axis” effect of one layer of microprisms.

As illustrated in FIG. 13, by designing microprisms specifically for the pixel dimensions of a given imager, the spectrum of an image pixel site can be spread over multiple (eg, 3 for RGB separation) subpixels of a CMOS or CCD imager without requiring a colored filter coating on the pixel surfaces. The distance between the pixel surface and the lenslet prism array can preferably range from about 200 to about 1000 microns, within conventional micro-optics ranges. Such separation provides atmospheric access for the environmental atmosphere to contact the MOX surface, for gas analyte detection. The lenslet prisms should have a converging design, to prevent the color divergence from spreading across adjacent pixels. “Light stoppers” can also be fabricated at each RGB pixel set, as illustrated in FIG. 13, to limit intrapixel color mixing. Complex analog lenslet surface curvatures such as the convex off-axis lens-prism structure of FIG. 13 are readily fabricated using analog (gray scale) photomasks. By using such a converging lens design, the spread spectrum can be controlled and “focused” on selected pixels or zones of an image sensor. Fabrication of converging, dispersive, color-separating microprism arrays can utilize conventional analog “gray scale” mask technology, such as HEBS continuous gray scale analog photomasks (Canyon Materials, Inc.), to precisely control the analog etching of thin films of TiO₂ and/or SnO2:F on a suitable substrate, to create the desired microprism arrays matched to selected CMOS or CCD imager geometry. As indicated, a number of organopolymers have high dispersion (low Abbe number), such as polystyrene. Plastic lenslet color-separating arrays can be inexpensively mass-produced by molding, stamping and other plastic MEMS and other forming techniques.

The resulting RGB microprism lenslet image color separation arrays are robust and efficient in light utilization, and are an effective design for dual function gas-sensor color cameras. Moreover, the design of the microprism lenslet array can be coordinated with the design of the CMOS or CCD image sensor, to maximize the geometry of the imager. For example, by using 3:1 frontside or backside pixel geometry (the length of each pixel is three times its width), the microprism lenslet pixels may be matched to the imager pixel array to form square image pixels, if desired. Optical barriers/reflectors may be fabricated at each RGB pixel boundary as illustrated in FIG. 13, to limit color crosstalk (eg, “red” refracted light intended for a specific “red” subpixel from impinging on the “blue” subpixel of an adjacent pixel). Such barrier/reflectors may also be fabricated on the lenslet prism array. If they are continuous between the lenslet prism array and the surface of the imager (and appropriately aligned therewith) the channels formed are useful for control of gas flow of specific gas samples to specific imager-gas-sensor zones, by appropriate manifolding. These design issues are simple and inexpensive to implement in “production ready” CMOS imagers. The lenslets can also be designed to avoid the in-pixel, inactive CMOS amplifiers and other “frontside” structures, to increase the effective “fill factor” in frontside CMOS or CCD imagers.

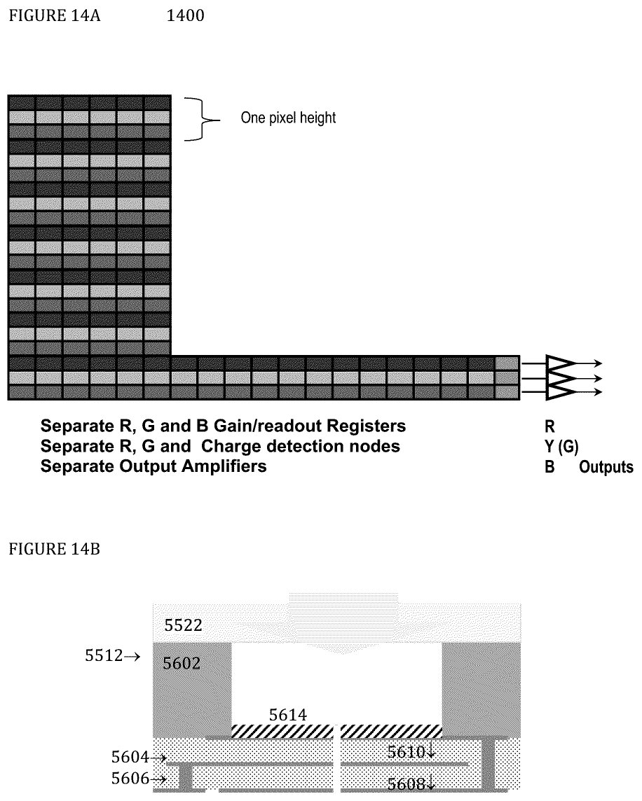

A 3:1 imager 1400 with colored zones indicating the pixels to which a color-separating prism lenslet array has distributed the image colors, is illustrated in FIG. 14A. The illustrated imager is an electron-multiplying CCD (eg, L3CCD or Impactron CCD) having a gain register with a large number of stages in which electrons are multiplied by low gain probability at every or multiple stages of the register to reduce readout noise. At very low gas analyte levels at which each pixel has few, if any electrons produced by gas reaction within the frame integration (sampling) timespan, noise associated with the stochastic multiplication is effectively removed at the cost of counting multiple electrons in the same pixel as a single electron.

As described herein, sensor systems can be provided with means for varying physical and/or electrochemical conditions under which the VOC is sensed, such as electrochemical potential, IR, VIS, UV excitation, refractive index change, and/or temperature. This is quite useful in providing “hyperolfaction” information for different analytes, in a manner somewhat conceptually similar to the use of hyperspectral imaging to distinguish visual field objects for image interpretation. A variety of differently-sensitive MOX or other detection materials may be applied to different preselected zones by conventional masking and deposition steps. A different masking and deposition step is used for each different detection zone. Such “brute force” methods are relatively expensive. By using a limited number of masking and deposition steps, combined with a limited number of deposition cycles, a wide variety of exponentially-increasing (with number of deposition cycles) different detection zones may be applied to the detection system surface:

Different MOX or other inorganic, organic, and/or mixed inorganic/organic materials may be applied to different sensor zones (“sensels”), to provide different sensitivity to the respective zones. For example, a layer of 1 to 5 nanometer TiO2 may be applied to a backside imager surface by Atomic Layer Deposition (ALD), which is subsequently stabilized at a temperature of 200-350 Centigrade in air for 1-15 minutes. This reduces dark current, and grows crystallite size. A TiO₂ sol gel with a preselected analyte compound dissolved therein, such as an organophosphorous nerve agent or insecticide, may then be spun onto the stabilized TiO2 layer to form a “molecularly imprinted” layer 2-100 nanometers thick. This molecularly imprinted layer may be slowly heated and/or washed with an extraction solvent in accordance with conventional practice, to remove the imprinting molecules while retaining the molecularly-imprinted capability of selectively and preferentially adsorbing the compound with which it was imprinted. The molecularly-imprinted layer may desirably be an aerogel or xerogel, having a density of less than 0.5 grams per cubic centimeter. “Click” chemistry processes⁷⁴ may also be used to apply specific surface layers of various materials which are differently-selective in response to vapor analytes, including vapor analyte mixtures. “Click” and other sequential deposition processes can produce a diverse range of functionality and differently-sensitive groups onto a variety of detection substrates. They are especially useful in producing combinatorially-different sensel detector surfaces with only a limited number of deposition cycles. The number of differently-constituted detector surfaces can increase exponentially with deposition cycle number. The location and structural composition of each different layer combination is inherent in the mask and deposition design.

For more generally discriminatory, more biomimetic vapor sensor systems, it is desirable to utilize hundreds to thousands of different detector elements of widely different kinds and types of selectivity. This may be accomplished in MOX sensor systems and in other systems such as transmission-interrogated plasmonic detection arrays which are directly coupled to dedicated VIS-NIR measurement imagers, as will now be described in more detail.

Conventional liquid crystal (“LC”) vapor sensor cells are known which employ optical polarization twist alignment or refractive index change in thick liquid crystal layers for through-thickness polarization rotation for through-thickness crossed-polarizer cell detection. Conventional anisotropic twisted nematic and smectic liquid crystals employed in such polarization cells, such as E7, 5CB and 8CB can produce refractive index changes, Δn, on the order of about 0.1 or more (10⁻¹) as a result of dielectric anisotropy, but they do not fully utilize these anisotropic properties for crossed-polarizer detection. Such cells employ rotational twist alignment change through thick (˜3 to 20+ micron) liquid crystal layers, triggered by the presence of phosphonates at metal perchlorate surfaces, for sufficient optical rotation for crossed-polarizer detection. It takes a relatively long time for very low-concentration nerve agent or other dangerous vapor to fill a relatively large crystal crossed-polarizer cell volume, and to diffuse to a metal perchlorate LC-alignment-change surface, compared to a much smaller, thinner zone. Conventional LC single cell vapor sensors developed by or through the US Department of Defense can lack sensitivity, or be enormously complicated, expensive, and unsuited for substantial differential sensitivity correlation of large numbers of different analytes, or field use.

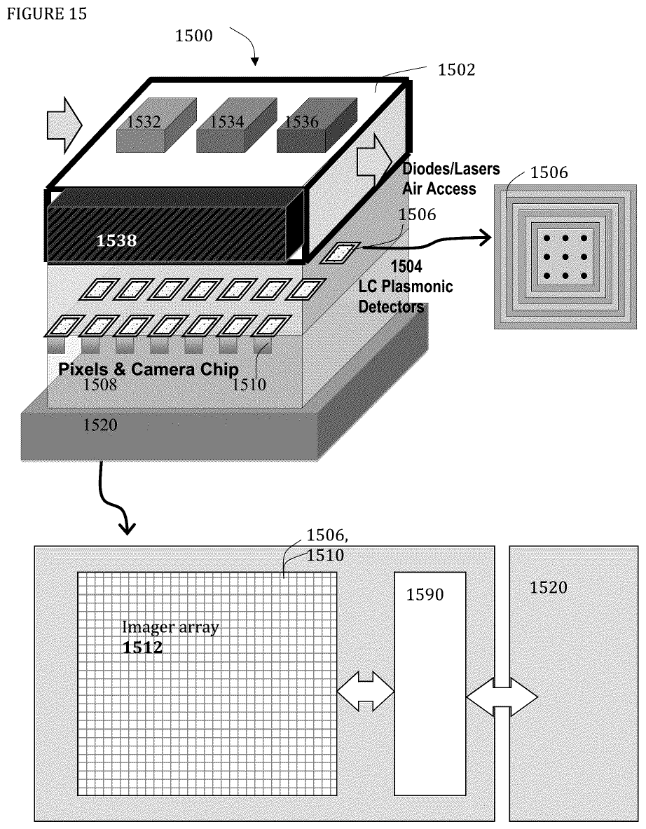

As described above, the present disclosure is directed to sensing methods and apparatus which can utilize thousands or millions of individual detector elements, rather than several or tens of detector elements, so they can sense and distinguish large numbers of different vapors in massive (eg, million-sensor) parallel. Embodiments of integrated sensing modules may be functionally biomimetic, to emulate the insect and mammalian “sense of smell”. In this regard, the illustrated embodiment(s) 1500 of FIG. 15 may have at least a hundred thousand, and preferably at least a million independent, isolated sensor sites. The sensor sites may comprise at least 25, more preferably at least a hundred, and more preferably at least 250 differently selective detector types with high sensitivity level, with multiple sensing sites of each different detector type. Such embodiments may also have fast detector element detection speed suitable for kinetics measurement and tracking. The detector elements may preferably have “reset” or analyte concentration modulation sensing capability (eg, capability of responding to concentration variations), summation (or other statistical organization) of like-detector element output, and pattern-recognition processing for analyzing, correlating and recognizing patterns of the summed/organized detector responses for specific odorants and their mixtures.

The illustrated sensor module 1500 comprises four integrated components. In this regard, the module comprises an interrogating light source 1502, which for compact modules may preferably be a semiconductor diode light source, to interrogate and generate refraction-sensitive plasmons at the detector sites of a plasmonic sensor array. The sensor module 1500 further comprises a plasmonic resonant light-transmissive array 1504 of a plurality of individual detector sites 1506 for generating plasmons sensitive to near surface refractive indices of the respective detector sites, and for transmitting VIS-NIR interrogation light from the light source 1502 through the plasmonic array detector sites as a function of refractive indices of the detector sites. By near surface is meant the zones within about 100 nm of the metallic surface of the plasmon detector sites. By VIS-NIR interrogation light is meant light within the practical photon detection range of silicon and silicon-germanium based solid state imagers, typically from about 300 to about 1100 nm (preferably from about 400 to about 950 nm for silicon, imagers and cameras-on-a-chip). For sensor systems 1500 using silicon based imagers, plasmonic arrays resonant in the longer wavelength range which is still efficiently detected by silicon, such as 600-900 nm, may be more economical to manufacture than such arrays with smaller features resonant in the 300-500 nm range. The plasmonic detector sites 1506 are provided with access to the atmosphere may be differently sensitive in refractive index change in response to different analytes, such as gases and vapors of measurement or detection interest. The plasmonic array may comprise a Lindquist Isolated Plasmon Array or other plasmonic sensor array which may include up to hundreds of thousands, or millions of individual crosstalk-limited detector sites. Lindquist Arrays can preferably have millions of individual plasmonic detector sites, with up to hundreds or thousands of differently-selective vapor sensing elements. The module 1500 further comprises a digital imager 1508 having a plurality of light detecting pixel sites 1510 respectively adjacent individual plasmonic detector sites 1506 for detecting and/or measuring VIS-NIR interrogation light transmitted through the respective individual detector sites of the plasmonic array. The imager pixels are individually aligned with the Lindquist Array or other plasmonic sensor array detector sites, to measure, digitize and report the transmitted light for selective vapor detection at each site. The digital imager means 1508 produces a digitized output of the detected and/or measured light transmitted through the respective individual plasmonic detector sites, together with the relative location of the respective pixel sites 1510 and corresponding plasmonic detector sites 1506. Each sensor site may be normalized and/or corrected with respect to response to transmitted VIS-NIR light and/or analyte vapor response. The module 1500 further comprises a programmable microprocessor control system 1520 (which may include a suitable power supply) for receiving and processing the digitized pixel output of the imager 1508 for classifying, correlating, recognizing and reporting the sensing of vapor analytes sensed by the plasmonic array. The microprocessor system 1520 may control the interrogation light source 1502, the operation of the digital imager system 1508, the processing of sensed data, and external communication, as will be described in more detail hereinafter.

The illustrated interrogation light source 1502 is a programmable light source under control of the microprocessor 1520. The interrogation light source comprises the upper component layer of the module 1500, including a simple, rugged air-access frame with one or more VIS and/or near IR diode light sources 1532, 1534, 1536 directed at the detector sites 1506 of the adjacent plasmonic sensing array 1504. LEDs and laser diodes are available across the UV-VIS-IR spectrum. Specialized semiconductor light sources are commercially available with myriad features such as high-intensity and tunability. Their light output may be continuous, but is preferably pulsed in synchrony with the imager chip operation for extremely low power consumption. A single LED is adequate for some purposes, but multiple light sources 1532, 1534, 1536 selected for different sensor plasmon interrogation wavelengths, or wavelength ranges, are preferred. For example, three semiconductor laser sources with center wavelengths separated by center wavelengths 10 to 25 nm apart can cover a relatively range of plasmonic transmission maxima of the detector sites in operational use. Angle of incidence differences in interrogation light at similar sites 1506 having different, known physical locations in the array with respect to the light source(s) can provide additional measurement accuracy. This produces more accuracy and range-of-analyte versatility. This “top” light interrogation layer 1502 provides atmospheric access for analyte sensing, and may be fabricated on a wafer scale, for integration and dicing into integrated modules in a similar manner as conventionally used in CMOS camera manufacture. The light interrogation system 1502 may also comprise one or more spectrographic infrared source(es) 1538 for IR spectroscopic analyte identification, as described below. This is an additional important aspect of preferred methods and apparatus in accordance with the present disclosure.

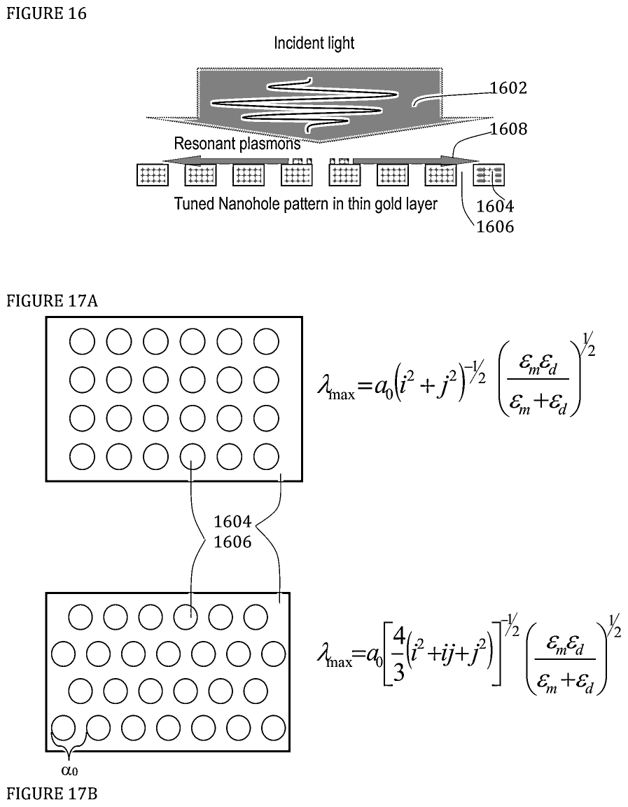

As indicated, the illustrated vapor-sensing module 1500 comprises a plasmonic sensing array 1504 of a plurality of individual, plasmonically isolated detector sites 1506. Plasmons are fluctuations in electron density at the interface of an electrically conductive metal and a dielectric. In this regard, FIG. 16 is a cross-sectional schematic illustration of incident light 1602 on a 2-dimensional optically dense (opaque) metal foil 1606 having regularly spaced subwavelength holes 1606 through the foil. As schematically illustrated in FIG. 16, Surface Plasmons (“SPs”) are coherent fluctuations 1608 in electron density reinforced by impinging light 1604 of appropriate wavelength which are confined at the surface of the metallic (eg, Au, Ag, Ti, Al) optically dense conductor 1604 having negative dielectric permittivity &, adjacent a dielectric with positive permittivity. SPs resonate along the metal surface, confined at this interface region⁷⁵. Properly designed subwavelength patterns of nanoholes 1606 in the metal layer 1604 can couple the impinging light 1602 into surface plasmons. The light is diffracted into evanescent modes at the surface of the metal which can effectively “funnel” light of wavelength larger than the width of the holes 1606 through to the other side of the metal film 1604. The resonant conditions of transmission are directly dependent on the dielectric constant of the dielectric at the metal surface⁷⁶. The plasmons decay exponentially away from the metal-dielectric interface, as a function of wavelength, with shorter wavelengths decaying faster. For VIS-NIR wavelengths, surface plasmons primarily sense dielectric/refractive index properties with logarithmically-declining effect within 100-200 nm, with the most influence within from about 0 to about 75 nanometers of the metal plasmon surface, and the most powerful effects within from about 0 to about 25 nm of the metal plasmon surface (shorter for “blue” and longer for red and near infrared wavelengths). The resonant SP wavelengths appear as intense maxima in the transmission spectra of the perforated metal films.⁷⁷ The nanoholes themselves also have localized plasmon resonance properties that can also be tuned and sense refractive index change, as will be discussed below.

FIG. 17A is a schematic top view of a metal film 1604 with a square array of through-penetrating holes 1606. As illustrated in FIG. 17A, for a square array of holes 1606 in an optically dense thin conductive metal film 1604, the SP resonance maxima λₘₐₓ, the wavelength of maximum transmission of light through the subwavelength holes of the metal film, may be approximated by:

$${λ}_{max} = {{a}_{0} ( {i}^{2} + {j}^{2} )}^{- 1 / 2} {( \frac{{ε}_{m} {ε}_{d}}{{ε}_{m} + {ε}_{d}} )}^{1 / 2}$$

where α₀ is the lattice constant (periodicity) of the square array, εₘ is the dielectric constant of the metal, Ed is the dielectric constant of the dielectric material immediately adjacent the metal surface, and i and j are momentum index integers. Primary transmission wavelength resonance occurs for i=j=1 at approximately 1.1 α₀ in air, with variation depending on the dielectric constants εₘ, ε_{d} and factors such as localized hole shape and resonances and front-back surface coupling through the holes. Similarly, a hexagonal array of holes 1606 in a metal film 1604 is illustrated in FIG. 17B. The hexagonal array of subwavelength holes 1606 through a thin optically dense metal conductor 1604 may tend to produce sharper and “cleaner” resonances and transmission maxima than square hole arrays because of their greater symmetry, with nominal transmission maxima λₘₐₓ of approximately:

$${λ}_{max} = {{a}_{0} [ \frac{4}{3} ( {i}^{2} + ij + {j}^{2} ) ]}^{- 1 / 2} {( \frac{{ε}_{m} {ε}_{d}}{{ε}_{m} + {ε}_{d}} )}^{1 / 2}$$

The metal film thickness⁷⁸, array pattern, hole area/width⁷⁹, depth, shape, and coatings⁸⁰ can all be employed to affect coupling of incident interrogation light from a source 1502 to plasmon resonances of an array 1504 and transmission through detector site subwavelength holes of a detector element 1506 [FIG. 15]. Square, rectangular, triangular, “bowtie” and step-function holes can also resonate and intensify the electric field at edges and small-radius “points”⁸¹.

Localized Plasmons (“LPs”) can also be generated in the subwavelength interrogation light transmission holes 1606 through the metal film. The localized plasmons within the holes can also be designed to resonate with the Surface Plasmons. The plasmonic electric fields can be greatly amplified at the edges of holes and other subwavelength structures, particularly if the LPs are resonant with the SPs. This can sharpen and enhance the sensitivity of adsorbed gas analyte detection at these surfaces. LPs which are in resonance with 2-D array-pattern-generated SPs on the patterned metallic focal plane are desirable to further enhance detection of refraction-changing gas adsorbates. Pyramidal and cone shapes can significantly concentrate the Plasmon electric field⁸². Localized Plasmons can also be excited by light on metal nanoparticles which are much smaller than the light wavelength⁸³. Localized plasmon resonance within the holes is also quite sensitive to local dielectric constant and refractive index change⁸⁴.

As indicated, the plasmon resonance, and consequently the wavelength(s) of maximum extraordinary transmission through an optically dense metal film, is a direct function of the dielectric constants of the metal and the dielectric immediately adjacent the metal. There is little if any influence from dielectric zones farther than about 125 nm from the metal surface, and only minor influence from dielectric zones greater than about 100 nm from the metal surface. This produces a very sensitive and rapid mechanism in the sensor 1500 for sensing vapor analytes by transducing the presence of analyte into changes in dielectric constant (and refractive index) measured by changes in extraordinary light transmission.

There are many different types of liquid crystal and other materials and phases having a variety of different anisotropic orientations and optical properties which may be employed in various embodiments of sensors described herein⁸⁵. Thermotropic liquid crystal materials exhibit anisotropic optical properties, and phase transition(s) as temperature is changed. The various LC phases (mesophases) can be characterized by the type of ordering, such as positional order (whether and what kind or order the liquid crystal molecules have in a fixed lattice) and/or orientational order (whether molecules are mostly pointing in the same direction). The range and extent of such order may also vary depending on temperature, material properties, analyte presence and other factors. Thermotropic liquid crystals typically have a range of anisotropic phases over an operable temperature range, above which they “melt” and become isotropic. That is, they no longer have different optical properties in different directions. For example, a liquid crystal may exhibit a number of smectic and nematic (and finally isotropic) phases as temperature is increased. Nematic liquid crystal phases are one important type of materials useful in the present sensors. In the nematic phase of a liquid crystal, rod-shaped organic molecules have no generally fixed positional order, but self-align to have long-range directional order with their long axes roughly parallel. Most nematics are uniaxial with one axis which is longer and preferred, with the other two axes perpendicular to the axes of the rod-shaped molecules having approximately equivalent optical properties. However, some liquid crystals are biaxial nematics which orient along their long axes and also orient along a secondary axis, and nematic materials may also have chirality or twisting along the axis. Nematics which have a polar endgroup and a less polar group at the other end of the rod-like molecules may be readily aligned by an external electric field. Smectic phases have both directional and a variety of positional orders which produce different refractive indices and dielectric constants in different directions. There are many different smectic phases, all characterized by different types and degrees of positional and orientational order. Liquid crystal blue phases appear in a temperature range between chiral nematic and an isotropic liquid phase. Disk-shaped liquid crystal molecules can orient as columns or layers which produce anisotropic refractive indices.

Because some lower molecular weight liquid crystals may tend to evaporate over time, limiting long-term storage and sensor stability, higher molecular weight liquid crystal polymers and oligomers such as siloxane oligomer and polymer liquid crystals⁸⁶ are useful as non-volatile dielectric components for the plasmon structures described herein. Siloxane liquid crystal materials can be relatively transmissive to many analytes, can be applied to metallic plasmon structures in thin layers (eg, ˜<5 microns thick, preferably less than about 1 micron thick), and can form MIPs upon subsequent crosslinking in the presence of a target analyte which is removed after crosslinking. The effective evanescent field thickness in dielectric sensing layers adjacent metal plasmon surfaces is typically effectively less than a micron, with most of the refractive index interaction being within 50 to 100 nanometers of the metal surface. Because response times for analyte sensing are inversely related to the thickness of the sensing layer, use of such thin liquid crystal layers of the present systems provide such systems with rapid response times.

A dimensionless unit vector, the Director, conventionally refers to the preferred orientation of the liquid crystal molecules. There are a number of standard positional order parameters which characterize the molecular density or other measures by the variation of the density of the center of mass of the liquid crystal molecules, or other statistical spatial characteristics, along a given vector. Even very small changes in the director and/or order parameters caused by the presence of a vapor or other analyte adsorbed in the liquid crystal at the detector site can change the near refractive index of the plasmonic resonance transmission to transduce analyte presence into a transmitted VIS-NIR light signal.

Initial alignment and/or order of the liquid crystal material without the presence of an analyte (eg, in pure air) is typically preferably to maximize the Δn and/or the Δε of the material such that subsequent presence of an analyte will disrupt and/or change the transmission passband through the detector site. For example, alignment of a birefringent nematic liquid crystal perpendicular to the surface of the plasmonic metal film 1550 will maximize nₑ perpendicular to the metal surface and nₒ parallel to the surface, such that the dielectric constant sensed by the surface plasmons will change when this perpendicular order is even slightly disrupted. Similarly, the liquid crystal and surface alignment material could be designed to be initially parallel to the plasmon metal surface, such that disruption of this parallel alignment by perpendicular alignment caused by the presence of a polar vapor analyte attracted to a molecularly imprinted zone at the metal film surface, will produce a refractive index change to vary the plasmon transmission resonance. Orientation and/or alignment of the liquid crystal coating can be controlled at or very near the metallic plasmon structure in various ways⁸⁷, such as physical anisotropic surface treatment or patterning, attachment of, or decoration with, various materials, polymerization oriented deposition or patterning, electric field modulation, molecular imprinting, etc. For example, the main director of a polar liquid crystal material such as birefringent nematic 4-cyano-4′-n-pentyl-biphenyl (5CB) can be made perpendicular to the metallic plasmon surface because the polar nitrile groups of 5CB align at the metal ions on the plasmonic metal film surface may be oriented perpendicularly to the metal plasmon detector site surfaces by an attached polar chemical such as a copper, zinc, or aluminum perchlorate. Conversely, a nematic liquid crystal may have its long axes directed parallel to the metallic plasmon detector sites by nonpolar surfaces. Because the liquid crystal materials have different dielectric permittivities (and refractive indices) along different anisotropic, the wavelength passband through the array holes is different for different anisotropic orientations of liquid crystal materials. The thermodynamic and other strength(s) of the alignment attraction vary over wide ranges for different liquid crystal materials and different surface properties. When an analyte vapor such as a phosphonate nerve agent enters the liquid crystal and is (more strongly) attracted to the plasmon surface treatment than the one-end terminal nitrile endgroup, the 5CB liquid crystal is displaced from strong homopolar orientation and changes orientation to be more parallel to the near metal plasmonic surface. This changes the dielectric constant (refractive index) and the transmission passband wavelengths of the nanohole pattern at the detector site. This change in interrogation light transmission is readily sensed by a respective imager pixel site adjacent the nanohole array.

Vapor(s) in the atmosphere are readily absorbed in the ultrathin liquid crystal layer adjacent the plasmonic detection zones 1506. Vapor absorbed in the liquid crystal can affect liquid crystal orientation, order, chirality, stacking and phase the near plasmon surface of the plasmon transmission detector sites 1506 in a variety of different ways, which provide information for sensing and measuring the presence of such vapor in the atmosphere being sensed. Different vapors affect different liquid crystals and alignment designs in different ways⁸⁸, which provides information for distinguishing different analytes. An adsorbed vapor may interfere with the anchoring of the liquid crystal to the plasmonic metal layer near surfaces, and/or may interfere with or modulate the intermolecular attraction or repulsion forces between the liquid crystal molecules, the macroscopic order parameter, the orientational order of the liquid crystal, which in turn affects the transmission band of light through the nanoholes in the plasmonic detector sites 1506. The adsorbed vapor may introduce defects⁸⁹, or interfere with hydrogen bonding⁹⁰ or be adsorbed on the surface of nanoparticles/nanoplatelets distributed in the liquid crystal layer, to which modulate the refractive index at the near plasmon surface and/or within the nanoholes. If the adsorbed vapor molecules are polar, an alternating electric field can heat or otherwise disrupt the delicate anisotropic liquid crystal structure, which produces refractive index change. Any or all of these factors may be utilized for dielectric constant change to transduce the presence of analytes into transmitted light signals in accordance with the present disclosure. Infrared light which is preferentially absorbed by an absorption band or line of an adsorbed vapor analyte will “vibrate” or heat the analyte and surrounding liquid crystal molecules, affecting their refractive index at the detector sites 1506, thereby transducing selective infrared absorption by the vapor analyte into dielectric constant change at the plasmon sensor sites, which is measured by changes in transmitted interrogation light as described. By selecting or scanning the IR wavelength(s) applied by the IR source 1538, IR absorption of an analyte vapor present at a detector site 1506 can be detected by change in the refractive index at that site as interrogated by the amount of plasmon-resonant transmitted VIS-NR light to its underlying dedicated image pixel 1510.

The dielectric constants of liquid crystals are typically wavelength dependent, and temperature dependent. In their smectic, nematic, chiral and other anisotropic phases, liquid crystals have dielectric constants (and corresponding refractive indices) which are different along different directions of the liquid crystal structure. Many rod-like nematic liquid crystals have an ordinary refractive index nₒ and an extraordinary refractive index nₑ Liquid crystals such as biaxial liquid crystals with multiaxial order may have different dielectric constants (and corresponding refractive indices) along multiple axes, which may be treated as a matrix or tensor. The wavelength-dependent complex dielectric constant ε of a liquid crystal can vary significantly along each different anisotropic direction of oriented liquid crystal materials. The complex dielectric constant ε for each anisotropic direction through the at least partially ordered liquid crystal has real εᵣₑₐₗ and imaginary ε_{imaginary} components, related to the real n and imaginary k components of the complex refractive index:

$$ε = {ε}_{r e a l} + i {ε}_{imaginary} = {( n + i k )}^{2}$$

$${ε}_{real} = {n}^{2} - {k}^{2}$$

$${ε}_{imaginary} = 2 n k$$

Accordingly, by virtue of the relationship between ε and n, the plasmonic transmission wavelength(s) described above are similarly related to refractive indices adjacent the near metal plasmonic surface. As indicated, liquid crystals may have different dielectric constants (which are not “constant”) along multiple axes. Conventional liquid crystal materials used for twisted nematic cells typically have positive dielectric anisotropy, Δε, defined as Δε=ε|/−ε⊥ however, liquid crystals having a negative dielectric anisotropy are also useful for transducing the presence of analyte vapor(s) into plasmon resonance changes sensed by changes in transmitted light through plasmonic holes. As also indicated, the dielectric “constants” ε are not constant; they are functions of and subject to inter alia, anisotropy, phase changes, and temperature. The temperature dependence of liquid crystal dielectric constants may be utilized for infrared spectral analysis, and for transducing infrared absorption into dielectric constant changes sensed as plasmon resonance changes interrogated by VIS-NIR light, for “multicolor” infrared cameras and sensors, as will be described below.

A wide variety of plasmonic detector structures may be utilized in the module 1500 for dielectric constant control of transmission of interrogating light through plasmon detector sites 1506 to respectively adjacent imager pixels 1510 of the imager 1508. Lindquist Isolated Plasmon Sensor Arrays (LIPSAs) are preferred isolated plasmon arrays of substantially crosstalk-free, surface plasmon (“SP”) analytical sensing nanostructures, which are very sensitive to extremely small changes in dielectric constant and dielectric constant/refractive index⁹¹ at their near surfaces. They may be used in surface plasmon modes, in-hole localized plasmon modes, or both, to transduce the analyte presence into transmitted plasmonic light signals through the detection sites 1506⁹².

An enlarged top view of a single isolated detector site 1506 of a Lindquist plasmon sensor array 1504 is presented at the right edge of FIG. 15. The illustrated Lindquist Plasmon sensor site 1506 comprises a thin optically dense gold film 1550 having a central 3×3 square array of plasmon-generating subwavelength diameter holes 1552 fully penetrating the gold film. The illustrated thin metal plasmonic film is optically thick, so that light does not substantially pass through it except through the subwavelength nanohole array under specific resonance conditions. Optically thick films of good conductors such as gold or silver with small skin depth may typically be at least 40 nanometers thick, more typically at least 100 nm thick for good extraordinary transmission plasmonic detector array surfaces. The metal film should best be deposited to be very smooth, but may be deposited at an oblique angle to introduce anisotropy for liquid crystal orientation purposes. Preferably however, a very thin dielectric coating atop the metal film is deposited obliquely if such anisotropic substrate orientation is desired. Surrounding the square array of holes 1552 is a series of grooves 1554 formed in the gold film which function as Bragg reflectors to reinforce plasmons formed by interrogation light at predetermined wavelength. The illustrated Bragg grooves 1554 are optically dense, do not penetrate the gold film 1550, and serve to isolate the plasmons generated by the central hole array within that array, so that they do not generate substantial crosstalk with adjacent detector sites.

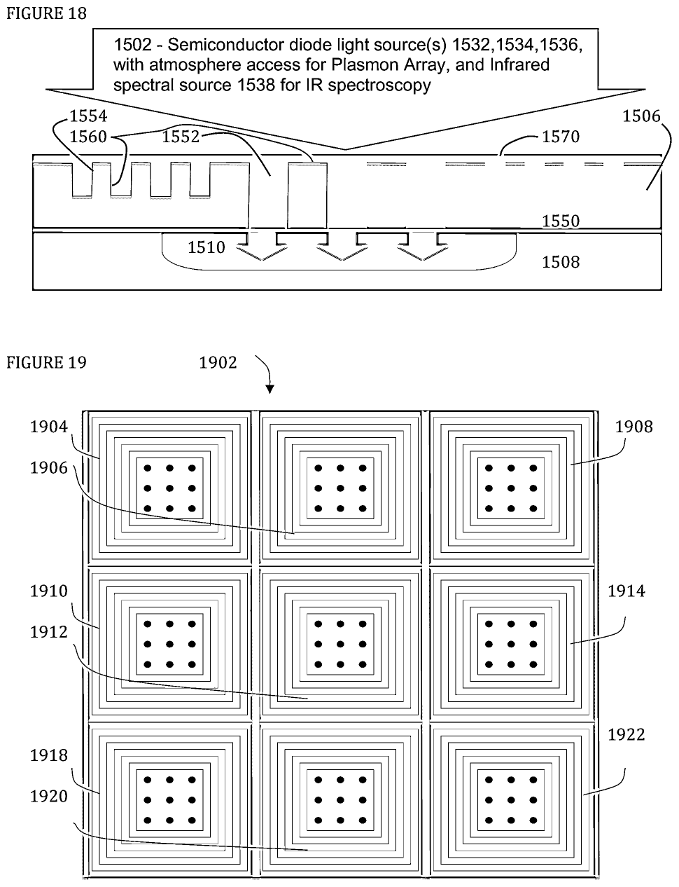

A cross sectional view of the detector site 1506 through the centermost hole, together with the interrogating light source 1502 and an individual pixel 1510 of the digital imager 1508 positioned to receive interrogation light transmitted through the subwavelength holes is schematically illustrated in FIG. 18. As illustrated in FIG. 18, the detector site 1506 further comprises a liquid crystal surface orienting layer which may comprise a conventional mercapto-amine attachment agent for the gold film surface, and a surface director agent such as copper or aluminum perchlorate, or a metalloporphyrin surface decoration which can serve as complexing or attracting agents for phosphonate nerve gas and other dangerous volatiles, yet function as a liquid crystal alignment agent in the absence of such volatile agents. As illustrated, the alignment surface 1560 may be formed atop the gold film surface, within the Bragg grating slots 1554, and/or within the subwavelength holes 1552. A very wide number of surface alignment agents may be used to promote different sensitivities for different volatile analytes, as will be described below.

As indicated, the relative attachment strength of a liquid crystal material to a substrate, as compared to that of an analyte absorbed to the substrate, can be important characterizing information for analyte determination. Different metal perchlorate surfaces are conventionally employed in crossed polarizer Fourier-plane (lens image focused) imaged liquid crystal vapor sensing systems. Disruption of liquid crystal order when a more-strongly adsorbed analyte displaces the liquid crystal at a boundary surface is measureable by conventional bulky crossed-polarizer systems. However, in accordance with the present disclosure, distinguishing characteristics of analytes adsorbed in LC at plasmon zones as described herein can be measured by applying an electric field to the plasmon structure to determine the molecular anchoring strength W of the liquid crystal in the presence of the analyte⁹³. The metal plasmon layer permits voltage-variation measurements which will provide additional analyte information⁹⁴. In this regard, the metal plasmon elements may be electrically isolated in fabrication, and operatively connected with a voltage source under programmed control. Potentials selected in the range of from about 5 volts to about −5 volts (or narrower ranges) may be applied in steps of for example 0.1 volt, to the electrically conductive plasmon layer structure. This applied potential will strengthen and/or weaken the attachment and directional order of the liquid crystal material of the respective detector sites, which will vary with different adsorbed analytes. Measurements are taken of the imager pixels at the different voltage potentials, which provides attachment strength information.

The illustrated sensor element 1506 of FIGS. 15 and 18 further comprises a thin liquid crystal layer 1570 atop the gold film 1550 (and orienting surface 1560). The liquid crystal layer 1570 may be relatively thin, because its effect on the plasmon resonance(s) is a near-surface phenomenon. For example, the detector 1506 can preferably have a liquid crystal thickness in the range of from about 25 to about 200 nanometers, and more preferably in the range of 25-75 or 50-100 nm. A variety of application methods are readily available for applying a thin 25-50 nanometer liquid crystal layer to these surfaces, including spin-coating, nanoprinting, vacuum vapor deposition, emulsion-attraction, and nano-pipetting⁹⁵. A conventional crossed polarizer liquid crystal transmission cells which use a twisted light polarization detection scheme may typically utilize a liquid crystal thickness about 100 times thicker, eg 2.5 to 25+ microns thick. With a linear Fick diffusion coefficient, diffusion of a nerve agent or other vapor through a thin 25 nanometer liquid crystal layer on a Lindquist Isolated Plasmon detector array may be roughly nominally a hundred times faster than through a hundred times thicker 2.5-to-25 micron liquid crystal layer of a conventional crossed polarizer transmission cell, and adsorbs roughly 100 times less of the nerve agent per liquid crystal layer atmospheric surface area for the same detection concentration of nerve agent or other volatile analyte in the liquid crystal volume.

The Lindquist Plasmon Sensor Arrays of FIGS. 15, 18 use a sensitive Δε, Δn refractive change through-hole plasmonic resonance light transmission transduction mechanism directly to respectively dedicated VIS-NIR light sensing pixels, rather than a twisted light polarization or prism reflection angle mechanism. The Lindquist plasmonic sensors, together with the respective transmitted interrogation light pixels can detect nominal refractive index changes, Δn, of ˜10⁻⁵ to 10⁻⁶ (or more) in a layer only 25 to 50 nanometers thick at the plasmonic array surface and/or within the nanoholes themselves. This is a factor of about 10,000 more sensitive than the ˜10⁻¹ Δn difference between the perpendicular and parallel refractive indices of a typical liquid crystal. By utilizing the very high refractive index change provided by liquid crystal refringence changes of many multiple transduction sensitivities at many multiple detection sites, detection levels similar to insect/mammal olfaction can be achieved.

As illustrated in FIGS. 15, 18, the detector elements 1506 of the illustrated Lindquist Isolated Plasmon Sensor arrays have a central regular nanohole pattern in a thin metal (Au, Ag, Cu, Al) film. The nanohole pattern generates surface plasmons from incident light at designed wavelengths. The resonant light wavelengths are determined by the size and pattern of the nanoholes and the nearby refractive index. The plasmons, when excited by this resonant light, funnel the light through the nanoholes to the other side of the metal film 1550, directly into the respective imager pixel 1510 for that plasmon detector site. As described, the Lindquist Arrays also have surrounding Bragg resonators⁹⁶, nominally tuned to the nanohole resonance wavelengths. The Bragg mirrors confine surface plasmons within the individual sensor elements 1506 of the array. This prevents or limits “crosstalk” to neighboring detector sites in the array, because plasmons can travel long distances (tens of microns) on a smooth metal film. Such crosstalk between adjacent plasmon sites 1506 would otherwise reduce or compromise detection measurement accuracy.

The incident interrogation light wavelength passband and amount of transmitted light through the nanohole pattern of each detector site 1506 to the respective dedicated light measuring pixel 1510 of each independent detector site, is very sensitive to refractive index changes in the nanoholes 1552, and/or at its near surface at that site. Plasmon sensors do not need thick liquid crystal layers, because plasmons are confined to the very thin metal-dielectric interface. The amount of incident light of a specific wavelength which passes through the nanohole pattern through the metal film changes with small changes Δn in the refractive index within the subwavelength nanoholes 1552, and/or at the metal film 1550 near surface. By sequentially detecting and comparing the amount of incident light which is transmitted through each individual plasmonic detector site from multiple laser diodes or LEDs of different wavelengths, extremely small changes in the refractive index caused by vapor adsorbates are detectable. Also, by fabrication of otherwise identical detector sites which have slightly varied distance between their nanoholes, very small changes in refractive index, Δn, can also be detected by comparing the changes in the amount of light transmitted through each respective detector site (of slightly different nanohole spacing) from a single laser diode source at a single narrow wavelength band.

Lindquist isolated plasmon sensor arrays have a central zone with a regular nanohole pattern designed for resonance with interrogation light wavelength(s) with specific values of dielectric constants for the metal and dielectric adjacent the plasmon metal surface. Published arrays cited herein have larger 7-by-7 nanohole patterns in a gold film, surrounded, isolated and enhanced by Bragg mirrors, and smaller sensor sites which each have 3-by-3 central nanohole patterns in the gold film, similarly enhanced and isolated by surrounding Bragg mirrors. For a backside imaging camera system 1508 with, for example, 3 micron pixels 1510, the smaller 3-by3 detector sites may desirably be arranged in 3-by-3 groups at 3 micron center-to-center spacing, each nanohole detector site having a footprint of less than one square micron. Each of the 3-by-3 sites in the 5-by-5 grouping may have a slightly different spacing of its central nanohole pattern, so that it is resonant with slightly different interrogation light wavelength. Larger plasmon sensing site arrays such as those with 5-by-5 nanohole groupings may be desirably used with frontside or backside imagers with larger center-to-center pixel spacings. Each sub-array may desirably have 9 different nanohole spacing periodicities, to fill all 9 locations of the 3-by-3 grouping, providing varying transmitted intensities at the same wavelength, and different sites responding to interrogation light at different wavelengths. Use of otherwise substantially identical detector sites with different nanohole spacing can provide increased sensitivity to wavelength shifts, and reduced detector noise after digital signal processing.

For example, in one embodiment 1902 illustrated in FIG. 19, the illustrated Lindquist Sensor detector elements like those of element 1506 may be fabricated as an array on a 200 nm thick gold film deposited on a 5 nm thick chromium adhesion layer on a thin, smooth glass substrate. Such arrays may have repeating patterns of 3-by-3 arrays 1904-1922 which each comprise nine individually unique nanohole patterns penetrating the gold film, each with a different nanohole periodicity αₒ (FIG. 17 A), ranging from 370 to 450 nm, and each increasing by 10 nm in subwavelength nanohole spacing. The sites 1904-1922 are otherwise substantially identical in liquid crystal composition and site analyte selectivity. The illustrated nanoholes in this embodiment all have a diameter of 150 nm. Accordingly, the subwavelength holes of site 1904 have a diameter of 150 nm, and a spacing of 370 nm, while the holes of site 1906 have a diameter of 150 nm and a hole-to-hole spacing of 380 nm. Site 1908 αₒ=390 nm; site 1910 αₒ=400 nm, site 1912 αₒ=410 nm, etc. The site 1922 with the largest spacing has holes of 150 nm and a square hole periodicity of 450 nm. Surrounding each nanohole array of each detector element 1904-1922 are four Bragg mirror grooves, 50 nm deep and 100 nm wide in the gold film with a periodicity nominally half that of their corresponding nanohole pattern to satisfy the Bragg requirement for SP wave reflection, with attention to the dielectric coating material properties. The distance between the inner Bragg mirror groove and the nanoholes is tuned to reflect the SP waves back into the nanohole pattern in a constructive manner, enhancing the overall transmission and the sharpness of the resonance peak. The array 1902 is particularly adapted to be used with a single laser diode light source 1502, but can benefit from use of multiple fixed wavelength, or scanning light sources. As the refractive indices of the liquid crystal coating changes due to adsorbed analyte(s), the single wavelength interrogation light transmitted by each site will vary in its own predetermined function, permitting precise computation (eg, extrapolation/interpolation) of the wavelength shift.

The sensitive, crosstalk-limited plasmonic sensor structures may also be fabricated directly on the imaging frontside or backside of CMOS or CCD imagers. Such fabrication can desirably use thin aluminum metal conducting surfaces compatible with CMOS and other IC fabrication procedures⁹⁷ for purposes of economy of manufacture compatible with CMOS and related silicon semiconductor integrated circuit processing and manufacture. Alternatively, they may be fabricated waferscale on a separate dielectric substrate like the waferscale camera optics for CMOS camera chips, and applied waferscale with plasmon-cell-to-individual-pixel alignment to the camera chips, in the same manner used commercially for inexpensive CMOS camera-on-a-chip manufacture. Liquid crystal or other materials may be applied to the surfaces of the LIPSA arrays, and/or within the nanoholes as illustrated in FIG. 18.

Liquid Crystals readily undergo phase/orientation changes that produce relatively large changes in anisotropic (eg, birefringent) refractive index. They also can undergo smaller changes which cause refractive index changes which can be detected by the interrogation light-plasmon resonance-imager pixel structure. There are a wide variety of different liquid crystal materials, having different compatibilities with alignment layers and atmospheric analytes. Because of the extreme sensitivity of the plasmonic sensors to refractive index change, full or even substantial liquid crystal realignment is not necessary. Very small disturbances in liquid crystal order or disorder can be sensed. This enables combinatorial sensing probes which can be applied in vast numbers of differently-sensing probes.

As illustrated in FIG. 15, an important component of the sensor system 1500 is an interrogation light imager 1508. The imager may functionally comprise a pixel array 1509 as illustrated in FIG. 15, together with on-chip digitizing and image processing circuitry 1590 in accordance with conventional practice. For example, a CMOS imager may comprise an imaging core with row select, column sample/hold, amplifier and digitizing circuitry, digital image processing circuitry (including pixel correction and normalization), and input-output circuitry. Preferably, the imager may be a silicon or silicon-germanium based imager which is sensitive to light in the 350-1000 nanometer range (referred to herein as VIS-R light). Frontside, and backside-thinned multi-megapixel silicon cameras-on-a-chip represent reliable, cost-mature technology for consumer cameras, as well as high-performance scientific applications⁹⁸. Specialized CCDs for astronomy and photon-counting can have extremely low noise floors⁹⁹. Very inexpensive CMOS consumer cameras-on-a-chip can have a noise floor of less than 5 electrons. Consumer manufacturers such as Sony, Samsung, Aptina, Cypress and Omnivision make inexpensive, high-performance silicon CMOS megapixel cameras-on-a-chip of remarkable complexity and performance. For example, a Sony IMX050 Backside Sensor with CXD4122GG camera chip generates 10 Megapixel images at 50 frames per second, and high-speed video up to 1,000 fps¹⁰⁰. The OmniVision 7692 camera module is a tiny 2.8×3.2×2.5 mm (total volume of ˜0.025 cubic centimeters) 25-pin cube at very low fabrication cost¹⁰¹. Another inexpensive Omnivision OV5656 5 megapixel cellphone camera-on-a-chip has a 37 dB S/N ratio, and a 73 dB dynamic range with 8× gain. It consumes only 340 milliwatts in operation, and can digitally output 5 megapixel frames at 30 frames per second in standard format, from a package size of 5.7×6.4 millimeters, for 150 million pixels of vapor analyte information per second to be analyzed by the microprocessor 1520 for detection, analysis and recognition. High speed imagers (eg, up to Million frame per second CCD imagers¹⁰²) can provide an extremely rapid record of refractive index change for kinetic evaluation of the presence of vapor analyte(s). Even standard-speed imagers and cameras-on-a-chip with consumer level performance (eg, less than 4 electron noise floor, 1-15 megapixels, 10 bit digitization, 30 frames per second) can generate enormously accurate and rapid vapor-sensing output for correlation and recognition processing by a processor such as 1520.

The sensor systems of FIG. 15 can be fast, low-cost, and easily integrated with mobile devices such as cellphones and other mobile devices, UAVs and other robots. They can be extremely small, exquisitely sensitive, with enormous vapor-detection and recognition capability. They can also be more sophisticated and sensitive with more sophisticated and sensitive components. Highly sophisticated 10 million pixel CMOS (and CCD) digital cameras are also relatively inexpensive. The data from a million-site Lindquist liquid crystal plasmon array applied pixel-wise to the pixels of a CMOS (or CCD) imager form “sensels”, each of which has a known location, has digitized output, and is readily corrected, normalized, correlated and modeled. Hidden Markov and more complex Bayesian modeling is useful for highly accurate speech, neural and other biological recognition modeling, as well as vapor analyte recognition. Many pixels of each sensor type greatly reduce noise due to averaging, much like olfactory neuron summation and recognition processing.

Detection of vapor by the sensor module of FIG. 15 is relatively straightforward. At least one interrogating light source 1502 is applied to the sensor array 1504, which has direct or indirect access to the atmosphere to be tested or monitored. Assuming initially synthetic or naturally clean air is present, the pattern of interrogation light transmission through each individual detection site 1506 is measured at each respective pixel 1510 is measured by the camera chip, for example as an 8-12 bit or more digitized value. This pattern may be compared to an expected value pattern, for check and normalization purposes. When the sensor module 1500 is exposed to an atmosphere containing vapor(s) or other analytes (not normal air) to be monitored, vapor analytes are adsorbed at the liquid crystal sensor sites 1506. The Δn caused by the adsorbate effects on liquid crystal organization is measured by the change in transmission at each pixel, and/or by comparing the relative change at each wavelength band for otherwise identical sensor sites with different nanohole spacing. The transmitted light values for multiple sites of the same type can be normalized and summed in the microprocessor 1520 for increased measurement accuracy. The values of transmitted interrogation light for each of the differently-sensitive detector sites may be compared and correlated for vapor detection and discrimination in accordance with conventional correlation and statistical processing techniques in the microprocessor 1520. Additional measurement accuracy may be obtained with polarization/phase-oriented Bragg mirrors in the plasmon sites. Adsorbate-differentiation, and real-time kinetic information about the rate of change is directly obtained by imaging speed of the camera system. The temperature of the tiny Lindquist LC sensor may compensated by known predetermined temperature correction data models, and/or may be controlled by a small thermoelectric (peltier) heater/cooler sheet, if desired. Camera chips typically include a temperature sensor for dark noise compensation, and normalization of each pixel's output.

Importantly, there are a wide variety liquid crystal materials with different polarizability, phase-change thermodynamics, phase temperature ranges, alignment properties, refractive indices and refractive index anisotropy, and refractive index change as a function of temperature. For birefringent liquid crystal materials, the refractive index difference, Δn, between the extraordinary index nₑ, and the ordinary index no (and the corresponding dielectric anisotropy, Δε) can be relatively large. For some liquid crystals, Δn can be as high as 0.45 or more for high-birefringence liquid crystalline mixtures (HBLCM)¹⁰³. Mono- and difunctional polymerizable and polymerized liquid crystal materials¹⁰⁴ are also useful. Atmospheric moisture, a problem for adsorbate measurement with conventional crossed-polarizer cells, can be normalized and modeled using a hygroscopic liquid crystal calibration site¹⁰⁵. Selective substrates which align the liquid crystal materials for polarization with different-axis Bragg mirrors of a Lindquist Array or other transmissive multisite plasmonic array may also be utilized for further sensitivity improvement¹⁰⁶ with polarized light sources 1502.

Adsorbate Discrimination and Differentiation as capability of massively parallel differently-sensitive detection sites. As discussed, an important feature of the embodiment of FIG. 15 is a wide variety of differently-sensitive detection sites 1506. Adsorbate selectivity differences at many hundreds or thousands of differently-sensitive sites is important for broad ranges of analyte discrimination and recognition. Combinations of different liquid crystals, different liquid crystal surface orientation materials, and different specific surface probes and molecular imprinting can produce an enormous number of differently-selective sensor sites. Sensitivity to a number of different vapor analyte characteristics, such as size, shape, polarity, complexing capacity, and infrared absorption is important for discrimination and analysis.

Solvatochromic indicators or dyes are also excellent differently-selective detector components¹⁰⁷ for plasmonic sensor sites, as are metal-organic frameworks¹⁰⁸, cyclodextrins and other cavitands, and phthalocyanines which change dielectric constant upon adsorption of various analytes based on characteristics such as analyte size or molecular characteristics. The excited or resonance state of the photochromic dye significantly affects its dielectric constant. Accordingly, adsorption of an analyte having a polarity different from the previous environment of the dye will change its dielectric constant, thereby changing the plasmonic resonance response of the plasmonic detection site which is coated with the dye. In turn, this change is detected and measured by the adjacent imager pixel associated with the plasmonic site bearing the dye at its metallic plasmonic surface. For example, Nile Red is a negative solvatochromic dye, which may be applied to plasmonic detector sites as a dilute solution with a polar polymer such as polyvinylpyrrolidone (PVP) in N,N-dimethylacetamide solvent, followed by solvent removal. Reicherts dye is a solvatochromophore which can similarly be applied as a dilute solution with PVP. Benziphthalocyanine, is a spirane solvatochromatic indicator which shifts between a strongly aromatic quinoidal form or a weakly aromatic phenol form; it can be used as a sensing agent which shifts dielectric constant (and hence plasmonic resonance frequencies of the plasmonic sensing structure) differently on the presence of different analytes¹⁰⁹. Photochromic dyes may also be dissolved in or with UV-curing or otherwise polymerizing and/or crosslinking monomers or oligomers, to produce a low or high polarity matrix for the respective dye. Alpha, beta and gamma cyclodextrins and other cavitands¹¹⁰ of respectively different size can change dielectric constant upon adsorbing analytes of size which fit within their central hollow structure, providing molecular size information about adsorbed analytes which can be combined with other detected analyte information to characterize the analyte(s).

Many of the most toxic vapors important to detect and recognize are excellent ligands for metal ions, and metalloporphyrins have been proven to be excellently-selective surfaces for such dangerous gases¹¹¹, and are useful as covalently bound surface decoration at the metal plasmonic surface, and as components of molecularly imprinted materials as discussed below. Perchlorate salt (copper, nickel, aluminum, zinc, other transition metal ions, etc.) anchoring surfaces for polar liquid crystal materials such as nitrile-terminated liquid crystals are also known to have selectivity for volatile phosphate adsorbates¹¹².

Many inorganic, organic, and mixed inorganic/organic matrices, including metal oxides such as silicon oxides and titanium oxides can form molecularly imprinted structures and which preselected chemicals are employed to guide the structural formation of the oxide, thereby creating “imprints” of shape, polarity, size and other characteristics in the surface and/or volume of the formed material. Upon removal of the imprinting compounds, the resulting “molecularly imprinted” material preferentially absorbs and interacts with compounds with which it was imprinted. Depending on fabrication design, precision and type of imprinting, the molecular imprinting material may also, typically to a lesser degree, preferentially select related compounds such as those with similar size, shape, polarities or other physical characteristics. Molecular imprinted (MIP) materials are also useful for providing detector sites 1506 with specific selectivity for various types of analytes. They may be prepared by forming a solid matrix on the plasmonic metal surface 1550 or in the holes 1552 in the presence of specific chemical compounds for which selectivity is desired. The molecularly imprinted layer should best be less than 25 nanometers thick for use with a liquid crystal coating, and more preferably less than 10 nm thick. MIP layers with surface imprinting may be fabricated with good thickness control below 10 nm, eg 5 nm, by ALD methods with addition of imprinting molecules in the layer processing. Upon removal of the imprinting molecules, “imprints” of these molecules remain in the imprinted material on the surface, and/or within its volume, which are selective for adsorbing the imprinted molecules¹¹³. Molecularly imprinted substrates are useful for selective adsorption of organophosphate and other analytes¹¹⁴, rivaling that of enzymes and antibody affinities. Inorganic oxides such as SiO₂ and TiO₂ are conventionally used for liquid crystal alignment surfaces. They are suitable for both molecular imprinting and liquid crystal anchoring/alignment control. Molecularly-imprinted SiO2 or TiO2 surfaces can change from polar to nonpolar with adsorption of gas analytes to their surface shape imprints. Sol-gel and/or Atomic Layer Deposition of inorganic oxide materials¹¹⁵, may be adapted to produce molecularly imprinted surfaces and adsorbate-selective refraction-change materials closely adjacent the plasmon array surfaces, and/or in the nanohole sites. Aerogel/xerogel materials which are molecularly imprinted can be interactive with liquid crystal materials, and useful in the atmosphere in view of their low refractive index¹¹⁶. Molecularly imprinted aerogels can have internal porosity for example of 80 to 95% or more, producing refractive indices which are close to one. Upon adsorption of vapor(s) for which they are selectively imprinted and thermodynamically attractive, the refractive index adjacent the plasmonic reporting structure can increase as a result of the presence and increased mass of the analyte itself, without utilizing its affect on liquid crystal orientation or structure. It may be noted that molecularly imprinted MOX aerogel/xerogels are also useful as surfaces for MOX sensors previously described.

By using molecularly imprinted surfaces or particles, vapor that is selectively adsorbed on the MIP liquid crystal anchoring surface can disrupt (or enhance) the liquid crystal orientation at the plasmon sensor surfaces and/or within the liquid crystal, producing dielectric and refractive index change detected by the site. A knowledge base of alignment substrates is available in the public literature for materials that can also be selected for “molecularly imprinting” on their surfaces to selectively adsorb analytes. By imprinting different sensor sites with different molecular imprints, differential sensing permits vapor recognition. In addition, adsorbate-selective molecularly-imprinted anisotropic dielectric nanoparticles (eg, nanoplatelets) may be coated with liquid crystal material, and applied to the plasmon surface, or in the nanoholes, to increase the interaction. Biological materials such as acetylcholinase enzymes (which obviously selectively adsorb and bind nerve gas!) and insect or mammalian odorant-specific proteins can also be “molecularly imprinted” onto the plasmon-sensed surfaces, and/or preferably in the nanoholes.

Combinatorial fabrication of hundreds (or thousands) of differently-selective sites is a useful way to fabricate large numbers of differently-sensitive detector sites. Bioanalytic chip manufacture is well developed for liquid-phase analysis of liquid-phase biological solutions, using photolithography and related techniques for attaching many thousands of known, different, designed probes to a substrate¹¹⁷ for selective attachment of analytes¹¹⁸. Synthetic linkers modified with photochemically removable protecting groups are conventionally attached to a substrate. Specific areas are locally deprotected by light through an appropriate photomask. A first chemical building block is attached to the deprotected surface zones, without affecting the still-protected zones. The entire surface is re-protected, and again deprotected in a different pattern of zones designed for a second attachment of a different chemical compound or layer. This process may be repeated, activating different sets of sites and coupling different layers, up to about 20+ layers of different materials. The number of physically and chemically different probes increases exponentially with cycle number. The number of different probes is limited only by lithographic resolution (which is well within sizes of the Lindquist Isolated Plasmon Array structures). Such combinatorial analytical probe technology is so capable and mature that even over decade ago, 400,000 different oligomers could be applied on small 1.28×1.28 cm chips (small for a good quality digital camera imager). Conventional digital micromirror maskless array synthesizers may be used instead of photolithographic masks¹¹⁹ to synthesize enormous numbers of differently-sequenced, differently-selective materials. ssDNA oligomers have been shown to have widely differently-selective properties for a range of vapors, based on resistance change on carbon nanotubes coated with different ssDNA probes of up to ˜20 mer or more¹²⁰. ssDNA, peptides, “click” chemistry sequences and cavitands, and other combinatorially-fabricated oligomers bound to the near plasmon surface have different sensitivities to different vapor adsorbates, and can change shape, conformation, dielectric constant, and/or presentation surface to a liquid crystal, solvatochromic dye, and/or fluorescent lasing dye and/or other analyte-detecting layer upon adsorption of vapor analytes. A wide variety of cavitands selective for vapor (such as nerve agents) of particular importance may be applied by click or other combinatorial chemistry¹²¹ to an individual imager array of pixels, and/or utilized for addressing self-assembly of specific detector materials and arrays to mating imager pixels¹²². This creates enormous recognition capacity for massively parallel systems in accordance with the present disclosure.

In accordance with other important aspects of the present disclosure, different detection elements may also be applied randomly, or in a guided or partially guided manner to sensor zones. In addition to combinatorial and “click” chemistry patterns for generating large numbers of differently selective detector site surfaces, randomized application of selective surface agents and materials, including both liquid crystal materials and/or selective surface materials, may be applied to a plasmonic surface array of sensel sites comprising detector sites and their respective immediately adjacent imager pixel sites. In this regard, with reference to the detector sites of FIGS. 18, 20, 21 and the like, the plasmon detector sites have a central nanohole zone (which in a 3×3 embodiment may be on the order of about a square micron in area) surrounded by a larger area of Bragg gratings. The central zone may be designed to be receptive to an emulsified and/or otherwise dispersed micron scale particles of a selection component fluid. The surrounding Bragg grating zone may be designed to be repellent or resistant to the micro-scale particles of a selection component fluid.

To apply the vapor analyte selective zones, a plurality of fluid mixtures is prepared which have dispersed particles of a specialized analyte selection component of a size and volume nominally adapted to coat or cover (to the exclusion of other particles after coating by virtue of matching size) a single detection zone 2206. For example, these dispersed particles may be nominally spherical, or non-spherical (e.g. flakes) of approximately 1 micron in diameter or major dimension for a 1 square micron nanohole site. In this regard for example, a liquid crystal material may be emulsified under appropriate conditions to produce such particles in an aqueous fluid. A sol-gel or a sol-gel with an imprinting compound may be emulsified and then cured/cross-linked or at least partially cross-linked and then sheared to produce a mixture of suitably sized particles in a fluid dispersion. A number (e.g., 25, 50, 100, 1000) such fluid dispersions of differently-analyte-selective materials may be prepared and blended together in desired proportions to produce a random mixture of dispersed particles of different selectivity zone precursors.

As indicated, the central zone of the detection sites 2206 may be made attractive to the dispersed particles, and the surrounding Bragg grating zones may be masked or otherwise made repellent or resistant to the particles (as by coatings or lack of coatings). Such attractiveness may be carried out in any suitable way. The dispersed particles may have a surface charge opposite that of the detector sites. They may have mutually-reactive chemical surface decoration, such as surface amine versus epoxy groups, or an antigen versus antibody attractive reactivity. The particles in the dispersion may be potentiometrically attracted to and deposited on the detector zones 2206, such as by surface redox reaction resulting from applied potential to the metallic plasmon film. After attachment of random particles to the respective detector sites, the fluid dispersion may be removed, the plasmon array washed, and the attracted/attached particles may be fixed/attached at the detector nanohole site by reaction or other suitable processing. The sensor system may be fully assembled, or partially assembled and tested wafer-scale, by applying seriatim a plurality of different analyte vapors, measuring the transmitted interrogation light response of each detector site to each different vapor, and determining the type of material attached to that site from such responses. In this manner, a map of the location of each sensel of a particular sensitivity type is created for subsequent processing of sensor response to unknown vapor(s) and analytes. Normalization constants for normalization or correction curves for the sensitivity of each detector site with respect to each different analyte may also be determined, in a manner similar to that conventionally used to correct imager pixel response (eg, origin, slope and/or response curve correction).

Infrared Spectroscopy is a fundamentally important analytic mainstay for distinguishing chemical compounds. The utility of mid-IR (here, broadly 2 to 12 micron) radiation for identifying molecules has long been an important tool for chemical identification by IR signature. Most molecular bonds have strong mid-IR absorption wavelengths at very specific “signature” frequencies. Vapor adsorbate sensing, discrimination and recognition can be significantly improved with measurement of multiple type of characteristics. As previously described with respect to the MOX embodiments, infrared absorption spectra are distinguishing molecular characteristics which are useful to exploit for adsorbate differentiation and recognition. In the MOX embodiments, selective heating of adsorbed vapor can affect charge carrier generation at the MOX interface for transport and detection at the immediate location of the respective underlying charge-carrier-detection pixel(s). In liquid crystal and other dielectric transduction embodiments, selective infrared absorption can vary the temperature and interfere with the liquid crystal order or dielectric constants of other materials, to produce a change in refractive index which can be measured with very high sensitivity by the plasmonic array at individual detector-pixel (“sensel”) sites.

The rate of change of refractive index with temperature can be relatively large in liquid crystals. Haller's approximation is conventionally used to approximate the change of birefringence in temperature ranges distant from the transition clearing point¹²³. For example, the rate of change of the extraordinary refractive index nₑ and the ordinary refractive index nₒ with temperature in the mesogenic birefringent range of a nematic liquid crystal may be approximated¹²⁴ by:

$${n}_{e} = A + B T + 2 [ Δ {{N}_{z e r o} ( 1 - T / Tc )}^{β} ] / 3$$

$${n}_{o} = A + BT - [ Δ {{N}_{z e r o} ( 1 - T / Tc )}^{β} ] / 3$$

where ΔN_{zero} is a (fictionally extrapolated) birefringence at T=0° K for the liquid crystal material, β is a characteristic constant for the liquid crystal material, T is the temperature for which nₑ, nₒ are calculated, Tc is the clearing temperature for the liquid crystal material (Kelvin), and A and B are empirical curve-fitting parameters. For a W-1680 mixture liquid crystal, the empirical curve-fit factors are

$$A = 1.7756 , B = - 0.0004 , Δ {N}_{z e r o} = 0.4 \; 7643 and β = 0.1665$$

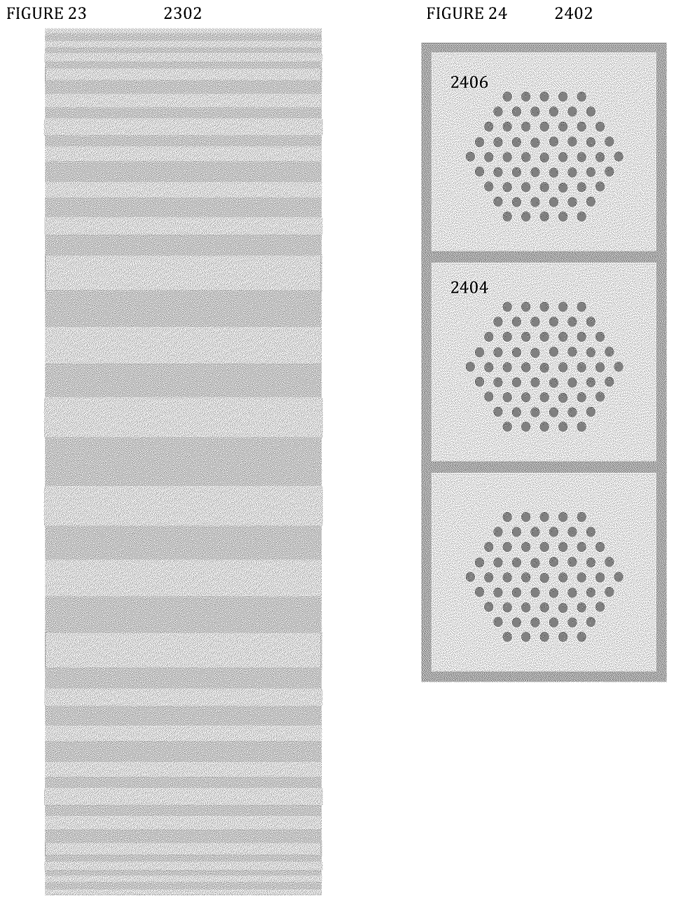

Other curve-fitting methods may also be used. For conventional birefringent liquid crystals such as W-1680 which may have for example rates of change of nₑ or nₒ on the order of 0.001 (˜10⁻³) to 0.004 per degree centigrade¹²⁵, a sensor like that of FIG. 18 which detects refractive index changes on the order of 10⁻⁵ to 10⁻⁶ or better, provides exquisite, low cost measurement of small temperature changes at the detection site produced by IR absorption at the site. Such transduction is utilized in the illustrated embodiment of FIG. 15 for IR spectral measurement, and in IR “multicolor” camera embodiment of FIG. 23. The rate of refractive index change with temperature is even larger as the liquid crystal transition clearing point temperature is approached, and for materials with ranges of dramatic dielectric phase change such as VO2 and Mott-bandgap materials.

In the illustrated embodiment of FIG. 15, IR spectra of vapor adsorbates may be transduced, or measured, using Δn measurement in the extremely sensitive liquid crystal Lindquist Array and underlying imager camera pixels. Because liquid crystal refraction change, Δn, can vary with temperature, the Lindquist Plasmon Arrays can also be made quite sensitive to temperature changes. Different liquid crystal materials have different Δn characteristics as a function of temperature. Adsorbed vapors (and other materials) have defined IR absorption bands in the near- and mid-IR, which is the basis of IR analytic spectroscopy for specific compound identification. In this regard, the infrared light source of the sensor system 1600 of FIG. 16 may comprise compact semiconductor near- and mid-IR diodes¹²⁶, tunable IR lasers, collimated IR plasmonic light sources tunable in the IR which can have a 1-axis spread spectrum¹²⁷, or other suitable infrared spectroscopic light sources 1538. Except for several absorption peaks, many liquid crystal materials are relatively transparent in near- and ranges of mid-infrared spectra where “signature” absorption bands of many vapor adsorbate chemicals occur¹²⁸. Different liquid crystal materials have different near- and mid-IR “windows”¹²⁹. With hundreds-of-thousands to millions of sensor sites available in the embodiment 1500 for different liquid crystal materials with different IR “windows”, analytically important ranges of the infrared spectrum are utilized for IR spectroscopic identification of compounds¹³⁰. By fast-pulsing IR of selected wavelength (or a wavelength band spread along a defined area of identically sensitive sensor elements 1506 of the sensor 1504) under programmed control of the sensor, adsorbed gases which absorb in that IR wavelength applied to the respective detector site will be heated by IR absorption, changing the refractive index at that site for plasmon light transmission measurement. The interrogation light may be applied at the same time and/or immediately after the IR pulse under programmed control of microcomputer system 1520 to measure Δn, and hence IR spectral information for that pixel. In this regard, IR light is selectively transduced to refractive index change, which is transduced to VIS-R light transmission change, measured at respective VIS-R light imager pixels. This analyte vapor IR absorption spectrum information can be diagnostic, particularly when combined with the other selectivity information of the sensor¹³¹.

A tunable diode laser light source 1538 is particularly useful for detection of specific vapor adsorbates of specific or critical importance, such as nerve agents or other hazardous gases. The emission wavelength of a tunable diode laser, such as a VCSEL, DFB, VCSEL may be programmed to direct one or more characteristic absorption lines of the analyte of interest onto the surface of the plasmon transmission array 1504. If a compound which absorbs infrared light at the selected absorption line(s) is present at a detector site 1506 receiving the infrared light, it will be absorbed to excite vibrational, rotational or other energetic modes, which heats or otherwise disrupts the liquid crystal material, changing the refractive index of the detector site. This change may be used, alone or preferably together with other sensor site measurements, to identify the adsorbed gas at the site, and to determine the adsorbed gas concentration. Different diode lasers may be used based on the application and the range over which tuning is to be performed. Typical examples for the near IR range are InGaAsP/InP (tunable over 900 nm to 1.6 nm), and InGaAsP/InAsP tunable over 1.6 nm to 2.2 nm. Tuning and linewidth narrowing can be enhanced by dispersive optics external to the active semiconductor region. Compact quantum cascade lasers are particularly useful for infrared wavelength tuning at mid and long wavelength spectroscopic regions. Quantum cascade lasers based on InGaAs/InAlAs lattice-matched to InP substrates have excellent performance across the mid-infrared spectral range. Distributed feedback quantum cascade lasers have a distributed Bragg Reflector (DBR) to control desired wavelength. DFB lasers can be pulsed under control of the microprocessor 1520 to rapidly “chirp” the laser output to rapidly scan a preselected spectral band, in precision timed interrogation with VIS light. Quantum cascade lasers with an external diffraction grating can be broadly tuned in their infrared light output (eg, ˜15% of the center wavelength)¹³², and are useful IR sources 1538.

The concentration of the adsorbed vapor which absorbed the specific infrared wavelength can be determined by the Beer-Lambert law, from the known molecular absorption properties of the molecule and its temperature (the illustrated imager chip and/or the plasmon transmission array 1504 have conventional temperature measurement means (not shown) from which the detector site temperature can be determined). In addition, two or more different absorption lines for a compound of interest may be probed while sweeping the laser across the absorption spectrum, so that the temperature may be determined by the ratio of the integrated absorbance, which is a function of temperature.

Because the adsorbed gas(es) may be present at the detector sites at very low concentration, it is desirable to use modulation processes to improve the signal-to-noise ratio over the relatively high background signal, and to increase the interaction of the adsorbed gas with the infrared probing light to enhance infrared absorption. In this regard, the infrared probing light source may be pulsed, or effectively “chopped”, to isolate the absorption signal. In addition, the interrogation light transmission one or more control sites which are substantially identical to the detection site (eg, in type of liquid crystal, physical structure, and wavelength of IR probe, but without atmospheric access so that it has no adsorbed vapor) may be measured to determine a baseline for refraction change due to infrared absorption by adsorbed gas(es) at the detector site(s).

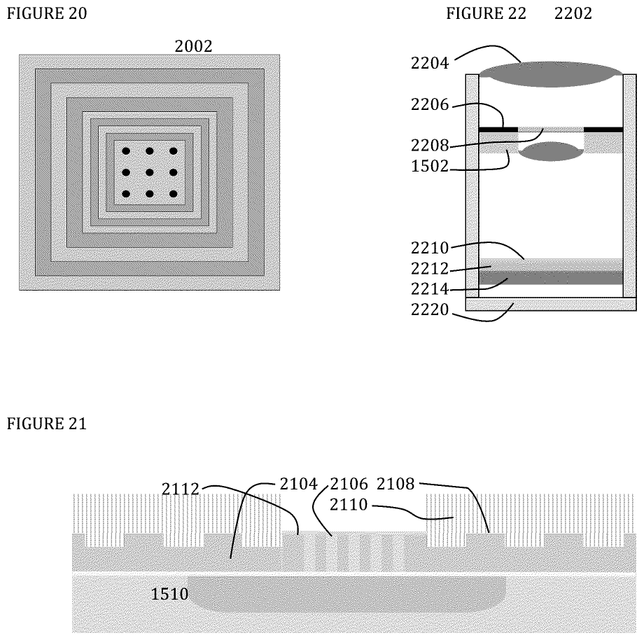

As illustrated in FIGS. 20 and 21, the effective pathlength of interaction of the probing infrared wavelength(s) may be increased by nontransmissive plasmon resonance of the infrared probe light at the detector site. In this regard, the detector site may be designed for plasmon resonance for both visible light interrogation at which the underlying silicon imager is sensitive (eg, 300-900 nm), and the infrared wavelength(s) at which the presence of the molecules of interest are probed. The illustrated plasmon detector element 1906 of FIG. 19 comprises a thin optically opaque metal film 1550 and an array of transmission nanoholes 1952 as described with respect to FIG. 18. A Bragg reflector array which is resonant at a specific infrared wavelength band designed for that detector site surrounds the nanohole array, with its first reflector positioned to also reinforce the VIS plasmon resonance. The IR Bragg zone creates multiple passes of the IR wavelength probe light through the transmission plasmon array, increasing the efficiency of absorption.

In addition to wavelength absorption information, Fourier-transform IR type techniques may be used to process the interrogation information to facilitate the resolution of analytes, liquid crystal absorption components, and mixtures of materials.

Electric field variation is another useful feature of the sensor embodiment of FIG. 15. Liquid crystal optical behavior can also be probed by electric field variation in the sensor embodiment of FIG. 15, under control of processor 1520. The conductive metal plasmon film 1550 permits electric field control by applying a desired voltage or AC signal to the metal film. Liquid crystal orientation vectors, their thermodynamic phase change drivers, and frequency effects of adsorbed vapor analytes on dielectric constant can be controlled and measured by electric field together with interrogation light as described herein. Adsorbed “interferent” vapors can affect the sensor An response to electric field and kinetics, based on their polarity and adsorption strength. Liquid crystal switching can be very fast and LC orientation patterns can facilitate fast phase changes¹³³, which can be disrupted or changed by the presence of adsorbed vapor(s).

Illustrated in FIG. 21 is a plasmonic sensor (“sensel”) 2102 for enhancing the infrared absorption of analytes present in the sensel to transform infrared absorption into dielectric change for VIS-NIR interrogation light transmission detection. The sensel 2102 comprises a plasmonic metal film 2104, a central transmission nanohole pattern 2106, nominally tuned to the interrogation VIS-NIR light sources 1502, and underlying VIS-NIR light pixel 1510 of a VIS (or VIS-NIR) image sensor 1508. The central nanohole array 2106 is surrounded by a Bragg grating 2108 nominally tuned to a preselected infrared wavelength range for enhancement of infrared absorption of that range by infrared absorbing analyte present in the sensel site 2102. The Bragg grating 2108 may have a dielectric coating 2110 to reduce the overall size of the sensel, by reducing the physical dimensions proportionately with the refractive index of the coating. High dielectric coated materials may be more “porous” at the top side to reduce reflection and may have liquid crystal repellent coatings such as a perfluoropolymer material to repel and contain the liquid crystal material 2112 in the central nanohole zone 2106.

Illustrated in FIG. 22 is a high performance, compact, non-cryogenic MWIR camera 2202. The infrared camera 2202 comprises an MWIR lens 2204 which may be of silicon, germanium or other suitable MWIR lens materials. It may be a refractive, diffractive, or preferably a hybrid refractive-diffractive lens or multiple lens assembly for minimizing dispersion across broad infrared ranges. The camera 2202 further comprises an aperture stop 2206 to prevent spurious infrared from reaching the imager plane, and a VIS-NIR interrogating light source 1502 such as previously described, for transducing infrared absorption into a VIS-NIR plasmonic transmitted signal. While the interrogating light source is illustrated at the interior periphery of the aperture stop 2206, it may also be positioned near the interior side of the lens 2204 (and to reflect off the high refractive index surface toward the infrared detection sensels at the focal plane). The illustrated infrared camera further may comprise a shutter or “chopper” 2208 for periodically interrupting the infrared image projected by the lens 2204 onto the plasmonic sensel array focal plane 2210. The sensitivity of the camera may be sufficiently great that “chopping is not needed. The chopper 2208 may be mechanical, or an electronic liquid crystal shutter system, in accordance with conventional practice. A liquid crystal shutter system may be temperature-controlled by appropriate Peltier or other thermal control device of desired. The plasmonic infrared-to-VIS-NIR transduction array 2210 may be similar to the arrays of FIGS. 15, 18, 19, 20, 21, 23, and/or 24, and may also include “rainbow” plasmon arrays resonant (eg, via surface structure) in the nontransmissive MWIR imaging range(s) and transmission resonant (eg via subwavelength nanohole patterns) in the VIS-NIR into which the MWIR image is transduced. The IR image projected by the lens heats the sensel zones, changing the refractive index in the nanohole plasmon pattern, which is measured by the interrogation VIS-NIR light transmitted through to the underlying respective pixels of the underlying imager. A pattern of sensel sites which absorb IR radiation at different wavebands, such as by using LCs of different absorbance, or mixing selectively IR absorbing “IR dye” materials in the sensel zone, provides a multicolor IR image when interrogated by VIS-IR light. In this regard, FIG. 23 illustrates a multipixel chirped metal film plasmon nontransmissive “rainbow” grating which receives wideband infrared radiation and separates it into waveband zones where that waveband is most resonant. VIS-NIR resonant and transmissive nanoholes (not shown) may be applied at different locations along the chirped array, adjacent respective imager pixels, to measure the IR waveband localized at that resonance portion of the chirped array. As described, rather than multilevel metal groves, dielectric layers and bands may be fabricated on the metal plasmon films to vary the plasmon-generating patterns. For wafer-scale manufacture, fabrication of dielectric materials may be more economical than metal film feature fabrication.

While the illustrated embodiments of FIGS. 15, 18, 20, 21, 23 and the like may use liquid crystal dielectric materials, other materials which have phase-changing or other significant electro-optical effects for plasmon-generating surfaces and cavities/holes may be used in other embodiments, such as vanadium oxide and Mott-bandgap materials. Vanadium oxide based materials have phase change characteristics which produce large changes in dielectric constant and electrical conductivity¹³⁴. Strongly correlated heterostructures also have important optoelectronic properties¹³⁵ and can have significant ranges of dielectric constant properties. Interfaces between band insulators such as SrTiO3 and Mott insulators such as LaTiO3 can produce metallic characteristics. The dielectric properties of such VO2-based, and strongly-correlated heterostructure materials are influenced by adsorbed analytes. Near-plasmon surfaces and nanoparticles of such materials which are affected in dielectric properties by adsorbed vapor(s) may be fabricated as molecularly-imprinted materials, and/or included in porous and other molecularly imprinted layers at the surface of the plasmonic metal film and/or nanoholes¹³⁶. Such effects are useful for varying the transmitted interrogation light through the plasmon nanoholes, as previously described.

Normalization, correction and self calibration are important features of sensor systems disclosed herein. The response correction for each sensel may be provided on the camera-on-a-chip, or within the microprocessor 1520. The response correction can include effective off-angle incidence of interrogation light (which effectively changes the wavelength), alignment of plasmonic nanoholes, with its respective dedicated imaging pixel, temperature correction, specific analyte concentration response correction, interrogation light response correction, etc. The illustrated embodiment 1500 may readily self-calibrate. CCD and CMOS cameras-on-a-chip may have extensive and sophisticated self-calibration systems built-in. The illustrated camera sensor 1520 has temperature sensor, dark current sensor pixels and pixel correction processors which are used to model and correct liquid crystal temperature effects. They have light-shielded pixels for light calibration, and dark-current correction. They have thousands-to-millions of identical pixel sites, permitting some to be used for liquid crystal reference and calibration. The sensor 1504 design includes self-calibration “sensor sites”, some of which are excluded from the atmosphere, as control sites. Some are excluded from light. Some can have no liquid crystal or sensitivity-selecting layers, to measure the imaging light intensity. Some have only have liquid crystal layers. Water-sensitive liquid crystal sites are used to calibrate and correct for atmospheric water vapor. The sensor modules may also be calibrated in a controlled environment with standards of specific vapor sources and known mixtures. The responses of each different sensor type (which may number hundreds or thousands of identical sites) are processed statistically such as by Hidden Markov Modeling to calibrate precise recognition modeling. The many identical detector sites also permit statistical noise reduction for high sensitivity. Calibration sites permit subtraction of unwanted background signals, and temperature, mechanical, vibration, and moisture compensation. The data may be further processed by modeling and statistical detection processing not possible for detectors with limited numbers of detector sites.

Frontside imagers and cameras-on-a-chip generally have pixel imaging zones for converting image light into charge carriers for measurement, together with frontside circuitry which consumes some of the frontside imaging area. The imaging areas are generally regularly spaced apart, with the integrated circuit control circuitry and electrodes in the intervening space. Other types of frontside imagers, such as frame-transfer CCD imagers may use semitransparent transfer electrodes, at some, typically limited, cost of image absorption by the transfer electrodes. When using frontside imagers, such as CMOS and CCD imagers are used to form sensels with overlying adjacent plasmonic transmission detector sites, the sites are readily positioned adjacent the individual imager pixels, with the Bragg or other isolation feature(s) positioned in the frontside circuitry area(s). Such frontside imagers may routinely have relatively large interpixel spacing, and pixel size, which can simplify application and fabrication of the plasmon array. In this regard, illustrated in FIG. 24 is a portion of a plasmonic transmission array 2404 of individual nominally VIS-NIR resonant hexagonal arrays 2406 fabricated atop the frontside pixels of a frontside CCD or frontside CMOS silicon imager. The plasmonic metal array may be directly fabricated on the imager front surface (without any lenslets or color filters) which has smooth dielectric-coated (eg silicon dioxide or silicon nitride) pixels and frontside circuitry. The metal film, such as gold or aluminum, may be deposited in accordance with conventional processes¹³⁷, with a thin adhesion layer if appropriate, on the imager surface. For mass production and wafer-scale manufacture, aluminum films are useful, with care to limit crystallization which interferes with plasmon resonance, as appropriate. For larger-sized pixel-to-pixel spacings, and for thin aluminum multilayer plasmon structures, simple patterning and etching isolation may be used to prevent crosstalk between sensels rather than Bragg gratings. A larger number of patterned nanoholes may be used to achieve better resonance sharpness, without the benefit of the Bragg feedback. However, dielectric patterns may be used in addition to, or instead of thickness-patterned gratings, as described herein. Suitable dielectric materials such can be applied and etched to create regular or “rainbow” Bragg and/or plasmon effects. Fabrication (etching, lift off, deposition patterning with resist, etc.) of isolated nanohole plasmon arrays can prevent inter-site plasmon crosstalk to isolate the response of each sensel.

Magnesia and alumina have ε values of about 10, Mg₂TiO₄ and MgTiO₃ have ε values of about 13-16, composite ceramics composed of Mg₂TiO₄ CaTiO₃ and Ba₃Ta₂MgO₉, Ba₃Ta₂ZnO₉, BaZrO₃, and BaCeO₃ (with various dopants for temperature and Q tuning) can have designed ε values from 13 to about 150. Dielectrics with ε values from about 40 to about 150 also can be produced from barium, strontium, zirconium and rare earth titanates. Various perovskites and other inorganic dielectrics such as BST can have very high ε values which may also have a high temperature coefficients, with significant changes in ε with changes in temperature. Some dielectrics, including high permittivity dielectrics, have high temperature coefficients, either positive or negative, so that their dielectric “constant” changes significantly with temperature. For example, pulsed-laser-deposited barium strontium titanate (BST) thin films such as (60/40 Ba:Sr) BST can have high dielectric constants with a sharp-peaked temperature coefficient of dielectric constant (TCD) of about 13% per ° K. Higher barium BST (75/25 Ba:Sr) can have a broad dielectric peak with a TCD of about 6% per ° K within a broad operating temperature range from about 25 to about 35° C.¹³⁸. Such materials are useful in molecularly imprinted material fabrication (including xerogel/aerogels), as patterned dielectrics for plasmon generation, as dielectrics for reducing the size of MWIR plasmon array structures, and as MWIR camera components.

Plasmon-based analyte sensing and differentiation platforms are provided using CMOS or CCD imagers/cameras-on-a-chip with up to millions of detector sites atop individual or small groups of pixels without intervening Fourier plane imaging optics. Plasmon systems are readily fabricated in thin, substantially plane or layered configuration, matched by design to the geometry of imager pixel arrays which absorb their transmitted light energy at specific pixel locations. Associated complete digital camera chips can be inexpensive (eg, $5-150), temperature-calibrated, very small, very sensitive (compensated readout noise can be ˜1 electron or less), and require very low power. Systems for IR spectral sensing, Raman sensing, and thermal sensing for non-cryogenic IR (eg, multiband-“color” MWIR) cameras¹³⁹ are provided in very compact form in accordance with the present disclosure.

The design of individual (or small groups of) plasmon transmission elements compactly adjacent respective imager pixels is useful for obtaining analyte Raman spectral information in an inexpensive compact detector system. In this regard, by compactly adjacent is meant that the distance between the emission surface of the plasmonic detector site layer and the respective adjacent imager pixel(s) is less than 5 millimeters, preferably less than 3 millimeters. In many of the preferred embodiments, the separation distance is less than a millimeter, while some ultracompact embodiments have the plasmonic layer fabricated directly on the imager surface. Importantly, such compact detector systems can function effectively without a Fourier (lens) imaging plane, which enables their compactness. While various described analyte sensor embodiments have been described with respect to direct transmission of plasmonically processed light from specific isolated plasmonic sites to adjacent respective pixels, other sensing and detecting systems such as Raman sensors are also provided in compact form.

Schematically illustrated in FIG. 26 is a cross-section of a SERS Raman system for detecting Raman spectra of adsorbed analytes. The illustrated system 2600 comprises a plasmonic SERS layer 2602 for selectively adsorbing analytes from an adjacent fluid, a refraction/diffraction layer 2604 and notch filter 2606 atop respective pixels of an adjacent imager. The plasmonic SERS layer 2602 may be a suitable means for adsorbing an analyte, applying an intense narrow wavelength interrogation light, resonantly enhancing the electric field of the applied light, and transmitting the Raman spectra induced by the applied light and its enhanced electric field¹⁴⁰. The refraction/diffraction layer may be a means for dispersing the Stokes and/or anti-Stokes Raman radiation transmitted through the plasmonic SERS layer along a wavelength gradient axis. The refraction or diffraction means may, for example, be a highly dispersive prism such as illustrated in FIG. 12, or a diffraction grating active to angularly spread the transmitted wavelengths. The system should also comprise a filter means for blocking the interrogation light wavelength(s) from being transmitted through the plasmon means to the adjacent imager pixel means for detecting and quantifying the Stokes and/or anti-stokes Raman radiation. An appropriately designed photothermal glass layer¹⁴¹ may function as both a notch filter and a dispersive element. Photo-thermo-refractive glasses are also important materials for fabrication of detector element components atop an imager (without a Fourier plane/optics) in accordance with the present disclosure.

The plasmonic sensor of the system 2602 may desirably comprise diffraction sensor elements¹⁴² such as those in which the plasmonic sensor comprising the analyte contacting dielectric is a diffraction element which has a diffractive response which is sensitive to analyte adsorption on or in the dielectric material adjacent the metal of the plasmonic metal-dielectric interface. In this regard, the plasmonic diffraction element may serve as both the plasmonic detector and the diffraction light-spreading element projecting a spread-spectrum or interference response across the imager pixels.

Other plasmonic sensing and plasmonic light-generating embodiments desirably may comprise active gain media as the dielectric plasmonic layer at the plasmon metal-dielectric interface. In this regard, by providing active gain media within an appropriately structured plasmonic resonance zone¹⁴³, emission from the active dielectric gain media can produce stimulated light emission under the influence of the plasmonic resonance and detection structure of the detection cells. By utilizing active gain media which are in turn influenced by adsorption of target analytes, the presence of such analytes can be selectively detected and reported. By varying the active media and/or plasmon resonance system, the emitted wavelength(s) can be adjusted and utilized in compact detection and distinguishing systems in accordance with the present disclosure.

“Chirped” or “Rainbow” plasmonic structures can also be used for very compact Raman and other optical multiwavelength sensing.

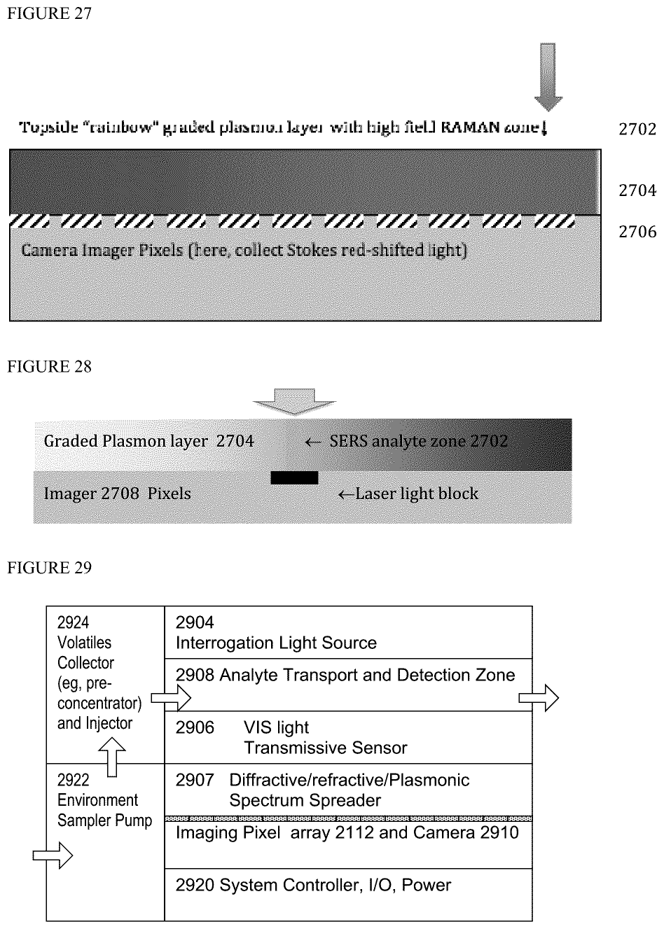

As schematically illustrated in FIG. 27, laser monochromatic light is directed to a SERS sensor zone 2702 means for absorbing analyte(s) which tuned to resonance with the center of a graded plasmon layer 2704. The laser light induces Stokes emission (at wavelengths longer than the incident laser wavelength) and anti-Stokes emission (at wavelengths shorter than the laser wavelength) from the analyte in the resonant SERS zone. The Raman-inducing laser light is directed onto selectively adsorbed analyte(s) in the SERS zone, which may pore(s)/slit(s) through the graded metal plasmon layer, or other suitable RAMAN structure. The laser wavelength is blocked or substantially attenuated by a suitable blocking filter¹⁴⁴. The Raman radiation from the sample resonates along the graded plasmon layer and is spread in wavelength along the backside of the graded plasmon layer 2704 adjacent the imager pixels. The Raman emitted radiation is separated into progressive wavelength zones along the imager pixels. The separated emission is emitted from the rainbow or chirped backside of the plasmon structure adjacent the respective imager pixels, which detect and measure the emission at the different wavelengths. A good quality of the metal atop the planar silicon provides a long plasmon resonance zone with wavelength separation in the relatively small wavelength range of the Stokes and/or the anti-Stokes emission. The top surface of the metal plasmon layer may also be tuned, and have SERS effects for transmission through the nanohole/slit(s), by making both sides of the plasmon metal layer have adjacent dielectric layers of substantially the same refractive index, or otherwise accommodating the tuning. Preferably the Raman emission is spread across at least 3, and more preferably at least 5 imager pixels.

Raman top- and/or-bottom “rainbow” structures and chirped gratings can directly apply top-generated Stokes or Anti-Stokes emission to individual, underlying pixels. The “rainbow” layers can be isolated by gaps, and/or Bragg reflectors. The top-layer incident excitation light is applied in a resonant zone which is isolated from penetration to the bottomside pixels, but the Raman light spread across the graded plasmon layer is resonantly transmitted through the adjacent plasmon zones which are resonant at shifted wavelengths. This Raman analyte spectral information, coupled with other selective-sensing info and IR information, even if not precise individual wavenumber spectral data, is very useful in analyte identification and discrimination.

Because Stokes emission is generally stronger than anti-Stokes emission, efficient compact structures can be designed to direct only the Stokes emission to imager pixels adjacent the “rainbow” emitting backside of the plasmon layer, as illustrated in FIG. 28.

The compact sensor system 2902 of FIG. 29 comprises an addressable matrix light source means 2904, a diffractive sensor means (which may be a plasmonic sensor means) 2906, a sample volume zone 2908 disposed between the addressable light matrix 2904 and the diffractive sensor means 2906 (which may be diffractive and may include a separate diffractive/refractive/“rainbow plasmonic spectrum spreader). The compact sensor 2902 further comprises a digital imager 2910 with an array of imager light sensing pixels 2912 disposed in the transmission diffraction zone of the diffractive sensor means 2906.

The sensor 2902 further comprises a control and data analyzing computer means 2920, and optionally a fluid pump means 2922 and a volatiles collecting (pre-concentration) means 2924 for collecting volatile components pumped from the fluid pump means, and for releasing collected components under control of the computer means 2920. The general gas flow through the sensor system is shown by arrows in FIG. 29; atmospheric gas(es) are pumped from the fluid pump 2922 through the pre-concentrator 2924 where analyte compounds may be collected and extracted from the sample gas for a period of time to concentrate the analyte(s). While the analytes are being collected, the gas from which analytes have been extracted is directed from the pre-concentrator 2724 into the analyte transport and detection zone 2908, where the gas makes contact with the various sensor cells of the VIS light transmissive sensor array 2906. Upon release of the captured and/or pre-concentrated analyte(s), typically by rapid heating of pre-concentrator absorbant material, the released analytes are pumped into the detection zone 2908 for intimate contact with the sensing cells of the light-transmissive sensor layer 2906. In embodiments without a pre-concentrator analyte extractor, the pump can direct a flow of the environmental atmosphere through the detection zone 2908. In lower-power embodiments without a pump or analyte extractor, a detector zone 2908 which is open to expose the sensing cells of the sensor 2906 to the atmosphere is more compact, and adequate for many applications for continuous or periodic atmosphere sampling and analysis.

Such a general-purpose, sensor-on-CMOS systems can be efficiently manufactured with multiple light interrogation for differently sensitive plasmonic diffraction zones, as described herein, which can be sensed simultaneously and/or sequentially, to provide low cost, multiplexed, label-free plasmonic sensing of liquid or vapor analytes.

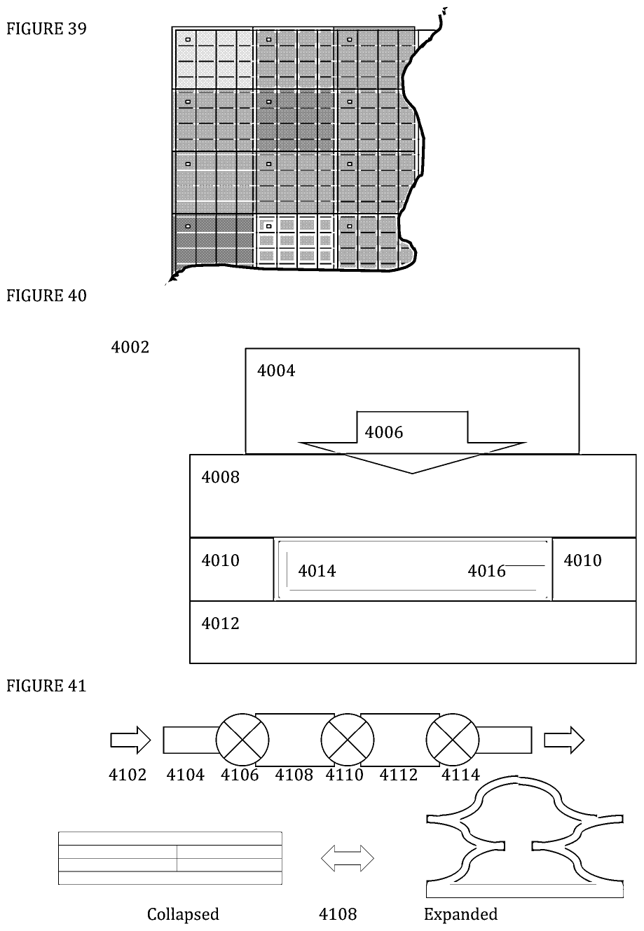

The interrogation light source 2904 is an important component of the sensor 2902. It is closely aligned with the sensor array 2906 to apply interrogating light to specific sensing cells of the light transmissive sensor array 2906 through the analyte application zone 2908. The light source is preferably an addressable LED, LCD, OLED or laser array having at least 8, and more preferably at least 64 addressable light generating elements as illustrated in FIG. 39. Addressable matrix light sources include LED arrays such as the mLED MicroLED 4096 pixellated GaN arrays which have 4096 matrix addressable 16 micron LEDs 50 μm center to center pitch. A variety of emitter shapes and sizes (2 to 100 μm) can be fabricated. A wide variety of addressable matrixed light sources can be made which are suitable for compact interrogation light sources for sensor systems described herein¹⁴⁵. Other integrated circuit addressable matrix LED/Laser light sources for inexpensive sensor manufacture include Small LCD arrays¹⁴⁶. Interrogating light sources with at least 256 or more preferably at least 512 individual light sources, when operatively coupled to corresponding analyte-selective sensor cells diffractively addressing an imager having at least a million pixels can provide formidable detection and discrimination capability. Desirably, each individually addressable light element is adapted to focus at least 50% of its emitted light output onto an area of a sensor cell of the sensor array which is less than 4 square millimeters, and more preferably less than 0.1 square millimeter. For a compact sensor, the LED or laser interrogating light source¹⁴⁷ can be scanned or multiplexed. FIG. 39 is a schematic semi-transparent view from the plane of the imager pixels of an imager camera having at least a million pixels, “upward” toward a monolithic LED light source having at least 256 addressable LED elements. The LED element sites are shown as small squares. The sensor zones of the differently sensitive sensor cells of the plasmonic sensor array which are interrogated by the matrixed light array are shown as larger 4×4 squares of different color, each of which has a different sensitivity to analytes, as described herein. The different sensor cell zones are relatively easy to manufacture, compared to manufacture of very small cells having the center-to-center spacing of the LED array. The LED elements are used to interrogate the different sensing cells in a staged manner to reduce crosstalk. The LEDs which are active are spread out uniformly across the imager surface so that the diffracted light from the sensor array does not overlap substantially between different LED “on” elements. The response of each LED through its respective sensor cell area is recorded by the pixel array of the camera imager. The responses to each LED “on” light source is separated, stored and evaluated by image processing software. This cycle is repeated by using another light source in each of the local zones, until all of the LED light sources have interrogated their respective sensor cells. In the illustrated example, this cycle will take 16 separate interrogations, one each for the 16 LED elements of the 4×4 separation pattern of the areas of the differently sensitive sensor cell zones. This produces a large amount of overlapping sample data for increasing the accuracy of the device.

Integrated addressable LED and VCSEL laser arrays are particularly preferred interrogation light sources¹⁴⁸. Diffractive¹⁴⁹ or refractive¹⁵⁰ converging lenses can be integrated with VCSEL emitting surfaces to focus the emitted beams.

The light source may be “white” or broad-spectrum for color information, or narrowband laser light for diffraction location position change determination. Interrogation light should have wavelength component(s) in the plasmonic or diffractive passband of the plasmonic sensor and/or diffraction grating (FIG. 26). The plasmonic detection cells can be nano arrays, diffraction slit arrays, interference arrays, “rainbow” structures and other nanoscale features which have their transmission or dispersion properties modified by changes in dielectric constant of their components in the near field, typically dialectic components, of the Plasmon's structure. They may also be nanoscale SERS Raman plasma sensor structures which diffract, refract or “rainbow” disperse the Raman emission transmitted along one or more axes for detection at the compactly adjacent integer pixels.

Both broadband “white” (for color diffraction and change of location of the interrogation light on the camera pixels) and monochromatic (for change of location of the transmitted light on the camera pixels) may be used in embodiments of these sensor systems. The placement on the imager pixel array of spread spectrum light, and monochromatic (eg, laser) light transmitted through the sensor elements depends on the change of n caused by analyte absorption or interaction with the sensor cells. The sensing need not be simultaneous—imagers can run at fast frame rates, so a scanning interrogation which reduces crosstalk is useful for increasing compactness of the number of sensing cells and addressable light sources. A scanning light source, such as a TI projector type electronic mirror system can scan rows or individual selective-analyte zones. Alternatively, an LC or other addressable imaging screen with microlenses on the addressable projecting pixels, can focus light points on the differently-sensitive cells of plasmon sensing layer at specific zones corresponding to differently selective analyte affinity zones. Or, an addressable LED or micro laser array can be used in the same way, eg a small “IPhone screen”. The space between the projected light array source and the plasmon layer carries the analyte flow. A Murata-type piezoelectric microblower can be used to drive air flow, directly, or through a collector/concentrator (eg, SPME material) which is periodically discharged (by heat, etc) to apply concentrated analytes over the sensor. For example, a sensor with many, say 100 different sensitivity zones each spread over many-pixels-areas over the imager, can be operated to pulse light simultaneously in each of the zones and record the 100 sensed results on an imager with 25 million pixels. Each different sensitivity zone can have many, say 100 different light-application “spots”. The light from an addressable 1000×1000 light source could apply a “point” of light to each of 100 differently-sensitive “spots” in the plasmon array of each of the differently sensitive zones, seriatim without crosstalk problems. At 30 frames per second, this takes less than 4 seconds for lots of data to reduce noise and bad pixels, and for control elements. Applying 100 differently-sensitivity materials over a broad area is much easier in 100 broad areas over the entire imager, rather than at individual or 10,000 pixel locations.

A variety of plasmon/dispersion/refraction layer(s) can be utilized. In this regard, one dimensional diffraction can reduce crosstalk, and increase overall system detector density. Plasmonic interferometers can be useful as compact 1-D elements, such as double-slit interferometer structures¹⁵¹ with p-polarized light for high contrast as a good design for a plurality (eg, more than 5) of effective sensing elements directly atop a camera imager.

Direct Raman sensor zones atop an imager such as illustrated in FIGS. 26-28 may be included on the sensor structure for even more analytical information. Microprisms such as illustrated in FIGS. 12 and 13 may be compactly useful as spectrum-sensitive components for directing interrogation or Raman light across a camera image array.

The compact sensor 2902 illustrated in FIG. 29, for use in both a liquid and vapor sensing environment, comprises a nanohole transmission array 2904, a small LED illumination source 2906 and a thin transparent spacer layer 2908 directly on top of an inexpensive compact CMOS integrated circuit imager 2910. In operation, transmitted light from the light source 2906 diffracts from the nanohole array, spreading into a spectrum over the thickness of the spacer layer (here approximately a millimeter) to land on the imager as a full spectrum. The nanohole array functions as both a plasmonic sensing surface, and as a diffraction grating to apply a dispersed spectrum to the imager pixels. The spectrum is monitored in real-time and the plasmon-enhanced transmission peaks shift upon exposure to different concentrations of glycerol-in-water solutions or ethanol vapors in nitrogen. The nanoholes may be filled or coated with solvatodielectric materials which change dielectric constant in the presence of analytes to enhance sensitivity, especially for vapor analytes. Solvatochromic dye such as Reichardt's dye is used in the following compact sensor system tests. Solvatochromism is the property of changing color when in association with a solvent, depending on the polarity of the solvent which affects the dye chromatophore energy levels. The dielectric constant of a solvatochromic dye such as Reichardt's dye can change upon absorption of analyte vapor, depending on properties, largely polarity, of the vapor compound which interact with the dye. Different solvatochromic compounds can have different dielectric and color responses to the same analyte, and different analytes. A wide variety of other solvatodielectric materials may be used, as described herein. Importantly, multiple differently-selective, sensitivity-enhancing materials may be applied in different sensing zones of the plasmonic array, to distinguish different analytes or analyte mixtures, as also described herein. The compact sensor system 2902 circumvents bulky components (e.g. microscopes, coupling optics, and spectrometers) of traditional plasmonic sensing systems.

As illustrated the compact sensor utilizes plasmonic nanohole arrays attached directly over a CMOS imager with an index-matching layer, diffracting light from the nanohole grating orders directly onto the imager pixels, thereby resolving the full spectrum of multiple sensing spots simultaneously and in real-time. This arrangement eliminates the need for an external spectrometer, drastically simplifying traditional nanohole-array based sensing platforms. To enhance sensitivity, the nanohole structure was coated with Reichardt's solvatochromic dye which changes its optical properties depending on the concentration and polarity of solvents and has been used to develop non-plasmonic optical liquid or vapor sensors¹⁵². To demonstrate potential for multiplexing, simultaneous signals from two side-by-side locations on the CMOS imager were tested.

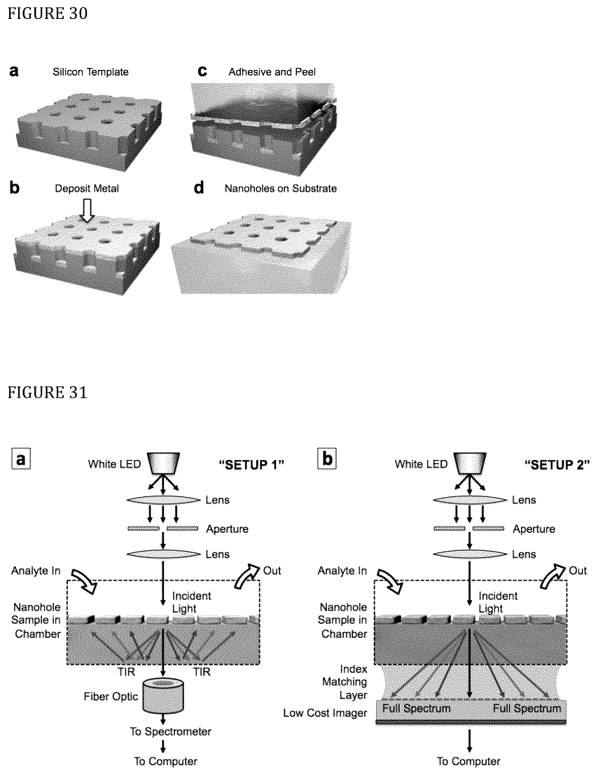

The illustrated nanohole array chips were fabricated by a template stripping method as shown in FIG. 30. While a variety of fabrication techniques may be used, template stripping offers many significant advantages, notably ultrasmooth surfaces and long plasmon propagation lengths, the ability to pattern arbitrary arrangements of bumps, holes, and grooves over large areas, and a reusable template¹⁵³. As illustrated in FIG. 30, a commercially available silicon template with 300 nm decp nanoholes is used to fabricate the nanohole sensing chips. (b) A thin layer of silver is evaporated onto the template. If the layer isn't too thick, it will form a silver film with nanoholes corresponding to the nanoholes of the silicon template. (c) Due to poor adhesion, the silver film with its nanohole array can be peeled from the template using an adhesive backing layer, forming (d) the nanohole sensing chip. The nanohole plasmonic “rainbow-grating-dispersion” chip is adhered to a glass microscope slide for support. Starting with a commercially-available silicon template (LightSmyth Technologies, Inc.) cleaned in a 1:1 solution of H₂O₂:H₂SO₄ and thoroughly rinsed in deionized water, silver was deposited to a thickness of 50 nm at a rate of around 10 nm per minute in a compact thermal evaporator (Oxford Vacuum Science). After deposition (FIG. 30b), a small amount of optical UV curable adhesive (Norland 61) was applied to the deposited silver film and attached to a glass microscope slide. After curing with a small UV LED (Thorlabs), the silver nanohole film was stripped from the template (FIG. 30c), to provide a large-area (1 cm-by-1 cm) nanohole array on the glass microscope slide (FIG. 30d). The template can then be cleaned of silver and reused dozens of times.

Illustrated in FIG. 31 are two optical setups that were used in testing. Setup 1 consists of an LED light source, relay lenses, an aperture to localize the illumination on the nanohole sample, and a testing chamber. Either vapor-phase or liquid-phase samples are injected into the sensing chamber. In this more traditional setup, only the zero-order, undiffracted light is passed through the nanohole substrate to a fiber optics spectrometer. The higher-order diffracted light form the nanohole array is lost to total internal reflection. (b) “Setup 2” consists of the same illumination optics as in “Setup 1” except the nanohole array is adhered directly to a CMOS imager (including its protective cover glass) via an index-matching layer. The diffracted light is now captured directly by the imager pixels as a full spectrum for real-time sensing, replacing the bulky external spectrometer system.
Resembling in part a more traditional plasmonic nanohole array sensing setup (“Setup 1”, FIG. 31a), a broadband white LED was used to illuminate the nanohole chip that was placed in a small sample chamber. The broadband LED light was collimated with a condenser lens and passed through a single-hole aperture that was imaged to a single point on the nanohole array surface. Various analytes were introduced into the sensing chamber, either ethanol vapors in nitrogen for gas sensing experiments or water-glycerol solutions for liquid index sensing experiments. For the vapor sensing experiments, a 99.99% pure nitrogen tank source was connected to a mass flow controller (Cole Parmer), a set of three-way valves (Cole Parmer), and a homemade mixing chamber¹⁵⁴ to receive liquid ethanol from a syringe pump (Cole Parmer) to introduce controlled analyte vapor gas stream concentrations into the sensing chamber. For liquid refractive index sensing, mixtures of water and glycerol were added to the sensing chamber via a micropipette. The refractive indices of the various solutions were verified with a portable refractometer. Light which passes through the nanohole arrays via plasmon-mediated extraordinary optical transmission²⁰ is collected by a fiber optic spectrometer (Ocean Optics) to be analyzed. In this setup, light is also diffracted from the nanohole array grating itself. Since the period of the array was a 700 nm hexagonal lattice (as discussed further below), this light emerged from the array beyond the critical angle and was trapped in the glass due to total internal reflection. In fact, six bright spots from the hexagonal lattice were observed around the edges of the glass microscope slide where this light would eventually emerge and scatter. To collect this light and for direct integration with a CMOS imager, the setup was altered as shown in FIG. 31b (“Setup 2”). The sensing platform still consisted of an LED, condenser lens, aperture, imaging lens, and a sample chamber, but the expensive external spectrometer was removed. In this case, the first diffracted order of LED light transmitted through the nanohole array was allowed to pass through the glass microscope slide via a layer of index matching oil (matching the refractive index of the nanohole chip with the CMOS imager coverglass). The diffracted color spectrum patterns from the nanohole arrays was therefore imaged directly onto the imager pixels, replacing the external spectrometer. This also permitted modification of the aperture to simultaneously illuminate multiple locations on the nanohole sample at once since the entire chip was imaged. This multiplex sensing was not possible with the fiber optic spectrometer and would typically require a more complicated imaging spectrometer for multiplexed spectral sensing²¹. Two different CMOS camera boards were used, one color and one black and white. The color boards were used for producing the diffraction pattern images seen in the figures below and the black and white boards were used in the actual sensing experiments. Both CMOS chips had a ⅓″ format and a 744-by-480 pixel array.

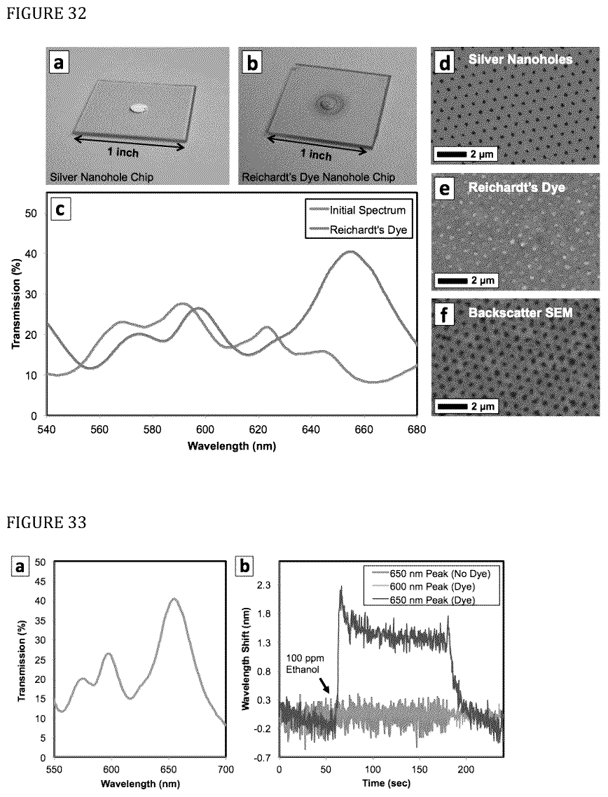

Reichardt's dye was dissolved as 10 mM solutions in 4 four different solvents—acetone, isopropanol, methanol, and ethanol—to determine the most effective carrier for application onto the nanohole array surface (FIG. 3a). With each of these dye solutions, a 75 μL aliquot was delivered to the nanohole surface and then spun at 2000 rpm for 30 seconds. This spin-coating process was repeated for a total of three cycles to ensure thorough coverage (FIG. 32b). Dye dissolved in methanol appeared to provide the most consistent coating results.

The free-space wavelengths of plasmon-mediated transmission maxima λₘₐₓ can be estimated via a grating coupling mechanism for a hexagonal lattice and illumination at normal incidence as previously described:

$${λ}_{max} = {{a [ \frac{4}{3} ( {i}^{2} + ij + {j}^{2} ) ]}^{- 1 / 2} [ \frac{{ε}_{m} {ε}_{d}}{{ε}_{m} + {ε}_{d}} ]}^{1 / 2}$$

where a is the period of the array, i and j represent the Bragg resonance orders of the plasmonic nanohole grating, and εₘ and ε_{d} are the dielectric constants of the metal and the surrounding dielectric, respectively. Since the nanohole array is on an adhesive substrate and is exposed to either air or water on its upper side, ε_{d} can represent air (ε_{d}=1.00), water (ε_{d}=1.78), or the adhesive (ε_{d}=2.43). While not accounting for the specific hole shape, film thickness, the presence of dye in the holes themselves, and other parameters, this equation can be used to generally identify grating-coupled plasmon resonances in the transmission spectrum, and shifts in transmission peak locations caused by changes in refractive index. With a period of 700 nm and the dielectric constant of the silver fit to a Drude model (εₘ=−13 at approximately 600 nm) with experimental optical constants, the peaks in the transmission spectra shown in FIG. 3c can be identified. The peak at 595 nm may correspond to the (i,j)=(1,1) substrate-side plasmon resonances, and the peak at 645 nm may correspond to the (i,j)=(1,0) air-side resonances. These peaks were excited at normal incidence from the LED and were collected at normal incidence (zero-order) in “Setup 1” via the fiber optic spectrometer. However, higher orders are also diffracted from the grating. This can be summarized with the grating diffraction equation:

$$n sin ( θ ) = \frac{{λ}_{max}}{a} {( \frac{4}{3} )}^{1 / 2}$$

where θ is the diffraction angle from an (i,j)=(1,0) order of the hexagonal grating and n is the refractive index of the substrate (n=1.56). For the 645 nm transmission peak, θ=43° is beyond the critical angle θ_{c}=40° and is therefore lost to total internal reflection. In “Setup 2” however, the nanoholes are bonded directly to the CMOS imager via an index-matching layer so the first-order diffraction from the grating can be collected as a full spectrum. Since the light diffracted into these higher orders is directly related to the near-field excitation, they will carry near-field refractive index information into the far-field and can be used for real-time multiplex sensing.

After the dye-coating process, the air-side transmission peak was seen to shift and strengthen considerably (FIG. 32c) indicating good coverage of the dye on the surface of the nanohole array. Interestingly, the transmission peaks that correspond to the substrate side of the silver film shift also shifted, perhaps indicating that the solvents used to deposit the dye coating penetrated slightly into the adhesive substrate under the silver. SEM images seem to corroborate this conclusion, since as the carrier solvent rapidly evaporated, the dye seemed to be deposited into the nanoholes themselves (FIG. 32 d,e,f). In other tests, it was found that the Reichardt's dye would easily stain the cured UV adhesive whereas it would more easily be washed from the silver surface. In any case, incorporation of the dye onto the nanohole array surface significantly enhanced the vapor sensitivity of the device as shown below.

During gas sensing experiments, the three main peaks after coating with dye at 650 nm, 595 nm, and 570 nm were monitored in real-time upon exposure to 100 ppm ethanol vapor in nitrogen. The peaks were fit and tracked with a local 3^{rd} order polynomial function. During these experiments, the chip was typically exposed to nitrogen for one minute, then mixed gasses for two minutes, and nitrogen again for one minute. As seen in FIG. 33, only the peak corresponding to the air-side resonance (650 nm) shifted in wavelength. Furthermore, the air-side peak of a nanohole array that didn't have any coating showed no appreciable shift—the incorporation of Reichardt's dye with the nanohole array provided a significant improvement in sensitivity.

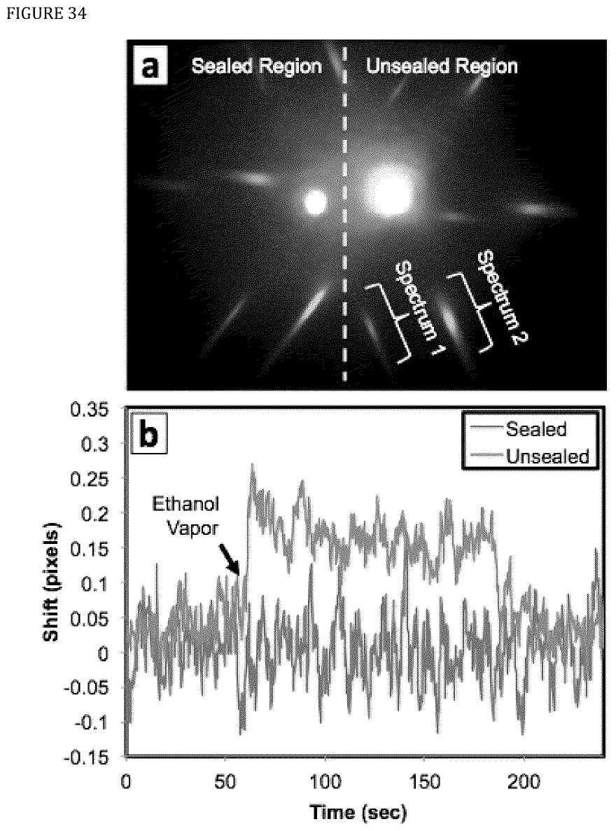

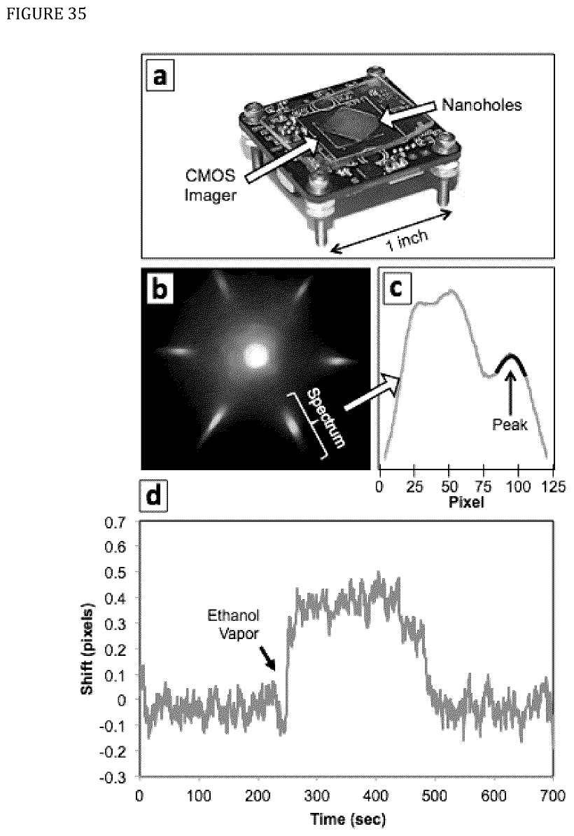

Given this baseline, the same nanohole chips were then tested in “Setup 2” directly on a CMOS imager (FIG. 34a). Focused, collimated light on the nanohole arrays produced a bright central region of the zero-order undiffracted light and a hexagonal diffraction pattern that were imaged on the camera chip (FIG. 34b). FIG. 34c shows that taking a cross-section of one of the diffraction patterns showed three peaks, assigned to the same three peaks shown with the fiber optic spectrometer shown in FIG. 33a although small shifts in transmission resonance wavelengths occur in the first-order relative to the zero-order. The relative intensities of the peaks were also different because the fiber optic spectrometer was normalized to the full spectrum of the white LED whereas the spectrum extracted directly from the CMOS imager was not. These peaks were similarly tracked upon exposure to 100 ppm ethanol vapor in nitrogen. FIG. 34d shows that, again, that the peak corresponding to the air-silver interface plasmon shifted. These results show that the diffracted light from the nanohole array contains spectral information that can be used for plasmonic sensing experiments. In effect, the nanohole array is acting as its own diffraction grating, eliminating the need for a second diffraction grating in the external fiber optic spectrometer.

Because of this direct spectral imaging setup, more than one region on the nanohole array chip can be tracked. To do this, the aperture in “Setup 2” was modified to contain two openings instead of one, thereby illuminating two side-by-side regions on a nanohole chip. FIG. 6A shows a new nanohole array, coated with dye as before, but this time with half covered in a transparent masking tape. The light is still transmitted through to the nanoholes and this time two distinct diffraction patterns are seen (FIG. 6a). The aperture was aligned such that the spectral signal from the two locations did not overlap although even overlapping spectral signal should be able to be unmixed since, effectively, there are six identical copies of each spectrum. In our experiments, the two side-by-side regions were both exposed to ethanol vapor, but this time the covered half of the chip showed no response, as expected. In this way, simultaneously multiplex sensing can be achieved with several independent spectral channels.

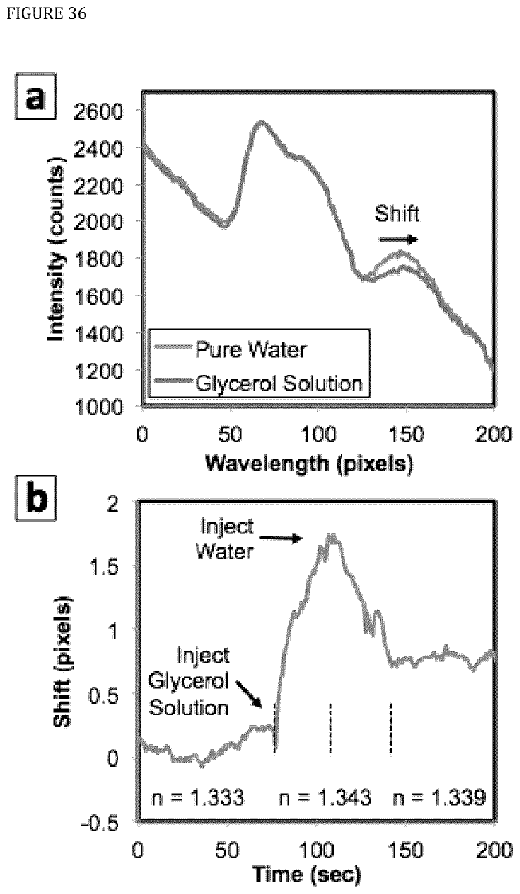

To test this compact, direct spectral imaging apparatus and procedure for liquid sensing, another set of nanohole chips was fabricated and this time immersed in 20 μL drop of water (n=1.333) placed directly on the nanohole surface in the sample chamber. Extracting the spectrum from the CMOS imager pixels produced a series of peaks, one of which shifted when mixed with a 20 μL drop of water and glycerol, increasing the refractive index of the solution (n=1.343). FIG. 36a shows the spectrum from the diffracted LED light extracted from the CMOS imager with the nanohole chip immersed in a liquid water environment. Upon changing the refractive index of the liquid nanohole environment by applying a water-glycerol mixture of higher refractive index, the transmission peak corresponding to the silver-water interface shifts while the others do not, as shown in FIG. 36b. This shifting peak can be tracked in real-time as before, showing good refractive index sensitivity to water (n=1.333) and glycerol solutions (n=1.343). Upon injecting pure water after the glycerol mixture, the peak shifts back to a position corresponding to the average of the refractive indices, because the glycerol solution remained on the chip and merely mixed with the additional water. Tracking this peak in real-time shows response of the peak to these changes in refractive index. Upon a final addition of another 10 μL drop of water, the solution had a slightly decreased refractive index (n=1.339) and finally stabilized. Looking at these calibrated results, it appears that a Δn=0.01 change in refractive index corresponds to a roughly 1.75 pixel shift on the CMOS camera, giving a sensitivity of 175 pixels/Refractive Index Unit (RIU). Accordingly, the unoptimized test setup should be able to detect ˜0.1 pixel shift corresponding to a Δn of around ˜5e-4. There are several ways in which this could be improved: (1) Adjusting the distance between the nanohole array chip and the CMOS imager to spread the spectrum out further, giving more pixels in the spectrum and improving the peak tracking; (2) Use a higher density CMOS pixel array. The illustrated CMOS imager was 744-by-480 pixels in a ⅓″ format corresponding to 6 μm pixels. Imagers with smaller pixels, lower noise, and/or higher sensitivity, as well as CCD imaging arrays can provide improved functionality and performance.

To simplify the standard optical setups of nanohole array sensors, the nanoholes, an LED illumination source and a suitable spacer layer are positioned directly on top of a CMOS or CCD imager. Transmitted light from the LED illumination source diffracts from the nanohole array, spreading into a full spectrum and landing on the imager pixels. The compactly integrated sensor is useful in both a liquid and a gas environment.

This compact system replaces bulky components (e.g. microscopes, coupling optics, and spectrometers) often used for traditional plasmonic sensing setups, uses the nanohole array as both the sensing surface and a diffraction grating, and maintains good sensitivity. Such compact sensing systems can be used for real-time, multiplex parallel sensing, and low-power, low-cost lab on a chip integration.

Gas chromatography is, in general, a mature “workhorse” technology with enormous capability, controllers and software, flow-control systems, ovens, detectors, separation column types and sorbent coatings, procedural technique availability and well-developed reference and standards information. US patent publications exemplify some of this mature GC technology, components, analytical procedures and capability¹⁵⁵. The MWIR-enhanced systems of the present disclosure can be particularly useful for improving separation and discrimination of compact GC devices and methods. A variety of switching valves are known and utilized in GC systems¹⁵⁶. A wide variety of compact and lab-on-a-chip GC system have been developed for portability, low-power use, and compactness, including samplers and preconcentrators, carrier gas, valveing components and systems, columns, and detectors, together with process controllers and I/O¹⁵⁷. Nevertheless, there is a need for improved and more flexible separation capability and enhancement. There is also a need for compact, chemical analysis systems combining high separation capability with chemical detection, discrimination and identification for analysis and monitoring chemicals, explosives, narcotics, and environmental pollutants¹⁵⁸. Desirable features include low-power, reversible gas phase collection and pre-concentration, non-destructive fractionation of chemical mixtures with high dynamic separation range, including the capability to discharge or “bleed off” all or part of specific fractions if desired. High-accuracy identification of compounds is also an important need in such compact systems.

US patent publications exemplify some of this mature GC technology, components, columns, stationary phases, ovens and thermal control, carrier gas flow control, analytical procedures and capability¹⁵⁹. A wide variety of compact and lab-on-a-chip GC system have been developed for portability, low-power use, and compactness, including samplers and pre-concentrators, carrier gas, valveing, columns, and detectors, together with process controllers and I/O¹⁶⁰. The MWIR-enhanced systems of the present disclosure can be particularly useful for improving separation and discrimination of compact GC devices and methods.

Broadband microwave and broadband IR radiant microwave GC ovens can generate uniform low-effective-mass heating on GC columns externally coated with microwave-absorbing materials which shield the GC column contents, to permit rapid heating, and fast cooling of the column¹⁶¹, but do not effectively selectively “heat” specific classes of compounds or functional groups to decrease their elution times in a GC column separation.

Microwave electromagnetic radiation lies between the radio and the infrared wavelengths in the range of from 1 millimeter to 1 meter (vacuum), or approximately from 300 MHz to 300 GHz in frequency. Common spectral regions reserved and used for commercial and industrial microwave heating and material treatment are bands centered at 915 MHz, 2.45 GHZ, and 5.85 GHz. Molecules that have a permanent dipole moment or charge absorb energy and are driven in kinetic motion (rotational, translational, vibrational) by the alternating electric field of microwave radiation¹⁶². These molecules become “hotter”. If microwave-absorbing molecules are in a mixture with other differently-energy-absorbing molecules, a non-equilibrium mixture is formed, with those molecules which absorb more microwave energy becoming statistically “hotter” than those which do not absorb as much (or very little) microwave energy. Subsequently the more energetic molecules transfer or dissipate energy to surrounding “less hot” molecules, toward reaching thermal equilibrium in the mixture. While microwave energy is being applied and absorbed by some molecules more than others in a mixture, the mixture does not reach a static thermal equilibrium because of the ongoing absorption of microwave energy by the more microwave-receptive molecules, which statistically remain somewhat “hotter”. More polar molecules tend to have greater interaction with, and heating by, microwave energy than less polar molecules.

Unlike microwave absorption characteristics which tend to be broadly related to polarity, different molecules tend to absorb infrared radiation in specific wavelengths determined by their particular molecular composition and structure. The infrared region most useful for selective MWIR energetic stimulation of organic compounds is the wavelength range from about 2.5 microns to about 12 microns (vacuum). Substantially all organic compounds absorb infrared radiation in resonance with a wide range of vibrational motions generally defined by their specific component atoms and structure. These resonance absorption bands are typically quantified and described by inverse centimeter notation: ______ cm⁻¹=10,000/λ (microns); 2.000μ=5000.00 cm⁻¹; 2.500μ=4000.00 cm⁻¹; 12.000μ=833.33 cm⁻¹

Some characteristic selective MWIR absorption bands¹⁶³, include

| | | Absorption peak |
|---|---|---|
| Bond | Type of bond | (cm⁻¹) |
| | | 1260 |
| | | 1380 |
| | | 2870 |
| C—H | alkyl (various) | 2960 |
| | | 1470 |
| | | 2850 |
| | | 2925 |
| | vinyl (various) | 900 |
| | —C—H absorption peaks above 3000 cm⁻¹ are typically due to | 2975 |
| | unsaturation | 3080 |
| | | 3020 |
| | | 900 |
| | | 990 |
| | | 670-700 |
| | | 965 |
| | | 800-840 |
| | Alkynes | 3300 |
| | aldehydes | 2720 |
| | | 2820 |
| | acyclic C═C | 1600-1645 |
| | conjugated C═C | 1600-1650 |
| | | 1650 |
| | | 1450 |
| C═C | aromatic C═C | 1500 |
| | | 1580 |
| | | 1600 |
| | C≡C | 2100-2140 |
| | | 2190-2260 |
| | | 1720 |
| | aldehyde/ketone | 1685 |
| | carbonyl stretching absorption is one of the strongest IR absorptions | 1685 |
| C═O | for selectively “heating” analyte compounds in GC analyses | 1750 |
| | | 1775 |
| | | 1725 |
| | | 1710 |
| | carboxylic acids/derivatives | 1680-1690 |
| | | 1735 |
| | | 1650 |
| O—H | alcohols, phenols | 3700-3584 |
| | | 3200-3400 |
| | carboxylic acids | 3500-3560 |
| | | 3400-3500 |
| N—H | primary amines | 1560-1640 |
| | secondary amines | >3000 |
| | amide stretch | 3700-3500 |
| | aliphatic amines | 1020-1220 |
| | C═N | 1615-1700 |
| C—N | C≡N (nitriles) | 2250 |
| | | 2230 |
| | R—N—C (isocyanides) | 2165-2110 |
| | R—N═C═S | 2140-1990 |
| | Fluoroalkanes | 1000-1100 |
| | | 1100-1200 |
| C—X | Chloroalkanes | 540-760 |
| | Bromoalkanes | 500-600 |
| | Iodoalkanes | 500 |
| | | 1540 |
| N—O | nitro compounds | 1380 |
| | | 1520 |
| | | 1350 |

The present disclosure is also directed to methods and apparatus for selectively applying midwave infrared radiation to specific absorption bands of organic compounds undergoing gas chromatographic separation, in order to change the elution time of the compounds, if present. There are a wide variety of MWIR materials and sources¹⁶⁴.

A rugate filter can be used with a broadband MWIR source to pass the absorption band(s) of specific compounds, or “generic’ classes of compounds such as nitrates, ethers, aromatics, aliphatic hydroxy, etc. However, MWIR lasers and LEDs are preferred as MWIR sources. For some applications, short-repetitive-pulse mid-IR solid state diode pumped lasers are useful for selective irradiation of GC sample mixtures. For example, designed single-mode emission selected in the wavelength range of 2.5 to 4 microns can be produced with less than 10 ns pulse durations and greater than 1 mJ pulse energy at greater than 10/second repetition rate to apply an effectively “continuous excitation energy” to sample components which absorb at the selected MWIR wavelength¹⁶⁵.

Laser diode MWIR lasers based on GaSb employing a AlGaln-AsSb material system epitaxially grown on GaSb substrates provides compact IR diode lasers in the 1850-2500 nm wavelength range, with single emitters having up to 1 W of Output Power and Up to 10 W of Output Power for Laser Arrays¹⁶⁶. Watt-level diode-pumped continuous wave and pulsed mid-infrared lasers based on Erbium-doped ZBLAN fibers are also useful in the mid-IR range (eg, ˜2.8μ)¹⁶⁷

Quantum cascade lasers are broadly useful MWIR sources in various embodiments of the present disclosure¹⁶⁸, for example for specific wavelengths in the λ=3.8 μm to λ=12.5 μm range, under continuous or pulsed operation at room temperature in broadened or substantially single frequency output by use of distributed-feedback waveguide fabrication. A multi-QCL light source (such as the MIRcat™ products of Daylight Solutions may be used as a programmable MWIR irradiation source operating under controller 3732 for applying specific MWIR energy for selective absorption by GC analyte mixtures as disclosed herein¹⁶⁹.

Substrate and/or stationary phase materials for MWIR irradiation zone and/or separation column (eg, capillary) components may be selected for the MWIR irradiation bands intended for the GC system. Silica glass intended for GC capillary tubing having relatively high IR transmission should best have very high purity, including extremely low metallic impurity and water content to minimize MWIR absorption. Pure silica glass is effectively transparent to IR from about 200 nm up to 3.5 to 4 microns, but becomes more absorbing or opaque at longer infrared wavelengths. A number of absorption bands at longer wavelengths can be attributed to —Si—O— bonds.¹⁷⁰

Gas-sorbent polymers can have IR-interactive bonding, which can be utilized to selectively “heat” molecules which are interacting with a stationary phase material in this manner, by applying MWIR radiation at the absorption wavelength(s) at which the interacting analyte and stationary phase interact. Gas sorbent polymers such as acidic poly(methyldi(1,1,1-trifluoro-2-trifluoromethyl-2-hydroxypent-4-enyl)silane (referred to as HCSFA2), exhibit large gas-polymer partitions for a variety of hazardous chemicals with basic hydrogen-bond properties¹⁷¹. These materials can be used as pre-concentrator components, and as stationary phase coatings in MWIR irradiation zones for IR wavelengths where they are not too strongly absorbing. Polymer stationary phases can be tested¹⁷² and selected for windows of transparency in MWIR ranges corresponding to specific wavelength ranges for selective elution or gas-transport enhancement. Polysiloxanes are common GS stationary phases in GC columns. Fully deuterated polydimethylsiloxane polymer has substantially no absorption bands in the wavelength range from 1670 to 2100 nm¹⁷³ so is a useful solid phase for use with selective IR elution enhancement of sample components which absorb in this range and its other transparent IR windows. Polytetrafluoroethylene (and related soluble copolymers) has wide transparent windows from 2.5μ (4000 cm⁻¹) to about 8μ (˜1240 cm⁻¹, and from about 10μ (˜1000 cm⁻¹) to about 14μ (˜700 cm⁻¹); polypropylene similarly has transparent MWIR windows from 2.5μ (˜4000 cm⁻¹) to about 3.12μ (˜3200 cm⁻¹) and 3.57μ (˜2800 cm⁻¹) to about 5.5μ (˜1500 cm⁻¹) with a small absorption peak centered at about 5.7 (˜1750 cm⁻¹), as useful stationary phases for use in MWIR irradiation zones¹⁷⁴.

Rare-earth doped chalcogenide glasses are suitable for narrow band (eg, laser) and broadband sources in the mid-IR¹⁷⁵. Supercontinuum, tunable, and fixed narrow-spectrum mid-IR sources such as chalcogenide¹⁷⁶, fluoride¹⁷⁷, selenide¹⁷⁸, phosphide,¹⁷⁹ and tellurite¹⁸⁰ systems are relatively compact and flexible¹⁸¹. Chalcogenide fibers are well-suited for mid-IR applications ranging from 2 to 11 microns which overlaps the spectroscopic molecular fingerprint region¹⁸².

For MWIR optical components employed herein, silica glass is usefully transmissive in NIR and shorter MWIR ranges, but may be effectively opaque in bulk thicknesses for wavelengths longer than 3.5-4.0 microns¹⁸³. High purity silicon has high IR transmission in the 1.5 to 7 micron range¹⁸⁴. Germanium is a versatile infrared material commonly used in infrared imaging systems and instruments in the 2 to 12 microns spectral region. CVD diamond is transparent from the UV (230 nm) to the far infrared, with only minor absorption between 2.5 and 6 μm.

A relatively simple gas-phase MWIR irradiation zone comprises a light-pipe flow cell. In such an embodiment, the GC sample flow may be conducted through a glass, quartz or other capillary, which is internally reflection-coated (with gold, silver or dielectric reflector) on the inside. The selectively-heating MWIR infrared radiation is directed axially through the hollow light-pipe, to selectively heat those analyte components within the hollow light pipe which absorb at the wavelength(s) directed into the lightpipe by the MWIR source. The lightpipe or other MWIR irradiation zone may be externally temperature-controlled (eg, heated) to avoid analyte condensation. Selective MWIR irradiation by specific GC analyte gas species which absorb IR at the pre-selected wavelength band(s) may be enhanced by applying high radiation and resolution power of a tunable external cavity quantum cascade laser (“EC-QCL”) by efficient coupling along the internal axis of an infrared hollow fiber lightpipe¹⁸⁵. MWIR selective heating using a gas cell 3902 such as a hollow optical fiber, preferably with reflective intensification such as mirror or distributed reflector, and/or distributed reflection providing IR cavity resonance.

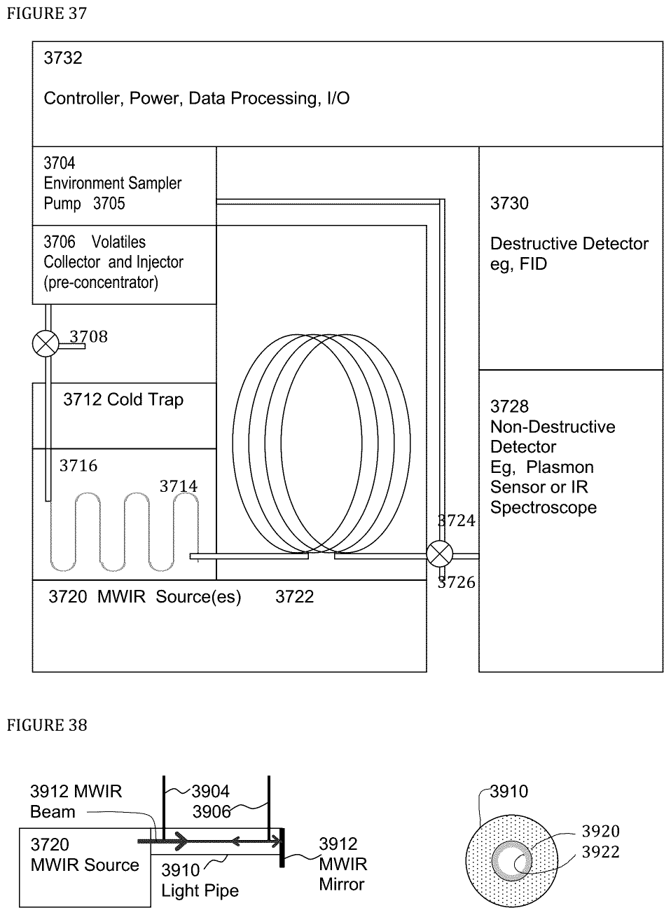

A useful MWIR selective irradiation configuration for some embodiments, such as those employing commercial fiber-delivered IR, and purpose-built irradiation components, is a resonating chamber design such as schematically illustrated in FIG. 38. An MWIR source 3720 (FIG. 37) such as a preferably tunable EC-QCL is configured to direct its IR light output beam into one end of a GC hollow lightpipe 3910 along its longitudinal axis. A narrow bore lightpipe (eg, a 10-500 micron ID capillary having a smooth, thin layer of gold, silver or other IR reflective layer coated on the inside may be used as an example. The lightpipe may be a conventional quartz GC capillary treated to have an internal reflective layer 3920, and in some embodiments such as illustrated in FIG. 38, a GC stationary phase coating 3922 which is relatively non-absorbing in the MWIR irradiation wavelength range such as poly-perfluoroethylene polymers.

The lightpipe is also connected to input and output GC column or capillary lines 3904, 3906 at its ends. The lightpipe 3910 further comprises an infrared reflector at its distal end opposite the MWIR source 3720, which may simply be a gold or silver coating on the polished hermetically sealed end of the lightpipe. The hollow fiber lightpipe may have a stationary phase coating on its interior, which is preferably selected to have low IR absorption in the wavelengths of IR radiation projected from the MWIR source 3720 into the lightpipe. The lightpipe may typically have a length of from about 1 centimeter to about 10 meters¹⁸⁶. In operation, the GC carrier gas should have a transit time of at least 1 second, and preferably at least 5 seconds in the MWIR irradiation zone.

Pulsed or continuous quantum cascade lasers with an external cavity can have emission wavelengths in the mid infrared, with a relatively broad spectral range. The Daylight Solution, Inc. Übertuner 7 (ÜT7) product is an example of a tunable EC-QCL with emission range between 1325-1550 cm⁻¹, and a peak power of ˜100 mW at a duty cycle of 5% (500 ns pulse width, 100 kHz repetition rate)¹⁸⁷. In the wavelength range of this ÜT7 EC-QCL, the fiber type HWEA from Polymicro Inc has a weak attenuation of around 1.5 dB/m, a hollow core diameter of 500 μm and a minimum bending radius of ˜6 cm. For some applications, short-repetitive-pulse mid-IR solid state diode pumped lasers are useful for selective irradiation of GC sample mixtures. For example, designed single-mode emission selected in the wavelength range of 2.5 to 4 microns can be produced with less than 10 ns pulse durations and greater than 1 mJ pulse energy at greater than 10/second repetition rate to apply an effectively “continuous excitation energy” to sample components which absorb at the selected MWIR wavelength¹⁸⁸. Laser diode MWIR lasers based on GaSb employing a AlGaIn—AsSb material system epitaxially grown on GaSb substrates provides compact IR diode lasers in the 1850-2500 nm wavelength range, with single emitters having up to 1 W of Output Power and Up to 10 W of Output Power for Laser Arrays¹⁸⁹. Watt-level diode-pumped continuous wave and pulsed mid-infrared lasers based on Erbium-doped ZBLAN fibers are also useful in the mid-IR range (eg, ˜2.8μ)¹⁹⁰

Quantum cascade lasers are broadly useful MWIR sources in various embodiments of the present disclosure¹⁹¹, for example for specific wavelengths in the λ=3.8 μm to λ=12.5 μm range, under continuous or pulsed operation at room temperature in broadened or substantially single frequency output by use of distributed-feedback waveguide fabrication. A multi-QCL light source (such as the MIRcat™ products of Daylight Solutions may be used as a programmable MWIR irradiation source operating under controller 3732 for applying specific MWIR energy for selective absorption by GC analyte mixtures as disclosed herein¹⁹².

Substrate and/or stationary phase materials for MWIR irradiation zone and/or separation column (eg, capillary) components may be selected for the MWIR irradiation bands intended for the GC system. Silica glass intended for GC capillary tubing having relatively high IR transmission should best have very high purity, including extremely low metallic impurity and water content to minimize MWIR absorption. Pure silica glass is effectively transparent to IR from about 200 nm up to 3.5 to 4 microns, but becomes more absorbing or opaque at longer infrared wavelengths. A number of absorption bands at longer wavelengths can be attributed to —Si—O— bonds.¹⁹³ Silicon and Germanium are transparent to somewhat longer wavelengths, and materials such as some chalcogenides and extend to even longer wavelengths.

Gas-sorbent polymers can have IR-interactive bonding, which can be utilized to selectively “heat” molecules which are interacting with a stationary phase material in this manner, by applying MWIR radiation at the absorption wavelength(s) at which the interacting analyte and stationary phase interact. Gas sorbent polymers such as acidic poly(methyldi(1,1,1-trifluoro-2-trifluoromethyl-2-hydroxypent-4-enyl)silane (referred to as HCSFA2), exhibit large gas-polymer partitions for a variety of hazardous chemicals with basic hydrogen-bond properties¹⁹⁴. These materials can be used as pre-concentrator components, and as stationary phase coatings in MWIR irradiation zones for IR wavelengths where they are not too strongly absorbing. Polymer stationary phases can be tested¹⁹⁵ and selected for windows of transparency in MWIR ranges corresponding to specific wavelength ranges for selective elution or gas-transport enhancement. Polysiloxanes are common GS stationary phases in GC columns. Fully deuterated polydimethylsiloxane polymer has substantially no absorption bands in the wavelength range from 1670 to 2100 nm¹⁹⁶ so is a useful solid phase for use with selective IR elution enhancement of sample components which absorb in this range and its other transparent IR windows. Polytetrafluoroethylene (and related soluble copolymers) has wide transparent windows from 2.5μ (4000 cm⁻¹) to about 8μ (˜1240 cm⁻¹, and from about 10μ (˜1000 cm⁻¹) to about 14μ (˜700 cm⁻¹); polypropylene similarly has transparent MWIR windows from 2.5μ (˜4000 cm⁻¹) to about 3.12μ (˜3200 cm⁻¹) and 3.57μ (˜2800 cm⁻¹) to about 5.5μ (˜1500 cm⁻¹) with a small absorption peak centered at about 5.7 (˜1750 cm⁻¹), as useful stationary phases for use in MWIR irradiation zones¹⁹⁷.

Rare-earth doped chalcogenide glasses are suitable for narrow band (eg, laser) and broadband sources in the mid-IR¹⁹⁸. Supercontinuum, tunable, and fixed narrow-spectrum mid-IR sources such as chalcogenide¹⁹⁹, fluoride²⁰⁰, selenide²⁰¹, phosphide,²⁰² and tellurite²⁰³ systems are relatively compact and flexible²⁰⁴. Chalcogenide fibers are well-suited for mid-IR applications ranging from 2 to 11 microns which overlaps the spectroscopic molecular fingerprint region²⁰⁵.

A capillary GC column can also be made a component of a fiber laser for even more compact designs. ZnSe and other zinc chalcogenide semiconductor materials can be doped with divalent transition metal ions to create mid-IR laser gain media with active function in the wavelength range 2-5⁺ microns using annular heterostructures with effective and low order mode coreclad waveguiding²⁰⁶.

For MWIR optical components employed herein, silica glass is usefully transmissive in NIR and shorter MWIR ranges, but may be effectively opaque in bulk thicknesses for wavelengths longer than 3.5-4.0 microns²⁰⁷. High purity silicon has high IR transmission in the 1.5 to 7 micron range²⁰⁸. Germanium is a versatile infrared material commonly used in infrared imaging systems and instruments in the 2 to 12 microns spectral region. CVD diamond is transparent from the UV (230 nm) to the far infrared, with only minor absorption between 2.5 and 6 μm.

In conventional or “benchtop” GC systems, the carrier gas source may comprise a pressurized tank of hydrogen, helium, argon or other gas tank together with the valveing, piping, pressure and/or flow control and temperature adjustment devices in accordance with conventional practice.

Components may have multiple functions and facilitate multiple modes of operation under programmed control. The blower in combination with the low temperature collection zone may be used to function as an extremely compact vapor analyte concentrator, sample injector and pressurized carrier gas source. For example, a tiny piezoelectric blower can be programmed to pump the atmosphere being sampled through the cold collection zone, which may also be an MWIR-transmissive IR irradiation zone, maintained under cold conditions to collect atmospheric vapors of interest, and then through the separation column. The detector(s) may be disabled during this sample collection time to conserve power. After a predetermined collection time, the cold collection zone may be rapidly heated to release the collected atmospheric sample. The heating may be by electrical resistance, and/or by MWIR radiation. The microblower can be programmed to continue to pump the sampled atmosphere through the now-heated collector, as the carrier gas. This carrier gas can contain volatile components, but they are continuously present in the carrier gas (sampled air) so raise the background detection signal but do not present a concentration peak at the detector(s). If it is desired to have substantially background-free elution detection data, a separate volatile-component collector may be included in the system as described herein. Upon abrupt release of collected volatile sample, the collector is cooled to again collect the atmospheric volatiles components, so that the air stream pumped through the separation column(s) is relatively cleaned of background components. If MWIR radiation is applied, those components which absorb such radiation are preferentially heated and advanced in elution time. The sampling can be repeated without selective MWIR elution enhancement (“control”), and with differently-selective MWIR-heated elution enhancement. Analytical comparison of the resulting data is a powerful differentiation and identification tool.

A wide variety of separation columns and materials are well-known and commercially available for general separation use, or for specific separation capabilities. The columns separate components, to a large degree based on vapor pressure/boiling point and the affinity of the respective different sample components for the stationary phase of the column. They at least partially-separated components are eluted from the discharge end of the separation column through the valve blank and optional discharge valve blank to one or more detector systems. Illustrated in FIG. 37 are a non-destructive detector which does not destroy the sample components such as an infrared absorption detector, or a plasmonic detector such as described herein, and a destructive detector such as a flame ionization detector which destroys the sample components upon detection and measurement thereof. In this conventional mode of operation, the various constituents of a sample mixture or a looted and detected by their retention time in a manner such as illustrated in FIG. 39. Known tracer or control compounds can be introduced in a sample mixture to calibrate the elution time determination of separated components. Specific components eluted may also be characterized and discriminated by mass spectrographic analysis in accordance with conventional procedure to determine the elution time of specific compounds under specific operating conditions.

The absorption or dissolution of analytes in the stationary phase of the gas chromatographic column can shift the IR absorption bands of the analyte and/or create new absorption bands. The MW infrared radiation may also be selected to be absorbed by the non-covalent bonding between specific analytes and the stationary phase of the column or other radiation zone [cite] this is particularly effective for selective “distillation” of the sample components which have thermodynamic affinity for the stationary phase. If it is desired to delay the elution of a specific compound, a filter mask of that (or a spectroscopicl related) compound may be used as an optical filter to remove MWIR radiation from a broadband MWIR source as shown in FIG. 39. As shown in FIG. 39, a plurality of broadband MWIR sources 3804, 3806, 3808 . . . 3810 which may, for example be LED arrays, are each arranged and positioned to irradiate respective zones of gas chromatographic column(s) etched in an infrared transparent wafer through respective filters 3814, 3816, 3818 . . . 3820. The infrared sources 3804 . . . 3810 may be turned “on” or “off”, or adjusted in output power, independently under control of the process controller of the apparatus. The respective filters 3814 . . . 3820 may be individual (or related) compounds of specific interest to precisely remove infrared radiation from the broadband output of the respective MWIR source which selectively heats such compound. The filters may also be through gate or other narrow or broadband filters which remove and/or transmit specific bands or patterns as desired for a specific analytical processing operation. A filter may also include the stationary phase of the column, to reduce infrared wavelength components which would otherwise tend to heat the stationary phase column material itself.

To achieve increased separation of components, “heart cuts²⁰⁹” of unresolved component mixtures can be subjected to further separation in a differently retaining column, or differently select the columns may be used, but this is bulky, time-consuming and expensive in practice. In accordance with this disclosure, a variety of operating procedures may be used to achieve increased separation in a more compact equipment system. In one procedure, selective infrared radiation from the IR source is applied to the sample being conducted through the non-static equilibrium in which the absorbing materials are “hotter” then they would be at static equilibrium, and accordingly are transported in the carrier gas and eluted more rapidly than in the absence of the selective infrared radiation.

The infrared radiation can be selected to be absorbed by specific functional groups or absorption mechanisms of components which are desired to be eluted more rapidly than they would be in the absence of the select of infrared radiation. In this procedure for example, selective MWIR radiation wavelength is absorbed and energizes (heats) compounds which have bonds or groups receptive to or resonating with the selective MWIR. The absorbed energy is rapidly dissipated to other sample component molecules and the carrier gas, but while the mixture is absorbing MWIR energy there remain molecules of higher effective temperature which are more rapidly eluted.

Illustrated in FIG. 37 is a gas chromatographic system which utilizes selective electromagnetic radiation to increase the effective temperature of components which absorb the specific wavelength(s) of the applied radiation. This selective energy transfer can assist in component separation in gas chromatographic systems of the present disclosure. Embodiments of MWIR selectively-heating GC systems which utilize such components are illustrated in FIG. 37 which schematically shows a gas chromatographic system 3702 which utilizes selective midwave infrared radiation {“MWIR”) applied to the analyte stream to selectively enhance or modify component separation and/or identification. The illustrated system 3702 comprises a carrier gas source means 3704 which may be a conventional pressurized inert (eg, helium, neon, argon) carrier gas system for “benchtop” GC systems, or may be, or may comprise an environmental atmosphere pump 3705 with a gas-purifying absorbent system for use with compact GC systems which can function without the need for tanks of purified pressurized nitrogen or neon. The system 3702 further comprises a sample injection means 3706, one or more reverse flow discharge valves 3708, 3710, one or more cold trap analyte collecting reservoirs or means 3712, 3714, one or more infrared radiation treatment zones 3716, 3718 for selective analyte excitation, one or more selective midwave infrared sources 3720, 3722, a forward flow discharge valve 3724, a reverse carrier flow introduction and control valve 3726 and one or more analyte detectors 3728, 3730. The GC system is controlled by digital computing means 3732 for controlling the data collection, operation and processing of the system components.

The MWIR radiation zone may comprise a cavity with an end mirror and MWIR laser input to resonate and increase absorption within the component mixture. The MWIR radiation zone can also be made of sodium chloride, chalcogenide or other materials which transmit radiation at wavelengths beyond about 4μ. Such materials may optionally be protected by a minimally MWIR-absorbing internal passivation monolayer).

In an example of operation of a gas chromatographic system like that illustrated in FIG. 37, a sample is introduced into the injector and is conducted through the exhaust outlet, and selective infrared irradiation and absorption zone., Which is at preselected temperature without incident infrared from the selective infrared radiation source. Easily replaceable sections of quartz capillary tubing without stationary phase absorbance are conventionally used in desktop GC systems to retain components which could damage downstream separation columns.

From the selective infrared radiation means 3720, 3912 the carrier gas (with sample components) is conducted to the conventional separation column(s) having a stationary phase on its interior service in accordance with conventional practice.

While absorbing MWIR energy in the irradiation zone, there is a non-static equilibrium in which the absorbing molecules are “hotter” than they would be at static equilibrium, and accordingly are transported in the carrier gas and diluted more rapidly than in the absence of the selective radiation.

In another mode of operation, a sample may be transported by carrier gas for a predetermined time or until a certain known or sought-four compound would elute. The exhaust valve 3708 may be opened, and the carrier gas input valve 3724, 3726 opened so that the carrier gas flow is reversed in the separation column. The component separation achieved by passage through the separation column [forward passage] will largely be lost by reverse flow under identical separation conditions in the same separation column. However, by changing the column temperature, some separation resolution can be retained. If an exhaust valve blank in the separation column length, the least-volatile and/or most highly-retained components can be discharged from the sample component mixture by reverse flow discharge, leaving the components in the column which are desired to be separated further.

The components can be collected in reverse flow at a specific location by a cold zone 3712 which can be cooled by thermoelectric, refrigerant liquid or refrigerant gas. Desirably the cold zone will be progressively cold in a countercurrent manner as the component's in reverse flow are conducted through it. In this way some of the component separation achieved in the first pass can be retained, if desired for specific separation of the preselected gas chroma photography procedure.

The cold collection zone may be separate from, or may be part of the infrared radiation zone in the illustrated embodiment. Upon “collecting” the components in reverse flow which are to be further separated, the valve blank and/or blank or closed, the valve blank is opened to restore flow in the forward direction to the detector blank and/or blank, and the carrier gases again introduced into the inlet and through the cold collection zone.

The collection zone is rapidly heated (progressively along its length) to vaporize the retained components. For normal “forward” transport. The heating may be applied by selective infrared radiation if desired and/or by rapid electrical resistance heating. Upon passage through this MWIR radiation zone, the remaining sample components with different IR absorption characteristics can be separated by applying selective absorb infrared radiation.

Conventional portable and miniaturized analytical systems may typically comprise microtraps or other preconcentrators in which a fluid sample stream is passed through the preconcentrator to collect very low-concentration analytes for a period of time, which is typically under preselected and/or programmed control. The collected, concentrated analytes (if any) can then be rapidly released from the preconcentrator to a gas chromatographic column or other detector for subsequent analysis within its sensitivity limits²¹⁰. However, various analytes having different chemical identities may have the same or similar elution times from the GC column, which limits analyte identification and analysis. A way to increase the effective resolution of miniature GC columns, and obtain additional information about the chemical identity and properties of the analytes is needed.

Illustrated in FIG. 40 is an analyte pre-concentrator and selective gas chromatograph injection means 4002 for collecting analyte samples, and for preferentially injecting portions of collected samples which absorb infrared light at preselected wavelengths in the MWIR spectrum (eg, from about 2.5 microns to about 12 microns) into a gas chromatographic column or detector. The system comprises a broadband MWIR source 4004 for emitting MWIR radiation 4006, a MEMS-based tunable Fabry-Perot interferometer comprising a first Bragg dielectric stack mirror reflector 4008 and a second parallel reflector 4012 which may be a stacked dielectric reflector like that of 4008 or a metallic reflector, which may be fabricated in accordance with conventional practice²¹¹. A metallic reflector may serve a dual purpose of reflecting MWIR light and of serving as an electrical pulse resistance element for indiscriminantly heating the sample collection zone to release substantially all collected analyte without regard to MWIR absorption properties.

The stacked dielectric Bragg mirror(s) comprise alternating high and low refractive index materials in which the optical film thickness of each layer is λ/4 of a preselected MWIR central measurement wavelength. The dielectric materials should be substantially transparent to the MWIR wavelengths used in the system for preferentially heating MWIR-absorbing analytes. A sample pre-concentration zone 4014, shown along its open axis of gas travel, is formed in the zone between the mirrors 4008, 4012. An absorptive coating 4016 is provided on the interior wall surface(s) of the zone 4014 for absorbing analytes. The sorbent coating is also substantially transparent to MWIR radiation in the wavelength range employed by the MWIR irradiation system. Suitable organic coating materials are described herein in respect to GC column and injectors. Piezoelectric or other separation control elements 4010 are provided to facilitate electrostatic adjustment of the distance between the mirrors 4008, 4012 to tune the MWIR wavelength spectrum reflected in the zone 4014 therebetween. The components 4010 may also comprise or house electrical resistance means for heating the analyte-absorptive substrate in the zone 4014 to cause release of absorbed analyte. Alternatively to the Fabry-Perot MWIR system, a quantum cascade laser such as the small Mini-QCL™ EC-QCL²¹² can be used to irradiate the pre-concentration zone. Desirably, the MWIR source applies MWIR radiation into the analyte concentration zone at a rate of at least 0.01 watt per square centimeter, and the sorbent 4016 absorbs less than 10% of such radiation (MWIR absorbed in the walls of the enclosure 4014 is less important than that absorbed in the sorbent itself which contains the adsorbed analyte). Similarly, a tuned hollow waveguide system²¹³ may be applied to irradiate the pre-concentration zone 4014 to selectively release analytes which absorb MWIR in the irradiated wavelength range from the sorbent of the pre-concentration zone 4014.

The pre-concentrator 4002 may be integrated with appropriate GC columns, valves, gas pumps and detector(s). In operation, a sample gas flow may be pumped through the concentrator and selective injector 4002. The gas stream may be discharged to the atmosphere by valve control (FIG. 37) or conducted through the chromatographic column. Organic components of the sample gas stream are absorbed by the sorbent film 4016. After a predetermined period of time, a flash of MWIR light of preselected wavelength range is directed from the light source into the concentration zone 4014 for a short period of time of less than about 5 seconds to selectively heat analyte(s) which absorb in this predetermined MWIR range. Shorter MWIR energy flash times tend to provide shorter injection times in to the gas chromatographic column, with correspondingly sharper elution peaks. The partial separation of preconcentrated analyte components which are not directly heated by the preselected MWIR wavelength flash, reduces interference from other components which might elute at similar times, and effectively increases the resolution of the column. For example, flashing infrared energy at wavenumbers 3200-3400 cm⁻¹ preferentially vaporizes alcohols and phenols, 3400-3500 cm⁻¹ preferentially vaporizes primary amines, or about 1540 preferentially vaporizes TNT. Similarly, MWIR energy at specific wavelength ranges within the 4-9 micron range can be employed to preferentially vaporize toxic compounds such as mustard gas, sulfur mustard, 4-dithiane, formaldehyde, hydrogen cyanide, hydrogen sulfide, phosgene and explosive PETN²¹⁴ and inject them into a chromatographic separation column with reduced interference from other components. Preferably the MWIR wavelength range or width of applied flashes will be less than 50 nm, and more preferably less than 20 nm. Broad MWIR flashes separate broad ranges of analytes. Narrow wavelength MWIR flashes can facilitate detection of specific compounds. A series of different MWIR flashes at different wavelengths, separated by time intervals adequate to permit chromatic separation of previous injection, may be applied to the concentration zone, to preferentially inject the respectively-absorbing analytes into the column which absorb at the respective flashed wavelengths. Together with the characteristic column elution time of the detected components, this IR absorption spectrum processing provides additional distinguishing information for analysis and detection. The analyte content of the concentration zone may also be “cleaned” or indiscriminantly injected into the GC column by a heating pulse in accordance with conventional practice. However, depletion of MWIR absorbing analytes from the heat-pulsed injection also provides analytical information not available to conventional pre-concentration systems. A microprocessor-based controller may be used to control the interval and the duration of the MWIR flashes and electrical pulses to a resistance heater for the concentration zone.

Portable miniature, MEMS, and more fully integrated GC systems conventionally integrate gas chromatography (GC) column, preconcentrator, and chemical sensor arrays in compact systems, which can conventionally employ integrated thermal control and use of air as the carrier gas²¹⁵. Gas chromatographs such as schematically illustrated in FIG. 37 typically comprise a sample injector, a carrier gas supply, one or more GC columns coated with stationary phase analyte affinity phase(s), a detector system, and associated control and data processing system. In a typical GC analysis, a sample is injected into and transported along the column by carrier gas flow²¹⁶. Different affinities of the components of the sample with the stationary phase cause different retention times for different analytes, which are accordingly separated along the length of the column for sequential detection by the detector system and at least partial identification by their respective elution times.

FIG. 39 is an illustration of an integrated, addressable multi-LED or laser interrogation light source array in alignment with differently sensitive sensing cells each diffracting onto an integrated megapixel camera chip, in a compact sensor system like that of FIG. 29. Each different sensing cell type of the illustrated embodiment has a plurality (here 16) individual plasmonic sensing elements which can be illuminated by an addressable interrogation light source. The diffracted light from each sensing element is directed to an underlying megapixel imager. The spacing of the addressing lights permits the diffracted reporting light to be detected on the imager pixels without crosstalk. When an analyte stream is directed across the multiple sensor areas, a sequential addressing of the interrogation light array produces a plurality (here 16) of readings to reduce error.

There are a number of processes to fabricate a wide variety of differently selective sensing zones immediately adjacent the plasmonic metal surfaces of respective multiple detector cells herein. One fabrication method comprises the steps of attaching selective molecular guidance means onto metallic electrically conductive surface zones of the respective detector zones, such as by bioanalytic chip manufacture techniques described hereinabove. The selective guidance means are adapted for selectively attaching with specific respective target surfaces of selective detector materials²¹⁷. The selective detector materials, which may be selected from but not limited to the wide variety thereof described herein, are then applied to the electrically conductive plasmon detector zones for self-assembled with their respectively corresponding attachment guide means. For example, DNA origami and other selective self-assembly methods are useful for selectively guiding and attaching various nanomaterials such as analyte-selective dielectric, semiconductive or metallic nanoparticles, carbon nanotubes and graphene which are functionalized for selective response to different analytes²¹⁸, and the like, with high, even nanoscale resolution onto plasmonic or other detector-cells as described herein. Emulsions or liquid suspensions of micro- or nanoparticles of partially-cured selectively sensitive components which are attached to complimentary ssDNA are desirable materials which can coalesce for final MIP formation or other curing or affixation on the respective plasmon surfaces after attachment via complementary ssDNA with their respective mating ssDNA attached to the respective detection cell sites. DNA hybridization of a complementary pair of single-strand DNAs (ssDNAs) is an example of target-guiding assembly technologies. Specific detector cell components such as analyte-selective (eg, via MIP structure) nano- or micro-particles in liquid suspension may be provided with surface ssDNA molecules with selectively “sticky ends” structured for selective complementary attachment to respectively complementary ssDNA molecules attached to specific target detector cell surfaces. Many, preferably at least 10, and more preferably at least 50 different detector cell components may be separately prepared and blended in a liquid for application to a plasmon or other detection system such as those described herein having respectively selective complementary ssDNA at a pattern of specific target detector cells for the respective components of the mixture such as fabricated by bioanalytic chip manufacture such as described hereinabove. In this way, many differently-selective analyte detection components may be applied from a liquid mixture of many such different components, and preferentially selectively fixed at respectively specific positions of the detector system. The complementary ssDNA or other self-assembly components may also be applied serially to the tagged metallic surfaces of the plasmonic detector cells. Mesoporous nanosilica particles having cylindrical, helical, hollow or vesicle structures as desired are readily synthesized²¹⁹, which may include different analytes for MIP selectivity and/or fluorescent dyes for plasmonic light emitting systems such as described herein. Such particles may be prepared with specific surface-functionalized selective-target ssDNA strands which are complementary to respectively corresponding ssDNA strands attached to specific detection reporting sites of a detector system. Microspot applicators²²⁰ may also be used in manufacture to apply different dielectric materials in different plasmonic sensing zones adjacent an imager.

The specific selective detection materials selected for the detector sites may be selected for the application for which the sensor system is intended. For example, for sensor applications directed to detection of certain dangerous target analytes, hyperbranched carbosilane polymers with functional hexafluoroisopropanol groups may be used in dielectric compositions in one or more of the detector sites. Such polymers have high affinity to reversibly bind hydrogen bond basic (HBB) analytes such as phosphonate ester nerve agents (eg, DMIP, GB, VX) and explosives such as TNT²²¹. They may desirably be included in the dielectric layer of the plasmonic detector sites, and may if desired be formed in MIP structures for further selectivity tuning, and/or crosslinked with a solvatochromic dye in a crosslinked MIP matrix. Such carbosilane polymers, without dye components, may also be useful as pre-concentrator absorption materials in preconcentration cells as described herein. For sensor systems for broader ranges of applications, a wide range of differently sensitive dielectric materials may be applied to different sites of the detector array 3800.

Nanoparticle MIPs, dyes, emulsions and solvatochromophores may be self-assembled at plasmon metal detector structure surfaces²²², in appropriate concentration, where they are most influential in inducing plasmon resonance change as a result of their dielectric (and refractive index) changes in response to contact with analytes to which they are sensitive. Such self-assembly for fluorescent and/or solvatochromic dyes preferably includes composite formation with a matrix material which provides a predetermined solvatochromic environment for the dye, and/or which selectively adsorbs specific analytes or classes of analytes. Especially useful dye systems are solvatochromic dyes which are formed in a molecularly imprinted structure. Preferred plasmonic selective sensor services are solvatochromic molecularly imprinted polymer layers or structures which preferentially absorb specific target analytes. Plasmonic sensing cells having solvatochromic molecularly imprinted dielectric sensing components²²³ as thin layers immediately adjacent their metallic plasmon layers are particularly useful for distinguishing a wide variety of analytes. The molecular imprinting of the dielectric layer is selective for the target molecules (and related molecules) by size and affinity. The absorption spectrum, luminescent properties (if the dye is luminescent) and dielectric constant (and refractive index) of the solvatochromic component of plasmonic dielectric layer may be altered by contact with the target analyte. The solvatochromic component is highly sensitive to the polarity of its immediate environment. When a target analyte is able to enter into the reporter site within the molecularly imprinted polymer, it will change the solvatochromic environment to produce a change in the dielectric constant and absorption spectrum of the solvatochromic component. Depending on the type of analyte sought to be detected, for example a polar analyte or a nonpolar target analyte, the solvatochromic dye(s) and crosslinking polymer may desirably be selected to emphasize or maximize the polarity change caused by the presence of the target analyte in the receptor sites of the solvatochromic MIP dielectric layer adjacent the metallic conductor of the plasmonic detector site(s). For example, an MIP for a highly polar target analyte may desirably be formed from a solvatochromic monomer and a nonpolar crosslinking agent such as divinyl benzene, while an MIP for a non-polar monomer may be formed from a solvatochromic monomer and a polar crosslinking agent such as N,N-methylenebisacrylamide, N,N-(1,2-dihydroxyethylene)bisacrylamide and/or ethylene glycol diacrylate (less polar). Of course, other MIP-forming suitable monomers/oligomers, and multifunctional solvatochromic components may also be used. A wide variety of solvatochromic dyes may be provided with polymerization functionality such as vinyl or allyl groups (for free radical or hydrosilyl polymerization), oxirane groups (for epoxy-type polymerizations), silicon halide or ester groups (for crosslinking with silica MIP formers such as tetraethoxysilane), etc. The solvatochromic functional monomer, a target analyte, a crosslinking agent such as trimethylolpropane trimethacrylate are mixed in a suitable solvent. A crosslinking agent such as azobisnitrile is added, and the solution is quickly applied to the plasmonic detector surface. The solvent is removed, and heat and/or UV is applied to crosslink the thin film. The target compound is then removed from the thin dielectric layer, typically by solvent and subsequent vacuum treatment. The dielectric layer exposed to the sensing atmosphere, is desirably in the range of from about 20 to about 1000 nanometers, and more preferably from about 50 to about 400 nanometers thick. The greatest effect of dielectric change upon plasmonic sensing in the detector sites is immediately adjacent the metal surface of the plasmonic metal-dielectric interface. Thin layers facilitate analyte absorption and desorption at this interface, improving detection sensitivity and speed.

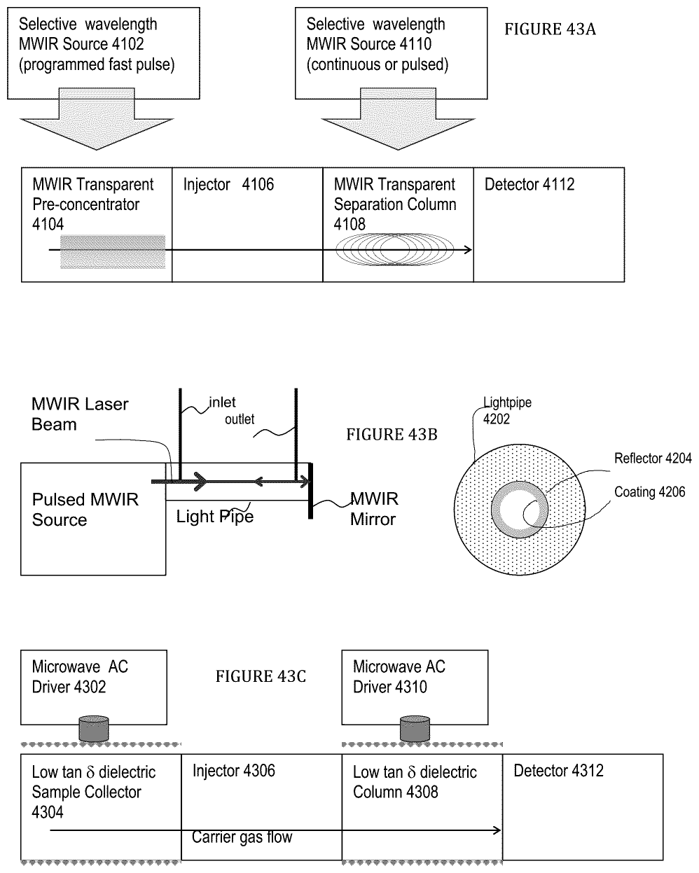

Plasmonic sensors are energy efficient and sensitive for use in compact portable GC and other detector devices. However, for some applications, it is also desirable to analyze GC eluants by mass spectrography for increased analyte identification capability. Miniaturization of gas chromatography systems and GC-mass spectrography (GC-MS) systems has progressed significantly²²⁴ in recent years. However, a major ongoing problem is the difficulty of producing miniaturized vacuum pumps for MEMS and integrated miniaturized GC-MS devices, despite efforts ranging from miniturbines to thermal pumps, to freezing liquid vapor components in the MS enclosure²²⁵. In this regard, a MEMS miniature vacuum pump 4102 is illustrated in FIG. 43A which utilizes 2-way shape memory alloy film²²⁶ and microfabricated valves to achieve “on-chip” vacuum levels suitable for mass spectroscopic operation and other pumping operations. The pump is shown schematically, and one of the memory alloy expansion structures is shown in schematic cross section in collapsed and in reversible expanded condition. The memory alloy films or layers of the illustrated expansion structure may be radially symmetrical, square-bellows shaped, or axially symmetrical. The illustrated pump comprises an inlet 4104, a valve 4106, a first gas-impervious 2-way shape memory alloy expansion structure 4108, an exit conduit and valve assembly 4110, and a second 2-way gas-impervious memory alloy expansion structure 4112. The expansion structure 4112 similarly has an exit conduit and exit valve assembly 4114. In operation, the first expansion structure is initially closed collapsed state having a minimal small volume, as is the second expansion structure. The inlet 4104 connects to a volume zone such as a miniaturized mass spectrograph (not shown) which is desired to be evacuated. The valve 4106 is opened to the first expansion structure, while the connecting valve 4110 is closed to prevent flow between the first and second expansion structures. The exit valve 4114 is also closed. The first expansion structure is then expanded by shape memory alloy thermal control to at least 3, and preferably at least 10 times its unexpanded volume, drawing gas from the mass spectrograph zone into its expanded volume, the valve 4106 is then closed to prevent gas flow therethrough, and the valve connecting the first and second expansion structures is opened. The second expansion structure is then expanded by shape memory alloy thermal control, while the first expansion structure is collapsed under thermal memory alloy memory shape control, transferring gas from the first expansion structure to the second expansion structure. The second expansion structure similarly expands its volume to at least 3, and more preferably at least 10 times its volume in its collapsed state. The connecting valve 4110 is then closed to prevent gas flow between the first and second expanding structures, and the exit valve is opened. Gas is then expelled through the exit valve 4110 from the second expansion structure by collapsing the structure under thermal memory control. The cycle may then be repeated. For efficiency of operation, the first expansion structure may pump gas through an open inlet valve 4106 from the mass spectrograph vacuum zone while the second expansion zone is expelling gas through the exit valve 4110. Additional expansion structures may be connected in series. Heating and cooling may be accomplished in a variety of ways, including resistance heating, thermoelectric heating and cooling, and ordinary convection/radiation. Such vacuum pumps may be fabricated and integrated in miniaturized MS and GC-MS systems to significantly improve analytical capabilities.

The detector (such as 4112 of FIG. 43A) may comprise any suitable GC detector, such as flame ionization detector (FID), thermal conductivity detector (TCD), electron capture detector (ECD), nitrogen phosphorous detectors (NPD), plasmonic detector (PD) infrared detectors (IR) and photoacoustic detectors (PAD). However, new, small, low-power detectors with analyte selectivity are needed for small portable systems. An example of a compact detector system is illustrated in FIG. 26 B, which can be integrated with a GC discharge stream.

FIG. 26 B schematically illustrates a top view and an adjacent side view (through dotted line indicating GC discharge flow direction) of multi-sensor plasmon interferometer-based detector array 2652. The differential detector array comprises a subwavelength slit-groove pair 2654, 2656 in a gold plasmon layer 2658 with a small angle between them²²⁷, so that the distance between the slit and the groove varies along the slits 2654. The slit-groove pairs may be made by focused Ga ion etching of 150 nm thick gold film deposited on a quartz substrate 2600. The length of the slit and groove are approximately 50 microns. The width of the slits 2654 through the gold film 2658 is approximately 100 nm, and the grooves 2654 are approximately 100 nm deep and 200 nm wide. The groove-slit structures are spaced far enough apart (e.g., 2 mm) that they do not interfere with each other. The interference pattern is transmitted through the respective slits directly onto an integrated circuit imager camera, through the VIS-transparent substrate 2660. The substrate has reverse side etched grooves which prevent optical crosstalk between the interference patterns emitted from the backside slit openings. Preferably the imager pixels will be smaller than about 2 microns, to facilitate resolution of the interference patterns. Thicker substrates will expand the interference patterns. Substrate thicknesses, which determine the distance between the backside slit emission openings and the imager pixels, in the range of from about 1 millimeter to about 10 millimeters are preferred.

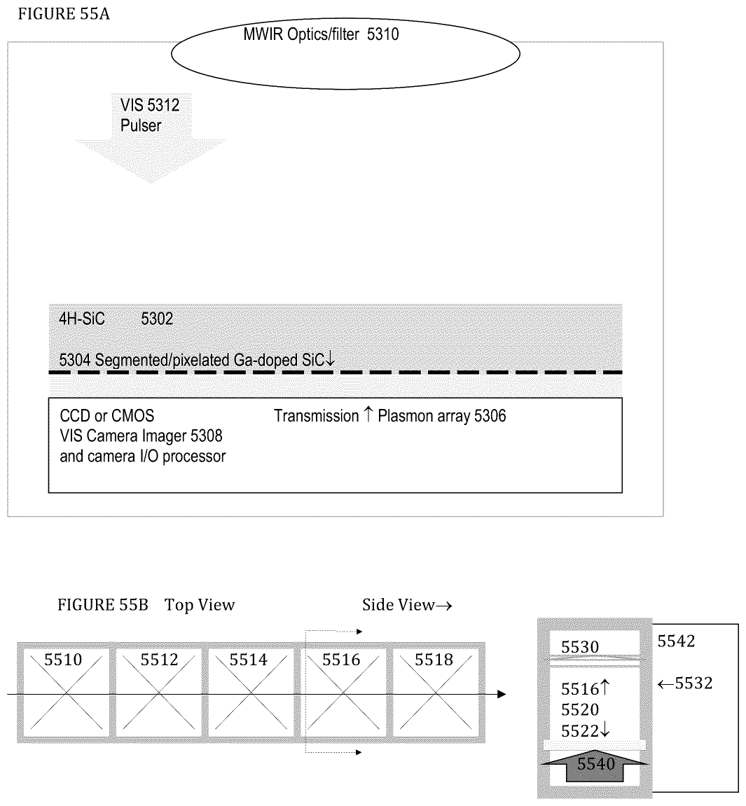

The respective groove-slit interference elements are each coated with a differently absorbing layer 2672, 2674, 2676, 2678, such as described herein. The absorption layers extend above the gold surface and may penetrate into the groove and slit. The layers may be applied by any suitable method, such as in solution with subsequent removal of solvent, by direct evaporation of the layer material onto the gold surface, by masked growth, or any other appropriate process. The layers may desirably be less than 300 nm in thickness, more preferably from about 75 to about 200 nm in thickness. Thinner layers respond more quickly to variation in analyte concentration in the surrounding environment, while the effective plasmon depth is effectively typically less than about 200 nm. Each of the slit-grove pairs has a differently-selective absorbant layer. In this regard, see also the embodiments of FIGS. 55-56.

In operation, the atmosphere to be analyzed, such as an open air environment, a pre-concentrator discharge, or a GC eluent discharge stream, is passed over the sensor array, eg, from left to right), preferably within an enclosing conduit. To detect analytes absorbed in the different layer materials at the respective slit-groove interferometers, the slit-grove pairs are illuminated with collimated diode laser light (eg, at λ 635 nm) with polarization perpendicular to the slit axes. The slit-groove interferometers produce interference patterns at far-field without intervening Fourier transform plane optics, directly on the imager camera chip 2680. Absorption of analyte into the differently-sensitive layers 2772, 2774, 2776, 2778, cause the refractive index of the slit-groove to change, producing a change in the interference pattern.

An important attribute of analytical GC is that specific compounds have a definitive elution time under specific GC operating conditions (column type, temperature, carrier flow, etc.). But miniaturized GC systems²²⁸ can have resolution limitations with elution overlap of different analytes, which can permit ambiguity and hamper precise, specific analyte identification. For example, compounds 4002, 4004 which elute closely or overlap because of lack of GC resolution, can mask the singular elution of a sought-after target compound 4006, as illustrated in

The present disclosure is directed to methods and apparatus for adjusting or modifying GC retention and elution characteristics, so that target compounds (eg, such as 4006) can be separated from masking compounds (such as 4002, 4004), and compound identification can be made more precise with separation of interferents and/or generation of multi-dimensional elution data.

Diagnostic MWIR²²⁹ wavelengths are absorbed by specific compound functional groups, to excite their molecular vibrational energy²³⁰. Methods are described herein for selective MWIR irradiation of the sample collector/injector, the GC separation column, or both, to selectively increase volatility and/or photodesorption²³¹ of the compounds which absorb the applied MWIR EM radiation. By selectively applying infrared radiation at one or more specific absorption bands of organic compounds undergoing gas chromatographic separation, their vibrational molecular energy is increased, and their elution time is decreased. use of MWIR quantum cascade lasers (QCLs) are conventionally employed to selectively vaporize remote trace explosives and drugs²³², and are effective in selectively modifying the partition coefficient of the MWIR absorbing analytes between the GC carrier gas and the GC stationary phase as described herein.

For example, as illustrated in FIG. 43A, by applying an infrared light pulse at the ˜6.25 μm N—O stretch wavelength(s) to a GC pre-concentrator and/or GC column, trinitrotoluene²³³ in the sample is selectively excited to increased volatility and desorption, which decreases its elution time. Energetic molecules of potential interest such as trinitrotoluene become effectively “hotter”, more volatile, and more partitioned into the carrier gas phase from the solid pre-concentrator or stationary phase of the GC column. Conventional spiral-etched micro-column designs may have a too-small bend radius for longer wavelength MWIR. So for etched micro-columns, simple 90° reflective corners may be used in a rectangular etched micro-column designs for end-fired MWIR etched column irradiation.

To optimize selective activation of target compounds, the GC column and pre-concentrator should preferably be made from materials which are relatively MWIR-transparent in the MWIR irradiation range²³⁴. Sample compounds with IR absorbing functional groups become selective energy sources within the GC column or pre-concentrator. Other sample components, the GC column coating, and the pre-concentrator absorbent, behave as relatively cooler heat sinks at the bulk GC operation temperature.

There is a wide variety of suitable MWIR sources, ranging from tunable LEDs and tunable lasers, to inexpensive “micro-hotspots” with fixed or variable dielectric filters²³⁵. Many materials with broad MWIR transparency windows are available for column coatings. MWIR lightpipes can be used as columns and pre-concentrator/injectors, particularly at longer MWIR wavelengths²³⁶: Conventional portable and miniaturized environmental GC and GC-MS systems use pre-concentrators²³⁷ to collect very low-concentration analytes over a period of time. The collected, concentrated analytes are typically rapidly and indiscriminately discharged as a bolus by a heat pulse from the pre-concentrator to a gas chromatographic column²³⁸.

By pulsing a MWIR laser through a pre-concentrator at a wavelength selected for target compound absorption, the target compound can be preferentially discharged from the pre-concentrator to the GC column, or an intermediate injector. The remaining sample components depleted in the target compound can be subsequently discharged for disposal, or injected into the GC column similar chromatographic separation. Comparison and crosscorrelation of these differently selectively vaporized sample runs, such as by Principal Component Analysis provides important multidimensional compound identification data for analyte discrimination and identification.

Dielectric heating may also be applied to a pre-concentrator and/or GC column to selectively energize polar compounds of GC samples being analyzed. Polar organic compounds are excited (physically rotated) and energized at microwave frequencies, and subsequently dissipate their acquired rotational, vibrational and translational energy as heat. Nonpolar compounds are not substantially affected in a microwave or AC dielectric field, and have little or no loss tangent, tan δ. By applying dielectric/capacitive or microwave field to a GC column or pre-concentrator/injector which does not absorb microwave energy, polar sample compound molecules are preferentially excited to increased volatility. Some excitation selectivity is available with variation of tan δ of different compounds as a function of dielectric driving frequency. As illustrated in FIG. 43C, a microwave AC driver 4302 may be coupled to a low tan δ dielectric sample collector 4304. Upon pulsed microwave energy applied to the sample collector (eg, pre-concentrator), polar compounds in the sample collector are energized and selectively vaporized for injection into the low tan δ dielectric GC column 4308, via injector 4306. Microwave AC driver 4310 coupled to the GC column 4308 selectively excites polar compounds undergoing chromographic separation in the column 4308, for accelerated elution to detector 4312.

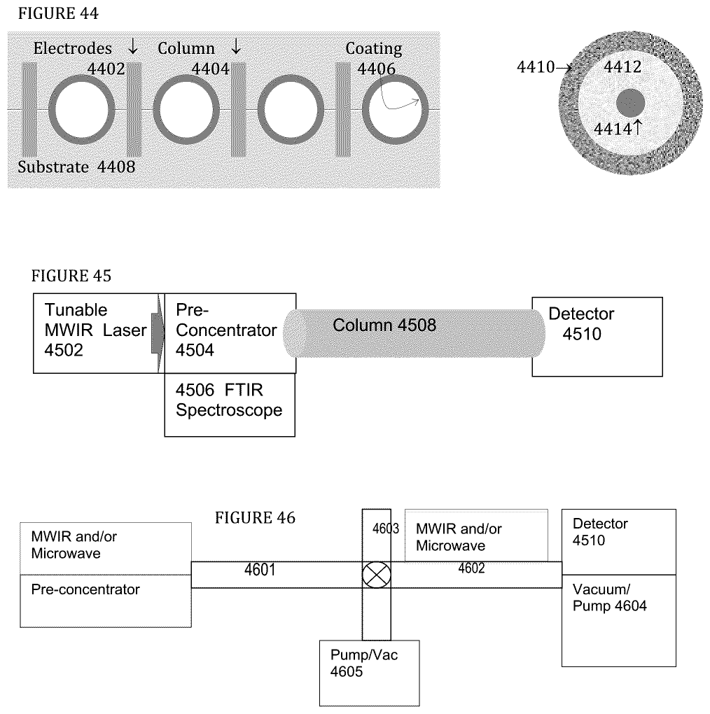

Dielectric generators can be relatively inexpensive²³⁹, which is useful for high-volume sensor applications. An example of column and/or pre-concentrator fabrication from etched substrate halves is relatively simple, as illustrated in FIG. 44.

Suitable substrate 4408 halves (eg, silicon, alumina, silica, etc) are etched to form a column in accordance with conventional procedures, electrodes 4402 are applied, a low dielectric loss GC stationary phase coating 4406 is applied, and the halves combined to form a miniature GC column. Similarly, to form an analyte-selective microwave dielectric-heated pre-concentrator, a cylindrical microwave conductor may be formed by a central electrode 4414, a surrounding porous low-tan delta polymeric analyte absorber 4412, and an external electrode 4410 which may be a porous metal and/or open-ended cylinder to permit atmospheric exposure. This approach permits relatively inexpensive programmable addition of another separation dimension (polarizability, tan δ) to a simple GC single-column system. It can also be used in combination with selective MWIR irradiation, to add additional selectivity dimension to a GC column.

Detectors are an important component of a GC analytical system. GC systems may comprise mass spectrometers for ionized fragment molecular weight measurement of GC eluted analytes. Depending on accuracy required, low energy GC-MS systems may range from lower-pressure atmospheric²⁴⁰, to a vacuum gas chromatograph which feeds into a mini-mass-spectrograph. Pulling a vacuum through a GC column can leave near-atmospheric pressure at or near its entrance adjacent a pre-concentrator (with or without a restriction). GC column temperature (and heating energy) are reduced under vacuum operation, which can reduce energy use. A pre-concentrator can collect passively in the open atmosphere²⁴¹, to reduce overall energy requirements. Sample components can then be selectively discharged from the pre-concentrator into the GC column input by selective MWIR laser or microwave pulse to vaporize target compounds, while minimizing interferents. A pre-concentrator design such as an MWIR lightpipe with porous internal, MWIR-transparent absorbant polymer is compact and efficient. The pre-concentrator can be then be flushed of interferent compounds into the open air if desired by conventional indiscriminant heat pulse, or they can be analyzed. Many target compounds are polar chemicals, so such an open-air pre-concentrator can be pulsed with sufficiently intense microwave energy to selectively vaporize them, leaving the pre-concentrator enriched in non-polar compounds. A coaxial microwave cable design, with a porous outer electrode and a porous sample absorbant as the cable dielectric, can serve as a pre-concentrator, as illustrated in FIG. 44.

Multiple pre-concentrators can be used seriatim for a single GC column to carry out GC analyses of the “same” samples under different elution conditions. Pre-concentrators can be pulsed with MWIR laser wavelength(s) for target compound(s). The enriched target vapor can be injected and processed, followed by the remaining pre-concentrator compounds being pulsed with MWIR of another wavelength, or a conventional thermal heater. An injector can collect MWIR-vaporized compounds from a pre-concentrator at a cooled temperature, then pulse them into the column to sharpen elution peaks. Forward and reverse carrier gas flow control with column discharge ports can be used to discharge unwanted compounds to make “elution room” for differently-selective MWIR and/or dielectric AC processing. Forward column flow separations of one selectivity type can be used with reverse flow separation of the sample components in the same column under different MWIR and/or microwave selective activation.

There is a need for energy-efficient and compact GC-based analytical systems²⁴², including ways to thermally program field GCs, such as for special locations or test runs, or for controlling peak-broadening elution at the higher end of an eluent molecular weight range. If the stationary phase has some (designed) MWIR or tan δ microwave absorption, a programmed GC temperature can be precisely controlled with minimum energy use, without directly heating all of the column or etched substrate mass, or pre-concentrator housing to full temperature. For example, if a stationary phase has some relatively clear MWIR transmission windows, but a wavelength range with some absorption peaks, those peaks can be used to heat the stationary phase in programmed operation steps. If the stationary phase has some known absorbance, compounds which absorb in that MWIR range will still also selectively be energized. Similarly, dielectric/microwave heating can be efficiently applied to a GC stationary phase which has some tan δ absorption, to very efficiently program the stationary phase temperature, with minimal excess heat loss (eg, an etched substrate will have a thermal profile, similar to an insulator).

Both MWIR and tan δ applications can effectively change, under program control, selective sample injection, and/or column retention characteristics. They can provide effective, programmable GC×GC with many more than 2 effectively different GC columns.

A fixed MWIR wavelength laser or filtered LED is typically less expensive than a tunable MWIR laser, for a device limited to sensing specific analytes (eg, specific nerve agents, drugs, explosives.) For a “universal” GC analyte detection and identification, a tunable MWIR laser source may be used, subject to flexibly programmed control.

Some examples of operation with reference to FIG. 45 are described below. In one example of an analyte detection program, the process may be designed to detect specific chemicals in a particular analysis run. The system dada library dials one or more of the MWIR wavelengths (or microwave frequencies) absorbed by those chemicals, and applies it to define the Pre-concentrator discharge and/or the GC column irradiation wavelength(s). A second run may be carried out by indiscriminately discharging any remaining compounds from the Pre-concentrator by heat pulse.

In another process example, the program adapts to its samples. A mini FTIR spectroscope scans the “loaded” Pre-concentrator. The “blank”, unloaded Pre-concentrator MWIR spectrum is subtracted to obtain a collected sample spectrum. Specific MWIR wavelengths are selected by algorithm for selective pre-concentrator injection and/or GC use, from the stored compound property library, based on the measured spectrum and goals for this analysis. A second run may be carried out by indiscriminately discharging any remaining compounds from the Pre-concentrator by heat pulse. The first run data, together with the second run data, provide significant information for component calculation and identification.

In another more generic processes, multiple GC runs may be carried out to progressively scan a range of MWIR wavelengths, sequentially applied to the same sample collected in the pre-concentrator:

### GC Run #1

Apply MWIR wavelength λ #1 by flash pulse to Pre-concentrator for selective injection, (optional λ #1 flash pulses to GC column). Record component elution times and peak amounts. This leaves compounds enriched in the Pre-concentrator which do not absorb MWIR λ #1.

GC Run #2 (after Finishing GC Run #1)

Apply wavelength λ #2 by flash pulse to Pre-concentrator for selective injection (optional λ #2 flash pulses to GC column) Record component elution times and peak amounts. This leaves compounds which do not absorb λ#1 or λ#2 still enriched in Pre-concentrator)

GC Run #n (after Finishing GC Run #n)

Apply MWIR wavelength λ #n by flash pulse to Pre-concentrator for selective injection, (optional λ #n flash pulses to GC column) Record component elution times and peak amounts. This leaves compounds which do not absorb at MWIR wavelengths λ#1, λ#2 . . . λ#n, still enriched in Pre-concentrator)

GC Run #n+1 (after Finishing GC Run #n+1)

Apply a conventional indiscriminant thermal heat pulse to vaporize all remaining analytes collected in the Pre-concentrator. Record component elution times and peak amounts.

The elution results from all runs on a sample in this example be correlated and processed utilizing library chemical compound standard elution time data, and methods such as Bayesian, Principal Component Analysis (PCA), canonical discriminate analysis (CDA), featured within (FW), cluster analysis (CA), artificial neural network (ANN) and/or radial basis function (RBF) analyses to identify and quantify the eluents. Each elution time (eg, second, whether blank or part of a peak) of each run under each different MWIR and/or tan δ condition may be processed as a different (at least partially orthogonal) data dimension. Blank elution times eliminate all known compounds in the system property library which elute at those times. Multiple, differently-responding detectors such as differently-selective plasmonic sensors and differently-selective acoustic sensors such as described herein an provide additionally-distinguishing data for analyte identification. Classification analysis with many dimensions, even without Mass Spectrometer data, provides capability to identify very large numbers of chemicals²⁴³. Even when not fully resolved by GC, overlapping and distorted peaks are readily decomposed mathematically and can be distinguished by multiple differently-sensitive detectors in accordance with conventional data processing such as Principal Component Analysis and similar characteristic or eigenvector processing.

Different “runs” of selectively-enriched analyte compositions will produce quantitative GC peak results, even if the peaks are not resolved. Co-eluting and distorted peaks with different chemicals under different column conditions can be separated mathematically, with elution times of “knowns” under each of the different GC run conditions. However, it is also useful to take a “Dean Switch Heart Cut” of unresolved peaks, and remove other analytes so a target chemical can be shifted to a “clean” elution time by selective analyte energization in accordance with the present disclosure. “Bleeding off” capability, which is ideal for clearing out a “clean” elution time when a sought-after target compound is made more volatile by energizing with MWIR or rotational tan δ.

Selective vibrational and/or rotational molecular excitation may create a slightly more volatile species of the absorbing compound, and may effectively heat other compounds while creating a range of “species” of the same chemical having a range of effective volatilities for GC separation. GC elution of the MWIR-absorbing chemicals may be effectively broadened or “smeared” over a wider elution time range. The energy relaxation to surrounding molecules is relatively fast. The thermodynamic drive toward equilibrium provides the molecules of each chemical with an Arrhenius statistical thermal/temperature distribution. Preferably in some embodiments, the incident MWIR radiation provided in the process is intense enough that most of the absorbing molecules are excited, so they will be excited together, relax together, and elute together. If the MWIR radiation is so weak that molecules are not mostly all excited at the same time, the elution may “smear” because the Arrhenius distribution at specific times will be broader. Processes in which short-pulse high-intensity MWIR radiation is applied to the GC column so that absorbing molecules are repeatedly excited together, and relax to ambient state together, are preferred. Fortunately, it is cheaper and easier to make and use pulsed MWIR lasers at higher power, than continuous MWIR lasers. An important practical “corollary” is that fast, tunable MWIR pulses of different wavelengths can be applied to selectively volatilize chemicals of very specific interest. Such chemicals generally have different functional groups with different MWIR absorption wavelengths. That is what gives them the properties of interest. By quickly applying tuned wavelength #1, #2, #n pulses at different absorption peaks of the same specific types of compounds, in fast sequences (for example, less that about 1 millisecond separation between pulses), very specific compounds can be even more selectively promoted to fast elution²⁴⁴ for fast, energy-saving, narrow, more easily detectable peaks. For example, by sequentially pulsing MWIR at wavelengths of 6.25, 7.41, 11.0 and 12.62 micron wavelength of different absorption functional groups, into the pre-concentrator within 500 microseconds, TNT, DNT and RDX can be more specifically selectively enriched in a pre-concentrator selective discharge bolus. By quickly applying such an MWIR sequence of different absorption peaks of a target compound to the analyte(s) in the GC column during GC separation, the target compound can more quickly and more specifically be eluted.

Selective dielectric tan δ rotational excitation differs from MWIR vibrational excitation, because the mechanism is not direct photon absorption dependent on the number of photons. The microwave/dielectric field is typically relatively uniformly oscillating, applying rotational force to each polar molecule, so continuous energy application has less potential for “smearing”. However, microwave energy can also be pulsed to result in uniformly simultaneous excitation and relaxation of the polar molecules, if appropriate or beneficial.

Those compounds which are absorbing will dissipate thermal energy, but are not in static thermal equilibrium with non-absorbing compounds or stationary coatings while absorbing. So they are more volatile in a multi-theoretical-plate separation column, even if the dissipation process is very fast.

For selective pre-concentrator discharge, both MWIR and microwave systems should best be fast-pulsed for selective injection.

A light-pipe flow cell is a preferred design for a MWIR irradiation zone. Etched minicolumns can also be fabricated as light pipes, and with reflective corners. A glass, quartz, silicon, germanium or other capillary or etched substrate is internally reflection-coated (with gold, silver or dielectric reflector) on the inside to form a lightpipe. A GC stationary phase with low electromagnetic absorption is then applied over the MWIR reflective internal surface. The selectively-heating MWIR infrared radiation is directed axially through the hollow light-pipe, to selectively heat those analyte components within the hollow light pipe which absorb at the wavelength(s) directed into the lightpipe by the MWIR source. The lightpipe column or pre-concentrator can be an integral part of a tunable external cavity quantum cascade laser (“EC-QCL”) by efficient coupling along the internal axis of the lightpipe²⁴⁵. A lightpipe does not require that the column material be transparent, because the MWIR is confined to the inside of the capillary/etched substrate. A commercial hollow lightpipe fiber, such as type HWEA from Polymicro Inc. may be used as a GC column, or pre-concentrator housing. Or an etched mini-GC could be internally gold-plated and then coated with a stationary phase in the conventional manner.

Many volatile compounds can have selective rotational spectroscopy absorption which creates a new separation dimension. Like MWIR, a broadband microwave pulse will partially separate polar compounds from non- or less-polar compounds. Although useful as an inexpensive alternative to MWIR vibrational excitation, molecular rotational excitation can also be precisely selective. Microwave, rotational and dielectric spectroscopy are relatively new analytical methods which utilize the different specific rotational energy resonances of different chemicals. So tan δ energization could also be highly selective for specific molecules or molecular functional groups. Rotational/dielectric spectroscopy is a relatively new analytical technique, made practical/possible by modern high-frequency electronics. Dielectric/rotational spectroscopy is strongly sensitive to intermolecular interactions²⁴⁶, which can include analyte/stationary phase interaction which is key to GC separations. Because of its unparalleled structural specificity, rotational spectroscopy is a powerful technique to unambiguously identify and characterize volatile, polar molecules²⁴⁷. With precision microwave generation, selective rotational excitation of specific chemicals is applied herein to selectively modify their elution times. Dielectric/rotational spectroscopic energy can be confined and applied to GC separation columns, injectors, pre-concentrators, and very small selected zones, so is able to avoid adverse effects to incompatible materials. Microwave energy can be applied to specific chemicals, and to specific pre-concentrator and GC column locations, in accordance with conventional practice in dielectric spectroscopy. The MWIR or tan δ energy may be fast-pulsed on/in the pre-concentrator, with standard GC injection schemes. The pre-concentrator absorbent material would best be a porous/high surface area material with relatively good transparency to the MWIR or microwave applied. MWIR could be applied axially to just the absorbent, or through the pre-concentrator casing. A wide variety of absorbent materials are available with limited MWIR or microwave absorbance. A wide range of pulsed energy sources may, but laser or tuned laser is best for MWIR, and pulsed microwave is very inexpensive, energy-efficient and reliable.

It is noted that column and stationary phase designs need not be both MWIR and microwave transparent. There are materials which are both IR and microwave transparent, but this does not block benefits of either approach. Dielectric heating of the stationary phase is an energy-efficient process, if it is desired to operate GC column separation at non-ambient temperature. Selective vibrational MWIR excitation, and rotational tan δ selective excitation are separate approaches which may be used together to maximize different separation dimensions for more certain compound identification. They have different excitation mechanisms, so that different pre-concentrator and GC column stationary phases can be used, providing more apparatus and process design capability.

MWIR and tan δ absorption are tools, like GC×GC or switching columns in conventional GC processes. They can be used with forward-backward carrier flow, mid- or end-column flushing, cold and reverse-cold collection, forward and reverse flow for sharpening and for flushing interferents. The same basic system can be programmed/optimized for different uses. Microwave/dielectric loss with a slightly-lossy stationary phase or column material is a low energy way to heat a column.

There are a wide variety of MWIR materials and sources²⁴⁸, and they are rapidly improving²⁴⁹. MWIR lasers can be fast-pulsed or continuous²⁵⁰. A capillary or etched GC column itself can also be made a component of a fiber laser for even more SWaP-compact designs. Substrate and/or stationary phase materials for MWIR irradiation zones and/or separation columns (eg, capillary) components may be selected for the MWIR irradiation bands intended for the GC system. Pure silica glass is effectively transparent to IR from about 200 nm up to 3.5 to 4 microns, but becomes more absorbing at longer infrared wavelengths via —Si—O— bonds.²⁵¹ For MWIR optical components employed herein, silica glass is usefully transmissive in NIR and shorter MWIR ranges, but may be effectively opaque in bulk thicknesses for wavelengths longer than 3.5-4.0 microns. High purity silicon has reasonable IR transmission in the 1.5 to 7 micron range²⁵², and some chalcogenides extend to even longer wavelengths. Germanium is a versatile infrared material commonly used in infrared imaging systems and instruments in the 2 to 12 microns spectral region. CVD diamond is transparent from the UV (230 nm) to the far infrared, with only minor absorption between 2.5 and 6 μm. Substrate and/or stationary phase materials for MWIR irradiation zone and/or separation column (eg, capillary) components may be selected for the MWIR irradiation bands intended for the GC system.

These materials can be used as pre-concentrator components, and as stationary phase coatings in MWIR irradiation zones for IR wavelengths where they are not too strongly absorbing. Polymer stationary phases can be tested²⁵³ and selected for windows of transparency in MWIR ranges corresponding to specific wavelength ranges for selective elution or gas-transport enhancement. Polysiloxanes are common GS stationary phases in GC columns. Fully deuterated polydimethylsiloxane polymer has substantially no absorption bands in the wavelength range from 1670 to 2100 nm²⁵⁴ so is a useful solid phase for use with selective IR elution enhancement of sample components which absorb in this range and its other transparent IR windows. Poly (tetrafluoroethylene) and related soluble copolymers have wide transparent windows from 2.5μ (4000 cm⁻¹) to about 8μ (˜1240 cm⁻¹) and from about 10μ (˜1000 cm⁻¹) to about 14μ (˜700 cm⁻¹); polypropylene similarly has transparent MWIR windows from 2.5μ (˜4000 cm⁻¹) to about 3.12μ (˜3200 cm⁻¹) and 3.57μ (˜2800 cm⁻¹) to about 5.5μ (˜1500 cm⁻¹) with a small absorption peak centered at about 5.7 (˜1750 cm⁻¹), as useful stationary phases for use in MWIR irradiation zones²⁵⁵.

GC×GC design with many different column type capabilities including miniature “Dean switch heart-cut system”

Forward carrier flow from Pre-concentrator/injector toward detector, via suction from Vacuum pump 4604. As target analyte group approaches valve ⊗ between GC column segments 4601 and 4602, close valve ⊗ to stop analyte progress in GC segment 4601. Open valve ⊗ to air or pump in air from pump 4605 to clear out GC section 4602 (the peaks may be detected and recorded) Turn on selective MWIR or microwave application to GC column section 4602. Close valve & to air, and restore carrier flow from GC section 4601 with the target analyte to separate and detect (heart cut) group.

Another example for stripping interferents from potential target compounds by column bleed off: A sample is injected into GC Column section 4601 and processed with selective MWIR. When the MWIR volatility-enhanced components (or the first components) almost reach the valve ⊗, it opens to the pump 4605, which forces carrier gas (air) into GC Column section 4601 to reverse its flow direction, and into GC Column 4602 to clear out any components. When the pump 4605 starts, the MWIR enhancement is stopped, so the MWIR absorbing analytes more slowly return toward the injection end of Column 4601 than in the forward direction. Before the target components (or any of the components) reach the injection point, the Valve ⊗ is returned to connect the Columns 4601 and 4602, the pump 4605 is turned off, MWIR enhancement is turned on for the entire Column 4601 and Column 4602 sections, and forward separation of components is resumed. The target compounds are the first to elute at the Detector, largely separated from other components.

Each different MWIR range or wavelength, and each different microwave frequency, are effectively a programmably-different GC column. Many other flow patterns are possible, from simple reversal of flow to back- and forth under different conditions, with thermoelectric retention of analytes at specific GC column positions to sharpen elution, etc.

Vacuum pumps are important components for many types of analytical GC systems. Miniaturization efforts²⁵⁶ for vacuum pumps (including microturbines²⁵⁷, microrotary and vibratory pumps, thermally-driven Knudsen devices, and vapor freezing²⁵⁸) have not reached inexpensive practicality for small MS devices. Professor R. R. A. Syms²⁵⁹, notes that “considerable development will be needed to achieve sufficient base pressure, pumping speed, and mechanical reliability”. General reviews of micropumps demonstrate the range of development effort²⁶⁰.

This disclosure is also directed to vacuum pumps which are useful for GC-MS and MS systems. Shape Memory Alloy and piezoelectric Vacuum pumps and methods. Mechanically simple, high-speed vacuum pumps can be based on high-strength Shape Metal Alloys (SMAs) and piezoelectric materials.

Shape Memory Alloys generate a very large recovery force of 100-700 MPa²⁶¹ upon thermal, electric or magnetic activation. This powerful SMA recovery force far exceeds atmospheric pressure of 0.1 MPa, by orders of magnitude. Sealed SMA structures of proper design can easily oppose and expand to an internal vacuum void, against atmospheric pressure. Forceful SMA vacuum pumps can fully expand from nominal “zero volume”, to make large vacuum zones in seconds, compared to hours for some micro-vacuum-pumps.

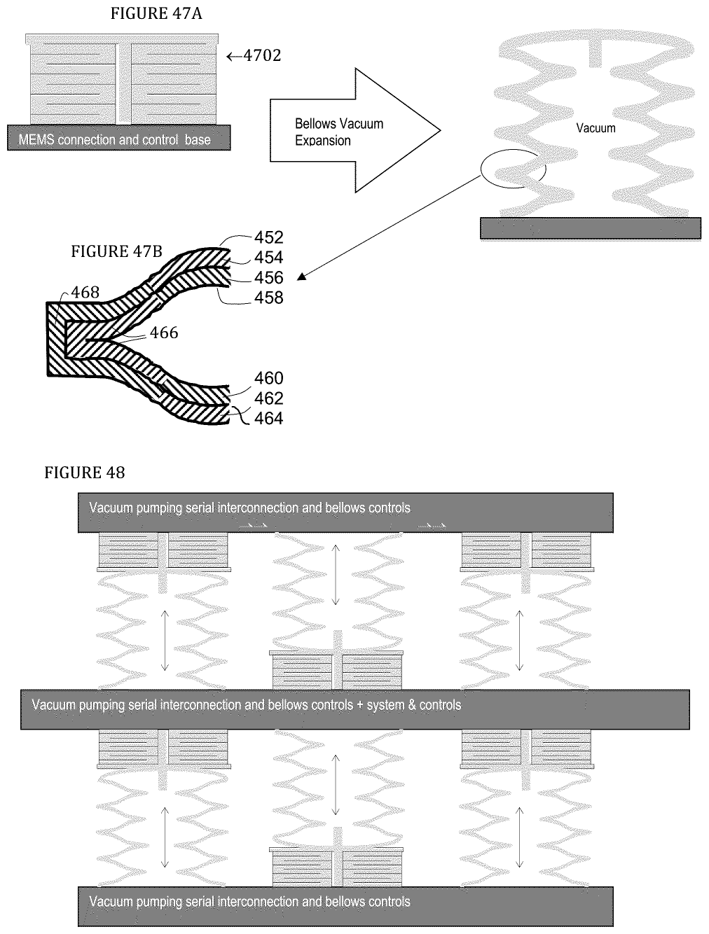

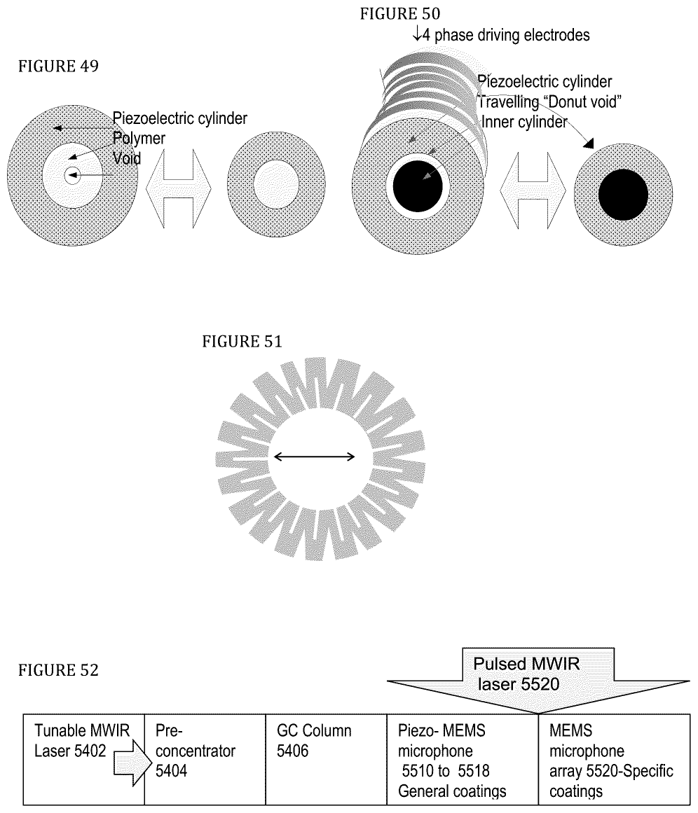

FIG. 47A is a schematic cross-sectional illustration²⁶² of a square or round SMA metal or piezoelectric bellows structure 4702 hermetically sealed and mounted on a MEMS chip with other GC-MS structures. It has little or no internal volume in its “collapsed” condition²⁶³. Upon activation, the SMA or piezoelectric bellows expands over 100:1 in internal volume, directly and immediately creating a vacuum zone. The “collapsed” low/no volume condition can be pre-pumped to subatmospheric pressure, greatly enhancing the resulting large-volume vacuum upon bellows expansion.

A shape memory alloy vacuum bellows pump may be fabricated from the shape memory alloy, which can be resistance heated for expansion, and cooled for contraction. The internal vacuum zone of the SMA or piezoelectric bellows can house a “collapsed” MS device structure which lengthens to form a vacuum path for ion travel. The top or base of the bellows can support a suitable detector, such as a TOF or 100 million Frame per Second CCD²⁶⁴.

SMA vacuum bellows can be designed in “2-way shape memory”, which generates less force. Or, as shown below, it can be designed with high-force, one-way SMA memory with complementary “antagonistic” bellows activated for return of the first bellows to the original “fully collapsed” condition. The internal volume increase of the antagonistic bellows can be valved to withdraw from its associated bellows. For simplicity, such valveing can be “automatically” accomplished by design using the respective bellows movements against internal valves.

SMA vacuum bellows can be stacked, assisted by one-way external SMA actuator force, alternated for continuous pumping, and/or connected in parallel or series.

The dielectric vacuum bellows is a useful vacuum system. Dielectric flexure bellows do not have the large bending displacement of each shape memory alloy layer (resulting from the large 8% SMA volume change). Each composite piezoelectric layer will typically only bend, say, about 1-2 millimeters. But a piezoelectric bellows can have many layers, and can operate at ambient-temperature at high frequency with low energy use. Collapsible zero-volume bellows designed in bending piezoelectric composites, like those previously described for shape memory alloys. Piezo composites have the advantage of ambient temperature operation, and high energy efficiency. Piezoelectrics have the disadvantage of lower volume change than shape memory alloy. But this is compensated by low energy cost, and very high rates of operation.

Piezoelectric bellows construction can utilize a multi-electrode, multi-layer piezoelectric ceramic construction which is optimized for bellows expansion and contraction. In this regard, the bellows walls may be of two layer piezoceramic construction with intermediate and external electrodes. An example of piezoelectric bellows fabrication is illustrated in FIG. 47B, whish shows a cross-section of a portion of the expanded bellows wall of FIG. 47A. The cross-section comprises a composite structure of electrodes 452, 458, 464 together with appropriately polarized ceramic piezoelectric layers 454, 456, 460, 462, 466, 468 with adjacent opposing polarization, so that upon application of activating potential to the electrodes the bellows respectively expands and contracts by composite bending force²⁶⁵. In the illustrate embodiment, the polarization of the bellows walls switches at the expansion inflection points, while the electrodes maintain electric field continuity. Alternatively, the electrodes may be split at the inflection points, and the composite polarization may remain continuous.

Dielectric bending can fast, and relatively energy-efficient, especially in resonance. The muRata Bernoulli pump referred to above operates at 26,000 Hz. Electrode drive timing is conventional, having been worked out over the past decades for CCD cameras and positive piezoelectric pumps²⁶⁶. Peristaltic positive liquid pumps which operate via fluid viscosity, without sealing, are well-developed for medical and positive liquid pumping. Miniature positive-pressure piezoelectric pumps have been analyzed, developed and integrated in systems for various uses such as positive liquid pumping, ink jet printers, medical pumps, etc. over the past couple of decades²⁶⁷.

New piezoelectric systems are described herein to provide compact, efficient vacuum (and pressure) for portable sensors/detectors such ad GC and MS analytical devices and processes.

Multilayer piezoceramic “bender” actuators provide a relatively efficient large stroke displacement, at relatively low piezo voltages. By applying a piezo voltage across a “bender” layer, the layer bends up, or down, depending on voltage polarity. Switching polarity reverses the bend direction²⁶⁸. Conventional piezo microblowers using a “bender” actuator can efficiently pump large amounts of gas from a small thin piezoceramic. For example, the inexpensive, small (2×2×0.2 cm) muRata “High Pressure, Ultra Thin Microblower” pumps a liter of air per minute using 0.18 watt at a 26 kHz resonance frequency. However, it is not well-adaptable to multi-stage design, and does not provide vacuum levels which are optimized for vacuum GC-MS.

By positioning a series of electrodes along a piezoceramic layer, the ceramic sheet can be formed into a series of isolated voids. By driving the piezolayer using multiple electrodes for each void, the voids can be effectively moved along the layer at very high speed.

The axial cylinder peristaltic piezoelectric vacuum pump described herein has a cylindrical compound piezoelectric ceramic layer which is distorted by applied electric fields driven by electrodes arranged axially along the cylinder shown schematically as ϕ1, ϕ2, ϕ3, and ϕ4, in a manner similar to CCD charge transfer.

It should be noted that the peristaltic pumping action can be reversed by reversing the driving sequence, and can be divided in different zones to control and direct the GC gas to different outlets. For example, a peristaltic array with electrodes to the left of the GC column outlet (above) can be activated to pump selected eluting compounds of GC vapor to a second detector, rather than to or from a Mass Spectrograph. It should also be noted that both sides of the piezoceramic layer can form piezoelectric multistage pumps against a surface or another piezcoceramic pump. One side can pump a vacuum, the other can pump air through a pre-concentrator. Or both can act as vacuum or positive pressure pumps at relatively high efficiency which is useful for GC and GC-MS systems.

Piezoelectric tubes²⁶⁹ which change radius may be designed as vacuum pumps, by using phased electrodes along the axis (inner and outer surfaces of the tube), and sealing-off an internal, moving void along the tube axis with the “compression” wave generated by the electrodes. Together with expansion when an electric field is applied in the direction of polarization in a cylindrical piezostructure the cylinder also contracts (transverse piezoelectric effect) orthogonal to its polarization direction. A simple axial vacuum pump has an outer piezoelectric dielectric (ceramic) cylinder and a resilient polymer inner surface with appropriate thickness and inner ID which matches the volume reduction of radial compression from phased driver electrodes to fill the central axial zone when the ceramic cylinder is compressed, and then to open the central axial zone when the adjacent ceramic cylinder is expanded by appropriate electrode driver.

The polymer layer and/or other piezoelectric cylinders can be a piezoelectric such as poly-(vinylidenedifluoride) PVDF, which itself can serve as a GC stationary phase or pre-concentrator phase if the pump is also designed for such use. These designs are also useful as valves.

Another efficient piezopump design illustrated in FIG. 50 B has an inner cylinder, against which the inner wall of the piezoelectric fits/presses when constricted by a passing (or static for a valve function) compression wave. The travelling wave inner contact surface of the dielectric cylinder is compressed against the inner cylinder when contracted, and forms a sealed, travelling “donut” void when expanded. The inner cylinder can synergistically be an opposite-driven peristaltic travelling wave piezoelectric, because “donut” volume is proportional to the square of the void volume radii. The design may also have an outer casing, against which the expanded cylinder is compressed to form another channel. The design can include thin polymer surfaces to seal the moving “donut” pockets. The co-travelling waves seal against each other. This nested, axial tubular design simplifies sealing and stress control. Importantly for small analytical instrument design, as well as size and structural strength concerns, this coaxial multichannel pump structure can also be implemented with a compact empty core, to house and integrate a miniature Mass Spec together with its vacuum system.

The radial contraction/expansion of conventional radial displacement designs is small, but powerful. As schematically illustrated in FIG. 51, a new design for facilitating and increasing the radial expansion/contraction for tubular axial piezopumps has an accordion-like flexure construction of a multilayer composite piezoelectric, readily manufacturable by coextrusion and/or machining. The cylindrical walls of the composite axial bending pump may be constructed as described with respect to FIG. 47 B.

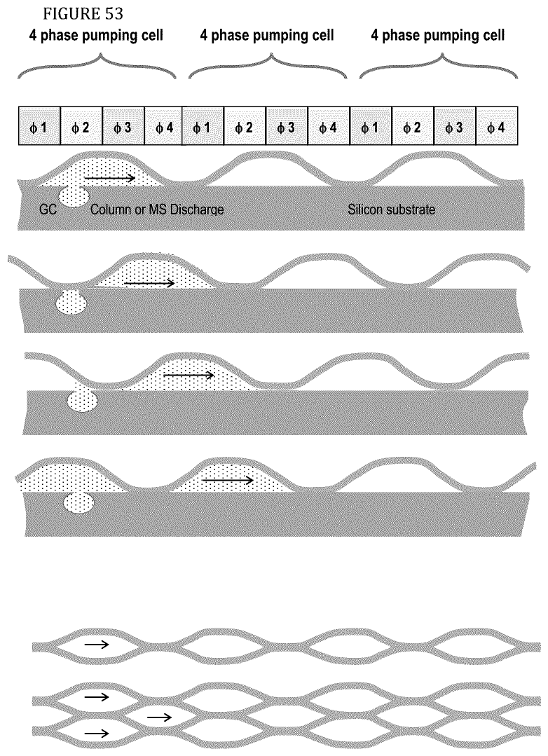

Stackable unitary “pond ripple” disk pump structures may also be optimized for GC and Mass spectrometer use. Piezoelectric disks having concentric 3 or 4-phase driving electrodes which produce radial travelling waves like ripples on a pond (either inward or outward) can produce high frequency travelling pumping action with simple edge scaling structures. The “pond ripple” vacuum pumps described herein may have 3 or 4 phase electrodes radially and concentrically arranged on compound piezodiscs. FIG. 53 generically shows the bending of the compound piezoelectrics in a wavelike motion, under the influence of the driver electrodes. Each of the 3 or 4 phase driving electrodes has a separate driving signal which, with the other signals, distorts the piezoelectric layer to form separated, moving gas pockets in a piezoelectric ceramic layer, which transport gas from a gas source (here the end of a GC column etched in a substrate) to a discharge site (not shown)²⁷⁰. Three phase driving electrodes can also be used, with appropriate drive timing. Driving the peristaltic pump at Khz speeds can produce high pumping volumes suitable for subatmospheric GC-direct MS connected instruments. The pumping capacity can be increased by stacking and/or connecting confined piezolayers together in series and/or parallel.

Radially inwardly or outwardly moving “waves” in circular ceramic disks are also useful for multistage pumping systems. The SMA and peristaltic pumps can also be combined as design components for different instruments. The disks can be efficiently stacked for series/parallel operation and reliable sealing. Again, a central hollow cylinder of the stacked assembly can house an associated miniature Mass Spectrometer.

An ambient temperature MWIR camera can be designed in a similar manner by using a shallow-doped semiconductor which changes refractive index upon MWIR absorption. By employing plasmonic sensor pixels with specific MWIR absorption wavelengths, directly sensed by adjacent VIS camera pixels, inexpensive ambient temperature MWIR cameras can be made which are very small and energy-efficient. Multi-band images can be produced by using different compounds or semiconductor doping with different MWIR absorption bands with the Liquid Crystal or semiconductor materials in an image array pattern.

Plasmonic devices can detect extremely small changes delta n in refractive index of 10⁻⁵ to 10⁻⁶. VIS CCD/CMOS megapixel cameras are now very sophisticated and very inexpensive digitizing systems (some complete, relatively good megapixel camera chips are under $25). Materials, such as Liquid Crystals and shallow-doped semiconductors (eg, Ga-doped 4H-SiC) produce large changes (10⁻¹) in refractive index upon electronic or thermal MWIR absorption. The large delta n of doped SiC upon MWIR absorption is reported by Geunsik Lim of Aravinda Kar's lab²⁷¹ at University of Central Florida, “Optical response of laser-doped silicon carbide for an uncooled midwave infrared detector”, Applied Optics/Vol. 50, No. 17/10 Jun. 2011; and “Improved optical properties and detectivity of an uncooled silicon carbide mid-wave infrared optical detector with increased dopant concentration”, J. Opt. 14 (2012) 105601 (13pp)]

The MWIR camera schematic in FIG. 55A has a monocrystalline 4H-SiC layer 5302 with a thin (eg, 150 nm) shallow band Ga implant 5304, on which is formed a gold/silver transmission plasmon array 5306. Both the doped SiC and the plasmon array are “pixelated” to limit crosstalk. The pixelated plasmon array is directly matched to, and adjacent to, the VIS imager pixels of a CMOS camera chip. In operation, an MWIR image passes through the SiC layer and is absorbed and formed on the Ga-implanted SiC. The MWIR light absorbed increases the SiC conductivity in the image parrern, and therefor the refractive index, of the SiC “pixels”. The refractive indices of the Ga-doped SiC layer “pixels” are increased in proportion to the MWIR image absorbed by the shallow-Ga-doped SiC pixels. A VIS light pulse, which may be from a narrow bandwidth laser source is applied to the plasmon array under control of the camera processor 5308. The VIS light transmitted through each “pixel” of the plasmon array is modulated by the changed refractive index of the adjacent Ga-doped SiC. A wide variety of transmission plasmon arrays, such as those described herein, may be used which are responsive to refractive index variation or modulation. The VIS image recorded by the VIS CMOS camera from the transmitted VIS light at each pixel is a function of the MWIR image. The Ga—SiC layer is then reset to ambient normal refractive index, by an electrode pulse (not shown), to reset the focal plane for the next image. Suitable plasmon arrays are described herein.

Highly sensitive, low power vapor sensors are needed, especially for portable, remote gas chromatograph systems with limited power and energy. Accordingly, additional aspects of the present disclosure are directed to VIS and MWIR photodetectors using multiple, very tiny, differently-selective mini-microphone sensors at either or both the pre-concentrator GC input, and the GC output after analyte-distinctive retention time delay. Such specific, and cross-sensing information will add important analyte-distinguishing information, and could eliminate the need for Mass Spectroscopy cost, size and energy use.

Photoacoustic spectroscopy can be very sensitive, down to the parts-per-trillion range under optimized conditions²⁷². Mini-MEMS microphones are very small, relatively simple, and can be integrated or otherwise included in a GC discharge gas stream.

As illustrated in FIG. 52, A tunable MWIR laser 5402 is employed to selectively pulse-inject analytes collected in a preconcentrator 5404 which absorb at the MWIR wavelength pulse. The selectively-injected analytes are separated in the GC column 5406 under standardized conditions of carrier gas flow, temperature and other operating conditions (which may include selective MWIR and/or microwave application to the GC column). The garrier gas and eluent stream from the discharge of the GC column 5406 is directed to an array of piezoMEMS microphones 5510-5518 (see FIGS. 55, 56) which are selectively responsive to different eluants. The eluent discharge stream from the array 5510-5518 is directed through a similar MEMS microphone array which is selectively sensitive to specific compounds of particular interest for an analytical application of the GC system. A MWIR laser pulse source 5520 directs MWIR laser pulses onto the active surfaces of the general cross-reactive MEMS pressure pulse transducers 5510-5518 and the 5520 array of more-specific chemically sensitive array 5520. The illustrated Laser source is a tunable MWIR laser which emits tunable midwave infrared wavelength pulses in the range of from about 4 to about 10 microns. The laser pulsewidth may desirably be selected in the range of from about 100 ns to about 1 millisecond.

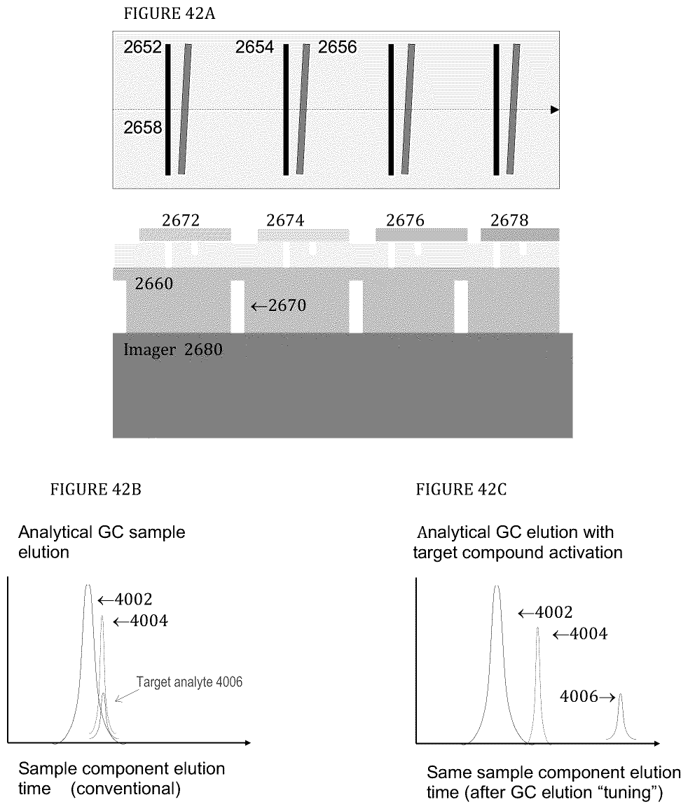

FIG. 55B is an enlarged schematic top view (left side) and cross sectional side view (right side through dotted line) of an integrated array of piezoelectric (or capacitive) MEMS microphones 5510, 5512, 5514, 5516, 5518 which each respectively have a differently-absorbing thin layer on the surface of their respective microcantilevers or diaphragms, such as described herein (see FIG. 42). There is a wide range of commercially available devices²⁷³ which may be modified and incorporated in the low-power sensor embodiment of FIG. 55B. An array of, for example, aluminum nitride piezoelectric diaphragms or cantilevers may be fabricated in a substrate-etched GC column, or as a separate attachment at a GC column outlet, as shown in FIGS. 52 and 56. Similarly, an array of capacitive MEMS microphones may be provided with differently-absorptive thin layers on their respective capacitive membrane surfaces. The MEMS array of FIG. 55B as shown by cross section through element 5516 is contained within a conduit 5532 which receives the carrier gas and eluent discharge from a gas chromatographic column, with gas flow as indicated by arrow in FIG. 55B. A pulsed light source, which in the illustrated embodiment is a tunable pulsed MWIR laser source, is provided to interrogate the surface of the MEMS microphone for the presence or absence of absorbed analyte which absorbs MWIR light at the emitting wavelength of the laser 5540. The MEMS microphone 5516 is positioned to receive a light pulse onto its sound-receiving surface or membrane from laser 5540, through transparent window 5522. The illustrated MEMS mini-microphones transduce pressure waves into electrical signals at high sensitivity. Such transducers may desirably be conventional, high-sensitivity piezoelectric MEMS microphones or capacitive microphones. Piezoelectric MEMS transducers comprise piezoelectric films or layers together with electrode to transmit the signal produced when the layers are bent or flexed. Capacitive microphones comprise a charged diaphragm or cantilever adjacent a charged baseplate, which produces an electrical signal when the distance between these capacitive plates is changed by a pressure wave. These signals are amplified and digitized for data processing. The MEMS microphones may have analog or digital output, in accordance with conventional practice. The respective outputs from analog MEMS transducers are externally digitized by corresponding external A/D converters for processing by the central detection and data processing system 5540. Conventional digital MEMS microphones comprise respective integrated analog-to-digital converters, which directly produce a digital output, typically in either a pulse density modulated (PDM) or inter-IC sound (I2S) output to reduce jitter, and for direct connection to a digital signal processor and/or microcontroller 5542.

FIG. 14B is a schematic cross-sectional view of one of the selectively-responding cross-reactive MEMS transducers 5516 of the array of FIG. 55B, shown inverted from orientation of FIG. 55B. The transducer 5516 comprises an etched substrate 5602, respectively poled (eg, aluminum nitride, AlN) piezoelectric layers 5604 and 5606 separated by (eg, Mo) electrode 5610, which are bounded on their outer surfaces by (eg Mo) metallic electrode 5608. When forced to move, the piezoelectric layers 5604, 5606 generate an electrical signal across the electrodes 5610, 5608. The illustrated electrode-piezoelectric composite is separated into segments to facilitate flexure in accordance with conventional MEMS microphone design. An important feature of the sensor 5512 is analyte absorptive layer 5614. The layer 5414 is applied to the surface of the composite piezoelectric cantilever components, in order to absorb eluants to be detected. The different sensor elements 5510, 5512, 5514, 5516 and 5518 are each provided with a differently absorptive layer 5614, in order to facilitate distinguishing different eluants. In the illustrated embodiment, the laser-pulse facing surface of the pressure-pulse sensing membrane/cantilever(s) is provided with a metallic, light-reflecting surface, in this embodiment the Mo electrode 5608. The laser pulses applied to the MEMS device which pass through the analyte-absorptive layer 5614 are reflected back through the analyte-absorptive layer 5614, thereby increasing selective pulse heating of any MWIR-responsive analyte in the layer, and reducing absorption in the electrogenerating component(s) of MEMS membrane. Desirably, the metal reflecting means should reflect at least about 50% of the interrogation light which reaches its surface from the pulsed laser source.

By applying differently-absorptive coatings to an array or series of differently selective analyte absorbing diaphragm transducers, analyte-distinguishing elution data can be combined with MWIR spectrographic data, and Gas Chromatographic elution time data, for specific analyte identification using Principal Component Analysis and/or related component distinguishing processing.

An important feature of differently-sensitive plasmon sensors is that specific analytes can be characterized by their pattern of behavior on different types of detectors. Principal Component Analysis (PC) and related techniques can distinguish analytes by their different absorption and/or chemical affinity characteristics. As few as 5 differently-absorbing general sensor surfaces may “describe much of the variance in the gas-solid partition coefficients for sorption of vapors into various polymers”²⁷⁴. Very specific absorbers²⁷⁵ can also be used for analytes of particular importance, such as drugs, and nerve agents.

Photoacoustic models for a solid phase analyte pulsed with MWIR, employing a separate microphone in the gas of a resonating enclosure, assume that a thin gas phase is flash-heated adjacent the solid surface, to create a sound-pulse which is picked up by the remote microphone. But by applying a thin selectively-absorbing layer directly on a piezoelectric or capacitive membrane of the mini-microphone itself, application of a light (eg, VIS or MWIR) pulse can abruptly head a surface layer with adsorbed analyte, and/or pulse-vaporize selectively adsorbed analyte. The abrupt thermal expansion with movement of the center-of-mass of the layer, and/or vapor movement away from the membrane/diaphragm/cantilever, produces Newtonian mass-reaction of the membrane in the opposite direction to generate an electrical output pulse from the thereby-displaced microphone membrane, diaphragm or cantilever. In operation, The GC eluent is passed over the array through passageways 5520, 5530 conduit 5532, thereby contacting the respective MEMS microphone array absorptive surfaces. The tunable MWIR laser 5540 applies short (eg, 1-10 microsecond) pulses of MWIR radiation onto the absorptive layers of the MEMS microphones 5512-5518. Repetitive pulses at the same wavelength may be applied at regular intervals to increase S/N ratio by lock-in-amplification, in accordance with conventional lock-in amplification practice. The MWIR wavelength of the pulses may also be scanned over a predetermined wavelength range to produce a spectroscopic scan of analyte absorption. The response of the respective layers/microphones without analyte present or absorbed may be determined and stored for subtraction from measurements made with analyte(s) present in the GC carrier gas/eluent stream. The pulse width and power of the laser pulses may be adjusted to suit the specific MEMS array and operating conditions.

Upon passage of an eluent bolus through the MEMS detector array, the analyte(s) are adsorbed into the layers on the MEMS microphones with a partition coefficient in a manner similar to their absorption into the stationary phase of the GC column. The different absorption layers absorb analytes differently, depending on their selective characteristics. Accordingly, as the eluent bolus passes through the MEMS detector array, the laser-induced responses of the differently-absorptive MEMS microphones are characteristically different, which provides additional distinguishing cross-reactive detector information for processing by the controller/microprocessor 5532 for distinguishing the respective analytes eluting from the GC column. By combining elution time, cross-reactive detector response, and MRIR absorption spectroscopy information using appropriate algorithms and analytical procedures as described herein (eg, PCA), the analytes can detected and distinguished using a very compact, low-power system.

In this regard, the MEMS transducer array can be very compact. The operating diaphragm or cantilever areas can typically be less that 2×2 millimeters in length, x width, so that an array of 5 differently sensitive fluid pressure pulse detectors can preferably be less than 15 millimeters in length. When fully integrated on a single substrate, the ratio of the side-by-side length of the array in millimeters, to the number of detectors can preferably be less than about 1.5²⁷⁶. The small footprint reduces size and weight, and facilitates laser light pulsing of the array using a single laser.

By applying differently-absorptive coatings such as described herein²⁷⁷ to produce an array or series of differently selective analyte absorbing diaphragm transducers, analyte-distinguishing elution data can be combined with MWIR spectrographic data, and Gas Chromatographic elution time data, for specific analyte identification using Principal Component Analysis and/or related component distinguishing processing. By pulsing MWIR light from a suitable (preferably tunable) laser at the analyte absorbing surface, the absorbed analyte is heated if the light pulse is within any of its absorption bands or wavelengths. The selective pulse heating warms the analyte in/on the adsorbing layer of the MEMS diaphragm/lever and adjacent gas, deflecting the diaphragm/membrane/cantilever of the MEMS microphone transducer, producing an electrical signal for processing in the microprocessor/DSP 5540.

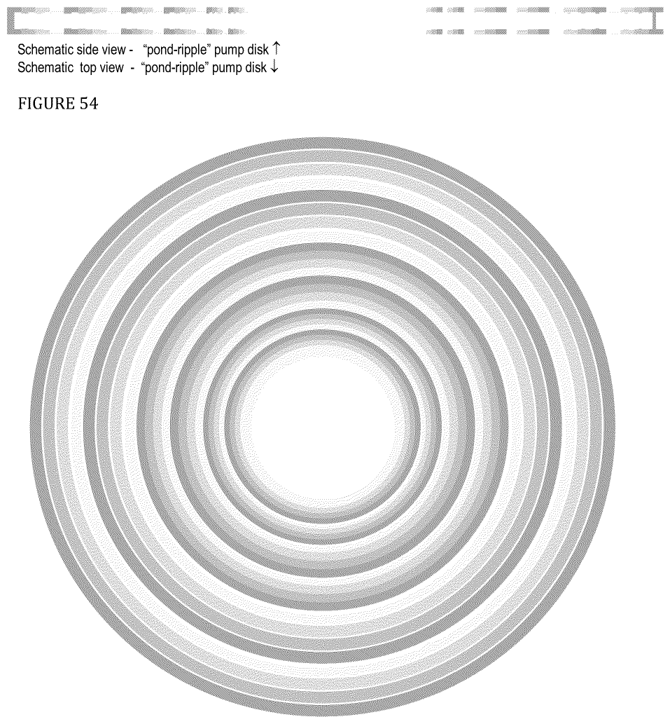

In one embodiment, a MEMS MWIR detector array is fabricated comprising a plurality of five MEMS microphones such as illustrated in FIG. 55B-56, having different analyte-absorbing layers on their respective pulsed-laser-facing pressure-transducing surfaces. The first MEMS detector may have a low crystalline polyethylene, Apiezon L™ or squalane layer 100 nm in thickness, as an aliphatic stationary phase, which has a relatively low MWIR absorption over relatively broad wavelength ranges. A second MEMS device has a nominally 150 nm coating of a poly(dimethylsiloxane) with more polar analyte affinity, and has relatively low MWIR absorbance from about 2.5 microns to about 6.5 microns except for an absorption band around 3.4 microns. A third MEMS microphone surface has a 50 nm coating of trifluoropropylmethyl polysiloxane (50% trifluoropropyl, 50% methyl) GC stationary phase polymer, which is moderately polar, and a fourth MEMS microphone surface is coated with a polar polyethylene glycol Carbowax 20M™ layer approximately 100 nm thick which has an infrared absorption spectrum with transparent windows similar to that of polydimethylsiloxane. A fifth MEMS sensor surface has an alpha, beta or gamma cyclodextrin compound bonded²⁷⁸ on its surface as a size-selective analyte absorber. In operation of a system dedicated to detection of nitrate explosives such as TNT and RDX, an AdTech Optics (City of Industry, CA 91748) 6.23 μm Distributed Feedback (DFB) Quantum Cascade Laser PART NO: HHL-15-69 is utilized as the selective preconcentrator laser source, and as the MEMS interrogation source 5540, under control of microcontroller 5542. An initial baseline response is obtained from the MEMS array without analyte present in the GC carrier gas or adsorbed on the pressure wave transducer components. The preconcentrator lightpipe (which contains a small test amount of TNT) is then pulsed with a 1 second duration of 200 mw 6.63 micron MWIR to selectively vaporize —NO2 containing analytes into the GC column. One microsecond pulses of 6.23 micron MWIR are directed at the MEMS microphones at a rate of 1 kHz. Their outputs are respectively filtered and smoothed to improve S/N of the output peaks vs. elution time. The TNT signal is recorded at its characteristic elution time under the predetermined GC operating conditions. The signal for each of the differently-coated transducer surfaces varies according to the affinity of TNT vapor with the respective coating. The baseline response may be subtracted from the eluent response to isolate the elution peak information. For a more general sensor system (eg, FIGS. 37, 54), a tunable MWIR source may be used for each of the preconcentrator and the MEMS interrogator laser 5540. The pulses from the interrogator laser 5540 may be scanned over predetermined wavelength range, such as from 4 to about 9 microns, over a relatively short period of time, for example less than 5 seconds, and preferably less than about 2 seconds. The eluants are detected at their respective elution times, together with their IR absorption signatures, and their respective affinity characteristic signature with respect to the different MEMS pressure pulse transducer coatings. The combination of these measurements is diagnostic for analytes.

Another embodiment of a multi-sensitive detector array utilizes a cross reactive sensor array in which adsorption of analytes causes color changes in the visible spectrum (generally 400-700 nm). The five MEMS pressure pulse transducer elements of the array may be coated with differently responding solvatochromic layers. Solvatochromic dyes may conventionally be incorporated in a polarity-controlled environment such as a specific polymer, so that color changes caused by absorption of analytes of different polarity can be processed by data analyses such as Principal Component Analysis to distinguish the analyte(s)²⁷⁹. For example, Nile red, Reichardt's dye, 4-Amino-N-Methylphthalimide, and 4-Aminophthalimide may be incorporated in polyvinylpyrrolidone (PVP) or polyvinylchloride (PVC) as matrices of different polarity. In this regard, 0.5 wt % Nile red and 46 wt % PVP; 2 wt % Reichardt's dye and 46 wt % PVP; 2 wt % 4-Amino-N-Methylphthalimide, and 46 wt % PVP; 2 wt % 4-Aminophthalimide and 46 wt % PVP; and 0.5 wt % Nile red and 35 wt % PVC may be individually dissolved in 2 ml N,N-dimethylacetamide at a 1:1 to 1:2 volume. The mixtures may be sonicated for 2 minutes to insure homogeneity and then respectively deposited on the pressure pulse transducer surfaces of the 5 MEMS devices of the array by spin coating, and dried to remove solvent. The thickness of the solvatochromic layers is adjusted by solution concentration and coating parameters to be in the range of from about 50 to about 200 nm. In operation, the 5 differently-absorbing and differently responding MEMS detectors may be interrogated by a pulsed light system which comprises a broad spectrum pulsed light source such as a “white light” LED or a mini xenon flashlamp. The broadband VIS output may be directed through a prism (here, window 5522) to disperse its VIS spectrum across the microphone array. The different color-change coatings²⁸⁰ can be arrayed if desired according to their color of maximum color change, along the dispersed spectrum directed onto the MEMS detector array.

An important feature of differently-sensitive plasmon sensors is that specific analytes can be characterized by their pattern of behavior on different types of detectors. Principal Component Analysis (PC) and related techniques can distinguish analytes by their different absorption and/or chemical affinity characteristics. As few as 5 differently-absorbing general sensor surfaces may “describe much of the variance in the gas-solid partition coefficients for sorption of vapors into various polymers”²⁸¹. Very specific absorbers can also be used for analytes of particular importance, such as drugs, and nerve agents. [Susan M. Daly et al, “Supramolecular surface plasmon resonance (SPR) sensors for organophosphorus vapor detection”, J. Mater. Chem., 2007, 17, 1809-1818.
1 Eg, see P. Jeanbourquin (2005) The Role of Odour Perception in the Sensory Ecology of the Stable Fly, Stomoxys calcitrans L., PHD Thesis Université de Neuchâtel
2 Rybczynski, R., Reagan, J. et al, (1989), A pheromone-degrading aldehyde oxidase in the antennae of the moth Manduca sexta, J. Neurosci (bombykal pheromone half-life estimated as ˜0.6 msec)
3 Ewald Grosse-Wilde, et al, (2011), “The antennal transcriptome of Manduca sexta”, Proceedings of the National Academy of Sciences USA, Early Edition, April 2011, DOI: 10.1073/pnas. 1017963108 The well-studied moth Manduca sexta (Tobacco Hornworm) has 68 (male) to 70 (female) different odorant receptors expressed in approximately 100,000 olfactory neurons, each connecting to a specific glomerulus in the insect brain to collectively distinguish a large number of odorants.
Takeshi Imai et al, “Topographic Mapping—The Olfactory System”, Cold Spring Harb Perspect Biol 2010; 2: a001776 originally published online Jun. 16, 2010
4 Insect olfaction is not entirely “steady-state”. Individual neurons fire in response to individual odorant molecule triggering. And wing flapping creates odorant concentration variation which is analogous to “sniffing”:
   Insects commonly make movements with their antennae or wings that are thought to change the capture rate or probability of chemical signal interception by the antennae and may be considered to be sniffing [“Sniffing By A Silkworm Moth: Wing Fanning Enhances Air Penetration Through And Pheromone Interception By Antennae”, The Journal of Experimental Biology 203, 2977-2990 (2000), citing Schneider, 1964)].
   For some adult male moths fan their wings vigorously in the presence of sex pheromone released by a conspecific female. Wing fanning by adult males of the oriental fruit moth Grapholitha molesta is correlated with successful mating, suggesting that wing fanning enhances the localization of the pheromone source (citing Baker and Cardé, 1979).
      “Sniffing” silkworm moths fan their wings at 35 to 55 Hz, generating a pulsed air velocity that “profoundly” changes the amount of odorant-laden air that goes through the sensilla of the antennae, at the pulsed air frequency:
   In the case of B. mori, the difference between air penetration through the antennae on a moth fanning its wings compared with a moth walking without fanning is profound. Although wing fanning produces air flow that is approximately 15 times faster than that generated by walking at top speed (0.023 ms−1; Kramer, 1986), the air flow through the gaps between the sensilla is predicted to be approximately 560 times faster during fanning (FIG. 6). This characteristic increase in air velocity near the sensilla leads to a much greater pheromone interception rate (FIG. 6C,D) during fanning than during walking, even though a smaller proportion of the molecules in the air passing between the sensilla have time to diffuse to them during fanning (FIG. 6B).
   In the absence of air flow around a sensory hair, the hair can deplete the air space immediately surrounding it of signal molecules if the molecules that diffuse to the hair are removed from the air by the hair. Such removal is probably a reasonable assumption for insect sensilla, since no release of adsorbed signal molecules is observed and most signal molecules are broken down after transduction (Kaissling, 1998). For example, in still air, a sensory hair 2 mm in diameter can encounter by diffusion enough molecules to deplete a ‘nominal volume’ of air around itself 15μ thick in just over 10⁻⁴ s, and 100μ thick in 10⁻² s.
      The diameter of silkworm moth sensory hairs is about 2 microns, and their length is approximately 100 microns, so odorant is depleted by absorption from still air around these sensory hairs in less than 1/100 second. Because the absorbed odorant as quickly destroyed by enzymes, the sensilla signal is quickly reduced in still air. When the insect beats its wings, the odorant-bearing air is periodically replenished at a “chopping” frequency determined by the wing frequency. It is speculated herein that the exact time for the insect brain antenna lobes to “look for” a signal could be determined by the mechanical receptors in the antennae, in the same way as a “lock in” amplifier. It is also possible that the firing of mechanical sensors in the antennae could sensitize the odorant neurons to firing coincident with the increased flow of odorant.
5 Sberveglieri, G., C. Baratto, et al. (2009). “Semiconducting tin oxide nanowires and thin films for Chemical Warfare Agents detection.” Thin Solid Films 517(22): 6156-6160.
Comini, E., A. Ponzoni, et al. (2009). SnO2 nanowires for detection of chemical warfare agents, Christchurch, New Zealand, Institute of Electrical and Electronics Engineers Inc.
Ponzoni, A., C. Baratto, et al. (2008). “Metal oxide nanowire and thin-film-based gas sensors for chemical warfare simulants detection.” IEEE Sensors Journal 8(6): 735-742.
Ponzoni, A., E. Comini, et al. (2007). Tin, niobium and vanadium mixed oxide thin films based gas sensors for chemical warfare agent attacks prevention, Atlanta, GA, United states, Institute of Electrical and Electronics Engineers Inc.
Ponzoni, A., C. Baratto, et al. (2007). Nerve agents simulants detection by tin oxide nanowires, San Francisco, CA, United states, Materials Research Society
Sharabi, D. and Y. Paz (2010). “Preferential photodegradation of contaminants by molecular imprinting on titanium dioxide.” Applied Catalysis B: Environmental 95(1-2): 169-178. (molecularly imprinted photocatalyst for WMD warfare agents)
S. Singh (2007), “Sensors—An effective approach for the detection of explosives”, Journal of Hazardous Materials, 144(1-2): 15-28
6 The interaction of a gas with an n-type semiconductor is different from its interaction with a p-type material. For example, when oxygen is ionosorbed on an n-type sensor, majority carriers are extracted from the conduction band, while minority carriers are extracted from the conduction band of a p-type sensor when oxygen is ionosorbed.
Wisitsoraat, A., A. Tuantranont, et al. (2009). “Characterization of n-type and p-type semiconductor gas sensors based on NiOx doped TiO₂ thin films.” Thin Solid Films 517(8): 2775-2780 (different gas-sensing responses of n-type and p-type NiOx doped TiO₂ thin film)
Wisitsoraat, A., E. Comini, et al. (2007). Studies of TiO2 based mixed oxide thin film materials prepared by ion-assisted electron beam evaporation for gas sensing applications, San Francisco, CA, United states, Materials Research Society. (NiOx addition with sufficiently high concentration has proven to produce p-type semiconducting thin film while WO3, MoO3, and ZnO inclusions result in typical n-type metal oxide semiconductor. The gas-sensing sensitivity, selectivity, and minimum detectable concentration can be effectively controlled by different dopants and doping concentrations)
Comini, E., G. Faglia, et al. (2005). Characterization of P-type Cr:TiO2 gas sensor, Irvine, CA, United States, Institute of Electrical and Electronics Engineers Inc., Piscataway, NJ 08855-1331, United States. (P-type conductivity and enhanced sensing with Cr-doped TiO2)
Comini, E., G. Faglia, et al. (2004). “Stable and very sensitive gas sensor based on novel mixed metal oxides.” SPIE 5275:1-8. (remarkable improvement attributed to the significant increase in grain boundary area due to the small grain size and increasing the surface area exposed to the interaction with gaseous species. Mo—Ti, Mo—W, Ti—W, Ti—Nb different p-type sensing materials for opposite behavior in sensor arrays)
7 Baratto, C., S. Todros, et al. (2009). “Luminescence response of ZnO nanowires to gas adsorption.” Sensors and Actuators, B: Chemical 140(2): 461-466.
Setaro, A., A. Bismuto, et al. (2008). “Optical sensing of NO2 in tin oxide nanowires at sub-ppm level.” Sensors and Actuators, B: Chemical 130(1): 391-395.
Lettieri, S., A. Setaro, et al. (2008). “On the mechanism of photoluminescence quenching in tin dioxide nanowires by NO2 adsorption.” New Journal of Physics 10: 043013
Lettieri, S., A. Setaro, et al. (2008). Light emission properties of SnO2 nanowires for applications in gas sensing, 25650 North Lewis Way, Stevenson Ranch, CA 9138-1439, United States, American Scientific Publishers.
Bismuto, A., S. Lettieri, et al. (2006). “Room-temperature gas sensing based on visible photoluminescence properties of metal oxide nanobelts.” Journal of Optics A: Pure and Applied Optics 8(7): 585-588.
Lettieri, S., A. Bismuto, et al. (2006). “Gas sensitive light emission properties of tin oxide and zinc oxide nanobelts.” Journal of Non-Crystalline Solids 352(9-20 SPEC ISS): 1457-1460. (Adsorbed NO2 on tin oxide and zinc oxide nanobelts and nanowires may induce fast non-radiative relaxation of surface electrons, competing with radiative surface-localized recombination without significantly changing the subsequent slower radiative processes. Adsorbate-related non-radiative recombination time could be lower than 1 ns)
Comini, E., C. Baratto, et al. (2007). “Single crystal ZnO nanowires as optical and conductometric chemical sensor.” Journal of Physics D: Applied Physics 40(23): 7255-7259.
Faglia, G., C. Baratto, et al. (2004). Visible photoluminescence and conductometric response of tin oxide nanobelts to NO2: Toward a selective gas sensor, Munich, Germany, Institute of Electrical and Electronics Engineers Inc., New York, NY 10016-5997, United States. (visible photoluminescence of tin oxide nanobelts quenched by NO2 at hundreds of ppb level in a fast (˜seconds) and reversible way. The response is highly selective towards humidity and other polluting species like CO and NH3. Comparison between conductometric—response to all the examined species is present at a much slower dynamics—and optical results shows that the two effects arise from completely different origin).
Faglia, G., C. Baratto, et al. (2004). “Metal oxide nanocrystals for gas sensing.” Proceedings of IEEE Sensors 1:182-183. (visible photoluminescence quenching and photoinduced desorption by subbandgap light)
Galatsis, K., L. Cukrov, et al. (2003). “P- and n-type Fe-doped SnO2 gas sensors fabricated by the mechanochemical processing technique.” Sensors and Actuators, B: Chemical 93:562-565. (Fe-doped SnO2 responded as a p-type semiconductor)
Comini, E., G. Sberveglieri, et al. (2003). “Novel p-type gas sensing thin film based on Nb—Ti—O mixed oxides.” Proceedings of IEEE Sensors 2:1116-1119. (p-type sensing layers for the discrimination of different gases)
Comini, E., L. Ottini, et al. (2004). “SnO2 RGTO UV Activation for CO Monitoring.” IEEE Sensors Journal 4(1): 17-20 (UV sensor activation and comparison between dark and UV irradiated condition)
Nebatti, A., C. Pflitsch, et al. (2010). “Sol-gel-deposition of thin TiO2: Eu3+ thermographic phosphor films.” Progress in Organic Coatings 68(1-2): 146-150 (decay time constant of the exponential emission decay under UV excitation with a Nd:YAG laser (355 nm, f=10 Hz) is strongly temperature dependent in the range from 200 C up to 400 C, making it useful for temperature evaluation. The temperature dependence was measured for the emission line at 617 nm; the results demonstrate that anatase doped europium (III) can be used as a thermographic phosphor)
8 Barillaro, G., A. Diligenti, et al. (2006). “Low-concentration NO2 detection with an adsorption porous silicon FET.” IEEE Sensors Journal 6(1): 19-23. (FET with porous silicon adsorbing layer between drain and source, in which adsorbed gas induces an inverted channel in crystalline silicon. NO2 was detected at 100 ppb.
Barillaro, G., A. Diligenti, et al. (2005). FET-like silicon sensor with a porous layer for NO2 detection, Irvine, CA, United States, Institute of Electrical and Electronics Engineers Inc., Piscataway, NJ 08855-1331, US (porous silicon for detection of low level NO2 concentrations (100 ppb) is an integrated p-channel JFET)
Barillaro, G., A. Diligenti, et al. (2004). Detecting NO2 with APSFET, an adsorption porous silicon FET, Vienna, Austria, Institute of Electrical and Electronics Engineers Inc., Piscataway, NJ 08855-1331, United States.
Baratto, C., G. Faglia, et al. (2001). “A novel porous silicon sensor for detection of sub-ppm NO2 concentrations.” Sensors and Actuators, B: Chemical 77(1-2): 62-66 porous silicon (PS) on alumina substrate with interdigital contacts (Italian Patent ENEA-INFM) was able to detect very low concentrations of nitrogen dioxide (100 ppb) without sensor heating)
9 Comini, E., C. Baratto, et al. (2009), Quasi-one dimensional metal oxide semiconductors: Preparation, characterization and application as chemical sensors, Progress in Materials Science 54(1): 1-67 (conductance, FET or optical gas sensors)
Comini, E., G. Faglia, et al. (2009). “Metal oxide nanowires: Preparation and application in gas sensing.” Journal of Molecular Catalysis A: Chemical 305(1-2): 170-177.
Kaciulis, S., L. Pandolfi, et al. (2008). Nanowires of metal oxides for gas sensing applications, Southern Gate, Chichester, West Sussex, PO19 8 SQ, United Kingdom, John Wiley and Sons Ltd.
Barillaro, G., A. Diligenti, et al. (2008). “NO2 adsorption effects on p+-n silicon junctions surrounded by a porous layer.” Sensors and Actuators, B: Chemical 134(2): 922-927.
Epifani, M., J. D. Prades, et al. (2008). “The role of surface oxygen vacancies in the NO2 sensing properties of SnO2 nanocrystals.” Journal of Physical Chemistry C 112(49): 19540-19546.
Comini, E., M. Ferroni, et al. (2008). Doped ZnO nanowires: Towards homojunctions, Lecce, Italy, Institute of Electrical and Electronics Engineers Inc.
Epifani, M., P. Siciliano, et al. (2008). The role of oxygen vacancies in the sensing properties of SnO2 nanocrystals, Lecce, Italy, Institute of Electrical and Electronics Engineers Inc.
Barreca, D., E. Comini, et al. (2007). “First example of ZnO—TiO2 nanocomposites by chemical vapor deposition: Structure, morphology, composition, and gas sensing performances.” Chemistry of Materials 19(23): 5642-5649.
Alessandri, I., E. Comini, et al. (2007). “Cr-inserted TiO2 thin films for chemical gas sensors.” Sensors and Actuators, B: Chemical 128(1): 312-319.
Comini, E., S. Bianchi, et al. (2007). “Functional nanowires of tin oxide.” Applied Physics A: Materials Science and Processing 89(1): 73-76.
Sberveglieri, G., C. Baratto, et al. (2007). Single crystalline metal oxide nano-wires/tubes: Controlled growth for sensitive gas sensor devices, Bangkok, Thailand, Inst. of Elec. and Elec. Eng. Computer Society. (quasi 1D nanostructures of semiconducting oxides as nanosized sensors)
Sberveglieri, G., C. Baratto, et al. (2007). “Synthesis and characterization of semiconducting nanowires for gas sensing.” Sensors and Actuators, B: Chemical 121(1): 208-213.
Baratto, C., S. Bianchi, et al. (2007). Metal oxide nanowires for optical gas sensing, San Jose, CA, United States, SPIE-International Society for Optical Engineering, Bellingham WA, WA 98227-0010, United States.
Ortolani, L., E. Comini, et al. (2007). “Electrical and holographic characterization of gold catalyzed titania-based layers.” Journal of the European Ceramic Society 27(13-15): 4131-4134.
Wisitsoraat, A., E. Comini, et al. (2007). TiO2 based nanocrystalline thin film gas sensors prepared by ion-assisted electron beam evaporation, Bangkok, Thailand, Institute of Electrical and Electronics Engineers Computer Society, Piscataway, NJ 08855-1331, United States.
Comini, E., G. Faglia, et al. (2006). “Oxide nanobelts as conductometric gas sensors.” Materials and Manufacturing Processes 21(3): 229-232.
Morandi, S., E. Comini, et al. (2006). “Cr—Sn oxide thin films: Electrical and spectroscopic characterisation with CO, NO2, NH3 and ethanol.” Sensors and Actuators, B: Chemical 118(1-2): 142-148.
Rumyantseva, M., V. Kovalenko, et al. (2006). “Nanocomposites SnO2/Fe2O3: Sensor and catalytic properties.” Sensors and Actuators, B: Chemical 118(1-2): 208-214.
Candeloro, P., A. Carpentiero, et al. (2005). SnO2 sub-micron wires for gas sensors, Elsevier, Amsterdam, 1000 AE, Netherlands.
Calestani, D., M. Zha, et al. (2005). Nucleation and growth of SnO2 nanowires, Elsevier, Amsterdam, 1000 AE, Netherlands.
Comini, E., L. Yubao, et al. (2005). “Gas sensing properties of MoO3 nanorods to CO and CH 3OH.” Chemical Physics Letters 407(4-6): 368-371.
Ponzoni, A., E. Comini, et al. (2005). Nanostructured WO3 deposited by modified thermal evaporation for gas-sensing applications, Elsevier, Amsterdam, 1000 AE, Netherlands.
Morandi, S., G. Ghiotti, et al. (2005). “FT-IR and UV-Vis-NIR characterisation of pure and mixed MoO3 and WO3 thin films.” Thin Solid Films 490(1): 74-80.
Comini, E., G. Faglia, et al. (2005). “Tin oxide nanobelts electrical and sensing properties.” Sensors and Actuators, B: Chemical 111-112(SUPPL): 2-6.
Kandasamy, S., A. Trinchi, et al. (2005). “Hydrogen and hydrocarbon gas sensing performance of Pt/WO3/SiC MROSiC devices.” Sensors and Actuators, B: Chemical 111-112(SUPPL): 111-116.
Comini, E., G. Faglia, et al. (2005). SnO2 sub-micron wires for gas sensors, Seoul, South Korea, Institute of Electrical and Electronics Engineers Computer Society, Piscataway, NJ 08855-1331, United States. (lithography and sputtering form a pattern of wires in the sub-micron scale with a maximum lateral size for the grains for improved sensing)
Candeloro, P., E. Comini, et al. (2005). “SnO2 lithographic processing for nanopatterned gas sensors.” Journal of Vacuum Science and Technology B: Microelectronics and Nanometer Structures 23(6): 2784-2788. (SnO2 patterning for nanowires for improved sensing)
Kandasamy, S., A. Trinchi, et al. (2005). Mixed oxide Pt/(Ti—W—O)/SiC based MROSiC device for hydrocarbon gas sensing, Irvine, CA, United States, Institute of Electrical and Electronics Engineers Inc., Piscataway, NJ 08855-1331, United States. (highly sensitive Pt/(Ti—W—O)/SiC gas sensor for detection of hydrocarbons)
Comini, E., S. Bianchi, et al. (2005). Tin and indium oxide nanocrystals based gas sensors characterization, Irvine, CA, United States, Institute of Electrical and Electronics Engineers Inc., Piscataway, NJ 08855-1331, United States. (Quasi ID crystals of Tin dioxide nanowires showed superior gas sensing performances with remarkable and fast variations in the conductance at temperatures around 100 C.)
Comini, E., G. Faglia, et al. (2005). Structural and electrical characterization of cobalt oxide p-type gas sensor, Irvine, CA, United States, Institute of Electrical and Electronics Engineers Inc., Piscataway, NJ 08855-1331, United States. (Thin films of cobalt oxide spinel CoCo2O4 with p-type sensing behavior for ethanol, carbon oxide, benzene and nitrogen dioxide. It was also shown that annealing temperature influences the grain size of the nanosized cobalt oxide grains.
Wisitsoraat, A., A. Tuantranont, et al. (2005). Gas sensing properties of TiO2-WO3 and TiO2-MO3 based thin film prepared by ion-assisted E-beam evaporation, Irvine, CA, United States, Institute of Electrical and Electronics Engineers Inc., Piscataway, NJ 08855-1331, United States. (gas sensing studies of WO3 and MO3 doped TiO2 thin films for NO2)
Zanotti, L., M. Zha, et al. (2005). “Growth of tin oxide nanocrystals.” Crystal Research and Technology 40(10-11): 932-936. (nanowire shape (SnO2-NW) asw highly-sensitive and stable gas sensors).
Faglia, G., C. Baratto, et al. (2004). Metal oxide nanocrystals for gas sensing, Vienna, Austria, Institute of Electrical and Electronics Engineers Inc.
Gouma, P., E. Comini, et al. (2004). Sol-gel processed MoO3 and WO3 thin films for use as selective chemo-sensors, Perth, WA, Australia, The International Society for Optical Engineering. (MoO3 and WO3 for selective vapor detection for environmental and medical diagnosis).
Trinchi, A., S. Kaciulis, et al. (2004). “Characterization of Ga2O3 based MRISiC hydrogen gas sensors.” Sensors and Actuators, B: Chemical 103(1-2): 129-135. (hydrogen gas response of Pt/Ga2O3/SiC devices operated as Schottky diodes)
Kandasamy, S., A. Trinchi, et al. (2004). Study of Pt/TiO2/SiC schottky diode based gas sensor, Vienna, Austria, Institute of Electrical and Electronics Engineers Inc., Piscataway, NJ 08855-1331, United States.
Setkus, A., C. Baratto, et al. (2004). “Influence of metallic impurities on response kinetics in metal oxide thin film gas sensors.” Sensors and Actuators, B: Chemical 103(1-2): 448-456. (the transients of the resistance response are described by a combination of the characteristics of both the layer and the surface chemical reaction)
Zampiceni, E., E. Comini, et al. (2003). “Composition influence on the properties of sputtered Sn—W—O films.” Sensors and Actuators, B: Chemical 89(3): 225-231.
Taurino, A., M. Catalano, et al. (2003). “Structural and electrical characterisation of molybdenum-titanium mixed oxides for ethanol sensing deposited by RF sputtering.” Sensors and Actuators, B: Chemical 92(3): 286-291.
Ferroni, M., V. Guidi, et al. (2003). “Selective sublimation processing of a molybdenum-tungsten mixed oxide thin film.” Journal of Vacuum Science and Technology B: Microelectronics and Nanometer Structures 21(4): 1442-1448.
Vomiero, A., G. Della Mea, et al. (2003). “Preparation and microstructural characterization of nanosized Mo—TiO2 and Mo—W—O thin films by sputtering: Tailoring of composition and porosity by thermal treatment.” Materials Science and Engineering B: Solid-State Materials for Advanced Technology 101(1-3): 216-221.
Faglia, G., C. Baratto, et al. (2002). A selective semiconductor gas sensor based on surface photovoltage, Melbourne, VIC., Australia, SPIE. (work function of tin oxide as a function of the exposure to different gaseous species in dark and in presence of subbandgap and suprabandgap light (Surface Photovoltage measurements). The light changes the response towards gases at room temperature. The results foresee the possibility to improve semiconductor sensor selectivity by using monochromatic light at well defined frequency able to activate/deactivate surface states where species are adsorbed)
Pan, Z., Z. L. Wang, et al. (2002). “Stable and highly sensitive gas sensors based on semiconducting oxide nanobelts.” Applied Physics Letters 81(10): 1869.
Galatsis, K., Y. X. Li, et al. (2002). “Comparison of single and binary oxide MoO3, TiO2 and WO3 sol-gel gas sensors.” Sensors and Actuators, B: Chemical 83:276-280. (comparison of sol-gel prepared TiO2, WO3, and MoO3 gas sensors)
Ferroni, M., V. Guidi, et al. (2002). “Coalescence inhibition in nanosized titania films and related effects on chemoresistive properties towards ethanol.” Journal of Vacuum Science and Technology B: Microelectronics and Nanometer Structures 20(2): 523-530.
Comini, E., G. Sberveglieri, et al. (2002). “Ti—Mo and Mo—W mixed oxides for gas sensing applications.” SPIE 4936:277-284.
Comini, E. and G. Sberveglieri (2002). A new technique for the manipulation of nanostrucured metal-oxides properties, Melbourne, VIC., Australia, The International Society for Optical Engineering.
Comini, E., M. Ferroni, et al. (2002). “Nanostructured mixed oxides compounds for gas sensing applications.” Sensors and Actuators, B: Chemical 84(1): 26-32. (gas sensors based on semiconducting thin films based on Ti, W, and Mo mixed oxides)
Burresi, A., B. Serrano, et al. (2002). “SnO2 Sensors with Variable Operating Temperature for CO Detection: Selectivity Enhancement.” Proceedings of IEEE Sensors 1:361-365.
Comini, E., G. Faglia, et al. (2001). CO and NO2 response of tin oxide silicon doped thin films, Basel, Elsevier Science B.V.
Lezzi, A. M., G. P. Beretta, et al. (2001). “Influence of gaseous species transport on the response of solid state gas sensors within enclosures.” Sensors and Actuators, B: Chemical 78(1-3): 144-150.
Guidi, V., D. Boscarino, et al. (2001). “Nanosized Ti-doped MoO3 thin films for gas-sensing application.” Sensors and Actuators, B: Chemical 77(1-2): 555-560. (reversible response to CO was achieved at 300 C, fast response for both CO and NO2 about 100 C below pure MoO3 layers)
Galatsis, K., Y. X. Li, et al. (2001). An analysis of MoO3-WO3 based gas sensors for monitoring applications, Budapest, Institute of Electrical and Electronics Engineers Inc. (MoO3-WO3 by sol-gel showed exceptional gas sensing properties to NO2 and ethanol with a response of 2.3 to 1 ppm of NO2 and 50 to 500 ppm of ethanol)
Galatsis, K., Y. X. Li, et al. (2001). “RF sputtered and sol-gel prepared MoO3-TiO2 thin film gas sensors.” IEEE Instrumentation and Measurement Technology Conference 1:425-428.
Galatsis, K., Y. X. Li, et al. (2001). “Semiconductor MoO3-TiO2 thin film gas sensors.” Sensors and Actuators, B: Chemical 77(1-2): 472-477. (low evaporation temperature of MoO3 cause sensors instability and irreversibility at high operating temperatures)
Comini, E., G. Sberveglieri, et al. (2001). “Production and characterization of titanium and iron oxide nano-sized thin films.” Journal of Materials Research 16(6): 1559-1564.
Comini, E., V. Guidi, et al. (2001). “CO sensing properties of titanium and iron oxide nanosized thin films.” Sensors and Actuators, B: Chemical 77(1-2): 16-21.
Comini, E., G. Faglia, et al. (2001). “CO and NO2 response of tin oxide silicon doped thin films.” Sensors and Actuators, B: Chemical 76:270-274. (15 ppm of CO and 200 ppb of NO2 with a response time of approximately 2-5 min)
Sberveglieri, G., E. Comini, et al. (2000). “Titanium dioxide thin films prepared for alcohol microsensor applications.” Sensors and Actuators, B: Chemical 66(1): 139-141. (Nanosized TiO2 thin films with different doping concentrations on alumina using a sol-gel)
Guidi, V., E. Comini, et al. (2000). “Study on nanosized TiO/WO3 thin films achieved by radio frequency sputtering.” Journal of Vacuum Science and Technology, Part A: Vacuum, Surfaces and Films 18(2): 509-514.
Guidi, V., D. Boscarino, et al. (2000). “Preparation and characterization of titanium-tungsten sensors.” Sensors and Actuators, B: Chemical 65(1): 264-266.
Garzella, C., E. Comini, et al. (2000). “TiO2 thin films by a novel sol-gel processing for gas sensor applications.” Sensors and Actuators, B: Chemical 68(1): 189-196 (sol-gel nanostructured films of pure anatase TiO2 after annealing at 500 C)
Comini, E., G. Sberveglieri, et al. (2000). “Ti—W—O sputtered thin film as n- or p-type gas sensors.” Sensors and Actuators, B: Chemical 70(1-3): 108-114.
Comini, E., G. Sberveglieri, et al. (2000). “NO2 monitoring with a novel p-type material: TiO.” Sensors and Actuators, B: Chemical 68(1): 175-183.
Comini, E., G. Faglia, et al. (2000). “Sensitivity enhancement towards ethanol and methanol of TiO₂ films doped with Pt and Nb.” Sensors and Actuators, B: Chemical 64(1): 169-174.
Comini, E., G. Faglia, et al. (2000). “Carbon monoxide response of molybdenum oxide thin films deposited by different techniques.” Sensors and Actuators, B: Chemical 68(1): 168-174.
Baratto, C., G. Sberveglieri, et al. (2000). “Gold-catalysed porous silicon for NOx sensing.” Sensors and Actuators, B: Chemical 68(1): 74-80. (Porous silicon from n-type silicon wafer for NO2 and NO at room temperature)
Baratto, C., E. Comini, et al. (2000). “Gas detection with a porous silicon based sensor.” Sensors and Actuators, B: Chemical 65(1): 257-259. (PS photoluminescence to 250 ppm of carbon monoxide)
Sberveglieri, G., C. Baratto, et al. (1999). “Recent progress on gas sensors based on semiconducting thin films.” Conference on Optoelectronic & Microelectronic Materials and Devices, Proceedings, COMMAD: 65-72.

### (Pulsed Temperature, Use of UV Irradiation)

Guidi, V., M. C. Carotta, et al. (1999). “Preparation of nanosized titania thick and thin films as gas-sensors.” Sensors and Actuators, B: Chemical B57(1-3): 197-200. (Nanosized titania operated within a remarkably lower temperature range (350-800 C) with respect to previously existing titania bulk sensors)
Ferroni, M., D. Boscarino, et al. (1999). “Nanosized thin films of tungsten-titanium mixed oxides as gas sensors.” Sensors and Actuators, B: Chemical B58(1-3): 289-294.
Faglia, G., E. Comini, et al. (1999). “Micromachined gas sensors for environmental pollutants.” Microsystem Technologies 6(2): 54-59. (pulsed temperature reaches steady state conditions (about 40 ms). The sensor heater is periodically supplied for hundred of milliseconds, and kept off for seconds or more.)
Faglia, G., E. Comini, et al. (1999). “Very low power consumption micromachined CO sensors.” Sensors and Actuators, B: Chemical B55(2-3): 140-146. (sensor heater is periodically supplied each 0.5-180 s, with a duty cycle of 100 ms)
Comini, E., G. Faglia, et al. (1999). “Alcohol and organic vapours sensor based on nano-sized TiO2 thin film.” Conference on Optoelectronic & Microelectronic Materials and Devices, Proceedings, COMMAD: 302-305 (nanosized TiO2 thin films using sol-gel process on alumina with Pt enhance the response towards toluene and ethanol)
Bogdanov, P., M. Ivanovskaya, et al. (1999). “Effect of nickel ions on sensitivity of In2O3 thin film sensors to NO2.” Sensors and Actuators, B: Chemical B57(1-3): 153-158.
Faglia, G., E. Comini, et al. (1998). “Square and collinear four probe array and Hall measurements on metal oxide thin film gas sensors.” Sensors and Actuators, B: Chemical B53(1-2): 69-75.
10 For both H2 and CO at 590K on SnO2, the probability β of desorption is calculated as ˜2×103. probability ν of oxidation reaction/unit time, which is ˜2-7×103 for H2 and ˜8-30×103 for CO at 590K on SnO2
11 Comini, E., A. Cristaslli, et al. (2000). “Light enhanced gas sensing properties of indium oxide and tin dioxide sensors.” Sensors and Actuators, B: Chemical 65(1): 260-263 (UV light on SnO2 and In2O3 semiconductor gas sensors for CO and NO2 for the development of sensor working at room temperature).
Comini, E., G. Faglia, et al. (2001). “UV light activation of tin oxide thin films for NO2 sensing at low temperatures.” Sensors and Actuators, B: Chemical 78(1-3): 73-77 (UV light on SnO2 thin film reduces response and recovery times)
Chen, H.-W., Y. Ku, et al. (2007). “Effect of LED optical characteristics of temporal behavior of o-cresol decomposition by UV/TiO2 process.” Journal of Chemical Technology and Biotechnology 82(7): 626-635 (UV-LED for the photocatalytic decomposition of o-cresol in aqueous solution)
Huang, X., H. Wang, et al. (2009). “Sterilization system for air purifier by combining ultraviolet light emitting diodes with TiO2.” Journal of Chemical Technology and Biotechnology 84(10): 1437-1440.
Ku, Y., Y.-C. Lee, et al. (2006). “Photocatalytic decomposition of 2-chlorophenol in aqueous solution by UV/TiO2 process with applied external bias voltage.” Journal of Hazardous Materials 138(2): 350-356.
Arpac, E., F. Sayilkan, et al. (2007). “Photocatalytic performance of Sn-doped and undoped TiO2 nanostructured thin films under UV and vis-lights.” Journal of Hazardous Materials 140(1-2): 69-74. (Nanostructure-TiO2 based thin films have been prepared on glass substrate by spin-coating technique. Hydrothermally synthesized nano-TiO2 particles are fully anatase crystalline form)
Zhang, J. L., Z. F. Yuan, et al. (2010). “Photocatalytic activity of TiO2 nanotube layers coated with Ag and Pt.” Advances in Applied Ceramics 109(6): 362-366.
Yates, J. J. (2009). “Photochemistry on TiO2: Mechanisms Behind the Surface Chemistry.” Reprint: Photochemistry on TiO2: Mechanisms Behind the Surface Chemistry.: 9p. (photooxidation of a monolayer of hydrocarbon (n-hexane) at equilibrium with ppm concentration of n-hexane in O2 at 1 atmosphere pressure)
Yang, X., C. Cao, et al. (2009). Photocatalytic activity of multi-doped TiO2 nanoparticles for degradation of rhodamine B, Nashville, TN, United states, American Institute of Chemical Engineers.
Wu, K.-R., C.-W. Yen, et al. (2009). Visible-light-responsive layered titanium oxide/tin indium oxide catalysts for hydrogen production, 25650 North Lewis Way, Stevenson Ranch, CA 9138-1439, United States, American Scientific Publishers. (Visible-light-responsive layered titanium dioxide/tin indium oxide (TiO2/ITO) catalysts prepared on unheated glass slides by DC magnetron
Wang, Y., I. Ramos, et al. (2007). “Optical bandgap and photoconductance of electrospun tin oxide nanofibers.” Journal of Applied Physics 102(9): 093517. (Optical and photoconductive properties of transparent SnO2 nanofibers, made from C22 H44 O4 Sn via electrospinning and metallorganic decomposition)
Wang, R., X. Wang, et al. (2010). “Advanced visible-light-driven self-cleaning cotton by Au/TiO2/SiO2 photocatalysts.” ACS Applied Materials and Interfaces 2(1): 82-85.
Vukievic, U., S. Ziemian, et al. (2008). “Self-cleaning anatase nanorods: Photocatalytic removal of structure directing agents and subsequent surface modification.” Journal of Materials Chemistry 18(29): 3448-3453.
Van Overschelde, O., G. Guisbiers, et al. (2008). “Alternative to classic annealing treatments for fractally patterned TiO2 thin films.” Journal of Applied Physics 104(10).
Tamaki, Y., K. Hara, et al. (2009). “Femtosecond visible-to-IR spectroscopy of TiO2 nanocrystalline films: Elucidation of the electron mobility before deep trapping.” Journal of Physical Chemistry C 113(27): 11741-11746 (transient absorption of nanocrystalline TiO₂ films in the visible-to-IR wavelength region was measured under UV excitation at 266 nm. deep trapping was found to occur with a time constant of 500 ps)
Sun, S., J. Ding, et al. (2010). “Photocatalytic oxidation of gaseous formaldehyde on TiO2: An in situ DRIFTS study.” Catalysis Letters 137(3-4): 239-246.
Pramanik, S. K., S. Das, et al. (2008). “Photodegradation of the herbicide penoxsulam in aqueous methanol and acetonitrile.” Journal of Environmental Science and Health-Part B Pesticides, Food Contaminants, and Agricultural Wastes 43(7): 569-575. (The phototransformation of penoxsulam was studied under UV light (max 290 nm) and sunlight in aqueous methanol and acetonitrile solvent system using TiO2 as sensitizer)
Neclavannan, M. G. and C. A. Basha (2010). “Ag—TiO2 doped photo catalytic degradation of Procion blue H-B dye in textile washwater.” Toxicological and Environmental Chemistry 92(8): 1423-1434. (The enhanced activity of silver-doped TiO22 is due to the enrichment of electron-hole separation by electron trapping of silver particles)
Mohamed, M. M. and M. M. Al-Esaimi (2006). “Characterization, adsorption and photocatalytic activity of vanadium-doped TiO2 and sulfated TiO2 (rutile) catalysts: Degradation of methylene blue dye.” Journal of Molecular Catalysis A: Chemical 255(1-2): 53-61.
Ma, C. M., Y. Ku, et al. (2008). “A new optical fiber reactor for the photocatalytic degradation of gaseous organic contaminants.” Reaction Kinetics and Catalysis Letters 94(2): 199-206.
Ma, C.-M. and Y. Ku (2006). “Photocatalytic oxidation of gaseous trichloroethylene by UV/TiO2 process.” Reaction Kinetics and Catalysis Letters 89(2): 293-301.
Liu, Y., L. Chen, et al. (2010). “TiO2 nanoflakes modified with gold nanoparticles as photocatalysts with high activity and durability under near UV irradiation.” Journal of Physical Chemistry C 114(3): 1641-1645.
Liao, M.-H., C.-H. Hsu, et al. (2006). “Preparation and properties of amorphous titania-coated zinc oxide nanoparticles.” Journal of Solid State Chemistry 179(7): 2020-2026. (Amorphous TiO2-coated ZnO nanoparticles by sol-gel coating. UV-VIS and photoluminescence intensity of ZnO direct-gap cores could be significantly enhanced by the indirect gap TiO2 shell)
Liang, C.-H., H.-Y. Chang, et al. (2008). Preparation and characterization of sol-gel-derived TiO2/ITO photoelectrodes, 5 Toh Tuck Link, Singapore, 596224, Singapore, World Scientific Publishing Co. Pte. Ltd.
Lee, D.-G., J.-T. Hong, et al. (2009). “A study on sterilization characteristics of elliptical reactor by using xenon flashlamp and photocatalyst.” Transactions of the Korean Institute of Electrical Engineers 58(3): 559-565.

Ku, Y., K.-Y. Tseng, et al. (2008). “Photocatalytic decomposition of gaseous acetone using TiO2 and Pt/TiO2 catalysts.” International Journal of Chemical Kinetics 40(4): 209-216.
Ku, Y., W.-H. Lee, et al. (2004). “Photocatalytic reduction of carbonate in aqueous solution by UV/TiO2 process.” Journal of Molecular Catalysis A: Chemical 212(1-2): 191-196 (The main products of the photocatalytic reduction of carbonate by the UV/TiO2 reduction process were found to be methanol and methane)
Klosek, S. and D. Raftery (2001). “Visible light driven V-doped TiO2 photocatalyst and its photooxidation of ethanol.” Journal of Physical Chemistry B 105: 2815-2819.
Kim, T.-H., M. Matsuoka, et al. (2010). “Photocatalytic activity of visible light-responsive TiO2 thin films deposited on various anodized Ti-metal substrates by a RF magnetron sputtering method.” Research on Chemical Intermediates 36(3): 319-326.
Kibanova, D., J. Cervini-Silva, et al. (2009). “Efficiency of clay-TiO2 nanocomposites on the photocatalytic elimination of a model hydrophobic air pollutant.” Environmental Science and Technology 43(5): 1500-1506.
Khan, M. A., H. Lee, et al. (2005). Synthesis and application of ultrahigh crystalline titania nanotubes, Cincinnati, OH, United states, American Institute of Chemical Engineers.
Kambalal, V. S. R. and R. Naidu (2009). “Disinfection studies on TiO2 thin films prepared by a sol-gel method.” Journal of Biomedical Nanotechnology 5: 121-129.
Hazra, S. K., S. R. Tripathy, et al. (2006). “Characterizations of porous titania thin films produced by electrochemical etching.” Materials Science and Engineering B: Solid-State Materials for Advanced Technology 131: 135-141. (Porous titania templates were prepared by thermal oxidation followed by electrochemical etching, with high sensitivity and fast response in 500 and 1000 ppm hydrogen of 5 s at 300 C)
Han, C.-H., D.-W. Hong, et al. (2007). “Catalytic combustion type hydrogen gas sensor using TiO2 and UV-LED.” Sensors and Actuators, B: Chemical 125: 224-228 (operable at a temperature of 82 C in the presence of UV-LED to measure hydrogen concentration in the range of 0.5-5%. The reduction of operating temperature from 253 to 82 C for hydrogen gas sensing in the presence of UV radiation is attributed to the enhanced activity of the chemisorbed oxygen ions which facilitate a higher rate of reaction between O2 and H2)
Gomathi Devi, L. N. and G. Krishnamurthy (2008). “Photocatalytic degradation of the herbicide pendimethalin using nanoparticles of BaTiO3/TiO2 prepared by gel to crystalline conversion method: A kinetic approach.” Journal of Environmental Science and Health-Part B Pesticides, Food Contaminants, and Agricultural Wastes 43(7): 553-561.
Comini, E., A. Cristalli, et al. (2000). “Light enhanced gas sensing properties of indium oxide and tin dioxide sensors.” Sensors and Actuators, B: Chemical 65(1): 260-263. The effects of UV light illumination on the performance of SnO2 and In2O3 semiconductor gas sensors toward CO and NO2 are reported. The sample were prepared with DC sputtering in Ar atmospheres by the Rheotaxial Growth and Thermal Oxidation (RGTO) technique and with reactive magnetron sputtering in Ar and O2 atmosphere, respectively. Results are quite promising for the development of sensor working at room temperature.
Chen, H.-W., Y. Ku, et al. (2007). “Photodecomposition of o-cresol by UV-LED/TiO2 process with controlled periodic illumination.” Chemosphere 69(2): 184-190. (photonic efficiency and temporal decomposition behavior of o-cresol by UV/TiO2 using light emitting diodes as the light source with UV light intensity of 6.7 W m−2)
Bosc, F., A. Ayral, et al. (2008). Mesostructured anatase TiO2 for visible light and UV photocatalysis with confinement effect and semiconductor coupling, 3 Park Avenue, New York, NY 10016-5990, United States, (coupling between TiO2 and WO3 semiconductors, leading to an improved photogenerated charge separation)
Baratto, C., S. Bianchi, et al. (2007). Metal oxide nanowires for optical gas sensing, San Jose, CA, United States, SPIE-International Society for Optical Engineering, Bellingham WA, WA 98227-0010, United States.
Malagu, C., E. Comini, et al. (2003). Scanning tunneling spectroscopy and photo-activation in WO3 gas sensors, Toronto, Ont., Canada, Institute of Electrical and Electronics Engineers Inc. (Pinning of the Fermi level due to surface states is decreased when the sample is illuminated at low temperature, whereas at high temperature the effect is masked by the high density of free carriers)
12 Comini, E., G. Sberveglieri, et al. (2003). “Novel p-type gas sensing thin film based on Nb—Ti—O mixed oxides.” Proceedings of IEEE Sensors 2: 1116-1119. (p-type niobium and titanium mixed oxides, compared to n-type response typical of TiO2 and the most of metal oxide sensors for the discrimination of different gases)
Galatsis, K., Y. X. Li, et al. (2001). “RF sputtered and sol-gel prepared MoO3-TiO2 thin film gas sensors.” IEEE Instrumentation and Measurement Technology Conference 1:425-428. (MoO3-TiO2 thin film response of 1.75 to 25 ppm of CO and 2.8 to 2 ppm of NO2)
Daniel, D. and I. G. R. Gutz (2007). “Microfluidic cell with a TiO2-modified gold electrode irradiated by an UV-LED for in situ photocatalytic decomposition of organic matter and its potentiality for voltammetric analysis of metal ions.” Electrochemistry Communications 9: 522-528.
Chen, H.-W., Y. Ku, et al. (2007). “Effect of LED optical characteristics of temporal behavior of o-cresol decomposition by UV/TiO2 process.” Journal of Chemical Technology and Biotechnology 82(7): 626-635.
Huang, X., H. Wang, et al. (2009). “Sterilization system for air purifier by combining ultraviolet light emitting diodes with TiO2.” Journal of Chemical Technology and Biotechnology 84(10): 1437-1440.
Nebatti, A., C. Pflitsch, et al. (2010). “Sol-gel-deposition of thin TiO2: Eu3+ thermographic phosphor films.” Progress in Organic Coatings 68(1-2): 146-150. (anatase doped europium (III) used as a thermographic phosphor)
Yoon, J.-H. and J.-S. Kim (2010). “Investigation of photocatalytic reaction for the titanium dioxide-phosphor composite.” Ionics 16(2): 131-135
Lu, N., S. Chen, et al. (2008). “Synthesis of molecular imprinted polymer modified TiO2 nanotube array electrode and their photoelectrocatalytic activity.” Journal of Solid State Chemistry 181(10): 2852-2858.
Yang, D.-H., M.-J. Ju, et al. (2006). “Design of highly efficient receptor sites by combination of cyclodextrin units and molecular cavity in TiO2 ultrathin layer.” Biosensors and Bioelectronics 22(3): 388-392.
Zhao, J., C. Jia, et al. (2008). “Structural and photoluminescence properties of europium-doped titania nanofibers prepared by electrospinning method.” Journal of Alloys and Compounds 455(1-2): 497-500 (quench effects)
Wisitsoraat, A., A. Tuantranont, et al. (2009). “Characterization of n-type and p-type semiconductor gas sensors based on NiOx doped TiO2 thin films.” Thin Solid Films 517(8): 2775-2780. (gas-sensing response differences between n-type and p-type NiOx doped TiO2 thin film)
Fujikawa, S., E. Muto, et al. (2009). “Nanochannel design by molecular imprinting on a free-standing ultrathin titania membrane.” Langmuir 25(19): 11563-11568. (imprinting of the template molecule in the film resulted in the formation of a size-selective channel across a 40 nm thickness)
Knorr, F. J., D. Zhang, et al. (2007). “Influence of TiCl4 treatment on surface defect photoluminescence in pure and mixed-phase nanocrystalline TiO2.” Langmuir 23(17): 8686-8690. (Room-temperature UV-excited photoluminescence spectra for nanocrystalline films of anatase, rutile, and mixed-phase)
Cai, Z.-F., H.-J. Dai, et al. (2008). “Molecular imprinting and adsorption of metallothionein on nanocrystalline titania membranes.” Applied Surface Science 254(15): 4457-4461.
Arpac, E., F. Sayilkan, et al. (2007). “Photocatalytic performance of Sn-doped and undoped TiO2 nanostructured thin films under UV and vis-lights.” Journal of Hazardous Materials 140(1-2): 69-74.
Barreca, D., E. Comini, et al. (2007). “First example of ZnO—TiO2 nanocomposites by chemical vapor deposition: Structure, morphology, composition, and gas sensing performances.” Chemistry of Materials 19(23): 5642-5649.
Shen, X., L. Zhu, et al. (2009). “Inorganic molecular imprinted titanium dioxide photocatalyst: Synthesis, characterization and its application for efficient and selective degradation of phthalate esters.” Journal of Materials Chemistry 19(27): 4843-4851.
Comini, E., G. Faglia, et al. (1999). “Alcohol and organic vapours sensor based on nano-sized TiO2 thin film.” Conference on Optoelectronic & Microelectronic Materials and Devices, Proceedings, COMMAD: 302-305.
Zhang, J. L., Z. F. Yuan, et al. (2010). “Photocatalytic activity of TiO2 nanotube layers coated with Ag and Pt.” Advances in Applied Ceramics 109(6): 362-366.
Zakrzewska, K., M. Radecka, et al. (2006). Response and sensitivity of TiO2-SnO2 semiconducting sensors for reducing gases. Optoelectronic and Electronic Sensors VI, Jun. 19, 2006-Jun. 22, 2006, Zakopane, Poland, SPIE (TiO2-SnO2 mixed oxide semiconductors for hydrogen gas sensors)
Zakrzewska, K. (2001). Mixed oxides as gas sensors. 2nd InternationalSeminar on Semiconductor Gas Sensors, Sep. 25, 2000-Sep. 28, 2000, Ustron, Poland, Elsevier. (SnO2-WO3, TiO2-WO3 and SnO2-TiO₂, and importance of non-destructive optical methods of measurements)
Yoriya, S., H. E. Prakasam, et al. (2006). “Initial studies on the hydrogen gas sensing properties of highly-ordered high aspect ratio TiO2 nanotube-arrays 20 m to 222 m in length.” Sensor Letters 4 334-339. (hydrogen gas sensing properties of self-aligned highly-ordered TiO2 nanotube arrays having lengths up to 222 m with a length-to-outer diameter aspect ratio of 1,500 made by potentiostatic anodization of Ti foil. The as-prepared nanotubes are amorphous and show no gas-sensing capabilities. The nanotube arrays crystallize upon annealing at elevated temperatures, 550 C, and subsequently demonstrate excellent hydrogen gas sensing capabilities but suffer from significant response and recovery times)
Yates, J. J. (2009). “Photochemistry on TiO2: Mechanisms Behind the Surface Chemistry.” 9p. (The UV-induced photodesorption of O2 from TiO2(110) and the hydrophilic effect caused by UV irradiation on TiO2)
Yao, H.-C., T.-C. Tsia, et al. (2007). “Effect of annealing on the Sn-doped TiO2 films prepared by DC/RF cosputtering.” Journal of the Electrochemical Society 154(12): G284-G290.
Wisitsoraat, A., A. Tuantranont, et al. (2006). Gas-sensing characterization of TiO2-ZnO based thin film, Daegu, Korea, Republic of, Institute of Electrical and Electronics Engineers Inc.
Wisitsoraat, A., A. Tuantranont, et al. (2005). Gas sensing properties of TiO2-WO3 and TiO2-MO3 based thin film prepared by ion-assisted E-beam evaporation, Irvine, CA, United States, Institute of Electrical and Electronics Engineers Inc., Piscataway, NJ 08855-1331, United States.
Wisitsoraat, A., E. Comini, et al. (2007). TiO2 based nanocrystalline thin film gas sensors prepared by ion-assisted electron beam evaporation, Bangkok, Thailand, Institute of Electrical and Electronics Engineers Computer Society, Piscataway, NJ 08855-1331, United States. (N-type and p-type TiO2 gassensing layers have been deposited by doping with various metal oxide materials including WO3, MoO3, and NiOx)
Wisitsoraat, A., E. Comini, et al. (2007). Studies of TiO2 based mixed oxide thin film materials prepared by ion-assisted electron beam evaporation for gas sensing applications, San Francisco, CA, United states, Materials Research Society.
Weng, M.-H., R. Mahapatra, et al. (2007). Trap-assisted gas sensing mechanism in Pd/TiO2/SiO2/SiC capacitors at high temperatures, 445 Hoes Lane/P.O. Box 1331, Piscataway, NJ 08855-1331, United States, Institute of Electrical and Electronics Engineers Inc. (capacitative sensor mechanism)
Varghese, O. K., D. Gong, et al. (2003). Hydrogen sensing using titania nanotubes. Proceedings of the Ninth International Meeting on Chemical Engineering, Jul. 7, 2003-Jul. 10, 2003, Boston, MA, United states, Elsevier. (Titanium dioxide nanotubes are highly sensitive to hydrogen with response times of approximately 150 s)
Topalian, Z., J. M. Smulko, et al. (2007). “Resistance noise in TiO2-based thin film gas sensors under ultraviolet irradiation.” Journal of Physics: Conference Series 76 (2007) 76: 1-5. (Resistance fluctuations in thin crystalline TiO2 films were investigated for gas sensing while irradiated by 370 nm UV) light in the presence of H2S. A prominent change in resistance noise level was discovered as the irradiated film was exposed to a gas containing 1.5 ppm of H2S, while no change was observed in the absence of UV. This effect is possibly due to decomposition of the adsorbed gas, via photocatalysis induced by TiO2, or to a decrease of the potential barrier between the charged grains)
Tamaki, Y., K. Hara, et al. (2009). “Femtosecond visible-to-IR spectroscopy of TiO2 nanocrystalline films: Elucidation of the electron mobility before deep trapping.” Journal of Physical Chemistry C 113(27): 11741-11746. (The transient absorption of nanocrystalline TiO2 films in the visible-to-IR wavelength region was measured under UV excitation at 266 nm in order to purposely generate plural electron-hole pairs in single nanoparticles. The mobility of the electrons before their deep trapping was found to occur with a time constant of 500 ps)
Sun, S., J. Ding, et al. (2010). “Photocatalytic oxidation of gaseous formaldehyde on TiO2: An in situ DRIFTS study.” Catalysis Letters 137(3-4): 239-246. (With UV irradiation, the adsorbed formaldehyde rapidly converts to the formate species even on pure TiO2 at room temperature and atmospheric pressure)
Smestad, G. P. (1992). Luminescence, radiative recombination, and current voltage characteristics in sensitized TiO2 solar cells, Toulouse, Fr, Publ by Int Soc for Optical Engineering.
Shuo, B., D. Dongyan, et al. (2009). Fabrication and hydrogen sensing properties of titania nanotubes. 2009 International Conference on Electronic Packaging Technology and High Density Packaging, ICEPT-HDP 2009 Aug. 10, 2009-Aug. 13, 2009, Beijing, China, IEEE Computer Society (good hydrogen sensing properties at room temperature)
Sennik, E., Z. Colak, et al. (2010). “Synthesis of highly-ordered TiO2 nanotubes for a hydrogen sensor.” International Journal of Hydrogen Energy 35(: 4420-4427. (Highly-ordered, vertically oriented TiO2 nanotubes with chemisorption of H2 on the highly active nanotube surface)

Sberveglieri, G., E. Comini, et al. (2000). “Titanium dioxide thin films prepared for alcohol microsensor applications.” Sensors and Actuators, B: Chemical 66(1): 139-141. (Nanosized TiO2 thin films with different doping concentrations on alumina substrates were prepared for for alcohol sensing are insensitive to interfering gases like benzene (10 ppm), CO (200 ppm), NO2 (6 ppm) at operating temperatures in the range of 300-500 C)
Sagawa, T., M. Kudo, et al. (2006). Surface molecularly imprinted TiO2 nanoparticle for photoreduction of viologen, San Francisco, CA, United states, Materials Research Society.
Ren, F., L. Huang, et al. (2010). “Grain boundaries dependent hydrogen sensitivity in MAO—TiO2 thin films sensors.” Sensors and Actuators, B: Chemical 148: 195-199.
Osterlund, L. and A. Mattsson (2006). Surface characteristics and electronic structure of photocatalytic reactions on TiO2 and doped TiO2 nanoparticles, San Diego, CA, United States, International Society for Optical Engineering, Bellingham WA, WA 98227-0010, United States.
Moon, W. J., J. H. Yu, et al. (2004). Selective gas detection of SnO2-TiO2 gas sensors, Kluwer Academic Publishers.

Melnyk, V., V. Shymanovska, et al. (2005). Low-temperature luminescence of different TiO2 modifications, Elsevier.
Ma, Y., J. Zhang, et al. (2010). “Synthesis and characterization of thermally stable Sm,N co-doped TiO2 with highly visible light activity.” Journal of Hazardous Materials 182(1-3): 386-393.
Ma, C. M., Y. Ku, et al. (2008). “A new optical fiber reactor for the photocatalytic degradation of gaseous organic contaminants.” Reaction Kinetics and Catalysis Letters 94(2): 199-206.
Ma, C.-M. and Y. Ku (2006). “Photocatalytic oxidation of gaseous trichloroethylene by UV/TiO2 process.” Reaction Kinetics and Catalysis Letters 89(2): 293-301.
Zhang, M. L. et al. (2008). “Fast response of undoped and Li-doped titania thick-films at low temperature.” Sensors and Actuators, B: Chemical 131: 680-686. (fast response of undoped and Li-doped TiO2 operating at low temperature to hydrogen and oxygen. At less than 3 mol % Li content, the response time of the Li-doped TiO2 gas sensors is much shorter than that of pure TiO2)
Lai, Y. K., L. Sun, et al. (2005). “Optical and electrical characterization of TiO2 nanotube arrays on titanium substrate.” Applied Surface Science 252(4): 1101-1106. (four overlapped peaks was observed in the photoluminescence)
Ku, Y., J.-S. Chen, et al. (2007). “Decomposition of benzene and toluene in air streams in fixed-film photoreactors coated with TiO2 catalyst.” Journal of the Air and Waste Management Association 57(3): 279-285.
Kawai, T., A. Shimogaki, et al. (2008). “Crystalline-phase dependent red luminescence of TiO2: Eu3+ particles prepared by a sol-gel method.” Philosophical Magazine Letters 88(1): 1-7.
Kandasamy, S., A. Trinchi, et al. (2004). Study of Pt/TiO2/SiC schottky diode based gas sensor, Vienna, Austria, Institute of Electrical and Electronics Engineers Inc., Piscataway, NJ 08855-1331, United States.
Kandasamy, S., A. Trinchi, et al. (2005). Mixed oxide Pt/(Ti—W—O)/SiC based MROSiC device for hydrocarbon gas sensing, Irvine, CA, United States, Institute of Electrical and Electronics Engineers Inc., Piscataway, NJ 08855-1331, United States (highly sensitive gas sensor employing mixed oxide (Ti—W—O) for the detection of hydrocarbons.)
Jones, B. J., M. J. Vergne, et al. (2007). “Cleavage of peptides and proteins using light-generated radicals from titanium dioxide.” Analytical Chemistry 79(4): 1327-1332. (hydroxyl radicals, produced at the TiO2 surface using UV light, are present for only hundreds of microseconds and are confined to a defined reagent zone, for cleavage at proline residues)
Han, C.-H., D.-W. Hong, et al. (2007). “Catalytic combustion type hydrogen gas sensor using TiO2 and UV-LED.” Sensors and Actuators, B: Chemical 125: 224-228. (thick film in the presence of UV-LED has reduction of operating temperature from 253 to 82 C for hydrogen gas sensing)
Garzella, C., E. Comini, et al. (2001). “Nanostructured TiO2 and W:TiO2 thin films by a novel sol-gel processing for alcohol sensing devices.” Microcrystalline and Nanocrystalline Semiconductors 2000 Nov. 27-30 2000 638: F5391-F5396.
Galatsis, K., Y. X. Li, et al. (2002). “Comparison of single and binary oxide MoO3, TiO₂ and WO3 sol-gel gas sensors.” Sensors and Actuators, B: Chemical 83: 276-280 (comparison of sol-gel prepared titanium dioxide (TiO2), WO3, and MoO3 single metal oxide based gas sensors
Galatsis, K., Y. X. Li, et al. (2001). “Semiconductor MoO3-TiO2 thin film gas sensors.” Sensors and Actuators, B: Chemical 77(1-2): 472-477.
Fasaki, I., I. Hotovy, et al. (2009). “Effects of post-deposition surface treatment on the optical, structural and hydrogen sensing properties of TiO2 thin films.” Thin Solid Films 518: 1103-1108.
Devi, G. S., T. Hyodo, et al. (2002). Nanostructured titania (TiO₂) as hydrogen gas sensor. Smart Materials, Structures, and Systems, Dec. 12, 2002-Dec. 14, 2002, Bangalore, India, SPIE.
Chou, J.-C. and C.-W. Chen (2009). Fabrication and application of ruthenium-doped titanium dioxide films as electrode material for ion-sensitive extended-gate FETs, 445 Hoes Lane/P.O. Box 1331, Piscataway, NJ 08855-1331, United States, Institute of Electrical and Electronics Engineers Inc.
13 Fort, A., M. Gregorkiewitz, et al. (2002). “Selectivity enhancement of SnO2 sensors by means of operating temperature modulation.” Thin Solid Films 418: 2-8. (two measurement techniques: chemical transient analysis and sensor temperature modulation)
Sberveglieri, G., C. Baratto, et al. (1999). “Recent progress on gas sensors based on semiconducting thin films.” Conference on Optoelectronic & Microelectronic Materials and Devices, Proceedings, COMMAD: 65-72. (pulsed temperature, use of UV irradiation).
14 Aroutiounian, V. M., Z. H. Mkhitaryan, et al. (2008). “Noise spectroscopy of gas sensors.” IEEE Sensors Journal 8(6): 786-790.
Chang, H.-C., L. B. Kish, et al. (2009). “Fluctuation-enhanced sensing of bacterium odors.” Sensors and Actuators, B: Chemical 142(2): 429-434.
Schmera, G., C. Kwan, et al. (2008). “Fluctuation-enhanced sensing: Status and perspectives.” IEEE Sensors Journal 8(6): 714-719. (selectivity and sensitivity of chemical sensors can be considerably improved by exploiting the information contained in microfluctuations present in the sensor system-results with Taguchi sensors, surface acoustic wave devices, MOSFET-based sensors, and nanosensors)
Kwan, C., G. Schmera, et al. (2008). “Advanced agent identification with fluctuation-enhanced sensing.” IEEE Sensors Journal 8(6): 706-713.
Kish, L. B., G. Schmera, et al. (2007). Fluctuation-enhanced sensing, Florence, Italy, SPIE, Bellingham WA, WA 98227-0010, United States.
Ederth, J., J. M. Smulko, et al. (2006). “Comparison of classical and fluctuation-enhanced gas sensing with Pd×WO3 nanoparticle films.” Sensors and Actuators, B: Chemical 113(1): 310-315.
Smulko, J. M., J. Ederth, et al. (2005). “Gas sensing by thermoelectric voltage fluctuations in SnO2 nanoparticle films.” Sensors and Actuators, B: Chemical 106(2): 708-712. (thermoelectric voltage fluctuation of monodispersed SnO2 nanoparticles films, with a mean diameter of 20 nm.
Solis, J. L., G. E. Seeton, et al. (2005). “Fluctuation-enhanced multiple-gas sensing by commercial taguchi sensors.” IEEE Sensors Journal 5(6): 1338-1345.
Kish, L. B., Y. Li, et al. (2005). “Detecting harmful gases using fluctuation-enhanced sensing with taguchi sensors.” IEEE Sensors Journal 5(4): 671-675.
Kim, J. U., L. B. Kish, et al. (2005). Identifying different types of stochastic processes with the same spectra, Austin, TX, United states, SPIE.
Torok, L. and L. B. Kish (2004). Integro-differential stochastic resonance, Maspalomas, Spain, SPIE.
Smulko, J. M., J. Ederth, et al. (2004). Resistance noise higher-order spectrums in nanoparticle gas sensors, Maspalomas, Spain, SPIE. (The resistance fluctuations of sensors in WO3 nanoparticle gas sensors with length scales is in the submicron range).
Ederth, J., J. M. Smulko, et al. (2004). Gas sensing by resistance fluctuations in Pdx WO3 nanoparticle films, Maspalomas, Spain, SPIE (changes in the resistance noise gave 300 times larger detection sensitivity than changes in the de resistance. This sensitivity reached a maximum at 250 C and was very reproducible for ethanol sensing)
Schmera, G. and L. B. Kish (2003). “Surface Diffusion Enhanced Chemical Sensing by Surface Acoustic Waves.” Reprint: Surface Diffusion Enhanced Chemical Sensing by Surface Acoustic Waves.: 6p.
15 Akiyama, Y., M. Takada, et al. (2009). “Effect of ZrO2 addition on tolerance characteristics of the electrical degradation of ZnO varistors.” IEEJ Transactions on Fundamentals and Materials 129: 320-326+324.
Atsumi, T. and H. Taimatsu (2004). “Electrical properties of ZnO varistors doped with Nb2O5 and TiO2.” Funtai Oyobi Fummatsu Yakin/Journal of the Japan Society of Powder and Powder Metallurgy 51: 269-273.
Bidadi, H., S. M. Hasanli, et al. (2010). “Temperature dependence of electrophysical characteristics of zinc oxide based varistors.” Vacuum 84: 1232-1235.
Bueno, P. R., J. A. Varela, et al. (2005). “A comparative study of thermal conductivity in ZnO- And SnO2-based varistor systems.” Journal of the American Ceramic Society 88: 2629-2631.
Chattopadhyay, S. and T. K. Nath (2009). Electrical properties of pulsed laser deposited ZnO thin films. International Conference on Nanomaterials and Devices: Processing and Applications, NADPA 2008 Dec. 11, 2008-Dec. 13, 2008, Roorkee, India, Trans Tech Publications.
Chen, W. P., K. Zhu, et al. (2008). “Hydrogen-induced failure in ZnO multilayer ceramic chip varistors with a zinc phosphate passivation layer.” Journal of the American Ceramic Society 91: 2064-2066.
Comesana, E. and G. A. Gehring (2007). “Spin polarized tunneling in a ferromagnetic Zener diode.” Applied Physics Letters 91: 142510.
Dadykin, A. A. and A. G. Naumovets (2003). “Low-macroscopic-field electron emission from piezoelectric thin films and crystals.” Materials Science and Engineering A 353: 12-21.
Frigura-Iliasa, F. M., D. Vatau, et al. (2010). “Heat dissipation improvement for ZnO based varistors.” 14th International Conference on Harmonics and Quality of Power, ICHQP 2010 Sep. 26, 2010-Sep. 29, 2010.
Gheno, S. M., R. H. G. A. Kiminami, et al. (2010). “Electric force microscopy investigations of barrier formations in ZnO-based varistors.” Journal of the European Ceramic Society 30: 549-554.
Glot, A. B., S. V. Mazurik, et al. (2010). “Current limiting and negative differential resistance in indium oxide based ceramics.” Journal of the European Ceramic Society 30: 539-544.
Gong, L.-W., Y.-F. Wen, et al. (2007). “Study on MOV characteristic of low current region in different media.” Gaodianya Jishu/High Voltage Engineering 33: 83-86.
Gubanski, A., W. Mielcarek, et al. (2009). “The effect of aluminium additive on the electrical properties of ZnO varistors.” Materials Science-Poland 27: 1207-1218.
Hasse, L., A. Konczakowska, et al. (2009). “Classification of high-voltage varistors into groups of differentiated quality.” Microelectronics Reliability 49: 1483-1490.
Hasse, L. and J. Smulko (2008). “Quality assessment of high voltage varistors by third harmonic index.” Metrology and Measurement Systems 15: 23-31.
He, J., J. Hu, et al. (2008). “ZnO varistors with high voltage gradient and low leakage current by doping rare-earth oxide.” Science in China, Series E: Technological Sciences 51: 693-701.
Hu, J., J. He, et al. (2007). High voltage gradient ZnO nonlinear resistor doped with rare-earth oxide. ICPADM 2006-8th International Conference on Properties and Applications of Dielectric Materials, Jun. 26, 2006-Jun. 30, 2006, Bali, Indonesia, Institute of Electrical and Electronics Engineers Inc.
Ke, L., D. Jiang, et al. (2010). “Fabrication of ZnO-based thick film varistors with high potential gradic.” Rare Metals 29: 390-395.
Kim, B.-J., Y. W. Lee, et al. (2010). “VO2 thin-film varistor based on metal-insulator transition.” IEEE Electron Device Letters 31: 14-16. (VO2 thin-film varistors with abrupt current jump)
Kuo, S.-T., W.-H. Tuan, et al. (2009). “Inner electrodes for multilayer varistors.” International Journal of Applied Ceramic Technology 6: 223-230.
Li, T.-Y., H.-W. Zhao, et al. (2009). “Novel varistor material based on terbium oxide.” Journal of Physics D: Applied Physics 42.
Lin, Y.-H., J. Cai, et al. (2008). “Grain boundary behavior in varistor-capacitor TiO2-rich CaCu3 Ti4O12 ceramics.” Journal of Applied Physics 103.
Long, W., J. Hu, et al. (2009). Dielectric spectroscopies of ZnO varistors with high voltage gradient under surge aging condition. 2009 IEEE 9th International Conference on the Properties and Applications of Dielectric Materials, ICPADM 2009 Jul. 19, 2009-Jul. 23, 2009, Harbin, China, Institute of Electrical and Electronics Engineers Inc.
Lu, H., Y. Wang, et al. (2009). “Structures, varistor properties, and electrical stability of ZnO thin films.” Materials Letters 63: 2321-2323 (ZnO thin films deposited by GDARE and annealed at 250 C for 2 h have strong nonlinear varistor-type I-V characteristics with a nonlinear coefficient of a single-layered ZnO thin film of 33 and that of a triple-layered sample of 62)
Meng, F.-M. (2005). “Influence of Ta2O5 on semi-conductivity properties TiO2-based varistor.” Yadian Yu Shengguang/Piezoelectrics and Acoustooptics 27: 554-556.
Moreira, M. L., S. A. Pianaro, et al. (2006). “Crystal phase analysis of SnO2-based varistor ceramic using the Rietveld method.” Materials Characterization 57: 193-198.
Ohashi, N., K. Kataoka, et al. (2009). Synthesis and characterization of ZnO/glass/ZnO structures showing highly nonlinear current-voltage characteristics, Jan. 14, 1932 Ichibancho, Aoba-ku, Sendai, 980-8544, Japan, Japan Institute of Metals (JIM).
Pandey, A., A. Prasad, et al. (2008). “Effect of manganese and cobalt doping on conductivity of ZnO based varistors: A study by complex plane modulus.” Journal of Materials Science: Materials in Electronics 19: 1122-1127.
Parra, R., Y. Maniette, et al. (2005). “The influence of yttrium on a typical SnO2 varistor system: Microstructural and electrical features.” Materials Chemistry and Physics 94:347-352.
Peng, Y.-Y., T.-E. Hsich, et al. (2009). “The conductive property of ZnO QDs-SiO2 and ZnO QDs-SiO xNy nanocomposite films.” Journal of Nanoscience and Nanotechnology 9:4892-4900.
Qi, P., J. F. Wang, et al. (2005). “(Yb,Co,Nb)-doped SnO2 varistor ceramics.” Materials Science and Engineering B: Solid-State Materials for Advanced Technology 119: 94-98.
Ramirez, M. A., W. Bassi, et al. (2008). “Comparative degradation of ZnO- and SnO2-based polycrystalline non-ohmic devices by current pulse stress.” Journal of Physics D: Applied Physics 41.
Takada, M., Y. Sato, et al. (2009). “Effect of heat treatment on tolerance characteristic for electrical degradation of Sb2O3-added ZnO varistors.” IEEJ Transactions on Fundamentals and Materials 129: 327-334+325.
Tan, D., K. Younsi, et al. (2008). Nano-enabled Metal Oxide Varistors for surge protection. 2008 IEEE International Power Modulators and High Voltage Conference, PMHVC, May 27, 2008-May 31, 2008, Las Vegas, NV, United states, Inst. of Elec. and Elec. Eng. Computer Society.
Thibodeaux, R. J. (1988). “Physics of zinc-oxide cryovaristors in high power switching applications.” IEEE Conference Record of Power Modulator Symposium: 288-291.
Wan, S., W. Lu, et al. (2010). “Low-temperature sintering and electrical properties of ZnO-Bi2O3-TiO2-Co2O3-MnCO3-based varistor with Bi2O3-B2O3 frit for multilayer chip varistor applications.” Journal of the American Ceramic Society 93: 3319-3323.
Weimer, M. A., L. F. Hakim, et al. (2008). “Ultrafast metal-insulator varistors based on tunable Al2O3tunnel junctions.” Applied Physics Letters 92 (matrix of micron-sized spherical Ni particles conformally coated with 7.5-22 nm Al2O3films exhibited transient response times (0.3 ns), capacitances (45 pF), leakage currents (33 pA), and nonlinearities (380) which were all markedly improved over conventional metal oxide varistors, resulting from Fowler-Nordheim tunneling of electrons through uniform Al2O3tunnel junctions separating adjacent particles within the matrix)
Xia, J. and X. Ni (2008). Preparation, characteristic and effect of annealing temperature of low voltage ZnO film varistor. 2008 2nd IEEE International Nanoelectronics Conference, INEC 2008 Mar. 24, 2008-Mar. 27, 2008, Shanghai, China, Inst. of Elec. and Elec. Eng. Computer Society (ZnO thin films with average size of crystal grains about 50 nm, highly c-axis oriented)
Xu, D., X.-n. Cheng, et al. (2009). “Sintering process as relevant parameter for Bi2O3 vaporization from ZnO—Bi2O3-based varistor ceramics.” Transactions of Nonferrous Metals Society of China (English Edition) 19: 1526-1532.
Yan, J., G. Gan, et al. (2010). “Effects of sintering temperature on microstructure and properties in TiO₂ varistor ceramics.” 6th China International Conference on High-Performance Ceramics, CICC-6, Aug. 16, 2009-Aug. 19, 2009 105-106: 324-328.
Yang, F., X. Zhang, et al. (2008). “Research on over voltage protection and energy absorbing characteristic of metal oxide varistor.” Wuhan Ligong Daxue Xuebao (Jiaotong Kexue Yu Gongcheng Ban)/Journal of Wuhan University of Technology (Transportation Science and Engineering) 32: 707-710.
Yao, L. and W. Lixi (2008). Recent progress of ohmic contact on ZnO. 2008 International Conference on Electronic Packaging Technology and High Density Packaging, ICEPT-HDP 2008 Jul. 28, 2008-Jul. 31, 2008, Pudong, Shanghai, China, Inst. of Elec. and Elec. Eng. Computer Society (recent advances of ohmic contacts on ZnO are analyzed and reviewed.)
Zagoruiko, Y. A., N. O. Kovalenko, et al. (2008). “ZnO films obtained by photoelectrothermal oxidation, their properties, and possibilities of practical application.” Crystallography Reports 53: 1173-1176.

Zang, G. Z., J. F. Wang, et al. (2005). “Effect of In2O3 doping and sintering on the electrical properties and the microstructure of (Co, Ta)-doped SnO2 varistors.” Journal of Non-Crystalline Solids 351: 941-945.
Zhao, K.-Y., H.-R. Zeng, et al. (2009). “Nanoscale elastic response of grain boundaries in ZnO varistors by acoustic mode AFM.” Wuji Cailiao Xuebao/Journal of Inorganic Materials 24:869-872.
16 Eg, see Yan et al, (2010) “Effects of sintering temperature on microstructure and properties in TiO2 varistor ceramics”, Applied Materials Research 105-106:324-328
17 Bomio, M. R. D., V. C. Sousa, et al. (2004). “Nonlinear behavior of TiO2-Ta2O5-MnO2 material doped with BaO and Bi2O3.” Materials Chemistry and Physics 85: 96-103.
Cassia-Santos, M. R., V. C. Sousa, et al. (2005). “Recent research developments in SnO2-based varistors.” Materials Chemistry and Physics 90: 1-9.
18 Fort, A. et al, “Metal-oxide nanowire sensors for CO detection: Characterization and modeling”, Sensors and Actuators B 148 (2010) 283-291
19 Sia, S. K. and Kricka, L. J., “Microfluidics and point-of-care testing,” Lab on a Chip 8, 1982-1983 (2008).
Chin, C. D., Laksanasopin, T., Cheung, Y. K., Steinmiller, D., Linder, V., Parsa, H., Wang, J., Moore, H., Rouse, R., Umviligihozo, G., and others, “Microfluidics-based diagnostics of infectious diseases in the developing world,” Nature medicine 17, 1015-1019 (2011).
Homola, J., Yee, S. S., and Gauglitz, G., “Surface plasmon resonance sensors: review,” Sensors and Actuators B: Chemical 54, 3 (1999).
Cooper, M. A., “Optical biosensors in drug discovery,” Nature Reviews Drug Discovery 1, 515 (2002).
20 Whittle, C. L., Fakharzadeh, S., Eades, J., and Preti, G., “Human breath odors and their use in diagnosis,” Annals of the New York Academy of Sciences 1098, 252-266 (2007).
Biggs, K. B., Camden, J. P., Anker, J. N., and Duyne, R. P. V., “Surface-Enhanced Raman Spectroscopy of Benzenethiol Adsorbed from the Gas Phase onto Silver Film over Nanosphere Surfaces: Determination of the Sticking Probability and Detection Limit Time†,” The Journal of Physical Chemistry A 113, 4581-4586 (2009).
Stuart, D. A., Biggs, K. B., and Duyne, R. P. V., “Surface-enhanced Raman spectroscopy of half-mustard agent,” Analyst 131, 568-572 (2006).
Kahn, N., Lavie, O., Paz, M., Segev, Y., and Haick, H., “Dynamic Nanoparticle-Based Flexible Sensors: Diagnosis of Ovarian Carcinoma from Exhaled Breath,” Nano letters 15, 7023-7028 (2015).
21 C. L. Whittle et al, “Human Breath Odors And Their Use In Diagnosis” Ann. N.Y. Acad. Sci. 1098: 252 (2011)
22http://ucsdnews.ucsd.edu/pressrelease/small portable sensors allow users to monitor exposure_to_pollution_on_thei https://sosa.ucsd.edu/confluence/display/CitiSensePublic/CitiSense
23 S. K. Pandey et al “Human body-odor components and their determination”, Trends in Analytical Chemistry, 30: 784-796 (2011)
R. M. Kramer, et al, “Analytical determination and detection of individual odor signatures. Proc. SPIE 8371 (2012).
24 IBM's 2012 “5-in-5 vision” predicts volatile compound “smell” sensors and “apps” for smartphones by 2017. http://ibmresearchnews.blogspot.com/2012/12/ibm-5-in-5-2012-smell.html
25 Hodgkinson, J. and Tatam, R. P., “Optical gas sensing: a review,” Measurement Science and Technology 24, 012004 (2013).
Long, F., Zhu, A., and Shi, H., “Recent advances in optical biosensors for environmental monitoring and early warning,” Sensors 13, 13928-13948 (2013)
26 Anker, J. N., Hall, W. P., Lyandres, O., Shah, N. C., Zhao, J., and Van Duyne, R. P., “Biosensing with plasmonic nanosensors,” Nature Materials 7, 442 (2008).
Stewart, M. E., Anderton, C. R., Thompson, L. B., Maria, J., Gray, S. K., Rogers, J. A., and Nuzzo, R. G., “Nanostructured plasmonic sensors,” Chemical Reviews 108, 494-521 (2008).
Gordon, R., Sinton, D., Kavanagh, K. L., and Brolo, A. G., “A new generation of sensors based on extraordinary optical transmission,” Accounts of Chemical Research 41, 1049 (2008).
27 Barnes, W. L., Dereux, A., and Ebbesen, T. W., “Surface plasmon subwavelength optics,” Nature 424, 824 (2003)
28 Bantz, K. C. et al, “Recent progress in SERS biosensing,” Phys. Chem. Chem. Phys. 13, 11551-11567 (2011)
Otto, L. M., Mohr, D. A., Johnson, T. W., Oh, S.-H., and Lindquist, N. C., “Polarization interferometry for real-time spectroscopic plasmonic sensing,” Nanoscale 7, 4226-4233 (2015).
Gao, Y., Xin, Z., Zeng, B., Gan, Q., Cheng, X., and Bartoli, F. J., “Plasmonic interferometric sensor arrays for high-performance label-free biomolecular detection,” Lab on a Chip 13, 4755-4764 (2013).
Gao, Y., Xin, Z., Gan, Q., Cheng, X., and Bartoli, F. J., “Plasmonic interferometers for label-free multiplexed sensing,” Optics express 21, 5859-5871 (2013)
29 Brolo, A. G., “Plasmonics for future biosensors,” Nature Photonics 6, 709-713 (2012).
Ebbesen, T. W., Lezec, H. J., Ghaemi, H. F., Thio, T., and Wolff, P. A., “Extraordinary optical transmission through sub-wavelength hole arrays,” Nature 391, 667 (1998).
30 Lee, S. H., et al, “Real-time full-spectral imaging and affinity measurements from 50 microfluidic channels using nanohole surface plasmon resonance,” Lab on a Chip 12, 3882-3890 (2012)
Lindquist, N. C., Lesuffleur, A., Im, H., and Oh, S. H., “Sub-micron resolution surface plasmon resonance imaging enabled by nanohole arrays with surrounding Bragg mirrors for enhanced sensitivity and isolation,” Lab on a Chip 9, 382-387 (2009).
Eftekhari, F. et al, “Nanoholes as nanochannels: flow-through plasmonic sensing,” Analytical Chemistry 81, 4308-4311 (2009).
Escobedo, C., Brolo, A. G., Gordon, R., and Sinton, D., “Flow-through vs flow-over: analysis of transport and binding in nanohole array plasmonic biosensors,” Analytical chemistry 82, 10015-10020 (2010).
31 Liedberg, B., Nylander, C., and Lundstrom, I., “Surface plasmon resonance for gas detection and biosensing,” Sensors and Actuators 4, 299 (1983).
Nylander, C., Liedberg, B., and Lind, T., “Gas detection by means of surface plasmon resonance,” Sensors and Actuators 3, 79-88 (1983).
Vukusic, P., Bryan-Brown, G., and Sambles, J., “Surface plasmon resonance on gratings as a novel means for gas sensing,” Sensors and Actuators B: Chemical 8, 155-160 (1992).
Miwa, S. and Arakawa, T., “Selective gas detection by means of surface plasmon resonance sensors,” Thin Solid Films 281, 466-468 (1996).
Notcovich, A. G., Zhuk, V., and Lipson, S., “Surface plasmon resonance phase imaging,” Applied Physics Letters 76, 1665-1667 (2000).
Wright, J. B., Cicotte, K. N., Subramania, G., Dirk, S. M., and Brener, I., “Chemoselective gas sensors based on plasmonic nanohole arrays,” Optical Materials Express 2, 1655-1662 (2012).
Bingham, J. M., Anker, J. N., Kreno, L. E., and Van Duyne, R. P., “Gas sensing with high-resolution localized surface plasmon resonance spectroscopy,” Journal of the American Chemical Society 132, 17358-17359 (2010).
Chen, Y.-Q. and Lu, C.-J., “Surface modification on silver nanoparticles for enhancing vapor selectivity of localized surface plasmon resonance sensors,” Sensors and Actuators B: Chemical 135, 492-498 (2009).
Ma, W., Yang, H., Wang, W., Gao, P., and Yao, J., “Ethanol vapor sensing properties of triangular silver nanostructures based on localized surface plasmon resonance,” Sensors 11, 8643-8653 (2011).
32 Im, H., et al, “Template-Stripped Smooth Ag Nanohole Arrays with Silica Shells for Surface Plasmon Resonance Biosensing,” ACS Nano 5, 6244 (2011).
33 Cetin, A. E., Coskun, A. F., Galarreta, B. C., Huang, M., Herman, D., Ozcan, A., and Altug, H., “Handheld high-throughput plasmonic biosensor using computational on-chip imaging,” Light: Science & Applications 3, e122 (2014).
34 Smith, E. A. and Corn, R. M., “Surface plasmon resonance imaging as a tool to monitor biomolecular interactions in an array based format,” Applied Spectroscopy 57, 320-332 (2003).
Steiner, G., “Surface plasmon resonance imaging,” Analytical and bioanalytical chemistry 379, 328-331 (2004).
Scarano, S., Mascini, M., Turner, A. P., and Minunni, M., “Surface plasmon resonance imaging for affinity-based biosensors,” Biosensors and bioelectronics 25, 957-966 (2010).
Brockman, J. M., Nelson, B. P., and Corn, R. M., “Surface plasmon resonance imaging measurements of ultrathin organic films,” Annual review of physical chemistry 51, 41-63 (2000).
35 Chen, Q., Das, D., Chitnis, D., Walls, K., Drysdale, T., Collins, S., and Cumming, D., “A CMOS image sensor integrated with plasmonic colour filters,” Plasmonics 7, 695-699 (2012).
Chen, Q., He, J., Shi, X., and Ma, Y., “Application of Surface Plasmon Polaritons in CMOS Digital Imaging, Plasmonics-Principles and Applications,” ISBN 978-953-51-0797-2, (2012).
Yokogawa, S., Burgos, S. P., and Atwater, H. A., “Plasmonic color filters for CMOS image sensor applications,” Nano Letters 12, 4349-4354 (2012).
Najiminaini, M., Vasefi, F., Kaminska, B., and Carson, J. J., “Nanohole-array-based device for 2D snapshot multispectral imaging,” Scientific reports 3, (2013).
36 Shah, R. R. et al, “Principles for measurement of chemical exposure based on recognition-driven anchoring transitions in liquid crystals”, Science 293 (5533): 1296-1299 (2001).
Cadwell K D et al, “Detection of organophosphorous nerve agents using liquid crystals supported on chemically functionalized surfaces”, Sensors and Actuators B 128 91-98 (2007).
37 N. L. Abbott et al, “A Liquid Crystal Based Gas Sensor Using Microfabricated Pillar Arrays as a Support Structure”, IEEE Sensors 2007 Conference p. 1044-1047
38 For simplicity, devices which use n-type MOX materials to generate electron charge carriers for multiplication are described. Devices which use p-type MOX materials and/or which use hole carriers are also important. Employing multiple types of detectors can generate different sensitivities for molecular gas analytes, which is important for distinguishing and identifying sensed chemicals.
39 The example shows an electron-avalanche diode with an n-type MOX sensor layer. Hole avalanche diodes, and p-type sensor layers can also be used.
40 E. Roncali et al, (2011) “Application of Silicon Photomultipliers to Positron Emission Tomography”, Annals of Biomedical Engineering DOI: 10.1007/s10439-011-0266-9
41 Henderson, R. K., E. A. G. Webster, et al. (2010). “A 3×3, 5 m pitch, 3-transistor single photon avalanche diode array with integrated 11V bias generation in 90 nm CMOS technology.” 2010 IEEE International Electron Devices Meeting, IEDM 2010 Dec. 6, 2010-Dec. 8, 2010: 14.12.11-14.12.14. (90 nm CMOS avalanche photodiodes with 3-transistor NMOS pixel circuitry-5 micron pixel pitch with 1% crosstalk, 250 Hz mean dark count rate (DCR) at 20 C, 36% photon detection efficiency at 410 nm (PDE) and 107 ps FWHM jitter. 5-stage capacitive charge pump generates the 11V breakdown voltage from a standard 2.5V supply obviating external high voltage generation)
Schuette, D. R., R. C. Westhoff, et al. (2010). “Hybridization process for back-illuminated silicon Geiger-mode avalanche photodiode arrays.” SPIE 7681: 76810P (high-performance back-illuminated silicon Geiger-mode avalanche photodiodes (GM-APDs) bonded to custom CMOS readout integrated circuits (ROICs). the oxide bonding is compatible with high-temperature processing steps that can be used to lower dark current and improve optical response in the ultraviolet)
Gersbach, M., R. Trimananda, et al. (2010). “High frame-rate TCSPC-FLIM using a novel SPAD-based image sensor.” SPIE-Detectors and Imaging Devices: Infrared, Focal Plane, Single Photon 7780: 77801H. (fully integrated image sensor containing 3232 pixels and fabricated in a 130 nm CMOS technology. The chip produces an overall data rate of 10 Gb/s in terms of time-of-arrival measurements in each pixel. low noise (100 Hz) and high photon detection probability (up to 35%) ensure a good photon economy over the visible spectrum for fast TCSPC-FLIM recordings such as in neuron signaling)
McClish, M., P. Dokhale, et al. (2010). “Performance measurements of CMOS position sensitive solid-state photomultipliers.” IEEE Transactions on Nuclear Science 57: 2280-2286.
Hong, K. J., Y. Choi, et al. (2009). Development of PET using 4×4 array of large size geiger-mode avalanche photodiode. 2009 IEEE Nuclear Science Symposium Conference Record, NSS/MIC, Orlando, FL (Geiger-mode avalanche photodiode (GAPDs) operated at a bias voltage of 32 V for a gain of 3.5×106)
Berard, P., M. Bergeron, et al. (2009). “Development of a 64-channel APD detector module with individual pixel readout for submillimetre spatial resolution in PET.” Nuclear Instruments and Methods in Physics Research, Section A: Accelerators, Spectrometers, Detectors and Associated Equipment 610:20-23.
Rech, I., A. Gulinatti, et al. (2009). “High performance Silicon.” SPIE 7320 (Advanced Photon Counting Techniques III): 73200H. (review of SPADs)
Deen, M. J., M. M. El-Desouki, et al. (2008). CMOS image sensors and camera-on-a-chip for low-light level biomedical applications. 2008 IEEE International Conference on Electron Devices and Solid-State Circuits, EDSSC (A fully integrated, 16×16 pixel avalanche photodiode CMOS camera-on-a-chip, fabricated in a standard CMOS 0.18 m technology, a fill-factor of 60% with all digital and analog blocks implemented on-chip)
Stoppa, D., L. Pancheri, et al. (2007). “A CMOS 3-D imager based on single photon avalanche diode.” IEEE Transactions on Circuits and Systems I: Regular Papers 54: 4-12. (64-pixel linear array in high-voltage 0.8 m CMOS with reduced pixel read-out dead-time for a high frame rate imaging)
Zappa, F., S. Tisa, et al. (2006). “Single-photon avalanche diode arrays for fast transients and adaptive optics.” IEEE Transactions on Instrumentation and Measurement 55: 365-374. (60 single-photon avalanche diode array (SPADA), free from read-out noise, with 10 kHz frame rate and nanosecond electronic gating and an integrated active-quenching circuit (AQC) for each pixel of the array)
Niclass, C., M. Sergio, et al. (2006). “A single photon avalanche diode array fabricated in 0.35m CMOS and based on an event-driven readout for TCSPC experiments.” Advanced Photon Counting Techniques, Oct. 1, 2006-Oct. 3, 2006 6372: 63720S. (single photon avalanche diode array in 0.35 m CMOS technology. 4112 pixels independently and simultaneously detect the arrival time of photons with picosecond accuracy)
Niclass, C., A. Rochas, et al. (2005). “Design and characterization of a CMOS 3-D image sensor based on single photon avalanche diodes.” IEEE Journal of Solid-State Circuits 40: 1847-1854. (an array of 32×32 rangefinding pixels that independently measure the time-of-flight of a ray of light with picosecond time discrimination. The detectors, based on a single photon avalanche diode operating in Geiger mode)
42 Hammatsu, a primary APD manufacturer, has APD arrays with multiple APD pixels (MPPCs) operating in Geiger mode. Each APD pixel of the MPPC outputs a pulse signal when it detects one photon. MPPCs are conventionally used for detecting extremely weak light at the photon counting level, at rates of 100 MHz to −4 GHz.
43 Li, K., H.-D. Liu, et al. (2010). “SiC avalanche photodiode array with microlenses.” Optics Express 18: 11713-11719 describes an SiC APD beveled mesa structure for avalanche of electrons in a high-field p-type region.
Vert, A., S. Soloviev, et al. (2009). “SiC avalanche photodiodes and photomultipliers for ultraviolet and solar-blind light detection.” Physica Status Solidi (A) Applications and Materials 206: 2468-2477 describes a non-reach-through separate absorption and charge multiplication (SAM) structure to reduce noise and dark count probability. The internal electric field is terminated in the n layer without extending into the n-absorption layer. There is no appreciable electric field in the absorption region, so photo-generated carriers travel via diffusion to the multiplication region. Sharp “Geiger mode” avalanche current spikes at an 8300 Hz are passively quenched by a series resistor without any after-pulsing effects. A dark count rate of only 600 Hz was measured at a 388 reverse volt bias.
Vert, A., S. Soloviev, et al. (2009). “Silicon carbide photomultipliers and avalanche photodiode arrays for ultraviolet and solar-blind light detection.” IEEE Sensors 2009 Conference—SENSORS 2009 Oct. 25, 2009-Oct. 28, 2009:1893-1896. This paper describes 8×8-64 APDs-SiC avalanche photodiode arrays
Liu, H.-D., X. Zheng, et al. (2009). “Double mesa sidewall silicon carbide avalanche photodiode.” IEEE Journal of Quantum Electronics 45: 1524-1528 describes a double mesa SiC avalanche photodiode (APD) that suppresses premature edge breakdown. The SiC APD has a uniform gain up to ˜4500.
Ho-Young, C. (2010). “Structural Optimization of Silicon Carbide PIN Avalanche Photodiodes for UV Detection.” Journal of the Korean Physical Society 56(2): 672-676. (Describes a hole avalanche SiC APD using N-type materials for the upper layers because the diffusion length of minority holes in N-type 4H-SiC has been reported to be longer than that of minority electrons in P-type 4H-SiC. While a high quantum efficiency may require a thick intrinsic photon absorption layer in an avalanche photodiode, quantum efficiency is not necessary for an Avalanche Organodiode in accordance with the present disclosure because the electrons are generated on the MOX surface. Accordingly, an intrinsic buffer and field-equalization layer can be thinned to increase multiplication for avalanche mode.
Vert, A., S. Soloviev, et al. (2010). Performance of silicon carbide avalanche photodiode arrays and photomultipliers. 13th International Conference on Silicon Carbide and Related Materials 2009, ICSCRM 2009 Oct. 11, 2009-Oct. 16, 2009, Nurnberg, Germany, Trans Tech Publications Ltd.
Green, J. E., W. S. Loh, et al. (2010). Characterisation of low noise 4H-SiC avalanche photodiodes. 13th International Conference on Silicon Carbide and Related Materials 2009, ICSCRM 2009 Oct. 11, 2009-Oct. 16, 2009, Nurnberg, Germany, Trans Tech Publications Ltd.
Bai, X., D. McIntosh, et al. (2009). “High single photon detection efficiency 4H-SiC avalanche photodiodes.” SPIE-Advanced Photon Counting Techniques III, Apr. 14, 2009-Apr. 16, 2009 7320 report 4H-SiC avalanche photodiodes with low dark current and high gain. Geiger mode operation with high single photon detection efficiency and low dark count probability.
44 Alexey Vert et al, “SiC avalanche photodiodes and photomultipliers for ultraviolet and solar-blind light detection”, Phys. Status Solidi A 206, No. 10, 2468-2477 (2009)
Manoj Kumar et al, “Growth of p-type ZnO thin film on n-type silicon substrate and its application as hybrid homojunction”, Current Applied Physics 11 (2011) 65e69 (undoped ZnO typically exhibits n-type conductivity . . . the as-grown ZnO: AleN codoped film is n-type. The conduction changed to p-type after annealing at 500 C for 60 min in Ar ambient)
Fahrettin Yakuphanoglu et al, “ZnO/p-Si heterojunction photodiode by sol-gel deposition of nanostructure n-ZnO film on p-Si substrate”, Materials Science in Semiconductor Processing 13 (2010) 137-140
Xia, Qiangfei, et al (2009), “Memristor-CMOS Hybrid Integrated Circuits for Reconfigurable Logic”, NANO LETTERS Vol. 9, No. 10, 3640-3645 (TiO2 sputtered on substrate at 270° C.)
Hwang, Huey-liang et al, (2009) “National Project on 45 to 32 nm Metal Oxide Semiconductor Field Effect Transistors for Next Century IC Fabrications”, e-J. Surf. Sci. Nanotech. Vol. 7 (2009) 507-512 (HfO2 deposited by ALD at 200° C. on p-type Si-Trimethyl aluminum, tetrakis (ethylmethylamino) hafnium and water were used as precursors, and argon was employed as carrier and purge gas)
Wong, Hei (2006), “On the scaling issues and high-j replacement of ultrathin gate dielectrics for nanoscale MOS transistors”, Microelectronic Engineering 83 (2006) 1867-1904 (Crystallization temperature for both HfO2 and ZrO₂ ALD thin film can be as low as 350 C, introducing shallow oxide traps at the grain boundaries, which can produce large leakage current)
Shi, Jian et al Growth of Titanium Dioxide Nanorods in 3D-Confined Spaces, Nanoletters, dx.doi.org/10.1021/nl103702j |Nano Lett. XXXX, XXX, 000-000 (TiO2 ALD)
45 Nanofibers/pillars/rods, ect can be grown or attached to the MOX surface to counteract surface stagnation effects, and facilitate adsorption of gas analytes. Eg, see E. Comini and G. Sberveglieri (2010), “Metal oxide nanowires”, Materials Today, 13:36-44
Gerald Lucovsky et al, (2005), “Intrinsic limitations for CMOS with high-k gate dielectrics: electrically-active grain boundary and oxygen atom defect states”, Proceedings of ESSDERC, Grenoble, France, (Session Invited) Paper 6.B.1, p. 439-444 Session Invited Paper 6.B.1 (describes HfO2 tunneling, etc)
   Note that the orthogonal transport of carriers through the MOX layer in the AOPs and imager designs herein do not require negative surface oxygen species—the detection mechanism is not bulk conductivity variation. Most MOX materials are n-type, but p-type can be used. A separate bias electrode can be attached atop the MOX layer to control its potential. as chemical sensors
46 A. J. Myrick and T C Baker (2010), “Locating a compact odor source using a four-channel insect electroantennogram sensor”, Bioinspir. Biomim. 6:016002
A. J. Myrick, et al (2009), “Detection and discrimination of mixed odor strands in overlapping plumes using an insect-antenna-based chemosensor system” J. Chem. Ecol. 35:118-130
A. J. Myrick, et al, (2008) “Real-time odor discrimination using a bioelectronic sensor array based on the insect electroantennogram” Bioinspiration & Biomimetics. 3:046006
   Different sensor surfaces of n- and p-type, and different composition would be used to obtain selective responses to different types of analytes. Highly selective molecularly imprinted sensors can be used for analytes of specific interest. SnO2 is a typical MOX gas sensor material, as is In2O3. ZnO has wide direct band gap (3.37 eV or 375 nm at room temperature) and is typically n-type, but can be p-doped with difficulty. ZnO can be applied with relatively high crystal quality, heterojunctions with Si, and other designs can function in LEDs, field emitters and transparent field effect thin-film transistors (TTFT). TiO2 has useful semiconductor properties including a bandgap in the near UV which is sufficiently energetic to split water and oxidize most organic compounds. “Self-cleaning” surfaces can be produced by applying UV light to an ambient temperature TiO2 surface TiO2 has 2 primary crystal structures. Anatase is an indirect typically n-type semiconductor with a bandgap of ˜3.0 volts, while rutile is a direct-gap semiconductor with a bandgap of ˜3.2 volts. The structure of TiO2, with a small highly-charged Ti4+ cation is strongly attractive to a variety of analytes such as oxidizing explosives. This distorts their chemical bonding, and permits raman analysis46. A useful approach to gain a benefit of an extremely thin TiO2 surface may be to apply SiCl4 vapor atop another MOX layer, such as a ALD nanothin HfO2 layer. Dopants will preferably be applied at the nanothin MOX surface, and will not be present at the MOX-silicon interface. Multiple MOX compositions may be used to optimize behavior. For example, a nanothin layer of SnO2, ZnO, ITO, HfO2 could be treated with TiCl4 or Ti (butoxide) 4 vapor to apply a molecularly-thin titania reactive surface.
47 Raul Díaz Delgado (2002), “Tin Oxide Gas Sensors: An Electrochemical Approach”, Thesis Universitat de Barcelona, 160 pages (high SnO2 sensing at ˜125 C)
48 Dougherty, A. W, Elvin Beach, E. et al, “Efficient orthogonalization in gas sensor arrays using reciprocal kernel support vector regression”, Sensors and Actuators B 149 (2010) 264-271
49 Mapson-Menard, H and Waltham, N., ERCIM News 65 April 2006 Special theme: Space Exploration, “Large-Format Science-Grade CMOS Active Pixel Sensors for Extreme Ultra-Violet Space Science”
50 http://www.chipworks.com/blogs.aspx?id=8214&blogid=86 http://www.photographyblog.com/news/omnivision_launches_second-generation_backside_illumination_pixel_technolog/
51 http://www.cetimes.com/electronics-news/4199526/Update-Aptina-rolls-sensors-tips-backside-technology
52 Yasushi Maruyama et al, United States Patent Application Publication 20110058062, “SOLID-STATE IMAGING DEVICE, METHOD FOR PRODUCING SAME, AND CAMERA”, published Mar. 10, 2011, assigned to Sony Corporation
   A useful conductive transparent material for biasing could be low-temperature Amorphous InGaZnO—see Sanghun Jeon, et al, “180 nm Gate Length Amorphous InGaZnO Thin Film Transistor for High Density Image Sensor Applications”, IEEE IEDM10-504-7
53 Lee, Jun Min et al, (2010), “Ultra-sensitive hydrogen gas sensors based on Pd-decorated tin dioxide nanostructures: Room temperature operating sensors”, International Journal of Hydrogen Energy, 35: 12568-12573
Han, Chi-Hwan et al, “Micro-bead of nano-crystalline F-doped SnO2 as a sensitive hydrogen gas sensor”, Sensors and Actuators B 109 (2005) 264-269
54 Oversimplifying, consider that 500 gas molecules of a mixture are collected on a cool pixel with one type of adsorption selectivity at ambient temperature over several seconds, and that 200 of those are molecules of a compound which preferentially reacts with the MOX surface of that pixel at elevated temperature or under UV. Next, consider another pixel which preferentially adsorbs 600 gas molecules, of which 400 are of a compound that will be preferentially reacted on this different MOX surface at elevated temperature. If the collected molecules on both pixels can be induced to react within several milliseconds (such as by pulsed heating of the nanothin MOX surface and/or the molecules themselves) the net pixel response of each pixel will be multiplied by the number of reacting molecules. The pixels will each have a different response, weighted toward the molecules to which they are selectively sensitive. A pulse-heated nanothin MOX surface layer will cool quickly, so than bulk silicon “dark current” from continuous higher temperature operation will be minimized.
55 Quantum Cascade MWIR lasers are available in small size, high power, and wide wavelength range (3-160 u m). [A. Hood et al (2008), “Type-II Superlattices and Quantum Cascade Lasers for MWIR and LWIR Free-Space Communications, SPIE Vol. 6900, 690005, (Northwestern University)] Inexpensive MWIR LEDs are also well developed [V. K. Malyutenko et al, (2006), “Room-temperature InAsSbP/InAs light emitting diodes by liquid phase epitaxy for midinfrared (3-5 μm) dynamic scene projection”, Appl. Phys. Lett. 89, 201114]
LEDs with UV below 410 nm and below 380 nm are inexpensive (less than $10) Cree has made UV LEDs and worked on UV lasers. http://www.crec.com Nichia has a 385 nm LED NC4U134 with 1200 mW output at 17 Volts. And a 365 nm LED NC4U133 LED at 17 Volts. www.nichia.com. Significant doping work has been done to decrease the TiO2 bandgap so that blue VIS light can be used for activation TiO2, which permits use of blue VIS LEDs for these compositions. See www.markettechinc.net www.optonlaser.com Shorter wavelength LEDs ar aalso available for other catalytic sensor oxides. Fox group 355 nm http://www.thefoxgroupinc.com/For example, Sensor Electronic Technology has commercial UV LEDS of AlInGaN with peak emission wavelengths in the range of 240-400 nm sealed in various metal-glass TO (TO-3, TO-18, TO-37, TO-39, TO-66, etc.) and SMD packages with UV-transparent optical windows. http://www.s-et.com/products.htm
AlN (210 nm), BN (215 nm) and diamond (235 nm) LEDs permit deep UV light sources. Kubota et al (2007). Deep Ultraviolet Light-Emitting Hexagonal Boron Nitride Synthesized at Atmospheric Pressure, Science 317 (5840): 932; Watanabe et al (2004) Direct-bandgap properties and evidence for ultraviolet lasing of hexagonal boron nitride single crystal. Nature Materials 3 (6): 404; Taniyasu et al (2006). An aluminium nitride light-emitting diode with a wavelength of 210 nanometres. Nature 441 (7091): 325.
   Brief high current (even beyond the steady DC capacity of the LED) can shorten the average wavelength of emitted radiation. This provides both a mechanism to control wavelength, and to achieve shorter wavelength output from less-expensive diode materials.
56 Chi-Hwan Han et al (2007), “Catalytic combustion type hydrogen gas sensor using TiO2 and UV-LED”, Sensors and Actuators B 125 (2007) 224-228
E. Comini, et al (2004), “SnO2 RGTO UV Activation for CO Monitoring”, IEEE SENSORS JOURNAL, 4:17-20
Han, Chi-Hwan et al, (2007) “Catalytic combustion type hydrogen gas sensor using TiO₂ and UV-LED” Sensors and Actuators B 125:224-228
   57 CCDs can be operated at effective frame rates from thousands to millions of frames per second. Even inexpensive CMOS “cameras-on-a-chip” can operate at up to a thousand frames per second. Different gas molecules will have a specific time-course of oxidation, which can be detected and characterized. Because the oxidation reaction of all the collected odorant molecules is initiated at the same time, the unique time-signature of the detected odorant(s) is magnified for detection in proportion to the number of molecules collected. We hypothesize that the oxidation reaction rates of organic molecules on MOX detectors are in the millisecond range, with larger, higher molecular weight molecules taking longer for stepwise oxidation. A pulsed reaction activation mode initiates reaction of all adsorbed gas molecules at precisely the same time. Accordingly, a fast frame rate through the pulsed reaction time will provide reaction rate information for gas characterization. Small, highly reactive gas molecules will be predominately detected in the first frame(s). Larger and less-reactive gas molecules will continue to be detected in later frames, on a pixel-by-pixel basis for each differently-adsorptive and differently-reactive pixel sensor surface.
58 Vo Le, C.; Etoh, T. G, et al (2009) A Backside-Illuminated Image Sensor with 200,000 Pixels Operating at 250,000 Frames per Second “, IEEE Trans. Electron Devices 2009, 56, 2556-2562. The test BSI-ISIS has been fabricated and evaluated (ISIS-V12) [5,13]. The pixel count is 200,000; the full well capacity is 10,000e−. The maximum frame rate is 250,000 fps and 1 Mfps, respectively for full well capacity and reduced charge handling capacity. The sensitivity is very high: images with a 4.9e− signal level in the 7.7e− noise floor was observed.
Etoh, T. G., et al, (2010). Backside illuminated CCD operating at 16,000,000 frames per second with sub-ten-photon sensitivity. Nuclear Instruments and Methods in Physics Research A, 1-5. [withdrawn by author after online publication]
59 Son, D. V. T., T. G. Etoh, et al. (2010). “Toward 100 Mega-Frames per Second: Design of an Ultimate Ultra-High-Speed Image Sensor”, Sensors 2010 (10): 16-35.
60 Jaing et al, “Ultraviolet Schottky detector based on epitaxial ZnO thin film”, Solid-State Electronics 52 (2008) 679-682 (The break-down voltage is higher than 100 V. The 10-90% rise and fall times were 20 ns and 250 ns, respectively. The measured 20 ns rise time may have been increased by the excitation laser, which has a nominal pulse duration FWHM of 10 ns)
61 Kong et al, (2009), “Metal-semiconductor-metal TiO2 ultraviolet detectors with Ni electrodes”, Appl. Phys. Lett. 94, 123502 (UV detector with Ni electrode based on TiO2 sol-gel thin film with absorption edge around 320 nm. The dark current of the detector is 1.83 nA, and high photoreponse of 889.6 A/W is found under the irradiation of 260 nm UV light. The ratio of photocurrent-to-dark current is about four orders of magnitude. The rise time and the fall time are 13.34 ms and 11.43 s, respectively. The high photoresponse is attributed to the large gain caused by hole traps at the interface)
Qing Shen et al, (2006), “Photoexcited hole dynamics in TiO2 nanocrystalline films characterized using a lens-free heterodyne detection transient grating technique”, Chemical Physics Letters 419, 464-468
Fritz J. Knorr, et al, ‘Influence of TiCl4 Treatment on Surface Defect Photoluminescence in Pure and Mixed-Phase Nanocrystalline TiO2”, Langmuir 2007, 23, 8686-8690 (recombination can be enhanced and trapping reduced by treatment with TiCl4 to form rutile surface)
Yoshiaki Tamaki et al (2009), “Femtosecond Visible-to-IR Spectroscopy of TiO2 Nanocrystalline Films: Elucidation of the Electron Mobility before Deep Trapping”, J. Phys. Chem. C 2009, 113, 11741-11746
S. H. Szczepankiewicz, et al, (2002) “Slow Surface Charge Trapping Kinetics on Irradiated TiO2”, J. Phys. Chem. B, 2002, 106 (11), 2922-2927
62 During a gas analyte detection process, the pixels are shuttered or otherwise shielded from scene lighting, to eliminate light image data.
63 Paul G. O'Brien, et al, (2010), “Selectively Transparent and Conducting Photonic Crystals”, Advanced Materials 22, 611-616
64 Jiajia Deng, et al (2011), “Electrochromic properties of WO3 thin film onto gold nanoparticles modified indium tin oxide electrodes”, Applied Surface Science 257, 5903-5907
Nicholas L. Stokes et al, (2010), “Spectrally selective coatings of gold nanorods on architectural glass”, J Nanopart Res 12:2821-2830 (gold nanorods absorb in the IR)
65 Tsuda, T., T. Sakamoto, et al. (2011). “Irradiation-Induced Metal Nanoparticles in Room-Temperature Ionic Liquid.” Abstract #2173, 218th ECS Meeting, The Electrochemical Society.
66 Graeme R. Jones et al, (1999), “Pheromone analysis using capillary gas chromatographic techniques”, Journal of Chromatography A, 843: 199-236
67 Eg, see U.S. Pat. No. 7,741,664 of Jun. 2, 2010 to Choi et al and U.S. Pat. No. 7,880,255 of Feb. 1, 2011 to Baggenstoss for fabrication of nanopillar surfaces.
David A Rider et al, (2011) Indium tin oxide nanopillar electrodes in polymer/fullerene solar cells “, J of Inst Physics Nanotechnology 22 (8): 085706 (2011)
Yujian Huang et al, (2010) “An ALD etch-back method to fabricate high aspect ratio nanopillar arrays for photonic crystal sensors”, Proc. Eurosensors XXIV, Sep. 5-8, 2010 Linz, Austria
A. Kathalingam et al, (2011), “Self assembled micro masking effect in the fabrication of SiC nanopillars by ICP-RIE dry etching”, Applied Surface Science 257: 3850-3855
Wong, S. M., H. Y. Yu, et al. (2011). “Si nanopillar array surface-textured thin-film solar cell with radial p-n junction.” IEEE Electron Device Letters 32: 176-178.
Tsiaoussis, I., V. Khranovskyy, et al. (2011). “Structural characterization of ZnO nanopillars grown by atmospheric-pressure metalorganic chemical vapor deposition on vicinal 4H-SiC and SiO2/Si substrates.” Journal of Applied Physics 109.
Padeste, C., H. Ozcelik, et al. (2011). “Replication of high aspect ratio pillar array structures in biocompatible polymers for tissue engineering applications.”.
Krishnamoorthy, S., K. K. Manipaddy, et al. (2011). “Wafer-level self-organized copolymer templates for nanolithography with sub-50 nm feature and spatial resolutions.” Advanced Functional Materials 21: 1102-1112.
Khranovskyy, V., I. Tsiaoussis, et al. (2011). “Selective homoepitaxial growth and luminescent properties of ZnO nanopillars.” Nanotechnology 22.
Kathalingam, A., M.-R. Kim, et al. (2011). “Self assembled micro masking effect in the fabrication of SiC nanopillars by ICP-RIE dry etching.” Applied Surface Science 257: 3850-3855.
Yu, H. (2010). Surface texturing of Si thin film solar cells via low cost periodic nanopillars array to enhance efficiency. 2010 10th IEEE International Conference on Solid-State and Integrated Circuit Technology, Nov. 1, 2010-Nov. 4, 2010, Shanghai, China, IEEE Computer Society.
Wang, H.-P., K.-Y. Lai, et al. (2010). “Periodic Si nanopillar arrays fabricated by colloidal lithography and catalytic etching for broadband and omnidirectional elimination of fresnel reflection.” Langmuir 26: 12855-12858.
Vj, L., A. M. Katzenmeyer, et al. (2010). “Harvesting and transferring vertical pillar arrays of single-Crystal semiconductor devices to arbitrary substrates.” IEEE Transactions on Electron Devices 57: 1856-1864.
Santos, A., P. Formentin, et al. (2010). “Fabrication and characterization of high-density arrays of P3HT nanopillars on ITO/glass substrates.” Solar Energy Materials and Solar Cells 94: 1247-1253.
Saleema, N., M. Farzanch, et al. (2009). “Fabrication of light absorbing TiO2-donuts.” Materials Letters 63:233-235.
Chen, M.-H., Y.-J. Chuang, et al. (2008). “Self-masked high-aspect-ratio polymer nanopillars.” Nanotechnology 19.
68 J. Hildenbrand, et al, (2009) “Explosive detection using infrared laser spectroscopy”, SPIE Vol. 7222, 72220B
69 Cai, Z.-F., H.-J. Dai, et al. (2008). “Molecular imprinting and adsorption of metallothionein on nanocrystalline titania membranes.” Applied Surface Science 254(15): 4457-4461.
Feng, L., Y. Liu, et al. (2004). “Molecularly imprinted TiO2 thin film by liquid phase deposition for the determination of L-glutamic acid.” Langmuir 20: 1786-1790.
Fujikawa, S., E. Muto, et al. (2009). “Nanochannel design by molecular imprinting on a free-standing ultrathin titania membrane.” Langmuir 25(19): 11563-11568.
Hashizume, M. and T. Kunitake (2003). “Preparation of Self-Supporting Ultrathin Films of Titania by Spin Coating.” Langmuir 19(24): 10172-10178.
Kunitake, T. and S.-W. Lee (2004). “Molecular imprinting in ultrathin titania gel films via surface sol-gel process.” Analytica Chimica Acta 504: 1-6.
Lahav, M., A. B. Kharitonov, et al. (2001). “Imprinting of chiral molecular recognition sites in thin TiO2 films associated with field-effect transistors: Novel functionalized devices for chiroselective and chirospecific analyses.” Chemistry—A European Journal 7:3992-3997.
Lee, S.-W., I. Ichinose, et al. (1998). “Molecular imprinting of azobenzene carboxylic acid on a TiO2 ultrathin film by the surface sol-gel process.” Langmuir 14(10): 2857-2863.
Lee, S.-W., D.-H. Yang, et al. (2005). “Regioselective imprinting of anthracenecarboxylic acids onto TiO2 gel ultrathin films: An approach to thin film sensor.” Sensors and Actuators, B: Chemical 104: 35-42.
Li, C., C. Wang, et al. (2006). “Development of a parathion sensor based on molecularly imprinted nano-TiO₂ self-assembled film electrode.” Sensors and Actuators, B: Chemical 117: 166-171.
Lisichkin, G. V., R. Y. Novotortsev, et al. (2004). “Chemically modified oxide surfaces capable of molecular recognition.” Colloid Journal 66: 387-399.
Lu, N., S. Chen, et al. (2008). “Synthesis of molecular imprinted polymer modified TiO2 nanotube array electrode and their photoelectrocatalytic activity.” Journal of Solid State Chemistry 181(10): 2852-2858.
Sharabi, D. and Y. Paz (2010). “Preferential photodegradation of contaminants by molecular imprinting on titanium dioxide.” Applied Catalysis B: Environmental 95(1-2): 169-178. (designing a photocatalyst for WMD warfare agents such as Sarin)
Shen, X., L. Zhu, et al. (2009). “Inorganic molecular imprinted titanium dioxide photocatalyst: Synthesis, characterization and its application for efficient and selective degradation of phthalate esters.” Journal of Materials Chemistry 19(27): 4843-4851.
Wang, C., C. Li, et al. (2006). “Phosphonate electrochemical recognition by molecularly imprinted deposited film.” Applied Surface Science 253: 2282-2288.
Wu, C.-T., P.-Y. Chen, et al. (2009). “Detection of nicotine based on molecularly imprinted TiO2-modified electrodes.” Analytica Chimica Acta 633(1): 119-126.
Xia, Q., W. Robinett, et al. (2009). “Memristor-CMOS hybrid integrated circuits for reconfigurable logic.” Nano Letters 9: 3640-3645.
Yang, D.-H., N. Takahara, et al. (2008). “Fabrication of glucose-sensitive TiO₂ ultrathin films by molecular imprinting and selective detection of monosaccharides.” Sensors and Actuators, B: Chemical 130: 379-385.
Zhang, Z., Y. Hu, et al. (2010). “Layer-by-layer assembly sensitive electrochemical sensor for selectively probing 1-histidine based on molecular imprinting sol-gel at functionalized indium tin oxide electrode.” Biosensors and Bioelectronics 26: 696-702.
70 Hu, S., A. Wang, et al. (2010). “Hydrothermal synthesis of liquid [Bmim] OH-modified TiO2 nanoparticles with enhanced photocatalytic activity under visible light.” Chemistry—An Asian Journal 5(5): 1171-1177. (TiO2 nanocomposites modified with the ionic liquid [Bmim] OH chemically bonded to the surface.
Giannakopoulou, T., N. Todorova, et al. (2008). Study of fluorine-doped TiO2 sol-gel thin coatings, 3 Park Avenue, New York, NY 10016-5990, United States, American Society of Mechanical Engineers (sol-gel prepared TiO2 thin with Trifluoroacetic acid (CF3COOH) used as fluorine source does not affect the crystallinity and band gap of the formed TiO2 film for the F: Ti ratios used in the starting sols)
Hyeok Choi, H., Kim, Y. K. et al, (2006), “Thermally Stable Nanocrystalline TiO2 Photocatalysts Synthesized via Sol-Gel Methods Modified with Ionic Liquid and Surfactant Molecules”, Chem. Mater. 18: 5377-5384
71 Wilson, A. D. and Baietto, M., “Applications and Advances in Electronic-Nose Technologies”, Sensors 2009, 9, 5099-5148 (review, many enose applications)
Patrick J. McCann, (2006) “Mid-Infrared Lasers and Molecular Spectroscopy Applications”, MM4 (Invited Paper) 0-7803-9556-5/06 IEEE
Get a whiff of this: Low-cost sensor can diagnose bacterial infections http://www.physnews.com/bio-medicine-news/cluster150552504/72
72 Wang, C., C. Li, et al. (2006). “Phosphonate electrochemical recognition by molecularly imprinted deposited film.” Applied Surface Science 253: 2282-2288. (thin films of titanium oxide imprinted with O,O-dimethyl-(2,4-dichlorophenoxyacetoxyl)(3-nitrobenyl)methinephosphonate (Phi-NO2) were prepared via liquid phase deposition (LPD) method on a glassy carbon electrode).
Wu, C.-T., P.-Y. Chen, et al. (2009). “Detection of nicotine based on molecularly imprinted TiO2-modified electrodes.” Analytica Chimica Acta 633(1): 119-126.
73 G. Mavrodiev, et al, “Properties of SnO2: F Films Prepared on Glass Substrates by the Spraying Method”, Thin Solid Films, 113 (1984) 93-100
74 Leroux, Y. R. and P. Hapiot (2013). “Nanostructured monolayers on carbon substrates prepared by electrografting of protected aryldiazonium salts.” Chemistry of Materials 25(3): 489-495.
Sokolova, N. V., D. V. Vorobyeva, et al. (2012). “Synthesis of -trifluoromethyl-hydroxy acid-peptide conjugates via click chemistry.” Synthesis 44(1): 130-136.
Shivananda, K. N., I. Cohen, et al. (2012). “Sequence-independent synthesis of -conjugated arylenevinylene oligomers using bifunctional thiophene monomers.” Advanced Functional Materials 22(7): 1489-1501.
Perez-Gavilan, A., P. J. Carroll, et al. (2012). “Efficient and systematic click-based synthetic routes to amino acid functionalized metallatricarbadecaboranes.” Organometallics 31(7): 2741-2748.
Li, Y. and H. Zuilhof (2012). “Photochemical grafting and patterning of organic monolayers on indium tin oxide substrates.” Langmuir 28(12): 5350-5359.
Kramer, J. R. and T. J. Deming (2012). “Preparation of multifunctional and multireactive polypeptides via methionine alkylation.” Biomacromolecules 13(6): 1719-1723.
Hayat, A., A. Sassolas, et al. (2012). “Highly sensitive ochratoxin A impedimetric aptasensor based on the immobilization of azido-aptamer onto electrografted binary film via click chemistry.”
Yamada, T., C. G. Peng, et al. (2011). “Versatile site-specific conjugation of small molecules to siRNA using click chemistry.” Journal of Organic Chemistry 76(5): 1198-1211.
Swarts, B. M. and Z. Guo (2011). “Chemical synthesis and functionalization of clickable glycosylphosphatidylinositol anchors.” Chemical Science 2(12): 2342-2352.
Merkul, E., F. Klukas, et al. (2011). “Rapid preparation of triazolyl substituted NH-heterocyclic kinase inhibitors via one-pot Sonogashira coupling-TMS-deprotection-CuAAC sequence.” Organic and Biomolecular Chemistry 9(14): 5129-5136.
Li, Y., M. Zhao, et al. (2011). “Biofunctionalization of a “clickable” organic layer photochemically grafted on titanium substrates.” Langmuir 27(8): 4848-4856.
Li, Y., J. Wang, et al. (2011). “Rapid grafting of azido-labeled oligo (ethylene glycol) s onto an alkynyl-terminated monolayer on nonoxidized silicon via microwave-assisted “click” reaction.” Langmuir 27(6): 2437-2445.
Li, Y., C. M. Santos, et al. (2011). “Click” Immobilization on alkylated silicon substrates: Model for the study of surface bound antimicrobial peptides.” Chemistry—A European Journal 17(9): 2656-2665.
Leroux, Y. R., F. Hui, et al. (2011). “Design of robust binary film onto carbon surface using diazonium electrochemistry.” Langmuir 27(17): 11222-11228.
Ladouceur, S., A. M. Soliman, et al. (2011). “One-pot click synthesis of IN-alkyl-4-aryl-1,2,3-triazoles from protected arylalkynes and alkyl bromides.” Synthesis (22): 3604-3611.
Huang, H., H. Guo, et al. (2011). “Click novel glycosyl amino acid hydrophilic interaction chromatography stationary phase and its application in enrichment of glycopeptides.” Talanta 85(3): 1642-1647.
Firstenberg, M., K. N. Shivananda, et al. (2011). “Harnessing “click”-type chemistry for the preparation of novel electronic materials.” Advanced Functional Materials 21(4): 634-643.
Liang, L., J. Ruiz, et al. (2010). “Click” Synthesis of a Heterobifunctional Ferrocenyl Dendrimer with Molecular Recognition Properties and Influence of the Ferrocenyl Redox Potential on the Formation of Gold Nanoparticles.” Journal of Inorganic and Organometallic Polymers and Materials 20(3): 503-510.
Leroux, Y. R., H. Fei, et al. (2010). “Efficient covalent modification of a carbon surface: Use of a silyl protecting group to form an active monolayer.” Journal of the American Chemical Society 132(40): 14039-14041.
Huang, L., S. Dolai, et al. (2010). “Click grafting of high loading of polymers and monosaccharides on surface of ordered mesoporous silica.” Langmuir 26(4): 2688-2693.
Hartwig, S. and S. Hecht (2010). “Polypseudopeptides with variable stereochemistry: Synthesis via click-chemistry, postfunctionalization, and conformational behavior in solution.” Macromolecules 43(1): 242-248.
Del Barrio, J., L. Oriol, et al. (2010). “Photoresponsive poly(methyl methacrylate)-b-azodendron block copolymers prepared by ATRP and click chemistry.” Journal of Polymer Science, Part A: Polymer Chemistry 48(7): 1538-1550.
Juricek, M., P. H. J. Kouwer, et al. (2009). “A novel modular approach to triazole-functionalized phthalocyanines using click chemistry.” Journal of Organic Chemistry 74(1): 21-25.
Guo, J., Y. Huang, et al. (2009). “Synthesis and characterization of functional poly(-benzyl-1-glutamate) (PBLG) as a hydrophobic precursor.” Polymer 50(13): 2847-2855.
Gadzikwa, T., O. K. Farha, et al. (2009). “Selective bifunctional modification of a non-catenated metal-organic framework material via “click” chemistry.” Journal of the American Chemical Society 131(38): 13613-13615.
Shen, X., H. Liu, et al. (2008). “Click-together azobenzene dendrons: Synthesis and characterization.” Macromolecules 41(7): 2421-2425.
Campos, L. M., K. L. Killops, et al. (2008). “Development of thermal and photochemical strategies for thiol-ene click polymer functionalization.” Macromolecules 41(19): 7063-7070.
Ciampi, S., T. Bocking, et al. (2007). “Functionalization of acetylene-terminated monolayers on Si(100) surfaces: A click chemistry approach.” Langmuir 23(18): 9320-9329.
75 De Ceglia, D, Vincenti, M A, et al. (2008) “Tailoring metallodielectric structures for superresolution and superguiding applications in the visible and near-IR ranges”, Physical Review A—Atomic, Molecular, and Optical Physics, 77:033848
76 Dhawan, A, Gerhold, M D, et al. (2008) “Plasmonic structures based on sub wavelength apertures for chemical and biological sensing applications”, IEEE Sensors Journal, 8:942-950
77 Thio, T., H. F. Ghaemi, et al. (1999). “Surface-plasmon-enhanced transmission through hole arrays in Cr films.” J. Opt. Soc. Am. B 16(10): 1743-1748.
78 Degiron A, Lezec H J, et al (2002) Effects of hole depth on enhanced light transmission through subwavelength hole arrays. Appl. Phys. Lett. 81:4327-29
79 van der Molen K L, Segerink F B, et al (2004). Influence of hole size on the extraordinary transmission through subwavelength hole arrays. Appl. Phys. Lett. 85:4316-18
Williams S M, Stafford A D, et al (2004) Extraordinary infrared transmission of Cu-coated arrays with subwavelength apertures: hole size and the transition from surface plasmon to waveguide transmission. Appl. Phys. Lett. 85:1472-74
80 Chen Y G, Wang Y H et al (2007) Numerical investigation of the transmission enhancement through subwavelength hole array. Opt. Commun. 274:236-40
Rodriguez K R, Tian H, et al (2007) Extraordinary infrared transmission resonances of metal microarrays for sensing nanocoating thickness. J. Phys. Chem. 111:12106-11
81 van der Molen K L, Koerkamp, K et al (2005) Role of shape and localized resonances in extraordinary transmission through periodic arrays of subwavelength holes: experiment and theory. Phys. Rev. B Condens. Matter Mater. Phys. 72:045421
Guo H., Meyrath T P, et al (2008), Optical resonances of bowtie slot antennas and their geometry and material dependence, Optics Express 16:7756-7766
Moller K D, Sternberg O, et al (2002) Thick inductive cross shaped metal meshes. J. Appl. Phys. 91:9461-65
Ishihara K, Ohashi K. (2005) Strong influence of surface structures on enhanced transmission through subwavelength hole arrays. Jpn. J. Appl. Phys. 44:L973-75 (“dimples”)
Kim J H, Moyer P J. (2006) Transmission characteristics of metallic equilateral triangular nanohole arrays. Appl. Phys. Lett. 89:121106
Sun M, Liu R J, et al. (2006) The influence of hole shape on enhancing transmission through subwavelength hole arrays. Chin. Phys. 15:1591-94
Sun M, Liu R-J, Li Z-Y, Cheng B-Y, Zhang D-Z, et al. 2007. Enhanced nearinfrared transmission through periodic H-shaped arrays. Phys. Lett. A 365:510-13
82 Zou, Y. and K. B. Crozier (2008). “Experimental measurement of surface plasmon resonance of pyramidal metal nanoparticle tips.” SPIE 7033: 70331.
83 Gerhold, M, Dhawan, A, et al. (2008) “Geometry-dependent plasmon resonances of metallic nanostructures for enhancement of localized electromagnetic fields around the nanostructures”, SPIE, 6902:690208; Ghoshal, A and Kik, PG (2008) “Theory and simulation of surface plasmon excitation using resonant metal nanoparticle arrays”, Journal Of Applied Physics 103:113111; Kundu, J, Le, F, et al. (2008) “Surface enhanced infrared absorption (SEIRA) spectroscopy on nanoshell aggregate substrates”, Chemical Physics Letters, 452:115-119; Johnson, WL, Kim, S A, et al. (2008) “Surface-plasmon fields in two-dimensional arrays of gold nanodisks”, SPIE, 7032:70321; Krenn, JR, Schider, G, et al. (2000) “Design of multipolar plasmon excitations in silver nanoparticles”, Applied Physics Letters, 77:3379-3381; Lamprecht, B, Krenn, J R, et al. (2001) “Surface plasmon propagation in microscale metal stripes”, Applied Physics Letters, 79:51; Lamprecht, B, Schider, G, et al. (2000) “Metal Nanoparticle Gratings: Influence of Dipolar Particle Interaction on the Plasmon Resonance”, Physical Review Letters, 84:4721-4724; Le, F, Brandl, D W, et al. (2008) “Metallic nanoparticle arrays: A common substrate for both surface-enhanced Raman scattering and surface-enhanced infrared absorption”, ACS Nano, 2:707-718; Leitner, A, Steinberger, B, et al. (2004) “Optical properties of tailor-made 1D and 2D noble metal particle arrays”, SPIE, 5339:644-651; Near-Field Spectral Analysis of Metallic Beads, p 97-123 Takayuki Okamoto, Optical Engineering Laboratory, RIKEN, Wako, Saitama 351-0198, Japan okamoto@optsun.riken.go.jp
84 J. Ferreira, J. et al, “Attomolar protein detection using in-hole surface plasmon resonance”, J. Am. Chem. Soc. 2009, 131, 436-437
85 V. Reiffenrath Et Al, “New Liquid-Crystalline Compounds With Negative Dielectric Anisotropy”, Liquid Crystals (1989) Vol. 5, No. 1, 159-170 [LCs with negative Δε having lateral, polar substituents such as —CN or fluorine on the mesogenic molecules]
Zakerhamidi, M. S., M. H. M. Ara, et al. (2013). “Dielectric anisotropy, refractive indices and order parameter of W-1680 nematic liquid crystal.” 181: 77-81 [dielectric permittivity and refractive indices measured as a function of temperature]
Yurtseven, H. and E. Kilit (2012). “Analysis of the dielectric constant as a function of temperature at constant electric fields for the smectic A-smectic G transition in A6.” ISRN Condensed Matter Physics: 969830 (969835 pp.) [temperature dependence of the dielectric constant under fixed electric fields for a ferroelectric liquid crystal]
Matsuyama, A. (2012). “Novel biaxial nematic phases of side-chain liquid crystalline polymers.” Journal of Chemical Physics 137(22): 224906 (224906 pp.).
Kaur, S., J. Addis, et al. (2012). “Understanding the distinctive elastic constants in an oxadiazole bent-core nematic liquid crystal.” Physical Review E (Statistical, Nonlinear, and Soft Matter Physics) 86(4): 041703 (041711 pp.)
Gupta, M. D., A. Mukhopadhyay, et al. (2012). “Thermal dependence of the dielectric behavior of two mesogens: A comparative study.” Molecular Crystals and Liquid Crystals 557: 240-250 [temperature dependence of the dielectric properties of the OC6 H13 and isothiocyanato]
Derouiche, Y., K. Koynov, et al. (2012). “Optical, electro-optical, and dielectric properties of acrylic tripropyleneglycol based polymer network systems including LCs.” Molecular Crystals and Liquid Crystals 561: 124-135.
Fragiadakis, D., S. Urban, et al. (2011). “Phase diagram and dynamics of the liquid crystal isopentylcyanobiphenyl (5*CB).” Journal of Physical Chemistry B 115(20): 6437-6444.
Feireisl, E., E. Rocca, et al. (2011). “On a Non-isothermal Model for Nematic Liquid Crystals.” Nonlinearity 24(1): 243-257.
Dhakal, S. and J. V. Selinger (2011). “Chirality and biaxiality in cholesteric liquid crystals.” Physical Review E-Statistical, Nonlinear, and Soft Matter Physics 83(2).
Diaz-Cuadros, J. C., L. Larios-Lopez, et al. (2010). “Ionic liquid crystals bearing bipyridinium and pentaphenylene groups.” Journal of Molecular Liquids 157(2-3): 133-141.
Chan-Shan et al, (2010). “The complex refractive indices of the liquid crystal mixture E7 in the terahertz frequency range.” Journal of the Optical Society of America B (Optical Physics) 27(9): 1866-1873
H. Sackmann (1989): Plenary Lecture. Smectic liquid crystals. A historical review, Liquid Crystals, 5:1, 43-55
D. Demus (1989): Plenary Lecture. One hundred years of liquid-crystal chemistry: Thermotropic liquid crystals with conventional and unconventional molecular structure, Liquid Crystals, 5:1, 75-110 [many different monomer and polymer LCs]
Jacques Malthete, Andre Collet & Anne-Marie Levelut (1989): Mesogens containing the DOBOB group, Liquid Crystals, 5:1, 123-131
C. Vauchier, F. Vinet & N. Maiser (1989): New bifluorinated liquid-crystal compounds with broad mesomorphic ranges, Liquid Crystals, 5:1, 141-151
U. Finkenzeller, T. Geelhaar, G. Weber & L. Pohl (1989): Liquid-crystalline reference compounds, Liquid Crystals, 5:1, 313-321
S. Sreehari Sastry, T. Vindhya Kumari, K. Mallika, B. Gowri Sankara Rao, Sie-Tiong Ha & S. Lakshminarayana (2012): Order parameter studies on EPAP alkanoate mesogens, Liquid Crystals, 39:3, 295-301
Jianqiang Xie, Guangming Zhu, Yusheng Tang & Zengping Zhang (2013): Synthesis and properties of reactive liquid crystal monomers and side-chain liquid crystalline polymers, Liquid Crystals, 40:4, 546-554 [polymers for long-term device stability, which are also suitable for molecular imprinting] Chandra Shekhar Pati Tripathi, Jan Leys, Patricia Losada-Pérez, Kathleen Lava, Koen Binnemans, Christ Glorieux & Jan Thoen (2013): Adiabatic scanning calorimetry study of ionic liquid crystals with highly ordered crystal smectic phases, Liquid Crystals, 40:3, 329-338
Ki-Han Kim et al, “Vertical alignment of liquid crystals without alignment layers, Liquid Crystals, 40:3, 391-395 (2013)
H. G. Walton, “Influence of TiO2 Nanoparticle Doping on the Splay and Bend Elastic Constants of the Nematic Liquid Crystal 4′-butyl-4-heptyl-bicyclohexyl-4-carbononitrile, CCN47, Molecular Crystals and Liquid Crystals, 574:1, 60-66 (2013)
Supreet, S. et al, “Enhanced stability of the columnar matrix in a discotic liquid crystal by insertion of ZnO nanoparticles, Liquid Crystals, 40:2, 228-236 (2013) [suitable for use of molecularly imprinted metal oxide nanoparticles of widely different types]
G. Derfel & M. Buczkowska (2013): Dynamics of electric field induced deformations in flexoelectric nematic layers, Liquid Crystals, 40:2, 272-280
M. Schadt (1988): The Twisted Nematic Effect: Liquid Crystal Displays and Liquid Crystal Materials, Molecular Crystals and Liquid Crystals Incorporating Nonlinear Optics, 165:1, 405-438
T. N. Govindaiah et al, “Optical and Thermal Characterization of Binary Mixtures of Liquid Crystals, Molecular Crystals and Liquid Crystals, 574:1, 9-18 (2013) [broad ranges of Δn with temperature]
V. Reiffenrath, J. Krause, H. J. Plach & G. Weber (1989): New liquid-crystalline compounds with negative dielectric anisotropy, Liquid Crystals, 5:1, 159-170 [biaxial, multiaxial, positive and negative dielectric anisotropy]
B. Mühlberger & W. Haase (1989): Properties of liquid-crystalline copper (II) complexes and their binary mixtures, Liquid Crystals, 5:1, 251-263 [for use with phosphonates, and as anchoring decoration instead of perchlorate salts]
José Carlos Díaz-Cuadros et al, “Ionic liquid crystals bearing bipyridinium and pentaphenylene groups”, Journal of Molecular Liquids 157 (2010) 133-141
T Seideman, “The liquid-crystalline blue phases”, Rep. Prog. Phys. 53 (1990) 659-705.
M. S. Zakerhamidi et al, “Dielectric anisotropy, refractive indices and order parameter of W-1680 nematic liquid crystal”, Journal of Molecular Liquids 181 (2013) 77-81
86 Pachter, R., S. S. Patnaik, et al. (1993). New smart materials: molecular simulation of nonlinear optical chromophore-containing polypeptides and liquid crystalline siloxanes. Smart Structures and Materials 1993. Smart Materials, 1-4 Feb. 1993
Natarajan, L. V., V. Tondiglia, et al. (1992). “Liquid crystalline siloxanes containing spiropyran chromophores as reversible optical data storage materials.” Advanced Materials for Optics and Electronics 1(6): 293-297.
87 “Liquid crystals into planar photonic crystals”, Ferrini, R. Editor: Tkachenko, G. V. Published in: New developments in liquid crystals, Chapter 2, p. 21-48, Vukovar, Croatia: In-Tech, 2009
Nina Podoliak et al, “High Optical Nonlinearity of Nematic Liquid Crystals Doped with Gold Nanoparticles”, J. Phys. Chem. C, (2012), 116 (23), pp 12934-12939 [Tetraoctylammonium bromide-coated gold nanoparticles dispersed in nematic liquid crystals provides enhancement of the nonlinear index coefficient]
M. L. Tingey et al, “Orientations of Liquid Crystals on Chemically Functionalized Surfaces That Possess Gradients in Nanometer-Scale Topography”, Advanced Materials V 14, p. 1224-1227 (2002)
Lay Min Lee et al, “Anchoring and electro-optical dynamics of thin liquid crystalline films in a polyimide cell: Experiment and theory”, The Journal Of Chemical Physics 125, 024705 (2006)
Woo-Sang Park, “Determination of the Order Parameters of Nematic Liquid Crystals by Infrared Spectroscopy”, Journal of the Korean Physical Society, Vol. 37, No. 3, September 2000, pp. 331-334 Note that Alignment layers may also serve as molecular imprint layers.
88 E. B. Feresenbet et al, “Optical Chemical Sensing Using Nematic Liquid Crystal”, Sensor Letters, Vol. 2, pp. 145-152(8) (2004)
89 M. Kléman (1989): Invited Lecture. Defects in small-molecule and polymeric nematics, Liquid Crystals, 5:1, 399-417
90 C. Kavitha et al, (2013): ThermalAnalysis of Supramolecular Hydrogen-Bonded Liquid Crystals Formed by Nonyloxy and Alkyl Benzoic Acids, Molecular Crystals and Liquid Crystals, 574:1, 96-113
91 Nathan Lindquist et al, “Lateral confinement of surface plasmons and polarization-dependent optical transmission using nanohole arrays with a surrounding rectangular Bragg resonator”, Appl. Phys. Lett. 91, 253105 (2007);
Nathan C. Lindquist and coworkers, Phys. Rev. B 76, 155109 (2007) and Appl. Phys. Lett. 90, 243110 (2007).
Commercial GE surface plasmon BIAcore™ systems have a Δn sensitivity of about ˜10⁻⁶. Surface plasmon systems have reported attomolar (1×10⁻¹⁵ mole/liter) detection sensitivity of each nanohole on a glass substrate for proteins using in-hole SPR effects [J. Ferreira, J. et al, “Attomolar protein detection using in-hole surface plasmon resonance”, J. Am. Chem. Soc. 2009, 131, 436-437; see also Jing Feng et al, “Nanoscale Plasmonic Interferometers for Multispectral, High-Throughput Biochemical Sensing”, Nano Lett. 2012, 12, 602-609]. Refractive index resolution approaching an astounding resolution of ˜1×10⁻⁷ using SP sensors has been reported. [M. Piliarik and J. Homola, “Surface plasmon resonance (SPR) sensors: approaching their limits?”, Opt. Express 17 16505 (2009)].
92 Nathan C. Lindquist et al, “Periodic modulation of extraordinary optical transmission through subwavelength hole arrays using surrounding Bragg mirrors”, Physical Review B 76, 155109 (2007)
93 V. Tkachenko, “Electrical reorientation of liquid crystal molecules inside cylindrical pores for photonic device applications”, Journal Of Optics A: Pure And Applied Optics, 10 (2008) 055301 (6pp) describes the refractive index change with applied field in LC-impregnated pores. By measuring this curve (eg, with a plasmon array like LIPSAs atop imager pixels) the affect of analyte “impurities” on refractive index as a function of molecular anchoring energy W could be directly measured to distinguish different impurities.
94 Xuan Zhou et al, “Anchoring Of Twisted Chiral Nematic Liquid Crystals On A Thin Polymeric Film”, International Journal of Modern Physics B Vol. 26, No. 10 (2012) 1250064 (10 pages) Yang Zou et al, “Influence of a bias voltage on surface-driven orientational transitions for liquid crystal-based chemical and biological sensors
95 “Liquid crystals into planar photonic crystals”, Ferrini, R. Editor: Tkachenko, G. V., Published in: New developments in liquid crystals, Chapter 2 p. 21-48, Vukovar, Croatia: In-Tech, (2009)
96 Nathan C. Lindquist et al, “Sub-micron resolution surface plasmon resonance imaging enabled by nanohole arrays with surrounding Bragg mirrors for enhanced sensitivity and isolation”, Lab Chip, 2009, 9, 382-387
see also Nathan C. Lindquist et al, Appl. Phys. Lett. 91, 253105 (2007); doi: 10.1063/1.2825587
see also Qiao Min et al, “Plasmonic Bragg Reflectors: Optimization and Application to Isolation”, IEEE Journal Of Selected Topics In Quantum Electronics, Vol. 14, No. 6, November/December 2008
97 Yuichiro Ikenoya et al, “Optical Resonances in Short-Range Ordered Nanoholes in Ultrathin Aluminum/Aluminum Nitride Multilayers”, online publication as of Mar. 25, 2013 dx.doi.org/10.1021/jp401372k
98 Mapson-Menard, H and Waltham, N., ERCIM News 65 April 2006 Special theme: Space Exploration, “Large-Format Science-Grade CMOS Active Pixel Sensors for Extreme Ultra-Violet Space Science”
99 Olivier Daigle et al, “Characterization results of EMCCDs for extreme low light imaging”, Society of Photo-Optical Instrumentation Engineers 2012.
100 http://www.chipworks.com/blogs.aspx?id=8214&blogid=86 http://www.photographyblog.com/news/omnivision_launches_second-generation_backside_illumination_pixel_technolog/
101 Romain Fraux, “Omnivision's VGA Wafer-Level Camera”, 3D Packaging, Issue 22, p. 26-27 Feb. 2012
102 D. Gardner et al, PCT Publication WO 97/46004 published 4 Dec. 1997
T. G. Etoh et al, Toward 100 Mega-Frames per Second: Design of an Ultimate Ultra-High-Speed Image Sensor “, Sensors 2010, 10, 16-35
103 LCs such as fluoro-substituted alkyltolane-, alkylphenyltolane-, alkylphenyl- and alkylbiphenyltolane isothiocyanates, see E. Nowinowski-Kruszelnicki Et Al, “High Birefringence Liquid Crystal Mixtures For Electro-Optical Devices”, Optica Applicata, Vol. XLII, No. 1, p. 167-180 (2012)
104 M. O'Neill et al, “Ordered materials for organic electronics and photonics”, Adv Mater. 23(5): 566-84 (2011)
see A. C. Bedoya et al, “Liquid crystal dynamics in a photonic crystal cavity created by selective microfluidic infiltration”, Opt Express. 2010 Dec. 20; 18(26): 27280-90. doi: 10.1364/OE.18.027280 wrt polymerizable or ionic LCs with no vapor pressure.
105 M. R. Hays et al, “Nonlinear Bending Mechanics of Hygroscopic Liquid Crystal Polymer Networks”, J. Appl. Mech. 79(2), 021009 (2012)
106 Thet Naing Oo et al, “Surface Alignment of Liquid Crystal Multilayers Evaporated on a Photoaligned Polyimide Film Observed by Surface Profiler”, “Advances in Technology of Materials and Materials Processing”, 7[1] (2005) 77-86.
107 Sung H. Lim et al, “A Colorimetric Sensor Array for Detection and Identification of Sugars”, Org. Lett., Vol. 10, No. 20, 2008 4405-4408
Michael C. Janzen et al, “Colorimetric Sensor Arrays for Volatile Organic Compounds”, Anal. Chem. 2006, 78, 3591-3600
Shannon E. Stitzel et al, “Organic vapor detection with fiber-optic bead arrays”, SPIE Vol. 3858 pp. 92-97 (1999)
David R Walt, “Bead-based optical fiber arrays for artificial olfaction”, Current Opinion in Chemical Biology 2010, 14:767-770
108 Ki-Joong Kim et al, “Plasmonics-enhanced metal-organic framework nanoporous films for highly sensitive near-infrared absorption. J. Mater. Chem. C, 2015; 3 (12): 2763 DOI: 10.1039/C4TC02846E
109 N. Toriumi et al, “18π-electron tautomeric benziphthalocyanine: A functional near-infrared dye with tunable aromaticity.” Angewandte Chemie International Edition 53, 7814-7818 (2014). DOI: 10.1002/anie.201404020
110 Zampolli et al, “Real-time monitoring of sub-ppb concentrations of aromatic volatiles with a MEMS-enabled miniaturized gas-chromatograph”, Sensors and Actuators B 141 (2009) 322-328
111 Rakow, N. A. and K. S. Suslick, A colorimetric sensor array for odour visualization. Nature, 2000. 406: p. 710-713
112 Heidi J. VanTreeck et al, “Quantitative detection of a simulant of organophosphonate chemical warfare agents using liquid crystals”, Sensors and Actuators B: Chemical V 158, p 104-110 (2011)
Shah, R. R et al, “Principles for measurement of chemical exposure based on recognition-driven anchoring transitions in liquid crystals”, Science 293(5533): 1296-1299 (2001)
Cadwell K D et al., “Detection of organophosphorous nerve agents using liquid crystals supported on chemically functionalized surfaces”, Sensors and Actuators B 128 91-98 (2007)
113 J.-D. Marty et al, “New Molecular Imprinting Materials: Liquid Crystalline Networks”, Macromolecules, Vol. 32, p. 8674-8677 (1999)
Xiaohong Chen et al, “Electrochemical and Spectroscopic Characterization of Surface Sol-Gel Processes”, Langmuir 2004, 20, 8762-8767
Maurice C. Cheung et al, “Porous Nanostructured Encapsulation and Immobilization Materials for Optical Biosensors”, IEEE Journal Of Selected Topics In Quantum Electronics, VOL. 18, p 1147-1159 (2012)
Manuel Azenha et al, “The requisite level of theory for the computational design of molecularly imprinted silica xerogels”, Biosensors and Bioelectronics 23 (2008) 1843-1849
F. L. Dickert et al, “Nano- and micro-structuring of sensor materials—from molecule to cell detection”, Synthetic Metals 138 (2003) 65-69
V. B. Kandimalla et al, “Molecular imprinting: a dynamic technique for diverse applications in analytical chemistry”, Anal Bioanal Chem (2004) 380:587-605
114 Seung-Woo, L., N. Takahara, et al. (2011). “A novel mass-sensitive sensor based on-cyclodextrin anchored bisphenol a-imprinted TiO2 ultrathin layers.” Sensors and Materials 23(4): 229-236.
Han, D. M., G. L. Dai, et al. (2010). “Preparation and photocatalytic activity of Cu2+-doped 2, 4-dichlorophenol molecularly imprinted SiO2-TiO2 nanocomposite.” Micro &amp; Nano Letters 5(2): 76-80.
Xin, C., Y. Zhengpeng, et al. (2009). “Potentiometric urea biosensor based on immobilization of urease onto molecularly imprinted TiO2 film.” Journal of Electroanalytical Chemistry 635(1): 1-6.
Xiantao, S., Z. Lihua, et al. (2009). “Inorganic molecular imprinted titanium dioxide photocatalyst: synthesis, characterization and its application for efficient and selective degradation of phthalate esters.” Journal of Materials Chemistry 19(27): 4843-4851.
Fujikawa, S., E. Muto, et al. (2009). “Nanochannel design by molecular imprinting on a free-standing ultrathin titania membrane.” Langmuir 25(19): 11563-11568. [A free-standing ultrathin film of a poly(vinyl alcohol) (PVA)/TiO2) with template molecules (4PABA) was prepared by spin coating. The thickness of the film was adjusted to 30-50 nm by changing the spin-coating speed and solution concentration]
Mizutani, N., Y. Do-Hycon, et al. (2007). Fabrication and application of enantioselective TiO2 nanofilms by molecular imprinting. IEEE Sensors 2006, 22-25 Oct. 2006, Piscataway, NJ, USA, IEEE.
Yang, D.-H., M.-J. Ju, et al. (2006). “Design of highly efficient receptor sites by combination of cyclodextrin units and molecular cavity in TiO2 ultrathin layer.” Biosensors and Bioelectronics 22(3): 388-392.
Wang, C., C. Li, et al. (2006). “Phosphonate electrochemical recognition by molecularly imprinted deposited film.” Applied Surface Science 253(4): 2282-2288.
Shengshui, H., C. Li, et al. (2006). “Development of a parathion sensor based on molecularly imprinted nano-TiO2 self-assembled film electrode.” Sensors and Actuators B (Chemical) 117(1): 166-171.
Kunitake, T. and S.-W. Lee (2004). “Molecular imprinting in ultrathin titania gel films via surface sol-gel process.” Analytica Chimica Acta 504(1): 1-6.
Lee, S.-W., I. Ichinose, et al. (1998). “Molecular imprinting of azobenzene carboxylic acid on a TiO2 ultrathin film by the surface sol-gel process.” Langmuir 14(10): 2857-2863.
Xiao Li et al, “Two-Dimensional Molecular Imprinting Approach to Produce Optical Biosensor Recognition Elements”, Langmuir 2006, 22, 9658-9663
Nan Zhao et al, “Surface plasmon resonance detection of ametryn using a molecularly imprinted sensing film prepared by surface-initiated atom transfer radical polymerization”, sensors and actuators B 166-167 (2012) Sensors and Actuators B 166-167 (2012) 473-479 (selective molecular imprint enhancement plasmon detection of Ametryn insecticide)
Masakazu Yoshikawa et al, “Surface Plasmon Resonance Studies on Molecularly Imprinted Films”, Journal of Applied Polymer Science, Vol. 110, 2826-2832 (2008)
Masakazu Yoshikawa et al, “Molecularly imprinted films derived from Torlonw polyamide-imide”, Journal of Molecular Structure 739 (2005) 41-46
Ze-Hui Wei et al, “Low crosslinking imprinted coatings based on liquid crystal for capillary electrochromatography”, Journal of Chromatography A, 1237 (2012) 115-121
C. Binet et al, Benefit of liquid crystal moieties in the MIP technique Analytica Chimica Acta 591 (2007) 1.
Bin Peng et al, “Homogeneously Aligned Liquid-Crystal Polymer Brushes”, Advanced. Materials 12, 821-824 (2000)
115 N. Lindquist and coworkers. “Atomic Layer Deposition of Dielectric Overlayers for Enhancing the Optical Properties and Chemical Stability of Plasmonic Nanoholes”, ACS Nano VOL. 4▪NO. 2▪947-954 (2010)
116 Maurice C. Cheung et al, “Porous Nanostructured Encapsulation and Immobilization Materials for Optical Biosensors”, IEEE Journal Of Selected Topics In Quantum Electronics, V. 18, p. 1147-1159 (2012)
117 S. Y. Hwang et al, “DNA Chip Technologies”, Biotechnol. Bioprocess Eng. 2000, 5: 159-163
118 S. Y. Hwang, (1997) “Whole genome analysis using DNA chips”, Korean Soc. Med. Biochem. Mol. Biol. News 4: 28-34.
119 S. Singh-Gasson, et al, (1999) Maskless fabrication of light-directed oligonucleotide microarrays using a digital micromirror array “, Nat. Biotechnol. 17: 974-978.
120 Paul Rhodes et al, US Patent Publication 2012/0028820 A1, “Hybrid Sensor Array”, published Feb. 2, 2012
121 Dalcanale, Enrico et al, “Cavitands For Chemical Vapor Sensing”, US Patent Publication 11307966 (2007)
122 Hao Qi et al, “DNA-directed self-assembly of shape-controlled Hydrogels”, Nature Communications 4:2275 | DOI: 10.1038/ncomms3275 (2013)
123 Chan-Shan Yang et al, “The complex refractive indices of the liquid crystal mixture E7 in the terahertz frequency range”, J. Opt. Soc. Am. B/Vol. 27, p 1866-1873 (2010)
Molly Dutta Gupta et al, (2012) “Thermal Dependence of the Dielectric Behavior of Two Mesogens: A Comparative Study”, Molecular Crystals and Liquid Crystals, 557:1, 240-250
S. Chakraborty & A. Mukhopadhyay (2011): Study of Birefringence and Dielectric Properties and Determination of Dipole Moment of the Mesogen: 4-Cyano-4′-n-Octylbiphenyl as a Function of Temperature, Molecular Crystals and Liquid Crystals, 548:1, 155-163 [order parameter and refractive index (dielectric anisotropy) decrease with increasing temperature]
124 M. S. Zakerhamidi et al, “Dielectric anisotropy, refractive indices and order parameter of W-1680 nematic liquid crystal”, Journal of Molecular Liquids 181 (2013) 77-81
125 S. Sreehari Sastry et al, “Order parameter studies on EPAP alkanoate mesogens”, Liquid Crystals, 39:3, 295-301 (2012)
126 See H. Q. Le, “Compact Broad-band Wavelength-Agile Mid-infrared Semiconductor Lasers for Spectroscopic Sensing”, Final Progress Report DAAD19-00-1-0361 (2004) (compact, broadly tunable and wavelength agile IR lasers in the 3-10 micron range)
127 J. J. Greffet et al, “Coherent Emission Of Light By Thermal Sources,” Nature (London) 416, 61-64 (2002).
S. E. Han et al, “Beaming Thermal Emission From Hot Metallic Bull's Eyes”, Optics Express, Vol. 18, No. 5/4829-4837 (2010) By spreading an IR “rainbow” spectrum from a Greffet source on a sensor with many sensing elements along the spectral region, an IR absorption spectrum of the adsorbed vpor(s) can be obtained in parallel.
128 Yuan Chen Et Al, “Low Absorption Liquid Crystals For Mid-Wave Infrared Applications”, Optics Express, Vol. 19, No. 11, 10843 (2011) (Low Vis-1.5 Micron Absorption, 1.8-2 Micron)
Lara Scolari Et Al, “Low Loss Liquid Crystal Photonic Bandgap Fiber In The Near-Infrared Region”, Optical Review Vol. 18, No. 1 (2011) 114-116 (Low-Loss Through 2 Microns.)
129 Adam J. Mott et al, “Calculated infrared spectra of nerve agents and simulants”, Spectrochimica Acta Part A 91 (2012) 256-260
Shin-Tson Wu et al, “Perdeuterated cyanobiphenyl liquid crystals for infrared applications”, Journal of Applied Physics, Vol. 92 Issue 12, p 7146 (2002) [Perdeuterated 4′-pentyl-4-cyanobiphenyl (D5CB) exhibits a much cleaner and reduced infrared absorption than 5CB]
Shin-Tson Wu, Absorption measurements of liquid crystals in the ultraviolet, visible and infrared “, Journal of Applied Physics Vol. 84 p 4462 (1998) [complete absorption spectra of three liquid crystals measured in the 0.185-20 micron spectral range
130 Silicon CMOS and CCD imagers don't absorb at >1 micron. IR bands converted to heat by an IR absorbant in a liquid crystal, is converted to An change for detection in plasmon detector. The resonance wavelength change induced by the refraction change is detected by interrogating light. This can actually form the basis for an entirely new kind of cheap, high performance multiband IR detectors on silicon cameras, at ambient temperatures!
131 DoD has developed high-power IR lasers for standoff thermal detection of explosives which absorb ˜6.25 microns, to heat the material about 1 degree C. This permits standoff detection with IR cameras. The proposed IR detection via IR absorption in a plasmon sensor is much simpler to carry out, and is not limited to a 6.25 micron atmospheric window.
132 Miles J. Weida et al, “Tunable QC laser opens up mid-IR sensing applications”, Laser Focus World, Jul. 1, 2006
133 L. Cattaneo et al, “Sub-millisecond nematic liquid crystal switches using patterned command layer”, Journal Of Applied Physics 113, 014503 (2013)
134 Wang, L., E. Radue, et al. (2012). “Surface plasmon polaritons in VO2 thin films for tunable low-loss plasmonic applications.” Optics Letters 37(20): 4335-4337. (1520 nm with temperature change)
Tong, G., Y. Li, et al. (2012). “Research progress on the optical properties and preparation methods of vanadium dioxide nanoparticles.” Electronic Components &amp; Materials 31(3): 82-86.
Shi, Q. W., W. X. Huang, et al. (2012). “Synthesis and terahertz transmission properties of nano-porous vanadium dioxide films.” Journal of Physics D: Applied Physics 45(38): 385302 (385306 pp.). [sol-gel 30 nm grains with broad hysteresis loops]
Qiwu, S., H. Wanxia, et al. (2012). “Terahertz transmission characteristics across the phase transition in VO2 films deposited on Si, sapphire, and SiO2 substrates.” Journal of Applied Physics 112(3): 033523 (033526 pp.) [VO2 film on the SiO2 substrate exhibits the widest hysteresis loop with the steepest slope]
Jeong-Ho, C., B. Young-Jun, et al. (2012). “Thermochromic characteristics of WO3-doped vanadium dioxide thin films prepared by sol-gel method.” Ceramics International 38: 589-593.
Yan, J., W. Huang, et al. (2011). “Infrared optical properties of VO2 films on muscovite substrate with different thickness.” Infrared Laser Engineering 40(7): 1305-1309.
Shidong, J., Z. Feng, et al. (2011). “Preparation of high performance pure single phase VO2 nanopowder by hydrothermally reducing the V2O5 gel.” Solar Energy Materials and Solar Cells 95(12): 3520-3526 [single crystal VO2 nanopowder]
Litao, K., G. Yanfeng, et al. (2011). “VO2 Films by Polymer-assisted Deposition: Investigation of Thermal Decomposition of Precursor Gel and Control of Phase Transition Temperatures.” Materials Science Forum 687:791-797.
Kang, L., Y. Gao, et al. (2011). VO2 films by polymer-assisted deposition: Investigation of thermal decomposition of precursor gel and control of phase transition temperatures. 11th IUMRS International Conference in Asia, IUMRS-ICA2010, Sep. 25, 2010-Sep. 28, 2010, Qingdao, China, Trans Tech Publications Ltd.
Lysenko, S., V. Vikhnin, et al. (2010). “Critical behavior and size effects in light-induced transition of nanostructured VO2 films.” Physical Review B (Condensed Matter and Materials Physics) 82(20): 205425 (205413 pp.).
Zhang, Q., Z. Wu, et al. (2009). Study on preparation and electrical properties of Mo-doped vanadium oxide thin films by organic sol-gel. 2009 International Conference on Optical Instruments and Technology: Optoelectronic Imaging and Process Technology, 19-21 Oct. 2009, USA, SPIE—The International Society for Optical Engineering.
Mohamad, N. E., K. Okimura, et al. (2009). “Effect of light irradiation on electric-field-induced resistance switching phenomenon in planar VO2/c-Al2O3 structure.” International Journal of Nanoscience 8(1-2): 147-150.
Lysenko, S., A. Rua, et al. (2009). “Optical nonlinearity and structural dynamics of VO2 films.” Journal of Applied Physics 105 (4).
Yun, S. J., B.-G. Chae, et al. (2008). “Preparation of V2O3 thin films by the reduction of VO2 in a very low pressure.” Electrochemical and Solid-State Letters 11(7): H173-H175.
Yan, J., Y. Zhang, et al. (2008). “Preparation of W doped VO2 films and study on its thermochromic properties.” Rare Metal Materials and Engineering 37(9): 1648-1651.
Yan, J., Y. Zhang, et al. (2008). “Effect of Mo—W co-doping on semiconductor-metal phase transition temperature of vanadium dioxide film.” Thin Solid Films 516(23): 8554-8558.
Yan, J., W. Huang, et al. (2008). “Microstructure and optic properties of VO2 films fabricated on different substrates.” Rare Metal Materials and Engineering 37(5): 819-822.
Nag, J. and R. F. Haglund, Jr. (2008). “Synthesis of vanadium dioxide thin films and nanoparticles.” Journal of Physics: Condensed Matter 20(26): 264016 (264014 pp.).
Ge, Z.-h., K.-y. Zhao, et al. (2008). “Study on VO2 thin films prepared by inorganic sol-gel method.” Electronic Components &amp; Materials 27(11): 46-49.
Chae, B. G., H. T. Kim, et al. (2008). “Characteristics of W- and Ti-doped VO2 thin films prepared by sol-gel method.” Electrochemical and Solid-State Letters 11(6): 53-55.
Vikhnin, V. S., H. Liu, et al. (2007). “Charge transfer model of metal-insulator phase transition and ultrafast optical response in VO2.” Optical Materials 29(11): 1385-1389.
Lysenko, S., V. Vikhnin, et al. (2007). “Photoinduced insulator-to-metal phase transition in VO2 crystalline films and model of dielectric susceptibility.” Physical Review B (Condensed Matter and Materials Physics) 75(7): 75109-75101.
Byung-Gyu, C., K. Hyun-Tak, et al. (2006). “Highly oriented VO2 thin films prepared by sol-gel deposition.” Electrochemical and Solid-State Letters 9(1): 12-14.
Moffatt, C. and A. Wigstein (2005). So-Gel Synthesis of VO2 Thin Films and the Effects of W and Re doping. Sweden: 50p.
Zhang, S., S.-L. Jiang, et al. (2004). “Effect of preparing process on the micro-structure of thin film of vanadium oxide.” Electronic Components &amp; Materials 23(6): 35-37.
Yuan, N.-Y., J.-H. Li, et al. (2004). “Influence of grain boundary tunneling on the resistivity of the VO2 films prepared by sol-gel method.” Journal of Infrared and Millimeter Waves 23(4): 317-320.
Scherbakov, A. V., A. V. Akimov, et al. (2003). Optically induced Bragg switching in opal-VO2 photonic crystals. International Conference on Superlattices Nano-Structures and Nano-Devices. ICSNN 2002, 22-26 Jul. 2002, Netherlands, Elsevier [strong changes in the VO2 dielectric constant]
Yin, D., N. Xu, et al. (1996). “High quality vanadium dioxide films prepared by an inorganic sol-gel method.” Materials Research Bulletin 31(3): 335-340 [pretreatment of the gel films in water vapor at about 150 C can lower the heat-treatment temperature for obtaining the desired films]
Songwei, L., H. Lisong, et al. (1996). “Synthesis and phase transition of Cu2+ ion doped VO2 thin films.” Journal of Materials Science Letters 15(10): 856-857.
Sidorov, A. I. (1996). “Enhancement of a light-induced diffraction grating in a laser with a mirror on the basis of vanadium dioxide.” Optics and Spectroscopy 81(5): 800-803.
135 Ueda, S., N. Kawakami, et al. (2012). Spin and charge ordering in heterostructures of strongly correlated electron systems. 26th International Conference on Low Temperature Physics (LT26), 10-17 Aug. 2011, Beijing, China, UK, IOP Publishing Ltd.
Korshunov, M. M., S. G. Ovchinnikov, et al. (2012). “Cuprates, Manganites and Cobaltites: Multielectron Approach To The Band Structure.” Modern Physics Letters B 26(24): 1230016 (1230025 pp.).
Marley, P. M., A. A. Stabile, et al. (2013). “Charge disproportionation and voltage-induced metal-insulator transitions evidenced in —Pbx V2O5 nanowires.” Advanced Functional Materials 23(2): 153-160.
Itoh, K. et al. (2013). “Collective excitation of an electric dipole on a molecular dimer in an organic dimer-Mott insulator.” Physical Review Letters 110(10).
Seo, S. S. A., W. S. Choi, et al. (2007). “Optical study of the free-carrier response of LaTiO3/SrTiO3 superlattices.” Physical Review Letters 99(26): 266801
Hotta, Y., T. Susaki, et al. (2007). “Polar discontinuity doping of the LaVO3/SrTiO3 interface.” Physical Review Letters 99(23): 236805-236801.
Nakamura, M., A. Sawa, et al. (2007). “Optical probe of electrostatic-doping in an n-type Mott insulator.” Physical Review B (Condensed Matter) 75(15): 155103-155101.
Junwoo, S., B. Jalan, et al. (2011). “Probing the metal-insulator transition of NdNiO3 by electrostatic doping.” Applied Physics Letters 99(19): 192107 (192103 pp.).
Son, J., S. Rajan, et al. (2011). “A heterojunction modulation-doped Mott transistor.” Journal Of Applied Physics 110(8): 084503 (084504 pp.).
Okamoto, S. and A. J. Millis (2004). “Electronic reconstruction at an interface between a Mott insulator and a band insulator.” Nature 428(6983): 630-633.
Okamoto, S. and A. J. Millis (2004). “Theory of Mott insulator-band insulator heterostructures.” Physical Review B (Condensed Matter and Materials Physics) 70(7): 75101-75101.
Okamoto, S. and A. J. Millis (2004). “Spatial inhomogeneity and strong correlation physics: a dynamical mean-field study of a model Mott-insulator-band-insulator heterostructure.” Physical Review B (Condensed Matter and Materials Physics) 70(24): 241104-241101.
Okamoto, S. and A. J. Millis (2005). “Interface ordering and phase competition in a model Mott-insulator-band-insulator heterostructure.” Physical Review B (Condensed Matter and Materials Physics) 72(23): 235108-235101.
Okamoto, S. and A. J. Millis (2005). “Interface phenomena in correlated electron systems.” Physica B 359-361:1378-1380.Okamoto, S. and A. J. Millis (2005). Electronic reconstruction in correlated electron heterostructures. Strongly Correlated Electron Materials: Physics and Nanoengineering, 31 Jul. 2005, USA, SPIE
Takizawa, M., H. Wadati, et al. (2006). “Photoemission from buried interfaces in SrTiO3/LaTiO3 superlattices.” Physical Review Letters 97(5): 057601-057601.
136 Chia-Sheng Cheng et al, “Organic vapour sensing using localized surface plasmon resonance spectrum of metallic nanoparticles self assemble monolayer”, Talanta 73 (2007) 358-365
137 J. Henzie et al, “Multiscale patterning of plasmonic metamaterials”, Nature Nanotechnology Vol 2 p. 549-54 (2007)
138 Kazuhiko Hashimoto et al, “Si monolithic microbolometers of ferroelectric BST thin film combined with readout FET for uncooled infrared image sensor”, Sensors and Actuators A 88 (2001) 10-19
139 Other phenomena such as photoluminescence and light amplification associated with Liquid Crystal anisotropy which can be modified by analyte presence are also good candidates for a plasmon-pixel camera system:
Qing-lan Ma et al., “Tunable photoluminescence of porous silicon by liquid crystal infiltration” Journal of Luminescence 131(2011) 2053-2057 describes UV-excited tunable luminescence of 5CB (blue) in porous silicon (red). Analyte impurities such as nitrate explosives should affect photoluminescence.
   Liquid crystalline chromophores for photonic band-edge laser devices
S. M. Morris, et al. Optical Materials (advance online publication), (2012)
D. J. Gardiner et al, Printed photonic arrays from self-organized chiral nematic liquid crystals “, Soft Matter, 8, 9977 (2012)
Electrically switchable random to photonic band-edge laser emission in chiral nematic liquid crystals S. M. Morris, D. J. Gardiner, P. J. W. Hands, M. M. Qasim, T. D. Wilkinson, I. H. White, H. J. Coles Applied Physics Letters, 100, 071110 (2012)
S. M. Morris et al, “Lowering the excitation threshold of a random laser using the dynamic scattering states of an organosiloxane smectic A liquid crystal”, Journal of Applied Physics, 111, 033106, (2012)
140 see for example Hyungsoon Im et al, “Vertically Oriented Sub-10-nm Plasmonic Nanogap Arrays” Nano Lett. 2010, 10, 2231-2236
Yang Jiao et al, “Controlling surface enhanced Raman scattering using grating-type patterned nanoporous gold substrates”, Optical Materials Express 3:1137 (2013)
Jing Feng et al, “Nanoscale Plasmonic Interferometers for Multispectral, High-Throughput Biochemical Sensing” Nano Lett. 2012, 12, 602-609
141 Alexei L. Glebov et al, “Volume Bragg Gratings as Ultra-Narrow and Multiband Optical Filters”, Proc. of SPIE Vol. 8428 84280C-1 (2012)
142 Jing Feng et al, “Nanoscale Plasmonic Interferometers for Multispectral, High-Throughput Biochemical Sensing”, Nano Lett. 2012, 12, 602-609
143 Ankun Yang et al, “Real-time tunable lasing from plasmonic nanocavity arrays”, Nature Communications (2015) 6:6939 | DOI: 10.1038/ncomms7939
144 See the following for Rainbow and/or chirped plasmon structures which can be combined with SERS analyte plasmon structures for compact sensor systems in accordance with the present disclosure: Yu Zhu et al, “Theoretical study of the all-optical tunable rainbow-trapping-like effect in chirped plasmonic slot waveguides”, Journal of Optics 15 (2013) 035003 (6pp)
Chao Zeng et al, “Rainbow trapping of surface plasmon polariton waves in metal-insulator-metal graded grating waveguide”, Optics Communications 290 (2013) 188-191
L. Chen et al, “Broadband slow-light in graded-grating-loaded plasmonic waveguides at telecom frequencies”, Appl Phys B (2011) 104:653-657
Qiaoqiang Gan et al, “Adiabatically Graded Plasmonic Structures for rainbow trapping effect”, 978-1-4244-8939-8/11/(2011) IEEE
Qiaoqiang Gan et al, “Experimental verification of the rainbow trapping effect in adiabatic plasmonic gratings”, PNAS | Mar. 29, 2011 | vol. 108 | no. 13 | 5169-5173
Yulan Fu et al, “Ultrawide-band photon routing based on chirped plasmonic gratings” Applied Physics Letters 102, 151110 (2013)
Dragomir N. Neshev et al, “Near-field studies of arrays of chirped subwavelength apertures”, Phys. Status Solidi RRL 4, No. 10, 253-255 (2010)
145 Zhao Jun, L., et al. (2013). “360 PPI Flip-Chip Mounted Active Matrix Addressable Light Emitting Diode on Silicon (LEDoS) Micro-Displays.” Journal of Display Technology 9(8): 678-682.
Liu, Z. J., et al. (2013). “A novel BLU-free full-color LED projector using LED on silicon micro-displays.” IEEE Photonics Technology Letters 25(23): 2267-2270.
Tokuda, T., et al. (2012). A CMOS-based on-chip neural interface device equipped with integrated LED array for optogenetics. 2012 34th Annual International Conference of the IEEE Engineering in Medicine and Biology Society (EMBC), 28 August-1 Sep. 2012, Piscataway, NJ, USA, IEEE.
Henry, B. (2012). A Multi-pixel LED Print-head for Novel Imaging Applications. NIP28. 28th International Conference on Digital Printing Technologies, 9-13 Sep. 2012, Springfield, VA, USA, IS&T: The Society for Imaging Science and Technology.
Amann, M.-C. and W. Hofmann (2008). “Single-mode and tunable VCSELs in the near- to mid-infrared.” Chinese Optics Letters 6(10): 743-747.
Kasten, A. M., et al. (2007). Fabrication and characterization of individually addressable vertical-cavity surface-emitting laser arrays and integrated VCSEL/PIN detector arrays. Vertical-Cavity Surface-Emitting Lasers XI, 24 Jan. 2007, USA, SPIE—The International Society for Optical Engineering.
Bare, H. F., et al. (1993). “A simple surface-emitting LED array useful for developing free-space optical interconnect.” IEEE Photonics Technology Letters 5(2): 172-175.
146 https://www.sparkfun.com/products/12923?gclid=CMn 9M2UgsoCFRAbgQodV10BUQ
147 Commercial INSlam™ S Laser Array Modules contain individually addressable single mode laser arrays of up to 100 emitters on a single monolithic chip at a number of wavelengths to suit the specific application. Arrays of 650 or 780 nm, single mode lasers with narrow and customizable pitch are also available-such as for use in the specific test device of FIG. 32 which uses nanohole array transmissive in the “red” nm region http://www.intenseco.com/products/inslam/inslam-s.asp
148 Chunfeng Wang et al, “Enhanced emission intensity of vertical aligned flexible ZnO nanowire/p-polymer hybridized LED array by piezo-phototronic effect”, Nano Energy, 14 (2015) Pages 364-371 Special issue on the 2nd International Conference on Nanogenerators and Piezotronics (NGPT 2014) C. L. Chua et al, “Independently addressable VCSEL arrays on 3-μm pitch”, IEEE Photonics Technology Letters (1998) 10(7): 917-919. DOI: 10.1109/68.681269
149 Mial E. Warren et al, “Integration of Diffractive Lenses with Addressable Vertical-Cavity Laser Arrays”, Proc. SPIE 2398, (1995) doi: 10.1117/12.206343
150 L. Zhu et al, “LED with integrated microlens array patterned by an ultraviolet linear micro-LED array”, Photonics Global Conference (PGC), 2010, pp 1-3, DOI: 10.1109/PGC.2010.5705976
151 dx.doi.org/10.1021/n1203325s | Nano Lett. 2012, 12, 602-609 Analyst, 2015, 140, 7263-7270
152 Reichardt, C., “Solvatochromic dyes as solvent polarity indicators,” Chemical Reviews 94, 2319-2358 (1994).
Blum, P., Mohr, G. J., Matern, K., Reichert, J., and Spichiger-Keller, U. E., “Optical alcohol sensor using lipophilic Reichardt's dyes in polymer membranes,” Analytica chimica acta 432, 269-275 (2001).
Sadaoka, Y., Sakai, Y., and Murata, Y.-u., “Optical humidity and ammonia gas sensors using Reichardt's dye-polymer composites,” Talanta 39, 1675-1679 (1992).
153 49. Nagpal, et al, “Ultrasmooth patterned metals for plasmonics and metamaterials,” Science 325, 594 (2009).
50. Lindquist, N. C., Nagpal, P., McPeak, K. M., Norris, D. J., and Oh, S.-H., “Engineering metallic nanostructures for plasmonics and nanophotonics,” Reports on Progress in Physics 75, 036501 (2012).
51. Hegner, M. et al, “Ultralarge atomicaliy flat template-stripped Au surfaces for scanning probe microscopy,” Surface Science 241, 39 (1993).
52. Lindquist, N. C. et al, “Monolithic Integration of Continuously Tunable Plasmonic Nanostructures,” Nano Letters 11, 3526 (2011).
154 Lindquist, N. C. et al, “Template fabricated plasmonic nanoholes on analyte-sensitive substrates for real-time vapor sensing,” RSC Advances 4, 15115-15121 (2014)
155 Eg, U.S. Pat. Nos. 8,871,149; 8,656,754; 8,499,615; 8,196,450; 7,130,534; 6,338,823; 6,612,153; 5,686,657; 4,057,998; 4,044,593;
generally, see also (recommended at: http://www.sigmaaldrich.com/analytical-chromatography/gas-chromatography/column-selection.html)
Harold McNair and James Miller, “Basic Gas Chromatography” (1997), Wiley, ISBN 0-471-17261-8.
David Grant, “Capillary Gas Chromatography” (1996), Wiley, ISBN 0-471-95377-6.
Dean Rood, “A Practical Guide to the Care, Maintenance, and Troubleshooting of Capillary Gas Chromatographic Systems” (1991), Hüthig, ISBN 3-7785-1898-4.
Konrad Grob, “Split and Splitless Injection in Capillary GC” (1993), Hüthig, ISBN 3-7785-2151-9.
Konrad Grob, “On-Column Injection in Capillary Gas Chromatography” (1991), Hüthig, ISBN 3-7785-2055-5.
William McFadden, “Techniques of Combined Gas Chromatography/Mass Spectrometry: Applications in Organic Analysis” (1988), Robert E. Krieger Publishing Company, ISBN 0-89464-280-4.
Marvin McMaster and Christopher McMaster, “GC/MS: A Practical User's Guide” (1998), Wiley-VCH, ISBN 0-471-24826-6.
Janusz Pawliszyn, “Solid Phase Microextraction: Theory and Practice” (1997), Wiley-VCH, ISBN 0-471-19034-9.
156 Eg, see U.S. Pat. No. 6,453,725,
157 Yi Li et al, “High-separation efficiency micro-fabricated multi-capillary gas chromatographic columns for simulants of the nerve agents and blister agents”, Nanoscale Research Letters 2014, 9:224
Rekha S. Pai et al, “Microfabricated Gas Chromatograph for Trace Analysis”, 2008 IEEE Conference on Technologies for Homeland Security (THS '08), 12-13 May 2008 pp 150-15
David F. Lemmerhirt et al, “Chip-Scale Integration of Data-Gathering Microsystems”, Vol. 94, No. 6, June 2006 | Proceedings of the IEEE 11-38-1159
M. Agah, et al, “High-speed MEMS-based gas chromatography”, IEEE Dig. Int. Electron Devices Meeting, 2004, pp. 27-30
Sandro Mengali et al, “Rapid screening and identification of illicit drugs by IR absorption”, Proc. of SPIE Vol. 8631, 86312F (2013)
Milad Navaei et al, “All Silicon Micro-GC Column Temperature Programming Using Axial Heating”, Micromachines 2015, 6, 865-878
Alastair C. Lewis et al, “Microfabricated planar glass gas chromatography with photoionization detection”, Journal of Chromatography A, 1217 (2010) 768-774
Jan Dziuban et al, “Silicon Components for Gas Chromatograph”, Proc. SPIE 4516, Optoelectronic and Electronic Sensors IV, 249 (Aug. 8, 2001); doi: 10.1117/12.435932
M. Navaei et al, “Micro-Fabrication of All Silicon 3 Meter GC Columns Using Gold Eutectic Fusion Bonding”, ECS Journal of Solid State Science and Technology, 4 (10) S3011-S3015 (2015)
Milad Navaei et al, “All Silicon Micro-GC Column Temperature Programming Using Axial Heating”, Micromachines (2015), 6, 865-878
158 http://www.iarpa.gov/index.php/research-programs/maeglin
159 Eg, U.S. Pat. Nos. 8,871,149; 8,656,754; 8,499,615; 8,196,450; 7,130,534; 6,338,823; 6,612,153; 5,686,657; 4,057,998; 4,044,593; 6,453,725,
generally, see also (recommended at: http://www.sigmaaldrich.com/analytical-chromatography/gas-chromatography/column-selection.html)
Harold McNair and James Miller, “Basic Gas Chromatography” (1997), Wiley, ISBN 0-471-17261-8.
David Grant, “Capillary Gas Chromatography” (1996), Wiley, ISBN 0-471-95377-6.
Dean Rood, “A Practical Guide to the Care, Maintenance, and Troubleshooting of Capillary Gas Chromatographic Systems” (1991), Hüthig, ISBN 3-7785-1898-4.
Konrad Grob, “Split and Splitless Injection in Capillary GC” (1993), Hüthig, ISBN 3-7785-2151-9.
Konrad Grob, “On-Column Injection in Capillary Gas Chromatography” (1991), Hüthig, ISBN 3-7785-2055-5.
William McFadden, “Techniques of Combined Gas Chromatography/Mass Spectrometry: Applications in Organic Analysis” (1988), Robert E. Krieger Publishing Company, ISBN 0-89464-280-4.
Marvin McMaster and Christopher McMaster, “GC/MS: A Practical User's Guide” (1998), Wiley-VCH, ISBN 0-471-24826-6.
Janusz Pawliszyn, “Solid Phase Microextraction: Theory and Practice” (1997), Wiley-VCH, ISBN 0-471-19034-9.
Spectral MWIR libraries are readily available. Bio-Rad's KnowItAll™ IR Spectral Library has over 235,000 infrared spectra. This resource can be used with Bio-Rad's KnowItAll™ software, or software from a number of IR instrument vendors to identify unknown spectra. Bio-Rad publication 96559-REV20151119 www.Bio-Rad.com Informatics Division www.knowitall.com
160 Yi Li et al, “High-separation efficiency micro-fabricated multi-capillary gas chromatographic columns for simulants of the nerve agents and blister agents”, Nanoscale Research Letters 2014, 9:224
Rekha S. Pai et al, “Microfabricated Gas Chromatograph for Trace Analysis”, 2008 IEEE Conference on Technologies for Homeland Security (THS '08), 12-13 May 2008 pp 150-15
David F. Lemmerhirt et al, “Chip-Scale Integration of Data-Gathering Microsystems”, Vol. 94, No. 6, June 2006 | Proceedings of the IEEE 11-38-1159
M. Agah, et al, “High-speed MEMS-based gas chromatography”, IEEE Dig. Int. Electron Devices Meeting, 2004, pp. 27-30
Sandro Mengali et al, “Rapid screening and identification of illicit drugs by IR absorption”, Proc. of SPIE Vol. 8631, 86312F (2013)
Milad Navaei et al, “All Silicon Micro-GC Column Temperature Programming Using Axial Heating”, Micromachines 2015, 6, 865-878
Alastair C. Lewis et al, “Microfabricated planar glass gas chromatography with photoionization detection”, Journal of Chromatography A, 1217 (2010) 768-774
Jan Dziuban et al, “Silicon Components for Gas Chromatograph”, Proc. SPIE 4516, Optoelectronic and Electronic Sensors IV, 249 (Aug. 8, 2001); doi: 10.1117/12.435932
M. Navaei et al, “Micro-Fabrication of All Silicon 3 Meter GC Columns Using Gold Eutectic Fusion Bonding”, ECS Journal of Solid State Science and Technology, 4 (10) S3011-S3015 (2015)
Milad Navaei et al, “All Silicon Micro-GC Column Temperature Programming Using Axial Heating”, Micromachines (2015), 6, 865-878
161 Eg, see J. Bao et al, “Negative Temperature Programming Using Microwave Open Tubular Gas Chromatography”, Journal of Chromatographic Science, Vol. 44, 108-112 (2006)
U.S. Pat. No. 7,130,534 “Gas chromatograph having a radiant oven for analytical devices”
162 Georgios D. Stefanidis et al, “A helicopter view of microwave application to chemical processes: reactions, separations, and equipment concepts”, Rev Chem Eng 2014; 30(3): 233-259
163 https://en.wikipedia.org/wiki/Infrared_spectroscopy_correlation_table
N. Ragunathan et al, “Gas chromatography with spectroscopic detectors”, Journal of Chromatography A, 856 (1999) 349-397
N. Ragunathan, “Multispectral detection for gas chromatography”, Journal of Chromatography A, 703 (1995) 335-382
Medha J. Tomlinson et al, “Applications Of Multidimensional Gas Chromatography-Mass Spectrometry And Gas Chromatography-Fourier Transform Infrared-Mass Spectrometry”, Mass Spectrometry Reviews, 15, 1-14 (1996)
164 Giovanni Brucoli et al, “High efficiency quasi-monochromatic infrared emitter”, Applied Physics Letters 104, 081101 (2014); doi: 10.1063/1.4866342

### Narrow Bandwidth and Highly Polarized Ratio Infrared Thermal Emitter

Appl. Phys. Lett. 97, 163112 (2010); 10.1063/1.3503631

### Two-Dimensional Tungsten Photonic Crystals as Selective Thermal Emitters

Appl. Phys. Lett. 92, 193101 (2008); 10.1063/1.2927484

### High Performance Midinfrared Narrow-Band Plasmonic Thermal Emitter

Appl. Phys. Lett. 89, 173116 (2006); 10.1063/1.2364860
Hira Nasim et al, “Diode lasers: From laboratory to industry” Optics & Laser Technology 56 (2014) 211-222
R. F. Curl et al, “Tunable infrared laser spectroscopy”, Annu. Rep. Prog. Chem., Sect. C, 2002, 98, 219-272
165 see http://www.Quantumcomposers.com
166 see http://www.m2k-laser.de/m2k-laser e.htm for commercial lasers
M. T. Kelemen et al, “Diode laser systems for 1.8 to 2.3 μm wavelength range”, Proceedings of the SPIE, vol. 7686, paper 20 (2010)
M. T. Kelemen, J. Gilly, M. Rattunde, J. Wagner, S. Ahlert, J. Biesenbach “Mid-infrared high-power diode lasers and modules”, Proceedings of the SPIE, vol. 7583, paper 23 (2010)
M. T. Kelemen, J. Gilly, S. Ahlert, H. Kissel, J. Biesenbach, M. Rattunde, J. Wagner “Diode laser arrays for 1.8 to 2.3 μm wavelength range”, Proceedings of the SPIE, vol. 7483, paper 11 (2009)
M. T. Kelemen, J. Gilly, M. Haag, J. Biesenbach, M. Rattunde, J. Wagner “Diode laser arrays for the 1.8 to 2.2 μm range”, Proceedings of the SPIE, vol. 7230, paper 56 (2009)
M. T. Kelemen, J. Weber, R. Moritz, J. Schmitz, M. Rattunde, J. Wagner, “High-power diode lasers for the 1.9 to 2.2 μm range”, Proceedings of the SPIE, vol. 6876, paper 13 (2008)
J. Gilly, P. Friedmann, J. Schleife, R. Moritz, M. Rattunde, M. Haag, M. T. Kelemen, “High-power diode laser bars for the 1.85 to 2.25 μm wavelength range”, Talk, MIOMD IX, Freiburg, Germany, September 7-11 (2008)
M. T. Kelemen et al, “High-power diode laser arrays emitting at 2 μm with reduced far-field angle”, Novel In-Plane Semiconductor Lasers V, Proceedings of the SPIE, vol. 6133, paper 45 (2006)
M. Rattunde et al, “GaSb based 1.9-2.4 μm quantum-well diode lasers with low beam divergence”, SPIE Proc. Vol. 5738, Paper 19 (2005)
J. Wagner et al, “(AlGaIn) (AsSb) quantum well diode lasers with improved beam quality”, SPIE Proc. Vol. 5732, Paper 82 (2005)
M. T. Kelemen et al, “High-power diode laser arrays at 2 μm for materials processing”, Proceedings of the Third International WLT-Conference on Lasers in Manufacturing 2005, (2005)
“High Brightness Emitters and Arrays” in “High Power Diode Lasers: Technology and Applications”, published by F. Bachmann, P. Loosen, Springer, ISBN 978-0-387-34453-9, 0387344535 (2007)
“Antimonide Quantum Well Laser Diodes for the 2-3 μm spectral range” in “Solid-state mid-infrared laser sources”, published by I. T. Sorokina, K. L. Vodopyanov, Springer, ISBN 3540006214, 9783540006213 (2003)
see also http://www.ipgphotonics.com/Mid_ir lasers.htm for commercil middle Infrared lasers (2-5 μm) based on ZnSe/S and U.S. Pat. Nos. 5,541,948; 6,960,486; 7,548,571
167 N. J. C. I.ibatique et al, “A compact diode-pumped passively Q-switched mid-IR fiber laser”, CLEO 2000 p 76-77 (2000)
A Oladeji et al, “Design of erbium doped double clad ZBLAN Fibre laser”, Journal of Physics: Conference Series 619 (2015) 012044
168 See http://atoptics.com/index.html
169 Christopher A. Kendziora et al, “Detection of trace explosives on relevant substrates using a mobile platform for photothermal infrared imaging spectroscopy (PT-IRIS)”, Proc. of SPIE Vol. 9467 94672R-2
170 Rei Kitamura et al, “Optical constants of silica glass from extreme ultraviolet to far infrared at near room temperature”, Applied Optics 46:8118-8133 (2007)
171 Dmitry A. Kozak et al, “Infrared spectroscopy for chemical agent detection using tailored hypersorbent materials”, Proc. of SPIE Vol. 9482 94820E-1 (2015)
172 You Wang et al, “Refractive indices and extinction coefficients of polymers for the mid-infrared region”, You Wang et al, 1998 y Vol. 37, No. 30 y Applied Optics 7091-7095
173 B. Zimmermann et al, “Studies on siloxane polymers for NIR-evanescent wave absorbance sensors”, Sensors and Actuators B 41 (1997) 45-54
Helmut Ritter et al, “Linkage of a-cyclodextrin-terminated poly(dimethylsiloxanes) by inclusion of quasi bifunctional ferrocene”, Beilstein J. Org. Chem. (2013), 9, 1278-1284 (IR windows in polysiloxanes)
174 Perkin Elmer Application Note “Infrared Spectroscopy-Polymer Identification Using Mid Infrared Spectroscopy” 010007_01 (2011)
175 B. Cole et al, “Core/clad selenide glass fiber doped with Pr 3+ for active mid-IR applications”, Journal Of Materials Science Letters 20, 2000, 465-467
176 Vincent Fortin et al, “Monolithic mid-infrared fiber lasers for the 2-4 μm spectral region” SPIE Vol. 8601, 86011H (2013)
177 Xiushan Zhu et al, “Compact 2 W wavelength-tunable Er:ZBLAN mid-infrared fiber laser”, Optics Letters V. 32 p. 2381-2383 (2007)
178 A. Lancaster et al, “Mid-infrared laser emission from Fe:ZnSe cladding waveguides”, Applied Physics Letters 107, 031108 (2015)
179 Espen Lippert et al, “High-power fiber-laser-pumped mid-infrared laser sources”, Proc. of SPIE Vol. 6397 639704-1 (2006)
180 Billy Richards et al, “˜2 lm Tm3+/Yb3+-doped tellurite fibre laser”, J Mater Sci: Mater Electron (2009) 20:S317-S320
181 Chenan Xia et al, “10.5 W Time-Averaged Power Mid-IR Supercontinuum Generation Extending Beyond 4 μm With Direct Pulse Pattern Modulation”, IEEE Journal Of Selected Topics In Quantum Electronics, VOL. 15. P. 422-434 (2009)
C. Kneis et al, “4.5 W mid-infrared supercontinuum generation in a ZBLAN fiber pumped by a Q-switched mode-locked Tm 3+-doped fiber laser”, Proc. of SPIE Vol. 9342 93420B-1 (2015)
Yang Wei-Qiang et al, “A novel 2-μm pulsed fiber laser based on a supercontinuum source and its application to mid-infrared supercontinuum generation”, Chin. Phys. B Vol. 23, No. 5 (2014) 054208
Xiaojun Xu et al, “High Power Mid-Infrared Continuous-Wave Optical Parametric Oscillator Pumped by Fiber lasers”, Proc. of SPIE Vol. 9255 925507-1 (2015)
M. Bernier et al, “Mid-infrared chalcogenide glass Raman fiber laser”, Optics Letters V.38 p. 127-129 (2013)
182 Kannan Krishnaswami et al, “Characterization of Single-mode Chalcogenide Optical Fiber for Mid-Infrared Applications”, Proc. of SPIE Vol. 7325, 73250Z (2009)
Nurmemet Abdukerim et al, “Mid-Infrared Raman Fiber Laser In Chalcogenide Microwire”, IEEE Photonics North Conference Proceedings, p. 1 (2015) DOI: 10.1109/PN.2015.7292476
183 Rei Kitamura et al, “Optical constants of silica glass from extreme ultraviolet to far infrared at near room temperature”, Applied Optics V. 46 p. 8118-8133 (2007)
184 eg, Float Zone Silicon including High Resistivity Float Zone Silicon is conventionally optimized for IR transmission, http://www.tydex.ru; HiTrantm silicon of Topsil Semiconductor Materials A/S, Siliciumvej 1 DK-3600 Frederikssund Denmark
185 Sandro Mengali et al, “Rapid screening and identification of illicit drugs by IR absorption”, Proc. of SPIE Vol. 8631, 86312F (2013)
For examples of selective MWIR absorption bands, see R. F. Curl et al, “Tunable infrared laser spectroscopy”, Annu. Rep. Prog. Chem., Sect. C, 2002, 98, 219-272
186 The lightpipe can be longer, for example if it is desired to have all or most of the GC column (including capillary columns) function as an MWIR selective irradiation zone.
187 J. Herbst et al, “Hollow fiber based quantum cascade laser spectrometer for fast and sensitive drug identification”, Proc. of SPIE Vol. 8268, 82681Q⋅(2012)
188 see http://www.Quantumcomposers.com
189 see http://www.m2k-laser.de/m2k-laser e.htm for commercial lasers
M. T. Kelemen et al, “Diode laser systems for 1.8 to 2.3 μm wavelength range”, Proceedings of the SPIE, vol. 7686, paper 20 (2010)
M. T. Kelemen, J. Gilly, M. Rattunde, J. Wagner, S. Ahlert, J. Biesenbach “Mid-infrared high-power diode lasers and modules”, Proceedings of the SPIE, vol. 7583, paper 23 (2010)
M. T. Kelemen, J. Gilly, S. Ahlert, H. Kissel, J. Biesenbach, M. Rattunde, J. Wagner “Diode laser arrays for 1.8 to 2.3 μm wavelength range”, Proceedings of the SPIE, vol. 7483, paper 11 (2009)
M. T. Kelemen, J. Gilly, M. Haag, J. Biesenbach, M. Rattunde, J. Wagner “Diode laser arrays for the 1.8 to 2.2 μm range”, Proceedings of the SPIE, vol. 7230, paper 56 (2009)
M. T. Kelemen, J. Weber, R. Moritz, J. Schmitz, M. Rattunde, J. Wagner, “High-power diode lasers for the 1.9 to 2.2 μm range”, Proceedings of the SPIE, vol. 6876, paper 13 (2008)
J. Gilly, P. Friedmann, J. Schleife, R. Moritz, M. Rattunde, M. Haag, M. T. Kelemen, “High-power diode laser bars for the 1.85 to 2.25 μm wavelength range”, Talk, MIOMD IX, Freiburg, Germany, September 7-11 (2008)
M. T. Kelemen et al, “High-power diode laser arrays emitting at 2 μm with reduced far-field angle”, Novel In-Plane Semiconductor Lasers V, Proceedings of the SPIE, vol. 6133, paper 45 (2006)
M. Rattunde et al, “GaSb based 1.9-2.4 μm quantum-well diode lasers with low beam divergence”, SPIE Proc. Vol. 5738, Paper 19 (2005)
J. Wagner et al, “(AlGaIn) (AsSb) quantum well diode lasers with improved beam quality”, SPIE Proc. Vol. 5732, Paper 82 (2005)
M. T. Kelemen et al, “High-power diode laser arrays at 2 μm for materials processing”, Proceedings of the Third International WLT-Conference on Lasers in Manufacturing 2005, (2005)
“High Brightness Emitters and Arrays” in “High Power Diode Lasers: Technology and Applications”, published by F. Bachmann, P. Loosen, Springer, ISBN 978-0-387-34453-9, 0387344535 (2007) “Antimonide Quantum Well Laser Diodes for the 2-3 μm spectral range” in “Solid-state mid-infrared laser sources”, published by I. T. Sorokina, K. L. Vodopyanov, Springer, ISBN 3540006214, 9783540006213 (2003)
see also http://www.ipgphotonics.com/Mid_ir lasers.htm for commercil middle Infrared lasers (2-5 μm) based on ZnSe/S and U.S. Pat. Nos. 5,541,948; 6,960,486; 7,548,571
190 N. J. C. I.ibatique et al, “A compact diode-pumped passively Q-switched mid-IR fiber laser”, CLEO 2000 p 76-77 (2000)
A Oladeji et al, “Design of erbium doped double clad ZBLAN Fibre laser”, Journal of Physics: Conference Series 619 (2015) 012044
191 See http://atoptics.com/index.html
192 Christopher A. Kendziora et al, “Detection of trace explosives on relevant substrates using a mobile platform for photothermal infrared imaging spectroscopy (PT-IRIS)”, Proc. of SPIE Vol. 9467 94672R-2
193 Rei Kitamura et al, “Optical constants of silica glass from extreme ultraviolet to far infrared at near room temperature”, Applied Optics 46:8118-8133 (2007)
194 Dmitry A. Kozak et al, “Infrared spectroscopy for chemical agent detection using tailored hypersorbent materials”, Proc. of SPIE Vol. 9482 94820E-1 (2015)
195 You Wang et al, “Refractive indices and extinction coefficients of polymers for the mid-infrared region”, You Wang et al, 1998 y Vol. 37, No. 30 y Applied Optics 7091-7095
196 B. Zimmermann et al, “Studies on siloxane polymers for NIR-evanescent wave absorbance sensors”, Sensors and Actuators B 41 (1997) 45-54
Helmut Ritter et al, “Linkage of a-cyclodextrin-terminated poly(dimethylsiloxanes) by inclusion of quasi bifunctional ferrocene”, Beilstein J. Org. Chem. (2013), 9, 1278-1284 (IR windows in polysiloxanes)
197 Perkin Elmer Application Note “Infrared Spectroscopy-Polymer Identification Using Mid Infrared Spectroscopy” 010007_01 (2011)
198 B. Cole et al, “Core/clad selenide glass fiber doped with Pr 3+ for active mid-IR applications”, Journal Of Materials Science Letters 20, 2000, 465-467
199 Vincent Fortin et al, “Monolithic mid-infrared fiber lasers for the 2-4 μm spectral region” SPIE Vol. 8601, 86011H (2013)
200 Xiushan Zhu et al, “Compact 2 W wavelength-tunable Er:ZBLAN mid-infrared fiber laser”, Optics Letters V. 32 p. 2381-2383 (2007)
201 A. Lancaster et al, “Mid-infrared laser emission from Fe: ZnSe cladding waveguides”, Applied Physics Letters 107, 031108 (2015)
202 Espen Lippert et al, “High-power fiber-laser-pumped mid-infrared laser sources”, Proc. of SPIE Vol. 6397 639704-1 (2006)
203 Billy Richards et al, “˜2 lm Tm3+/Yb3+-doped tellurite fibre laser”, J Mater Sci: Mater Electron (2009) 20: S317-S320
204 Chenan Xia et al, “10.5 W Time-Averaged Power Mid-IR Supercontinuum Generation Extending Beyond 4 μm With Direct Pulse Pattern Modulation”, IEEE Journal Of Selected Topics In Quantum Electronics, VOL. 15. P. 422-434 (2009)
C. Kneis et al, “4.5 W mid-infrared supercontinuum generation in a ZBLAN fiber pumped by a Q-switched mode-locked Tm 3+-doped fiber laser”, Proc. of SPIE Vol. 9342 93420B-1 (2015)
Yang Wei-Qiang et al, “A novel 2-μm pulsed fiber laser based on a supercontinuum source and its application to mid-infrared supercontinuum generation”, Chin. Phys. B Vol. 23, No. 5 (2014) 054208
Xiaojun Xu et al, “High Power Mid-Infrared Continuous-Wave Optical Parametric Oscillator Pumped by Fiber lasers”, Proc. of SPIE Vol. 9255 925507-1 (2015)
M. Bernier et al, “Mid-infrared chalcogenide glass Raman fiber laser”, Optics Letters V. 38 p. 127-129 (2013)
205 Kannan Krishnaswami et al, “Characterization of Single-mode Chalcogenide Optical Fiber for Mid-Infrared Applications”, Proc. of SPIE Vol. 7325, 73250Z (2009)
Nurmemet Abdukerim et al, “Mid-Infrared Raman Fiber Laser In Chalcogenide Microwire”, IEEE Photonics North Conference Proceedings, p. 1 (2015) DOI: 10.1109/PN.2015.7292476
206 Pier J. A. Sazio et al, “Templated growth of II-VI semiconductor optical fiber devices and steps towards infrared fiber lasers”, Proc. of SPIE Vol. 9342 93420A-1 (2015)
207 Rei Kitamura et al, “Optical constants of silica glass from extreme ultraviolet to far infrared at near room temperature”, Applied Optics V. 46 p. 8118-8133 (2007)
208 eg, Float Zone Silicon including High Resistivity Float Zone Silicon is conventionally optimized for IR transmission, http://www.tydex.ru; HiTrantm silicon of Topsil Semiconductor Materials A/S, Siliciumvej 1 DK-3600 Frederikssund Denmark
209 D R Deans, “Use Of Heart Cutting In Gas Chromatography A Review”, Journal Of Chromatography 203 (1981) 19-28
210 S. Mitra, “Microfabricated Microconcentrator for Sensor and Gas Chromatography,” U.S. Pat. No. 7,147,695 issued Dec. 12, 2006 and the references there cited
S. Mitra et al, Microtrap assembly for greenhouse gas and air pollution monitoring “, U.S. Pat. No. 9,116,141 issued Aug. 25, 2015 and the references there cited.
211 Anna Rissanen et al, “Monolithically integrated microspectrometer-on-chip based on tunable visible light MEMS FPI”, Sensors and Actuators A 182 (2012) 130-135
Martin Ebermann et al, “Recent advances in expanding the spectral range of MEMS Fabry-Pérot filters”, (2010) Proc. of SPIE Vol. 7594 75940V-1
212 Of Block Engineering, Marlborough, MA. See Anish K. Goyal et al, “Detection of chemical clouds using widely tunable quantum cascade lasers”, Proc. of SPIE Vol. 9455, 94550L (2015)
213 M. Kumar et al, “Tunable hollow optical waveguide with high contrast grating”, IEEE Lasers and Electro-Optics Society, LEOS (2008) pages 523-524 DOI: 10.1109/LEOS.2008.4688722
214 M. E. Webber et al, “Optical detection of chemical warfare agents and toxic industrial chemicals: Simulation”, Journal Of Applied Physics 97, 113101 (2005)
215 M. Navaei et al, “All Silicon Micro-GC Column Temperature Programming Using Axial Heating”, Micromachines 2015, 6, 865-878; doi: 10.3390/mi6070865
M. Navaei et al, “Micro-Fabrication of All Silicon 3 Meter GC Columns Using Gold Eutectic Fusion Bonding”, ECS Journal of Solid State Science and Technology, 4 (10) S3011-S3015 (2015)
Sandro Mengali et al, “Rapid screening and identification of illicit drugs by IR absorption spectroscopy and gas chromatography”, Proc. of SPIE Vol. 8631, 86312F (2013); doi: 10.1117/12.2003903
Jan Dziuban et al, “Silicon components for gas chromatograph”, Proc. SPIE 4516, Optoelectronic and Electronic Sensors IV, 249 (Aug. 8, 2001); doi: 10.1117/12.435932
216 R. S. Pai et al, “Microfabricated Gas Chromatograph for Trace Analysis”, IEEE Conference on Technologies for Homeland Security, May (2008) p. 150-154; DOI: 10.1109/THS.2008.4534440
217 Martinez-Veracocchea, F. J. and M. E. Leunissen (2013). “The entropic impact of tethering, multivalency and dynamic recruitment in systems with specific binding groups.” Soft Matter 9(12): 3213-3219
Akishiba, T., N. Tamura, et al. (2013). DNA origami assembly on patterned silicon by AFM based lithography. 2013 IEEE 26th International Conference on Micro Electro Mechanical Systems (MEMS), 20-24 Jan. 2013, Piscataway, NJ, USA, IEEE.
Xing, C., H. Qiao, et al. (2012). “Fractal self-assembly of single-stranded DNA on hydrophobic self-assembled monolayers.” Journal of Physical Chemistry B 116(38): 11594-11599
Su, H.-J., C. E. Castro, et al. (2012). Design and fabrication of DNA origami mechanisms and machines. 2nd ASME/IFToMM International Conference on Reconfigurable Mechanisms and Robots, ReMAR 2012 Jul. 9, 2012-Jul. 11, 2012, Tianjin, China, Springer Science and Business Media Deutschland GmbH
Xin, X., X. Han, et al. (2012). “Synthesis of spiropyran photochromic polymer.” Advanced Materials Research 380:64-68.
Satish Kumar, M. V. and P. K. Maiti (2012). “Structure of DNA-functionalized dendrimer nanoparticles.” Soft Matter 8(6): 1893-1900.
Proctor, T. J. and A. S. Finch (2012). DNA: Multiple architectures for use in electronics applications. Energy Harvesting and Storage: Materials, Devices, and Applications III, Apr. 23, 2012-Apr. 24, 2012, Baltimore, MD, United states, SPIE.
Liang, J., M. Castronovo, et al. (2012). “DNA as invisible ink for AFM nanolithography.” Journal of the American Chemical Society 134(1): 39-42
Jin, X., S. Yang, et al. (2012). “Bio-inspired special wetting surfaces via self-assembly.” Science China: Chemistry 55(11): 2327-2333.
Correa, N. M., J. J. Silber, et al. (2012). “Nonaqueous polar solvents in reverse micelle systems.” Chemical Reviews 112(8): 4569-4602.
Yamaguchi, H., R. Kobayashi, et al. (2011). “Self-assembly of gels through molecular recognition of cyclodextrins: Shape selectivity for linear and cyclic guest molecules.” Macromolecules 44(8): 2395-2399.
Slater, J. H., J. S. Miller, et al. (2011). “Fabrication Of Multifaceted Micropatterned Surfaces With Laser Scanning Lithography.” Advanced Functional Materials 21(15): 2876-2888.
Siegwart, D. J., K. A. Whitehead, et al. (2011). “Combinatorial synthesis of chemically diverse core-shell nanoparticles for intracellular delivery.” Proceedings of the National Academy of Sciences of the United States of America 108(32): 12996-13001.
Harada, A., R. Kobayashi, et al. (2011). “Macroscopic self-assembly through molecular recognition.” Nature Chemistry 3(1): 34-37.
Finch, A. S., C. M. Jacob, et al. (2011). DNA architectures for templated material growth. Nanobiosystems: Processing, Characterization, and Applications IV, Aug. 21, 2011-Aug. 22, 2011, San Diego, CA, United states, SPIE.
Durai, C. R. S. and M. M. Harding (2011). “Targeting nucleic acids using dynamic combinatorial chemistry.” Australian Journal of Chemistry 64(6): 671-680.
Arpin, K. A., J. H. Pikul, et al. (2011). “Template directed assembly of dynamic micellar nanoparticles.” Soft Matter 7(21): 10252-10257.
Li, F., W. Chen, et al. (2008). “Development of DNA electrochemical biosensor based on covalent immobilization of probe DNA by direct coupling of sol-gel and self-assembly technologies.” Biosensors and Bioelectronics 24(4): 787-792.
Feng, L., C. Wei, et al. (2008). “Development of DNA electrochemical biosensor based on covalent immobilization of probe DNA by direct coupling of sol-gel and self-assembly technologies.” Biosensors & Bioelectronics 24(4): 787-792.
218 Shuman, C., P. Haihui, et al. (2012). “Ag nanocrystal as a promoter for carbon nanotube-based room-temperature gas sensors.” Nanoscale 4(19): 5887-5894.
Bonanni, A., A. Ambrosi, et al. (2012). “Nucleic acid functionalized graphene for biosensing.” Chemistry-A European Journal 18(6): 1668-1673
Niederberger, M., G. Garnweitner, et al. (2007). “Nonaqueous synthesis, assembly and formation mechanisms of metal oxide nanocrystals.” International Journal of Nanotechnology 4(3): 263-281
219 Yuan, P. and X. Bao (2013). “A facile and finely-controlled synthesis of versatile porous silica nanomaterials: Nanopods, helical nanorods and nanovesicles.” Materials Letters 109:199-202.
220 http://www.arrayit.com/Products/Microarrayers/Microarray Spotter/microarray spotter.html http://www.labnext.com/ua.html
221 R. S. Pai et al, “Microfabricated Gas Chromatograph for Trace Analysis”, IEEE Conference on Technologies for Homeland Security, May (2008) p. 150-154; DOI: 10.1109/THS.2008.4534440
222 Ivashenko, O., J. T. Van Herpt, et al. (2013). “UV/Vis and NIR light-responsive spiropyran self-assembled monolayers.” Langmuir 29(13): 4290-4297
Xue, P., R. Lu, et al. (2012). “A smart gelator as a chemosensor: Application to integrated logic gates in solution, gel, and film.” Chemistry—A European Journal 18(12): 3549-3558.
Mysliwiec, J., M. Czajkowski, et al. (2012). Photonic applications of photochromic molecules. Organic Photonic Materials and Devices XIV, 23-25 Jan. 2012, USA, SPIE—The International Society for Optical Engineering
Herrero, E., N. Carmona, et al. (2007). “Sensitive glasslike sol-gel materials suitable for environmental light sensors.” Journal of the European Ceramic Society 27(16): 4589-4594
223 H-W Lam et al, U.S. Pat. No. 8,338,553 issued Dec. 25, 2012 and references there cited P. Manesiotis et al, “An enantioselective imprinted receptor for Z-glutamate exhibiting a binding induced color change”, Chem Commun (Camb) 2004 Oct. 21; (20): 2278-9
Hall, A. J.; Manesiotis, P.; Emgenbroich, M.; Quaglia, M.; De Lorenzi, E.; Sellergren, B., Urea Host Monomers for Stoichiometric Molecular Imprinting of Oxyanions. The Journal of Organic Chemistry 2005, 70, (5), 1732-1736
Wan, Wei: Molecularly imprinted chromogenic and fluorogenic receptors as optical sensor matrix; Dissertation, Humboldt-Universität zu Berlin, Mathematisch-Naturwissenschaftliche Fakultät I, publiziert am 17.07.2015, urn: nbn: de: kobv: 11-100231344
224 P. M. Holland et al, “Miniaturized GC/MS instrumentation for in situ measurements: micro gas chromatography coupled with miniature quadrupole array and Paul ion trap mass spectrometers”, SPIE Vol. 4878 p. 1-7 (2003)
A. Nomerotski et al, “Pixel imaging mass spectrometry with fast silicon detectors”, Nuclear Instruments and methods in Physics Research A 633 (2011) S243-S246 (Dalsa fast framing camera)
Richard R A Syms et al, “MEMS mass spectrometers: the next wave of miniaturization”, J. Micromech. Microeng. 26 (2016) 023001
225 K. Sugiyama et al, “Development of on-chip vacuum generation by gas-liquid phase transition”, Sensors and Actuators A 176 (2012) 138-142
K. Sugiyama et al, “Study on on-chip mass spectrometry in a low vacuum operation”, 16th International Conference on Miniaturized Systems for Chemistry and Life Sciences, MicroTAS (2012) p. 1351-1353 October 28-Nov. 1, 2012, Chemical and Biological Microsystems Society.
Miniturbine: http://www.pddnet.com/article/2013/11/worlds-smallest-vacuum-size-penny P. Siebert, G. Petzold, A. Hellenbart, and J. Muller, Surface microstructure/miniature mass spectrometer: processing and applications, Appl. Phys. A, 67, pp. 155-160, (1998).
V. Sharma et al, “MEMS Micro-vacuum Pump for Portable Gas Analyzers”, MIT MS.22 Microsystems Technology Laboratories Annual Research Report 2009 MEMS & BioMEMS URI: http://hdl.handle.net/1721.1/54643
226 Christoph Chluba et al, “Ultralow-fatigue shape memory alloy films, Science 348, 1004 (2015); DOI: 10.1126/science.1261164 (Ti54.7Ni30.7Cu12.3Co2.3)
Robert Zarnetta et al, “Identification of Quaternary Shape Memory Alloys with Near-Zero Thermal Hysteresis and Unprecedented Functional Stability”, Adv. Funct. Mater. 2010, 20, 1917-1923
227 Ozlem Yavas et al, “Plasmon interferometers for high-throughput sensing”, Optics Letters Vol. 37 No. 16 (2012) 3396-3398
Yu Wang, U.S. Pat. No. 6,297,907 issued 2001, “Devices based on surface plasmon interference filters”
228 Yi Li et al, “High-separation efficiency micro-fabricated multi-capillary gas chromatographic columns for simulants of the nerve agents and blister agents”, Nanoscale Research Letters 2014, 9:224
Rekha S. Pai et al, “Microfabricated Gas Chromatograph for Trace Analysis”, 2008 IEEE Conference on Technologies for Homeland Security (THS '08), 12-13 May 2008 pp 150-15
David F. Lemmerhirt et al, “Chip-Scale Integration of Data-Gathering Microsystems”, Vol. 94, No. 6, June 2006 | Proceedings of the IEEE 11-38-1159
M. Agah, et al, “High-speed MEMS-based gas chromatography”, IEEE Dig. Int. Electron Devices Meeting, 2004, pp. 27-30
Sandro Mengali et al, “Rapid screening and identification of illicit drugs by IR absorption”, Proc. of SPIE Vol. 8631, 86312F (2013)
Milad Navaei et al, “All Silicon Micro-GC Column Temperature Programming Using Axial Heating”, Micromachines 2015, 6, 865-878
Alastair C. Lewis et al, “Microfabricated planar glass gas chromatography with photoionization detection”, Journal of Chromatography A, 1217 (2010) 768-774
Jan Dziuban et al, “Silicon Components for Gas Chromatograph”, Proc. SPIE 4516, Optoelectronic and Electronic Sensors IV, 249 (Aug. 8, 2001); doi: 10.1117/12.435932
M. Navaei et al, “Micro-Fabrication of All Silicon 3 Meter GC Columns Using Gold Eutectic Fusion Bonding”, ECS Journal of Solid State Science and Technology, 4 (10) S3011-S3015 (2015)
Milad Navaei et al, “All Silicon Micro-GC Column Temperature Programming Using Axial Heating”, Micromachines (2015), 6, 865-878
Richard R A Syms et al, “MEMS mass spectrometers: the next wave of miniaturization”, Journal of Micromechanics and Microengineering 26 (2016) 023001 (28pp)
R. R. A. Syms, “The Development Of Mems Mass Spectrometers”, IEEE Transducers 2013, Barcelona, SPAIN, 16-20 Jun. 2013, p. 2749-2754
Paul M. Holland et al, “Miniaturized GC/MS instrumentation for in situ measurements: micro gas chromatography coupled with miniature quadrupole array and Paul ion trap mass spectrometers”, SPIE Vol. 4878:1-7 (2003)
P. Siebert et al, “Surface microstructure/miniature mass spectrometer: processing and applications”, Appl. Phys. A, 67, pp. 155-160, (1998)
Ricardo Arevalo et al, “Design and Demonstration of the Mars Organic Molecule Analyzer (MOMA) on the ExoMars 2018 Rover”, 2015 IEEE Aerospace Conference, AERO 2015 Mar. 7, 2015-Mar. 14, 2015, p. 1-11 DOI: 10.1109/AERO.2015.7119073
Xue Wang et al, “Microfluidics-to-mass spectrometry: A review of coupling methods and applications”, Journal of Chromatography A 1382 (2015) 98-116
A. Nomerotski et al, “Pixel imaging mass spectrometry with fast silicon detectors”, Nuclear Instruments and Methods in Physics Research A 633 (2011) S243-S246
Valentine Grimaudo et al, “High-Resolution Chemical Depth Profiling of Solid Material Using a Miniature Laser Ablation/Ionization Mass Spectrometer”, Analytical Chemistry (2015), 87, 2037-2041
A. Riedo et al, “Performance evaluation of a miniature laserablation time-of-flight mass spectrometer designed for in situ investigations in planetary space research”, Journal of Mass Spectrometry 2013, 48, 1-15
Te-Hsuen Tzeng et al, “A Portable Micro Gas Chromatography System for Volatile Compounds Detection with 15 ppb of Sensitivity”, 2015 IEEE International Solid-State Circuits Conference, p. 388-390, 978-1-4799-6224-2/15
M. P. Sinha et al, “Miniature focal plane mass spectrometer with 1000-pixel modified-CCD detector array for direct ion measurement” Rev. Sci. Instrum. vol. 76, 025103, 2005.
229 The infrared spectrum is typically studied in three regions; near-infrared NIR (˜ 0.8-2.5 u wavelength) midwave-infrared MWIR, (˜2.5-15 u which excites fundamental molecular vibrations used in IR spectroscopy), and the far infrared.
230 For example, see http://www2.chemistry.msu.edu/faculty/reusch/VirtTxtJml/Spectrpy/Infrared/infrared.htm
231 Gian Paolo Brivio et al, “A classical analysis of photodesorption by resonant IR-laser adsorbate coupling”, Surface Science 261 (1992) 359-374
232 http://techlinkcenter.org/summaries/photothermal-infrared-imaging-spectroscopy-pt-iris-stand-trace-detectionUS U.S. Pat. No. 8,101,915 to R. A. McGill et al, issued Jan. 24, 2012, including FIG. 3 thereof.
233 J. Hildenbrand et al, “Explosive detection using infrared laser spectroscopy”, Proc. of SPIE Vol. 7222 72220B-1 (2009)
234 Polymer stationary phases for pre-concentrators and separation columns can be selected for their windows of transparency in MWIR ranges corresponding to specific wavelength ranges for selective elution or gas-transport enhancement. Fully deuterated polydimethylsiloxane polymer has substantially no absorption bands in the wavelength range from 1.7 to 2.1μ. Polytetrafluoroethylene and related soluble copolymers have wide transparent windows from 2.5μ to about 8μ and from about 10μ to about 14μ; polypropylene similarly has transparent MWIR windows from 2.5μ to 3.12μ and 3.57μ to 5.5μ with a small absorption peak centered at 5.7μ, as useful stationary phases for MWIR pre-concentration and separation column irradiation zones. They can all be crosslinked for high temperature GC operation
   Pure silica glass is effectively transparent to IR to 3.5 to 4 microns. Pure silicon has high IR transmission in the 1.5 to 7 micron range, which is useful for etched column and pre-concentrator systems. Germanium is a versatile infrared material with good transmission in the 2 to 12 micron spectral region. CVD diamond is transparent from the UV (230 nm) to the far infrared, with only minor absorption between 2.5 and 6 μm.
235 See IARPA seedling grant to Cornell University, FA8650-15-C-9100
K V Sreekanth et al, “Excitation of volume plasmon polaritons in metal-dielectric metamaterials using 1D and 2D diffraction gratings”, Journal of Optics 16 (2014) 105103 (8pp)
Yongkang Gong et al, “Coherent emission of light using stacked gratings”, PHYSICAL REVIEW B 87, 205121 (2013), with tunability via refractive index change under voltage control
Wenjia Zhou et al, “Monolithically, widely tunable quantum cascade lasers based on a heterogeneous active region design”, Scientific Reports | 6:25213 (2016) | DOI: 10.1038/srep25213
Christopher A. Kendziora et al, “Detection of trace explosives on relevant substrates using a mobile platform for photothermal infrared imaging spectroscopy (PT-IRIS)”, Proc. of SPIE Vol. 9467 94672R-2
Anish K. Goyal et al, “Detection of chemical clouds using widely tunable quantum cascade lasers, Proc. of SPIE Vol. 9455 94550L-1
Bo Meng et al, “Broadly tunable single-mode mid-infrared quantum cascade lasers”, Journal of Optics 17 (2015) 023001
Martin Ebermann et al, “Recent advances in expanding the spectral range of MEMS Fabry-Pérot filters”, (2010) Proc. of SPIE Vol. 7594 75940V-1
M. Kumar et al, “Tunable Hollow Optical Waveguide with High Contrast Grating”, LEOS 2008-21st Annual Meeting of the IEEE Lasers and Electro-Optics Society >523-524; DOI 10.1109/LEOS.2008.4688722
236 A relatively simple MWIR irradiation zone for pre-concentrator or separation column fabrication comprises a light-pipe flow cell. The GC sample flow is conducted through a glass, quartz or other capillary, which is internally reflection-coated (with gold, silver or dielectric reflector) on the inside surface, to which a MWIR-transparent stationary phase GC coating is applied. The selectively-heating MWIR infrared radiation is directed axially through the hollow light-pipe, to selectively heat those analyte components within the hollow light pipe which absorb at the wavelength(s) directed into the lightpipe by the MWIR source. The lightpipe or other MWIR irradiation zone may also be externally temperature-controlled.
237 S. Mitra, “Microfabricated Microconcentrator for Sensor and Gas Chromatography,” U.S. Pat. No. 7,147,695 Dec. 12, 2006
M. Camara et al, “Tubular gas preconcentrators based on inkjet printed micro-hotplateson foil”, Sensors and Actuators B 236 (2016) 1111-1117
238 S. Mitra, “Microfabricated Microconcentrator for Sensor and Gas Chromatography,” U.S. Pat. No. 7,147,695 issued Dec. 12, 2006 and the references there cited
S. Mitra et al, Microtrap assembly for greenhouse gas and air pollution monitoring “, U.S. Pat. No. 9,116,141 issued Aug. 25, 2015 and the references there cited.
239 eg, for a 3.0 GHz generator at $200, David Issadore et al, “Microwave Dielectric Heating of Drops in Microfluidic Devices”, Lab on a Chip, (2009) 9, 1701-1706
240 Du-Xin Li et al, “Gas chromatography coupled to atmospheric pressure ionization mass spectrometry (GC-API-MS): Review”, Analytica Chimica Acta 891 (2015) 43-61
241 And/or while having a vacuum pulled through the column and pre-concentrator.
242 The US IARPA intelligence agency, with its highly expert staff and intergovernment access, seeks development of such equipment by its MAEGLIN Program: Molecular Analyzer for Efficient Gas-phase Low-power INterrogation (MAEGLIN)

### Program Information:

### IARPA-BAA-16-01

“The MAEGLIN program intends to develop an ultra low power chemical analysis system for remote site detection and identification of explosives, chemical weapons, industrial toxins and pollutants, narcotics, and nuclear materials in the presence of significant background and interferents. Program goals include definitive chemical identification of species with an atomic mass <500 atomic mass units (amu); a system footprint of less than or equal to 1.5 liters and weight of less than or equal to 7 kg, including sufficient power and, if necessary, consumables for two year operation with daily sample analysis; autonomous operation, including calibration; and a modular front end for gas, liquid and particulate aerosol, and bulk liquid and solid analysis.
In Phase 1 (covered by this solicitation) the program will be structured as three separate Thrust Areas:
1. Collection—Low-power, reversible gas phase collection/storage/release technology. Modular front end sampling adaptor to add additional capability for liquid or particulate aerosol and/or bulk liquid and solid phase collection and volatilization.
2. Separation—Low-power, non-destructive separation of chemical mixtures with a broad concentration range, potentially including the ability to “bleed off” all or part of the collected sample if desired. System will use minimal (preferably no) consumables.
3. Identification—Low-power, high-accuracy identification of chemicals as pure compounds or low-count mixtures with a large library. System will use minimal (preferably no) consumables. Phase 2 (which will be covered by a separate solicitation) will focus on system integration and will culminate in a prototype demonstration.
243 eg, see Professor Suslick's group, “A colorimetric sensor array for identification of toxic gases below permissible exposure limits”, Chem. Commun., 2010, 46, 2037-2039
Hyuntae Kim et al, “Electronic-nose for detecting environmental pollutants: signal processing and analog front-end design”, Analog Integr Circ Sig Process (2012) 70:15-32
A. J. Myrick et al, “Detection and Discrimination of Mixed Odor Strands in Overlapping Plumes Using an Insect-Antenna-Based Chemosensor System”, J Chem Ecol (2009) 35:118-130
244 Multiple lasers may be used, but at cost and potential SWaP penalty.
245 Sandro Mengali et al, “Rapid screening and identification of illicit drugs by IR absorption”, Proc. of SPIE Vol. 8631, 86312F (2013)
For examples of selective MWIR absorption bands, see R. F. Curl et al, “Tunable infrared laser spectroscopy”, Annu. Rep. Prog. Chem., Sect. C, 2002, 98, 219-272
246 Santiago Aparicio et al, “Microwave dielectric spectroscopy of pure and mixed aromatic ester solvents”, PMC Physics B 2008, 1:4
247 Medcraft, C. and M. Schnell (2016). “A Comparative Study of Two Bicyclic Ethers, Eucalyptol and 1,4-Cineole, by Broadband Rotational Spectroscopy.” Zeitschrift fur Physikalische Chemie 230(1): 1-14.
McCarthy, M. C., et al. (2016). “Isotopic studies of trans- and cis-HOCO using rotational spectroscopy: Formation, chemical bonding, and molecular structures.” Journal of Chemical Physics 144(12): 124304 (124311 pp.).
Martin-Drumel, M. A., et al. (2016). “Automated microwave double resonance spectroscopy: a tool to identify and characterize chemical compounds.” Journal of Chemical Physics 144(12): 124202 (124207 pp.) (“Owing to its unparalleled structural specificity, rotational spectroscopy is a powerful technique to unambiguously identify and characterize volatile, polar molecules”)
Jun-Chau Chien et al, “Oscillator-Based Reactance Sensors With Injection Locking for High-Throughput Flow Cytometry Using Microwave Dielectric Spectroscopy”, IEEE Journal Of Solid-State Circuits, VOL. 51, NO. 2 (2016)
Tulimat, L., et al. (2015). “The microwave spectrum of allyl acetone.” Journal of Molecular Spectroscopy 312:46-50.
McCarthy, M. C., et al. (2015). “High-resolution rotational spectroscopy of iminosilylene, HNSi.” Molecular Physics 113(15-16): 2204-2216. (Fourier transform microwave spectroscopy).
Sanz, M. E., et al. (2014). “Rotational spectrum of tryptophan.” Journal of Chemical Physics 140(20): 204308 (204306 pp.).
Larsen, N. W. and O. V. Nielsen (2014). “Internal rotation potential and structure of six fluorine substituted nitrobenzenes studied by microwave spectroscopy supported by quantum chemical calculations.” Journal of Molecular Structure 1071: 111-122.
Vlachogiannakis, G., et al. (2016). A 40-nm CMOS permittivity sensor for chemical/biological material characterization at RF/microwave frequencies. 2016 IEEE MTT-S International Microwave Symposium, I M S 2016 May 22, 2016-May 27, 2016, San Francisco, CA, United states, Institute of Electrical and Electronics Engineers Inc. (complex permittivity sensor, integrated in 40-nm CMOS, for microwave dielectric spectroscopy 0.1 to 12 GHZ)
Chien, J.-C. and A. M. Niknejad (2016). “Oscillator-Based Reactance Sensors With Injection Locking for High-Throughput Flow Cytometry Using Microwave Dielectric Spectroscopy.” IEEE Journal of Solid-State Circuits 51(2): 457-472.
Chen, W., et al. (2016). Impact of sensor metal thickness on microwave spectroscopy sensitivity for individual particles and biological cells analysis. IEEE Topical Conference on Biomedical Wireless Technologies, Networks, and Sensing Systems, BioWireleSS 2016 Jan. 24, 2016-Jan. 27, 2016, Austin, TX, United states, Institute of Electrical and Electronics Engineers Inc.
Blakey, R. T. and A. M. Morales-Partera (2016). “Microwave dielectric spectroscopy A versatile methodology for online, non-destructive food analysis, monitoring and process control.” Engineering in Agriculture, Environment and Food 9(3): 264-273.
Leroy, J., et al. (2015). “Microfluidic biosensors for microwave dielectric spectroscopy.” Sensors and Actuators A: Physical 229:172-181.
Landoulsi, A., et al. (2015). A microwave sensor dedicated to dielectric spectroscopy of nanoliter volumes of liquids medium and flowing particles. 2015 IEEE Topical Conference on Biomedical Wireless Technologies, Networks, and Sensing Systems, BioWireleSS 2015 Jan. 25, 2015-Jan. 28, 2015, San Diego, CA, United states, Institute of Electrical and Electronics Engineers Inc.
Artis, F., et al. (2015). Sub-microliter microwave dielectric spectroscopy for identification and quantification of carbohydrates in aqueous solution. 2015 IEEE Topical Conference on Biomedical Wireless Technologies, Networks, and Sensing Systems, BioWireless 2015 Jan. 25, 2015-Jan. 28, 2015, San Diego, CA, United states, Institute of Electrical and Electronics Engineers Inc. (miniature microwave dielectric spectroscopy from 40 MHz to 40 GHZ)
Wagner, N., et al. (2014). “Numerical 3-D FEM and Experimental Analysis of the Open-Ended Coaxial Line Technique for Microwave Dielectric Spectroscopy on Soil.” IEEE Transactions on Geoscience and Remote Sensing 52(2): 880-893. (100 MHz to 10 GHz)
Rakhmatullin, R. M., et al. (2014). “EPR, optical, and dielectric spectroscopy of Er-doped cerium dioxide nanoparticles.” Physica Status Solidi B-Basic Solid State Physics 251(8): 1545-1551.
Ocket, I., et al. (2014). A bottom-up cell modeling strategy using broadband microwave and millimeter wave dielectric spectroscopy. 2014 IEEE MTT-S International Microwave Workshop Series on RF and Wireless Technologies for Biomedical and Healthcare Applications (IMWS-BIO), 8-10 Dec. 2014, Piscataway, NJ, USA, IEEE.
Grenier, K., et al. (2013). Microwave dielectric spectroscopy: An emerging analyzing technique for biological investigations at the cellular level. 2013 IEEE Topical Conference on Biomedical Wireless Technologies, Networks, and Sensing Systems, BioWireleSS 2013-2013 7th IEEE Radio and Wireless Week, R W W 2013 Jan. 20, 2013-Jan. 23, 2013, Austin, TX, United states, IEEE Computer Society.
Kozhevnikov, A. (2010). “Wideband radio-frequency device for measurements of dielectric properties of small volumes of liquids.” Measurement Science and Technology 21(4).
Cataldo, A., et al. (2010). “Quality and anti-adulteration control of vegetable oils through microwave dielectric spectroscopy.” Measurement 43(8): 1031-1039.
Aparicio, S., et al. (2008). “Liquid structure of ethyl lactate, pure and water mixed, as seen by dielectric spectroscopy, solvatochromic and thermophysical studies.” Chemical Physics Letters 454(1-3): 49-55.
Chunrong, S., et al. (2006). Microwave dielectric properties of on-chip liquid films. 2006 IEEE/NLM Life Science Systems and Applications Workshop, 13-14 Jul. 2006, Piscataway, NJ, USA, IEEE.
Garcia-Ruiz, I., et al. (2001). “Development of a microwave dielectric spectroscopy system for materials characterization using the open-ended coaxial probe technique.” Revista Mexicana de Fisica 47(1): 62-69.
248 Giovanni Brucoli et al, “High efficiency quasi-monochromatic infrared emitter”, Applied Physics Letters 104, 081101 (2014); doi: 10.1063/1.4866342

### Narrow Bandwidth and Highly Polarized Ratio Infrared Thermal Emitter

Appl. Phys. Lett. 97, 163112 (2010); 10.1063/1.3503631

### Two-Dimensional Tungsten Photonic Crystals as Selective Thermal Emitters

Appl. Phys. Lett. 92, 193101 (2008); 10.1063/1.2927484

### High Performance Midinfrared Narrow-Band Plasmonic Thermal Emitter

Appl. Phys. Lett. 89, 173116 (2006); 10.1063/1.2364860
Hira Nasim et al, “Diode lasers: From laboratory to industry” Optics & Laser Technology 56 (2014) 211-222
R. F. Curl et al, “Tunable infrared laser spectroscopy”, Annu. Rep. Prog. Chem., Sect. C, 2002, 98, 219-272
249 Zhou, W. et al. “Monolithically, widely tunable quantum cascade lasers based on a heterogeneous active region design”, Scientific Reports 6, 25213; doi: 10.1038/srep25213 (2016).
M. Razeghi, “Quantum cascade lasers: from tool to product”, Optics Express 8464, Vol. 23, No. 7 (2015)
250 see http://www.Quantumcomposers.com http://www.m2k-laser.de/m2k-laser_e.htm for commercial lasers http://atoptics.com/index.html
M. T. Kelemen et al, “Diode laser systems for 1.8 to 2.3 μm wavelength range”, Proceedings of the SPIE, vol. 7686, paper 20 (2010)
M. T. Kelemen et al, “Mid-infrared high-power diode lasers and modules”, Proceedings of the SPIE, vol. 7583, paper 23 (2010)
M. T. Kelemen, J. Gilly, S. Ahlert, H. Kissel, J. Biesenbach, M. Rattunde, J. Wagner “Diode laser arrays for 1.8 to 2.3 μm wavelength range”, Proceedings of the SPIE, vol. 7483, paper 11 (2009)
M. T. Kelemen, J. Gilly, M. Haag, J. Biesenbach, M. Rattunde, J. Wagner “Diode laser arrays for the 1.8 to 2.2 μm range”, Proceedings of the SPIE, vol. 7230, paper 56 (2009)
M. T. Kelemen, J. Weber, R. Moritz, J. Schmitz, M. Rattunde, J. Wagner, “High-power diode lasers for the 1.9 to 2.2 μm range”, Proceedings of the SPIE, vol. 6876, paper 13 (2008)
J. Gilly, P. Friedmann, J. Schleife, R. Moritz, M. Rattunde, M. Haag, M. T. Kelemen, “High-power diode laser bars for the 1.85 to 2.25 μm wavelength range”, Talk, MIOMD IX, Freiburg, Germany, Sep. 7-11 (2008)
M. T. Kelemen et al, “High-power diode laser arrays emitting at 2 μm with reduced far-field angle”, Novel In-Plane Semiconductor Lasers V, Proceedings of the SPIE, vol. 6133, paper 45 (2006)
M. Rattunde et al, “GaSb based 1.9-2.4 μm quantum-well diode lasers with low beam divergence”, SPIE Proc. Vol. 5738, Paper 19 (2005)
J. Wagner et al, “(AlGaln) (AsSb) quantum well diode lasers with improved beam quality”, SPIE Proc. Vol. 5732, Paper 82 (2005)
M. T. Kelemen et al, “High-power diode laser arrays at 2 μm for materials processing”, Proceedings of the Third International WLT-Conference on Lasers in Manufacturing 2005, (2005)
“High Brightness Emitters and Arrays” in “High Power Diode Lasers: Technology and Applications”, published by F. Bachmann, P. Loosen, Springer, ISBN 978-0-387-34453-9, 0387344535 (2007)
“Antimonide Quantum Well Laser Diodes for the 2-3 μm spectral range” in “Solid-state mid-infrared laser sources”, published by I. T. Sorokina, K. L. Vodopyanov, Springer, ISBN 3540006214, 9783540006213 (2003)
see also http://www.ipgphotonics.com/Mid_ir_lasers.htm for commercial middle Infrared lasers (2-5 μm) based on ZnSe/S and U.S. Pat. Nos. 5,541,948; 6,960,486; 7,548,571
N. J. C. I.ibatique et al, “A compact diode-pumped passively Q-switched mid-IR fiber laser”, CLEO 2000 p 76-77 (2000)
A Oladeji et al, “Design of erbium doped double clad ZBLAN Fibre laser”, Journal of Physics: Conference Series 619 (2015) 012044
Christopher A. Kendziora et al, “Detection of trace explosives on relevant substrates using a mobile platform for photothermal infrared imaging spectroscopy (PT-IRIS)”, Proc. of SPIE Vol. 9467 94672R-2
J. Herbst et al, “Hollow fiber based quantum cascade laser spectrometer for fast and sensitive drug identification”, Proc. of SPIE Vol. 8268, 82681Q⋅(2012)
251 Rei Kitamura et al, “Optical constants of silica glass from extreme ultraviolet to far infrared at near room temperature”, Applied Optics 46:8118-8133 (2007)
252 eg, Float Zone Silicon including High Resistivity Float Zone Silicon is conventionally optimized for IR transmission, http://www.tydex.ru; HiTrantm silicon of Topsil Semiconductor Materials A/S, Siliciumvej 1 DK-3600 Frederikssund Denmark
253 You Wang et al, “Refractive indices and extinction coefficients of polymers for the mid-infrared region”, You Wang et al, 1998 y Vol. 37, No. 30 y Applied Optics 7091-7095
254 B. Zimmermann et al, “Studies on siloxane polymers for NIR-evanescent wave absorbance sensors”, Sensors and Actuators B 41 (1997) 45-54
Helmut Ritter et al, “Linkage of a-cyclodextrin-terminated poly(dimethylsiloxanes) by inclusion of quasi bifunctional ferrocene”, Beilstein J. Org. Chem. (2013), 9, 1278-1284 (IR windows in polysiloxanes)
255 Perkin Elmer Application Note “Infrared Spectroscopy-Polymer Identification Using Mid Infrared Spectroscopy” 010007_01 (2011)
256 V. Singhal et al, “Microscale Pumping Technologies for Microchannel Cooling Systems” (2004). CTRC Research Publications. Paper 293, Appl Mech Rev vol 57, no 3, May 2004, pp. 191-221
257 Honeywell microturbine http://www.pddnet.com/article/2013/11/worlds-smallest-vacuum-size-penny
258 Kiyotaka Sugiyama et al, “Study On On-Chip Mass Spectrometry In A Low Vacuum Operation”, 16th International Conference on Miniaturized Systems for Chemistry and Life Sciences, p. 1351-1353; 978-0-9798064 May 2/μTAS Oct. 28-Nov. 1, 2012, Okinawa, Japan
Kiyotaka Sugiyama et al, “Development of on-chip vacuum generation by gas-liquid phase transition”, Sensors and Actuators A 176 (2012) 138-142
259 Richard R A Syms et al, “MEMS mass spectrometers: the next wave of miniaturization”, Journal of Micromechanics and Microengineering 26 (2016) 023001 28pp.
260 B. D. Iverson and S. V. Garimella, “Recent Advances in Microscale Pumping Technologies: A Review and Evaluation”, Microfluidics and Nanofluidics, Vol. 5, No. 2, pp. 145-174, 2008.
D. J. Laser and J. G. Santiago, “A review of micropumps”, Journal of Micromechanics and Microengineering, Vol. 14, No. 6, 2004.
261 J. E. Huber et al, “The selection of mechanical actuators based on performance indices”, Royal Society Proceedings: Mathematical, Physical and Engineering Sciences, Vol. 453, No. 1965 (Oct. 8, 1997), pp. 2185-2205
Nitin Choudhary et al, “Shape memory alloy thin films and heterostructures for MEMS applications: A review”, Sensors and Actuators A 242 (2016) 162-181
Christoph Chluba et al, “Ultralow-fatigue shape memory alloy films”, Science, 29 May 2015⋅Vol 348 Issue 6238
Robert Zarnetta et al, “Identification of Quaternary Shape Memory Alloys with Near-Zero Thermal Hysteresis and Unprecedented Functional Stability”, Adv. Funct. Mater. 2010, 20, 1917-1923
David Dye, “Towards practical actuators”, Nature Materials | Vol 14 | August 2015, p. 760-761 Richard D. James “Taming the temperamental metal transformation”, Science 29 May 2015⋅VOL 348 ISSUE 6238 p. 969-969
262 The vacuum pump designs can be made by conventional SMA processes such as sheet laser welding, electrodeposition, cold tube forming, vapor deposition, etc.
263 Series-connected SMA bellows or a small, “prior art” pump can be used to reduce the pressure in the “collapsed” SMA volume before expansion.
264 Mahadeva P. Sinha et al, “Miniature focal plane mass spectrometer with 1000-pixel modified-CCD detector array for direct ion measurement”, Review Of Scientific Instruments 76, 025103 (2005)
265 U.S. Pat. No. 3,816,774 to Katuhiro Ohnuki issued Jun. 11, 1974 for “Curved Piezoelectric Elements”
266 Chung-Shao Chao et al, “Design and analysis of charge-recovery driving circuits for portable peristaltic micropumps with piezoelectric actuators”, Sensors and Actuators A 168 (2011) 313-319 267 Insoo Lee et al, “Four-electrode micropump with peristaltic motion”, Sensors and Actuators A 245 (2016) 19-25
Hyun-Hoo Kim et al, “Design of valveless type piezoelectric pump for micro-fluid devices”, Procedia Chemistry 1 (2009) 353-356.
Bar-Cohen, U.S. Pat. No. 5,961,298 issued Oct. 5, 1999 for “Travelling Wave Pump employing Electroactive Actuators”
Bruno Dehez, et al, “Improved constitutive equations of piezoelectric monomorphs: Application to the preliminary study of an original traveling-wave peristaltic pump”, Sensors and Actuators A: Physical 169 (2011) 141-150
Guillaume Beckers, Bruno Dehez, “Design and Modeling of a Quasi-Static Peristaltic Piezoelectric Micropump”, IEEE 2013 International Conference on Electrical Machines and Systems, Oct. 26-29, 2013, Busan, Korea
Eunki Hong PhD thesis (2004) Pennsylvania State University, entitled “Surface Micromachined Peristaltic Pumps Using Lead Zirconate Titanate Film”
Nekrasov, S. G. (2016). To the Projection of a Peristaltic Slit Pump. 2nd International Conference on Industrial Engineering, ICIE 2016 May 19, 2016-May 20, 2016, Chelyabinsk, Russia, Elsevier Ltd.
Huang, P.-C., et al. (2016). “Experimental analysis of time-phase-shift flow sensing based on a piezoelectric peristaltic micropump.” Journal of Physics D: Applied Physics 49(17).
Thoma, F., et al. (2015). “A new concept of a drug delivery system with improved precision and patient safety features.” Micromachines 6(1): 80-95.
Pear, B., et al. (2014). “Piezoelectric peristaltic micropump with a single actuator.” Journal of Micromechanics and Microengineering 24(10). (Piezoelectric PDMS peristaltic micropump with a single actuator-back-pressure performance [up to 360 mbar/up to 80 mbar] and suction pressure performance [down to −165 mbar/down to −140 mbar]).
Feth, H., et al. (2014). “Design, fabrication and characterization of a piezoelectrically actuated bidirectional polymer micropump.” Microsystem Technologies 20(7): 1299-1310. (piezoelectrically actuated fully polymeric three chamber peristaltic micropump)
Cazorla, P. H., et al. (2014). Piezoelectric micro-pump with PZT thin film for low consumption microfluidic devices. 28th European Conference on Solid-State Transducers, EUROSENSORS 2014 Sep. 7, 2014-Sep. 10, 2014, Brescia, Italy, Elsevier Ltd.
Zhang, W. and R. E. Eitel (2013). “An integrated multilayer ceramic piezoelectric micropump for microfluidic systems.” Journal of Intelligent Material Systems and Structures 24(13): 1637-1646 (unloaded bidirectional flow rates of 450 L/min and a blocking pressure of 1.4 kPa)
Nakahara, K., et al. (2013). “A peristaltic micropump using traveling waves on a polymer membrane.” Journal of Micromechanics and Microengineering 23(8). (a peristaltic micropump that utilizes traveling waves on polymer membranes to transport liquids at 1.5 ml min-1 at 180 mW)
Beckers, G. and B. Dehez (2013). Design and modeling of a quasi-static peristaltic piezoelectric micropump. 2013 International Conference on Electrical Machines and Systems (ICEMS), 26-29 Oct. 2013, Piscataway, NJ, USA, IEEE.
Liang, L., et al. (2012). “Structure design and simulation of circular ring piezoelectric peristaltic pump.” Nongye Gongcheng Xuebao/Transactions of the Chinese Society of Agricultural Engineering 28(11): 40-44.
Fuchs, O., et al. (2012). “A novel volumetric silicon micropump with integrated sensors.” Microelectronic Engineering 97:375-378. (fabrication process based on Silicon On Insulator wafer, enabling additional photolithography or ion implantation)
Aizawa, E., et al. (2012). Design of ring type trench PZT for tube type micropump by using FEM analysis. 2012 23rd International Symposium on Micro-NanoMechatronics and Human Science (MHS), 4-7 Nov. 2012, Piscataway, NJ, USA, IEEE.
Li, L., et al. (2011). Structural design and simulation of a piezoelectric peristaltic pump driven by circumferential traveling-wave. 2011 International Conference on Advanced Design and Manufacturing Engineering, ADME 2011 Sep. 16, 2011-Sep. 18, 2011, Guangzhou, China, Trans Tech Publications. (Piezoelectric peristaltic pump driven by circumferential traveling-wave)
Dehez, B. (2011). “Improved constitutive equations of piezoelectric monomorphs: Application to the preliminary study of an original traveling-wave peristaltic pump.” Sensors and Actuators, A: Physical 169(1): 141-150.
Chao, C.-S., et al. (2011). “Design and analysis of charge-recovery driving circuits for portable peristaltic micropumps with piezoelectric actuators.” Sensors and Actuators, A: Physical 168(2): 313-319.
Tamez, J. P., et al. (2010). Polyvinylidene Fluoride (PVDF) piezoelectric for intravascular monitoring of blood pressure and arterial blood flow rate. Advances in Electroceramic Materials II—2009 Material Science and Technology Conference, MS and T09, Oct. 25, 2009-Oct. 29, 2009, Pittsburgh, PA, United states, American Ceramic Society.
Oh, J. H., et al. (2009). Design of a piezoelectric pump using no physically moving components. 9th Russian-CIS-Baltic-Japanese Symposium on Ferroelectricity, RCBJSF-9, Jun. 15, 2008-Jun. 19, 2008, Vilnius, Lithuania, Taylor and Francis Inc. (vibration mode of PZT ring)
Kim, H. H., et al. (2009). Design and modeling of piezoelectric pump for microfluid devices. 9th Russian-CIS-Baltic-Japanese Symposium on Ferroelectricity, RCBJSF-9, Jun. 15, 2008-Jun. 19, 2008, Vilnius, Lithuania, Taylor and Francis Inc.
Kim, H.-H., et al. (2009). “Design of valveless type piezoelectric pump for micro-fluid devices.” Procedia Chemistry 1(1): 353-356.
Jang, L.-S., et al. (2009). “Effect of actuation sequence on flow rates of peristaltic micropumps with PZT actuators.” Biomedical Microdevices 11(1): 173-181.
Yang, H., et al. (2008). Portable valve-less peristaltic micropump design and fabrication. DTIP of MEMS and MOEMS-Symposium on Design, Test, Integration and Packaging of MEMS/MOEMS, Apr. 9, 2008-Apr. 11, 2008, Nice, France, Inst. of Elec. and Elec. Eng. Computer Society.
Suzuki, T., et al. (2007). Development of a micro biochip integrated traveling wave micropumps and surface plasmon resonance imaging sensors. ASME-ISPS/JSME-IIP Joint conference on Micromechatronics for Information and Precision Equipment, Santa Clara, California, USA, 2006, Springer Verlag.
Li, J.-H., et al. (2007). A portable micropump system based on piezoelectric actuation. 33rd Annual Conference of the IEEE Industrial Electronics Society, IECON, Nov. 5, 2007-Nov. 8, 2007, Taipei, Taiwan, IEEE Computer Society. (stand-alone micropump system with battery-based driving circuit)
Teymoori, M. M. and E. Abbaspour-Sani (2005). “Design and simulation of a novel electrostatic peristaltic micromachined pump for drug delivery applications.” Sensors and Actuators, A: Physical 117(2): 222-229.
Nguyen, N.-T. and X. Huang (2005). “Development of a peristaltic pump in printed circuit boards.” Journal of Micromechatronics 3(1): 1-13.
Goldschmidtboing, F., et al. (2005). “A generic analytical model for micro-diaphragm pumps with active valves.” Journal of Micromechanics and Microengineering 15(4): 673-683. (maximum flow rate of 1.4 ml min-1 and backpressure of 40 kPa)
Husband, B., et al. (2004). Novel actuation of an integrated peristaltic micropump. Micro and Nano Engineering 2003 Sep. 22, 2003-Sep. 25, 2003, Cambridge, United kingdom, Elsevier. (driver circuits to operate a peristaltic silicon micro pump integrated within a lab-on-a-chip)
Eunki Hong (2004). Surface micromachined peristaltic pumps using lead zirconate titanate film, Penn State PHD Thesis, ProQuest LLC.
Eunki Hong et al. (2003). Fabrication of micromachined piezoelectric diaphragm pumps actuated by interdigitated transducer electrodes. Nano- and Microelectromechanical Systems (NEMS and MEMS) and Molecular Machines. Symposium, 2-4 Dec. 2002, Warrendale, PA, USA, Mater. Res. Soc.
Eunki Hong et al. (2002). Fabrication of micromachined piezoelectric diaphragm pumps actuated by interdigitated transducer electrodes. Nano- and Microelectromechanical Systems (NEMS and MEMS) and Molecular Machines, Dec. 2, 2002-Dec. 4, 2002, Boston, MA, United states, Materials Research Society.
Bar-Cohen, Y. and Z. Chang (2001). Piezoelectrically actuated miniature peristaltic pump. Smart Structures and Materials 2001-Smart Structures and Integrated Systems-, Mar. 5, 2001-Mar. 8, 2001, Newport Beach, CA, United states, SPIE.
Bar-Cohen, Y. and C. Zensheu (2000). Piezoelectrically actuated miniature peristaltic pump. Smart Structures and Materials 2000: Active Materials: Behavior and Mechanics, 6-9 Mar. 2000, USA, SPIE-Int. Soc. Opt. Eng. (piezo pumps that are miniature and consume low power for NASA)
Bar-Cohen, Y. and Z. Chang (2000). Piezoelectrically actuated miniature peristaltic pump. Smart Structures and Materials 2000-Active Materials: Behavior and Mechanics, Mar. 6, 2000-Mar. 9, 2000, Newport Beach, CA, USA, Society of Photo-Optical Instrumentation Engineers.
268 https://www.physikinstrumente.com
269 http://www.piezo.com/tech2intropiezotrans.html https://www.piceramic.com/en/products/piezoceramic-components/
270 The ceramic inner surface and the substrate may each have a somewhat resilient polymer coating (eg, polyimide) to ensure a gas-tight seal.
271 Arivinda Kar et al, US patents:
U.S. Pat. No. 9,064,798 Optical device and method of making Jun. 23, 2015
U.S. Pat. No. 8,912,549 Optical device and method of making Dec. 16, 2014
U.S. Pat. No. 8,828,769 Energy conversion device Sep. 9, 2014
U.S. Pat. No. 8,772,061 Process of making a solid state energy conversion device Jul. 8, 2014
U.S. Pat. No. 8,722,451 Solid state energy photovoltaic device issued May 13, 2014
U.S. Pat. No. 8,674,373 Solid state gas dissociating device, solid state sensor, and solid state transformer
U.S. Pat. No. 7,951,632 Optical Device and Method of Making May 31, 2011
272 Deepak Kumar et al, “Ultrasonic photoacoustic spectroscopy of trace hazardous chemicals using quantum cascade laser”, Optics Communications 381 (2016) 271-276
273 http://vespermems.com
http://www.knowles.com/eng/Products/Microphones/SiSonic™-surface-mount-MEMS
https://www.invensense.com/products/digital/http://www.st.com/en/mems-and-sensors/mems-microphones.html?querycriteria=productId=SC1922
http://www.akustica.com/microphones.asp
https://www.cirrus.com/en/products/pro/areas/PA173.html
http://www.thinkic2.com/products/microphones/?gclid=CMup9vH56tACFdQ7gQodWmgN1w
http://www.eetimes.com/document.asp?doc_id=1324827

### US Patent Title

U.S. Pat. No. 9,462,395 Biasing circuit for a MEMS acoustic transducer with reduced start-up time
U.S. Pat. No. 9,428,380 Shielded encapsulating structure and manufacturing method thereof
U.S. Pat. No. 9,380,380 Acoustic transducer and interface circuit
U.S. Pat. No. 9,363,608 Acoustic transducer
U.S. Pat. No. 9,340,413 Integrated acoustic transducer in MEMS technology, and manufacturing process thereof
U.S. Pat. No. 9,329,610 Biasing circuit for a microelectromechanical acoustic transducer and related biasing method
U.S. Pat. No. 9,226,079 Microelectromechanical sensing structure for a capacitive acoustic transducer including an element limiting the oscillations of a membrane, and manufacturing method thereof
U.S. Pat. No. 9,096,424 Assembly of a capacitive acoustic transducer of the microelectromechanical type and package thereof
U.S. Pat. No. 9,060,227 Shielded encapsulating structure and manufacturing method thereof
U.S. Pat. No. 8,987,871 Cap for a microelectromechanical system device with electromagnetic shielding, and method of manufacture
U.S. Pat. No. 8,952,468 Acoustic sensor, acoustic transducer, microphone using the acoustic transducer, and method for manufacturing the acoustic transducer
U.S. Pat. No. 8,942,394 Integrated acoustic transducer obtained using MEMS technology, and corresponding manufacturing process
U.S. Pat. No. 8,861,753 Acoustic transducer, and microphone using the acoustic transducer
U.S. Pat. No. 8,837,754 Microelectromechanical transducer and corresponding assembly process
U.S. Pat. No. 8,836,111 Semiconductor integrated device assembly and related manufacturing process
U.S. Pat. No. 9,055,372 Acoustic transducer with gap-controlling geometry and method of manufacturing an acoustic transducer
U.S. Pat. No. 8,896,184 Piezoelectric MEMS microphone
U.S. Pat. No. 8,531,088 Piezoelectric MEMS microphone
U.S. Pat. No. 9,516,421 Acoustic sensing apparatus and method of manufacturing the same
U.S. Pat. No. 9,503,814 Differential outputs in multiple motor MEMS devices
U.S. Pat. No. 9,502,028 Acoustic activity detection apparatus and method
U.S. Pat. No. 9,500,739 Estimating and tracking multiple attributes of multiple objects from multi-sensor data
U.S. Pat. No. 9,491,539 MEMS apparatus disposed on assembly lid
U.S. Pat. No. 9,485,560 Embedded circuit in a MEMS device
U.S. Pat. No. 9,479,854 Microphone assembly with barrier to prevent contaminant infiltration
U.S. Pat. No. 9,478,234 Microphone apparatus and method with catch-up buffer
U.S. Pat. No. 9,467,785 MEMS apparatus with increased back volume
U.S. Pat. No. 9,437,188 Buffered reprocessing for multi-microphone automatic speech recognition assist
U.S. Pat. No. 9,402,131 Push-pull microphone buffer
274 Keith J. Albert et al, “Cross-Reactive Chemical Sensor Arrays”, Chem. Rev. (2000), 100, 2595-2626 including page 2598
275 Susan M. Daly et al, “Supramolecular surface plasmon resonance (SPR) sensors for organophosphorus vapor detection”, J. Mater. Chem., 2007, 17, 1809-1818
276 Katherine Knisely et al, “A MEMS AlN transducer array with flexible interconnections for use as a cochlear Implant”, AIP Conference Proceedings 1703, 100004 (2015) 277 and see:
D. R. Walt et al “Cross-Reactive Sensors”, U.S. Pat. No. 7,250,267 issued Jul. 31, 2007
K. S. Suslick “Apparatus and Method for Detecting and Identifying Microorganisms”, U.S. Pat. No. 8,852,504 issued Oct. 7, 2014
K. S. Suslick “Colorimetric Artificial Nose Having an/array of Dyes and Method for Artificial Olefaction”, U.S. Pat. No. 7,261,857 issued Aug. 28, 2007
Shannon E. Stitzel et al, “Artificial Noses”, Annu. Rev. Biomed. Eng. 2011. 13:1-25
Michael H. Abraham et al, “Solubility properties in polymers and biological media: 10. The solubility of gaseous solutes in polymers, in terms of solute-polymer interactions”, POLYMER, (1987), Vol 28 pp. 1363-1389
Molecularly Imprinted Chromogenic and Fluorogenic Receptors as Optical Sensor Matrix 2014 Dissertation (Dr. rer. nat.) im Fach Chemie eigereicht an der Mathematisch Naturwissenschaftlichen Fakult.t I der Humboldt-Universit.t zu Berlin, Vorgelegt von Dipl.-Chem., Wei, Wan
Jacqueline M. Rankin et al, “Solvatochromic sensor array for the identification of common organic solvents”, Analyst, 2015, 140, 2613 (Principal Component Analysis)
278 C J Lee et al, “alpha-Cyclodextrin-modified infrared chemical sensor for selective determination of tyrosine in biological fluids”, Anal Biochem. (2006) 359(1): 124-31
279 Rajibur Rahaman Khan et al, “Fiber-optic multi-sensor array for detection of low concentration volatile organic compounds”, Optics Express Vol. 21, No. 17, 20119 (2013); DOI: 10.1364/OE.21.020119
280 Askim, J. R., et al. (2016). “An optoelectronic nose for identification of explosives.” Chemical Science 7(1): 199-206.
Wenxuan, Z. and K. S. Suslick (2015). “Matrix Discriminant Analysis With Application to Colorimetric Sensor Array Data.” Technometrics 57(4): 524-534.
Rankin, J. M., et al. (2015). “Solvatochromic sensor array for the identification of common organic solvents.” Analyst 140(8): 2613-2617.
Li, Z., et al. (2015). “Differentiation among peroxide explosives with an optoelectronic nose.” Chemical Communications 51(83): 15312-15315.
Zhang, Y., et al. (2014). “Identification of pathogenic fungi with an optoelectronic nose.” Analyst 139(8): 1922-1928.
Askim, J. R., et al. (2013). “Optical sensor arrays for chemical sensing: the optoelectronic nose.” Chemical Society Reviews 42(22): 8649-8682.
Suslick, K. S., et al. (2011). “Colorimetric sensor array for determination and identification of toxic industrial chemicals.” Anal. Chem. 82(22): 9433-9440.
Musto, C. J., et al. (2010). “Colorimetric detection and identification of natural and artificial sweeteners.” Anal. Chem. 81(15): 6526-6533.
Feng, L., et al. (2010). “A colorimetric sensor array for identification of toxic gases below permissible exposure limits.” Chemical Communications 46(12): 2037-2039.
Lim, S. H., et al. (2009). “A colorimetric sensor array of porous pigments.” Analyst 134(12): 2453-2457.
Zhang, C., et al. (2006). “Colorimetric sensor arrays for the analysis of beers: a feasibility study.” J. Agric. Food Chem. 54(14): 4925-4931.
281 Keith J. Albert et al, “Cross-Reactive Chemical Sensor Arrays”, Chem. Rev. (2000), 100, 2595-2626 including page 2598

What is claimed is:

1. An avalanche biomimetic organodiode gas sensor for multiplying the number of electronic charge carriers produced by interaction with a single gas analyte molecule, having a Geiger mode bandwidth exceeding the neuron-firing bandwidth (<100 Hz) of an insect olfactory neuron, the sensor comprising:
an electronic carrier generating means having an outer sensor surface for generating electronic carriers in response to an organic analyte molecule at said outer surface, and an inner surface for electrical contact
an integrated circuit semiconductor avalanche diode means having an outer electronic charge carrier input layer in adherent electrical contact with said electronic carrier generating means inner electrical contact surface for successively receiving-a single electronic charge carrier transported through said carrier generating means from said outer sensor surface to said inner surface, and a fully depleted reverse biased high avalanche electric field layer epitaxially adjacent said inner surface electrical contact layer for multiplying said single electronic charge carrier by carrier avalanche through a high avalanche electric field within said avalanche electric field layer remote from said outer electron input layer to produce an avalanche Geiger mode multiplied carrier output signal in response to a single electron charge carrier transported through said carrier generating means from said outer sensor surface to said inner surface and into said high avalanche electric field layer epitaxially adjacent said inner surface electrical contact layer, wherein said carrier generating means is a thin MOX sensor material layer adherently deposited on said outer surface of said heterojunction avalanche diode means, and
avalanche output signal detection means for detecting and processing individual avalanche multiplied carrier output signals generated from successive single electronic carriers multiplied by carrier avalanche through a high avalanche electric field within said avalanche electric field layer.

2. The avalanche organodiode gas sensor in accordance with claim 1 wherein said thin MOX sensor layer is applied by Atomic Layer Deposition, pulsed laser deposition or Molecular Beam Epitaxy having a thickness of less than 100 nanometers, wherein said heterojunction avalanche diode detection means comprises means for resetting avalanche diode conductivity after avalanche, and wherein said MOX sensor layer, said heterojunction diode means and said detection means are adapted to function in Geiger mode at rates up to at least 10,000 detections per second.

3. A gas analyte sensor for direct sensing of MOX charge carriers released by interaction of analyte as to time and location of carrier release comprising:
a gas analyte detecting layer for generating electronic carriers and/or a change in transmitted interrogation light in response to reactive gas analyte contact, and an integrated circuit two dimensional CMOS or CCD imager array having pixel charge wells in direct electrical contact with said gas analyte detecting layer for transporting electronic carriers and/or changes in transmitted interrogation light generated at said gas analyte detecting layer to charge wells of immediately adjacent pixels of said imager array.

4. The gas analyte sensor in accordance with claim 3 wherein said sensor comprises a multifunction gas analyte and imaging sensor, wherein gas analyte detecting layer is at least partially light transparent, wherein said imager array comprises a plurality of at least 10,000 detector sites comprising at least 25 different sensitivities for different analytes and at least 10 detection sites of each of said different sensitivities.

5. The gas analyte sensor in accordance with claim 3 wherein said sensor comprises a means for transducing the presence of analytes at detector sites into a set of charge carriers and/or a change in transmitted interrogation light through a plasmonic resonance transmission zone of each site as a transduced analyte measurement signal, and a means for correlating the transduced analyte measurement signal from multiple, differently-sensitive detector sites to sense the presence of vapor analytes in the analyzed atmosphere, and for characterizing the sensed vapor analytes.

6. The gas analyte sensor in accordance with claim 3 wherein said gas analyte detecting layer is at least partially transparent to visible light such that said sensor is adapted to also function as a camera imager.

7. The gas analyte sensor in accordance with claim 3 wherein said gas analyte detecting layer comprises an array of a plurality of differently-sensitive MOX detection zones which are differently responsive in charge carrier generation to different analytes, and wherein said camera imaging means provided means for measuring the amount of charge carriers transported to and collected at each pixel respectively adjacent each of said differently-sensitive MOX detection zones to determine the presence or absence of analyte at each detector zone, and for correlating the responses of multiple detector sites to at least partially distinguish or identify analytes so detected.
